(19) United States
(12) Patent Application Publication
(10) Pub. No.: US 2018/0277780 A1
(43) Pub. Date: Sep. 27, 2018

(54) POLYMERIZABLE COMPOSITION AND OPTICALLY ANISTROPIC BODY USING SAME

(71) Applicant: DIC Corporation, Tokyo (JP)

(72) Inventors: Kouichi Endo, Kita-adachi-gun (JP); Kazuaki Hatsusaka, Kita-adachi-gun (JP); Mika Takasaki, Kita-adachi-gun (JP)

(73) Assignee: DIC Corporation, Tokyo (JP)

(21) Appl. No.: 15/764,755

(22) PCT Filed: Sep. 15, 2016
(86) PCT No.: PCT/JP2016/077247

§ 371 Date: Mar. 29, 2018

(30) Foreign Application Priority Data
Sep. 30, 2015 (JP) 2015-193558

(51) Int. Cl. H01L 51/50; C08L 87/00; C08L 57/00; C08F 20/10; G02F 1/1337; G02F 1/1335; G02F 1/137; G02F 1/13363

(52) U.S. Cl. CPC H01L 51/50; C08L 87/00; C08L 57/00; C08F 20/10; G02F 1/1337; G02F 2001/133638; G02F 1/137; G02F 1/13363; C08L 2203/20; G02F 2001/133738; G02F 1/133528

(57) ABSTRACT

The present invention provides a polymerizable composition having excellent solubility and high storage stability with no precipitation of crystals or the like, and provides a polymerizable composition that is unlikely to develop unevenness when a polymer of the composition is produced and is unlikely to deteriorate the appearance due to offset of the surfactant. Also provided are a polymer, optically anisotropic body, display element, light-emitting element, and the like using the polymerizable composition. Specifically, provided is a polymerizable composition a) one or more polymerizable compounds having one polymerizable group or two or more polymerizable groups that satisfy formula (I) Re(450 nm)/Re(550 nm)<1.0 (I) and b) a surfactant having a weight average molecular weight of 5000 or higher. Also provided are a polymer, optically anisotropic body, display element, light-emitting element, and the like using the polymerizable composition.

### TECHNICAL FIELD

The present invention relates to a polymer having optical anisotropy that requires various optical characteristics, a polymerizable composition which is useful as a constituent member of a film, an optically anisotropic body, a retardation film, an optical compensation film, an anti-reflective film, a lens, and a lens sheet which are formed of the polymerizable composition, a liquid crystal display element, an organic light-emitting display element, a lighting element, an optical component, a polarizing film, a colorant, a security marking, a member for emitting a laser, and a printed matter for which the polymerizable composition is used.

### BACKGROUND ART

A compound (polymerizable compound) containing a polymerizable group is used for various optical materials. For example, a uniformly aligned polymer can be prepared by aligning a polymerizable composition containing a polymerizable compound in a liquid crystal state and then polymerizing the aligned composition. Such a polymer can be used for a polarizing plate, a retardation plate, and the like which are required for a display. In many cases, a polymerizable composition containing two or more polymerizable compounds is used to satisfy optical characteristics, the polymerization rate, the solubility, the melting point, the glass transition temperature, the transparency of the polymer, the mechanical strength, the surface hardness, the heat resistance, and the light resistance to be required. At this time, it is necessary that the polymerizable compounds to be used provide excellent physical properties for the polymerizable composition without adversely affecting other characteristics.

In order to improve the viewing angle of a liquid crystal display, wavelength dispersion of the birefrinqence of a retardation film needs to be low or reversed. As materials for this purpose, various polymerizable liquid crystal compounds having reversed wavelength dispersion or low wavelength dispersion have been developed. However, precipitation of crystals occurs and storage stability is insufficient in the case where those polymerizable compounds are added to a polymerizable composition (PTL 1). Further, there is a problem in that unevenness tends to occur in the case where a base material is coated with the polymerizable composition and polymerized (PTLs 1 to 3). Unevenness occurs in brightness of a screen or the color tone thereof becomes unnatural in the case where the film in which unevenness has occurred is used for a display or the like, and this results in a problem of significant degradation of the quality of a display product. Therefore, there has been a demand for development of polymerizable liquid crystal compounds having reversed wavelength dispersion or low wavelength dispersion, which can solve such problems. In response to the problems caused by unevenness, a surfactant is usually added to the composition including the polymerizable liquid crystalline compound (PTLs 2 to 5). Further, it is also problematic that coating a polymerizable composition onto a substrate and polymerizing and putting the substrate repeatedly in contact with the polymer result in offset of the surfactant present on the coating surface into the substrate and cause appearance deterioration. Thus, optimized surfactant selection has already become a core technique to deal with the problems from the coating unevenness fore-mentioned and the offset of surfactant simultaneously.

### CITATION LIST

### Patent Literature

[PTL 1] JP-A-2008-107767

[PTL 2] JP-T-2010-522892

[PTL 3] JP-T-2013-509458

[PTL 4] WO12/147904

[PTL 5] JP-A-2009-062508

### SUMMARY OF INVENTION

### Technical Problem

An object of the present invention is to provide a polymerizable composition having excellent solubility and such a high storage stability that precipitation or the like of crystals does not caused; and a polymerizable composition capable of providing a film-like polymer, prepared by polymerizing the composition, which is unlikely to cause unevenness and poor appearance attributable to offset of a surfactant. Further, another object thereof is to provide a polymer, an optically anisotropic body, a display element, and a light-emitting element using the polymerizable composition.

### Solution to Problem

The present invention has been made to deal with the problems and completed as a result of intensive research by focusing on a polymerizable composition obtained by using a polymerizable compound having a specific structure which contains one or two or more polymerizable groups and a surfactant having a specific weight-average molecular weight.

That is, the present invention provides a polymerizable composition containing one or two or more polymerizable compounds (a) which include one polymerizable group or two or more polymerizable groups and satisfies Formula (I) and a surfactant (b) having a weight-average molecular weight of 5,000 or more.

Re(450 nm)/Re(550 nm)<1.0 (I)

(In the formula, Re(450 nm) represents an in-plane phase difference of the compound containing one polymerizable group at a wavelength of 450 nm in the case where the molecules of the compound are aligned on a substrate such that a longitudinal axis direction of each molecule is aligned substantially horizontally with respect to the substrate, and Re(550 nm) represents an in-plane phase difference of the compound containing one polymerizable group at a wavelength of 550 nm in the case where the molecules of the compound are aligned on a substrate such that a longitudinal axis direction of each molecule is aligned substantially horizontally with respect to the substrate.)

Further, the present invention provides a polymer, an optically anisotropic body, a display element, and a light-emitting element each using the polymerizable composition.

### Advantageous Effects of Invention

By using the polymerizable compound having reversed wavelength dispersion, having one polymerizable group or two or more polymerizable groups, and being formed of a specific structure together with the surfactant having a specific weight-average molecular weight according to the present invention, not only a polymerizable composition exhibiting excellent solubility and storage stability can be obtained, but also a polymer, an optically anisotropic body, and a retardation film can be obtained at a high productivity, while exhibiting excellent leveling properties for a coating surface and low offset properties of a liquid crystal coating surface.

### DESCRIPTION OF EMBODIMENTS

Hereinafter, the best mode of a polymerizable composition according to the present invention will be described. In the present invention, the “liquid crystalline compound” is intended to refer to a compound having a mesogenic skeleton, which is a rigid skeleton with which liquid crystallinity may be exhibited, and the compound alone does not need to exhibit liquid crystallinity.

Further, the polymerizable compound can be made into a polymer (or a film) by performing a polymerization treatment by means of irradiating the polymerizable composition with light such as ultraviolet rays or heating the polymerizable composition.

(Polymerizable Compound Containing One Polymerizable Group or Two or More Polymerizable Groups)

The birefrinqence of the liquid crystalline compound containing one or two or more polymerizable groups of the present invention is larger on a long wavelength side than on a short wavelength side in a visible light region. Specifically, insofar as the liquid crystalline compound containing one or two or more polymerizable group satisfies Formula (I), the birefringence thereof does not need to be larger on a long wavelength side than on a short wavelength side in an ultraviolet region or an infrared region.

Re(450 nm)/Re(550 nm)<1.0 (I)

(In the formula, Re(450 nm) represents an in-plane phase difference of the compound containing one polymerizable group at a wavelength of 450 nm in the case where the molecules of the compound are aligned on a substrate such that a longitudinal axis direction of each molecule is aligned substantially horizontally with respect to the substrate, and Re(550 nm) represents an in-plane phase difference of the compound containing one polymerizable group at a wavelength of 550 nm in the case where the molecules of the compound are aligned on a substrate such that a longitudinal axis direction of each molecule is aligned substantially horizontally with respect to the substrate.)

The compound is preferably a liquid crystalline compound. The compound preferably includes at least one liquid crystalline compound selected from the group consisting of liquid crystalline compounds represented by any one of General Formulae (1) to (7).

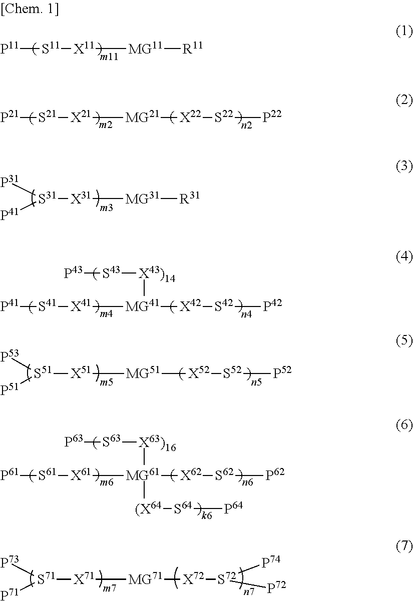

In the formulae, P¹ to P⁷⁴ represent a polymerizable group, S¹¹ to S⁷² represent a spacer group or a single bond, and in the case where plural groups are present with respect to each of S¹¹ to S⁷², these may be the same as or different from each other.

X¹¹ to X⁷² represent —O—, —S—, —OCH₂—, —CH₂O—, —CO—, —COO—, —OCO—, —CO—S—, —S—CO—, —O—CO—O—, —CO—NH—, —NH—CO—, —SCH₂—, —CH₂S—, —CF₂O—, —OCF₂—, —CF₂S—, —SCF₂—, —CH═CH—COO—, —CH═CH—OCO—, —COO—CH═CH—, —OCO—CH═CH—, —COO—CH₂CH₂—, —OCO—CH₂CH₂—, —CH₂CH₂—COO—, —CH₂CH₂—OCO—, —COO—CH₂—, —OCO—CH₂—, —CH₂—COO—, —CH₂—OCO—, —CH═CH—, —N═N—, —CH—N—N═CH—, —CF═CF—, —C≡C—, or a single bond, and in the case where plural groups are present with respect to each of X¹¹ to X⁷², these may be the same as or different from each other, provided that each of P—(S—X)— bonds does not have —O—O—.

MG¹¹ to MG⁷¹ each independently represent formula (a):

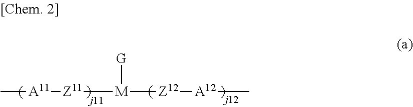

(In the formula, A¹¹ and A¹² each independently represent a 1,4-phenylene group, a 1,4-cyclohexylene group, a pyridine-2,5-diyl group, a pyrimidine-2,5-diyl group, a naphthalene-2,6-diyl group, a naphthalene-1,4-diyl group, a tetrahydrunaphthalene 2,6-diyl group, a decahydronaphthalene-2,6-diyl group, or a 1,3-dioxane-2,5-diyl group, these groups may be unsubstituted or substituted with one or more L's, and in the case where plural groups are present with respect to each of A¹¹ and A¹², these may be the same as or different from each other.

Z¹¹ and Z¹² each independently represent —O—, —S—, —OCH₂—, —CH₂O—, —CH₂CH₂—, —CO—, —COO—, —OCO—, —CO—S—, —S—CO—, —O—CO—O—, —CO—NH—, —NH—CO—, —SCH₂—, —CH₂S—, —CF₂O—, —OCF₂—, —CF₂S—, —SCF₂—, —CH═CH—COO—, —CH═CH—OCO—, —COO—CH═CH—, —OCO—CH═CH—, —COO—CH₂CH₂—, —OCO—CH₂CH₂—, —CH₂CH₂—COO—, —CH₂CH₂—OCO—, —COO—CH₂—, —OCO—CH₂—, —CH₂—COO—, —CH₂—OCO—, —CH═CH—, —N═N—, —CH═N—, —N—CH—, —CH═N—N═CH—, —CF═CF—, —C≡C—, or a single bond, and in the case where plural groups are present with respect to each of Z¹ and Z¹², these may be the same as or different from each other.

M represents a group selected from groups represented by Formula (M-1) to Formula (M-11), and these groups may be unsubstituted or substituted with one or more L¹'s:

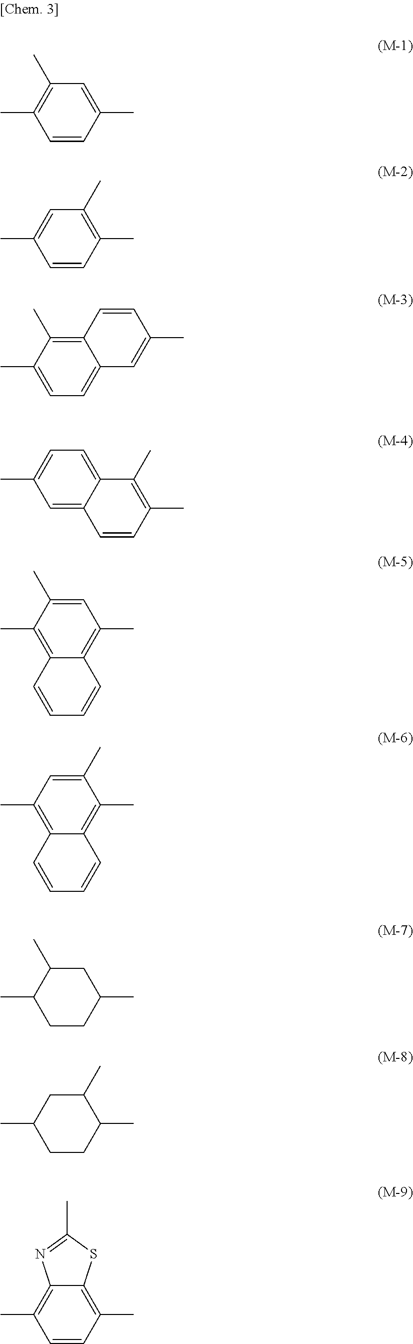

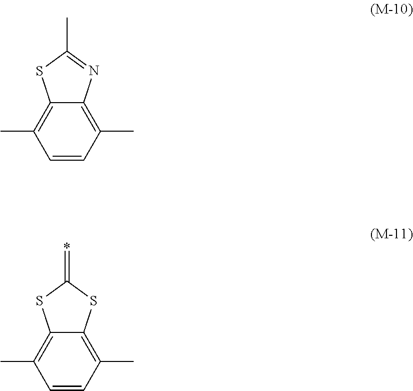

G represents a group selected from groups represented by Formula (G-1) to Formula (G-6):

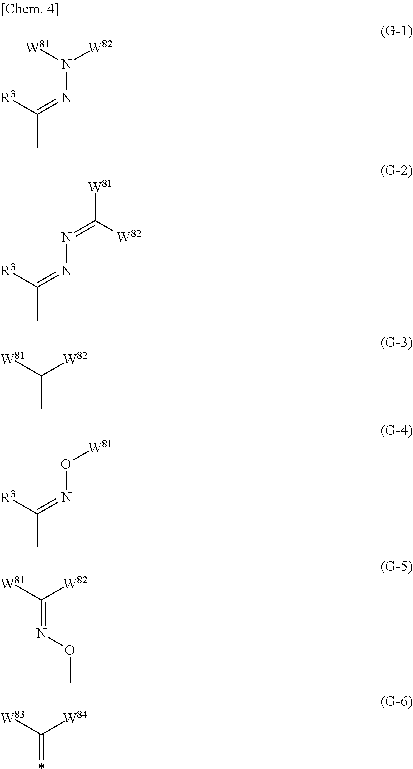

(In the formulae, R³ represents a hydrogen atom or an alkyl group having 1 to 20 carbon atoms, the alkyl group may be linear or branched, one or more of arbitrary hydrogen atoms in the alkyl group may be substituted with a fluorine atom, and one —CH₂— or two or more (—CH₂—)'s which are not adjacent to each other in the alkyl group may be each independently substituted with —O—, —S—, —CO—, —COO—, —OCO—, —CO—S—, —S—CO—, —O—CO—O—, —CO—NH—, —NH—CO—, or —C≡C—;

W⁸¹ represents a group having at least one aromatic group and 5 to 30 carbon atoms and the group may be unsubstituted or substituted with one or more L¹'s;

W⁸² represents a hydrogen atom or an alkyl group having 1 to 20 carbon atoms, the alkyl group may be linear or branched, one or more of arbitrary hydrogen atoms in the alkyl group may be substituted with a fluorine atom and/or —OH, one —CH₂— or two or more (—CH₂—)'s which are not adjacent to each other in the alkyl group may be each independently substituted with —O—, —S—, —CO—, —COO—, —OCO—, —CO—S—, —S—CO—, —O—CO—O—, —CO—NH—, —NH—CO—, —CH═CH—COO—, —CH═CH—OCO—, —COO—CH═CH—, —OCO—CH═CH—, —CH═CH—, —CF═CF—, or —C≡C—, W⁸² may have the same definition as that for W⁸¹, W⁸¹ and W⁸² may be linked to each other to form the same ring structure, or W⁸² may represent a group represented by P⁸—(S⁸—X⁸)ⱼ—, where P⁸ represents a polymerizable group, S⁸ represents a spacer group or a single bond, and in case where a plurality of S's are present, these may be the same as or different from each other, X⁸ represents —O—, —S—, —OCH₂—, —CH₂O—, —CO—, —COO—, —OCO—, —CO—S—, —S—CO—, —O—CO—O—, —CO—NH—, —NH—CO—, —SCH₂—, —CH₂S—, —CF₂O—, —OCF₂—, —CF₂S—, —SCF₂—, —CH═CH—COO—, —CH═CH—OCO—, —COO—CH═CH—, —OCO—CH═CH—, —COO—CH₂CH₂—, —OCO—CH₂CH₂—, —CH₂CH₂—COO—, —CH₂CH₂—OCO—, —COO—CH₂—, —OCO—CH₂—, —CH₂—COO—, —CH₂—OCO—, —CH═CH—, —N═N—, —CH═N—N—CH—, —CF—CF—, —C≡C—, or a single bond, and in the case where a plurality of X⁸'s are present, these may be the same as or different from each other, provided that P⁸—(S⁸—X⁸)ⱼ— bonds does not have —O—O—, and j represents an integer of 0 to 10; and

W⁸³ and W⁸⁴ each independently represent a halogen atom, a cyano group, a hydroxy group, a nitro group, a carboxyl group, a carbamoyloxy group, an amino group, a sulfamoyl group, a group having at least one aromatic group and 5 to 30 carbon atoms, an alkyl group having 1 to 20 carbon atoms, a cycloalkyl group having 3 to 20 carbon atoms, an alkenyl group having 2 to 20 carbon atoms, a cycloalkenyl group having 3 to 20 carbon atoms, an alkoxy group having 1 to 20 carbon atoms, an acyloxy group having 2 to 20 carbon atoms, or an alkylcarbonyloxy group having 2 to 20 carbon atoms, one —CH₂— or two or more (—CH₂—)'s which are not adjacent to each other in the alkyl group, the cycloalkyl group, the alkenyl group, the cycloalkenyl group, the alkoxy group, the acyloxy group, and the alkylcarbonyloxy group may be each independently substituted with —O—, —S—, —CO—, —COO—, —OCO—, —CO—S—, —S—CO—, —O—CO—O—, —CO—NH—, —NH—CO—, or —C≡C—, provided that G represents a group selected from groups represented by Formula (G-1) to Formula (G-5) in the case where M represents a group selected from groups represented by Formula (M-1) to Formula (M-10) and G represents a group represented by Formula (G-6) in the case where M represents a group represented by Formula (M-11).)

L¹ represents a fluorine atom, a chlorine atom, a bromine atom, an iodine atom, a pentafluorosulfuranyl group, a nitro group, an isocyano group, an amino group, a hydroxy group, a mercapto group, a methylamino group, a dimethylamino group, a diethylamino group, a diisopropylamino group, a trimethylsilyl group, a dimethylsilyl group, a thioisocyano group, or an alkyl group having 1 to 20 carbon atoms, and the alkyl group may be linear or branched, one or more of arbitrary hydrogen atoms may be substituted with a fluorine atom, one —CH₂— or two or more (—CH₂—)'s which are not adjacent to each other in the alkyl group may be each independently substituted with a group selected from —O—, —S—, —CO—, —COO—, —OCO—, —CO—S—, —S—CO—, —O—CO—O—, —CO—NH—, —NH—CO—, —CH═CH—COO—, —CH═CH—OCO—, —COO—CH═CH—, —OCO—CH═CH—, —CH═CH—, —CF═CF—, or —C≡C—, and in the case where a plurality of L¹'s are present in the compound, these may be the same as or different from each other.

j11 represents an integer of 1 to 5, and j12 represents an integer of 1 to 5, provided that j11+j12 represents an integer of 2 to 5.)

R¹¹ and R³¹ represent a hydrogen atom, a fluorine atom, a chlorine atom, a bromine atom, an iodine atom, a pentafluorosulfuranyl group, a cyano group, a nitro group, an isocyano group, a thioisocyano group, or an alkyl group having 1 to 20 carbon atoms, the alkyl group may be linear or branched, one or more of arbitrary hydrogen atoms in the alkyl group may be substituted with a fluorine atom, and one —CH₂— or two or more (—CH₂—)'s which are not adjacent to each other in the alkyl group may be each independently substituted with —O—, —S—, —CO—, —COO—, —OCO—, —CO—S—, —S—CO—, —O—CO—O—, —CO—NH—, —NH—CO—, or —C≡C—, m11 represents an integer of 0 to 8, and m2 to m7, n2 to n7, 14 to 16, and k6 each independently represent an integer of 0 to 5.

In General Formula (1) to General Formula (7), it is preferable that polymerizable groups P¹¹ to P⁷⁴ represent a group selected from groups represented by any of Formulae (P-1) to (P-20) and these polymerizable groups are polymerized by radical polymerization, radical addition polymerization, cationic polymerization, and anionic polymerization.

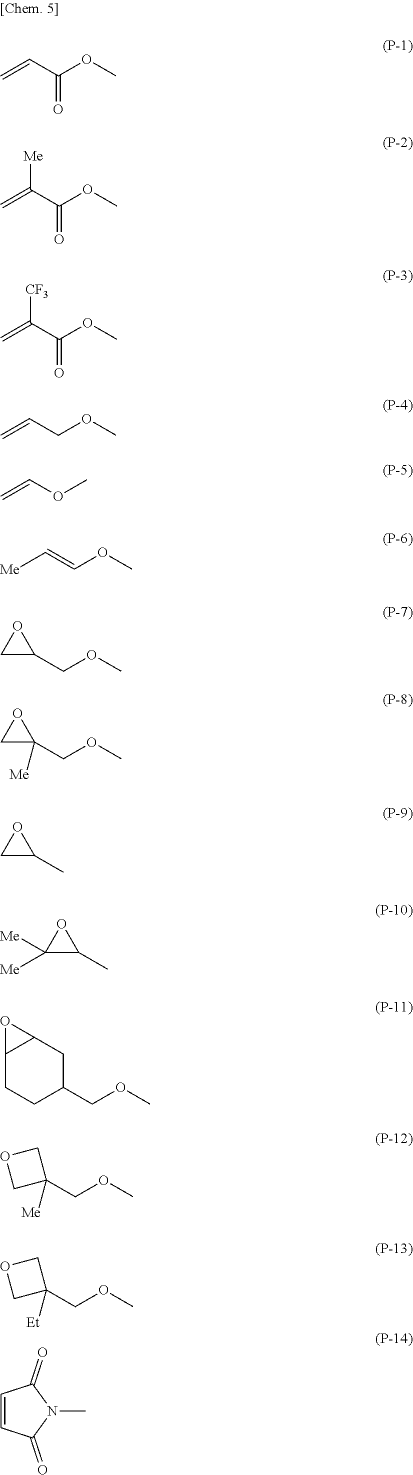

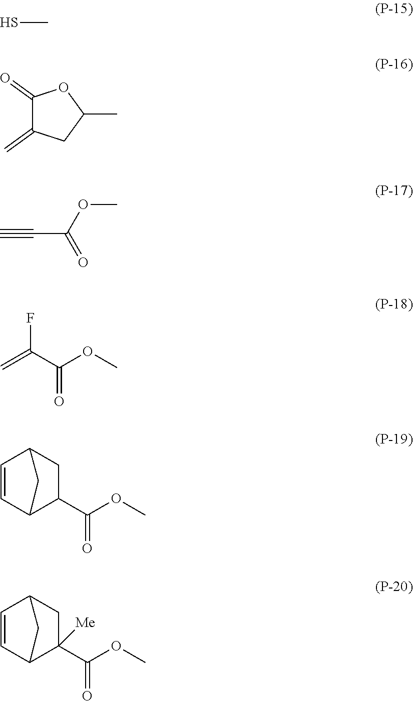

Particularly, in the case where ultraviolet polymerization is performed as a polymerization method, Formula (P-1), Formula (P-2), Formula (P-3), Formula (P-4), Formula (P-5), Formula (P-7), Formula (P-11), Formula (P-13), Formula (P-15), or Formula (P-18) is preferable, Formula (P-1), Formula (P-2), Formula (P-7), Formula (P-11), or Formula (P-13) is more preferable, Formula (P-1), Formula (P-2), or Formula (P-3) is still more preferable, and Formula (P-1) or Formula (P-2) is particularly preferable.

In General Formula (1) to General Formula (7), S¹¹ to S⁷² represent a spacer group or a single bond, and in the case where plural groups are present with respect to each of S¹¹ to S⁷², these may be the same as or different from each other. Further, it is preferable that the spacer group is an alkylene group having 1 to 20 carbon atoms in which one —CH₂— or two or more (—CH₂—)'s which are not adjacent to each other may be each independently substituted with —O—, —COO—, —OCO—, —OCO—O—, —CO—NH—, —NH—CO—, —CH═CH—, —C≡C—, or the following Formula (S-1).

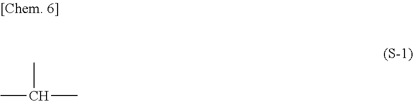

From the viewpoints of easily obtaining raw materials and ease of synthesis, it is more preferable that S¹¹ to S⁷² each independently represent a single bond or an alkylene group having 1 to 10 carbon atoms in which one —CH₂— or two or more (—CH₂—)'s which are not adjacent to each other may be each independently substituted with —O—, —COO—, or —OCO— in the case where a plurality of S's are present, these may be the same as or different from each other, it is still more preferable that S each independently represent an alkylene group having 1 to 10 carbon atoms or a single bond, and it is particularly preferable that S each independently represent an alkylene group having 1 to 8 carbon atoms, in the case where a plurality of S's are present, these may be the same as or different from each other.

In General Formula (1) to General Formula (7), X¹¹ to X⁷² represent —O—, —S—, —OCH₂—, —CH₂O—, —CO—, —COO—, —OCO—, —CO—S—, —S—CO—, —O—CO—O—, —CO—NH—, —NH—CO—, —SCH₂—, —CH₂S—, —CF₂O—, —OCF₂—, —CF₂S—, —SCF₂—, —CH═CH—COO—, —CH═CH—OCO—, —COO—CH═CH—, —OCO—CH═CH—, —COO—CH₂CH₂—, —OCO—CH₂CH₂—, —CH₂CH₂—COO—, —CH₂CH₂—OCO—, —COO—CH₂—, —OCO—CH₂—, —CH₂—COO—, —CH₂—OCO—, —CH═CH—, —N═N—, —CH═N—N═CH—, —CF═CF—, —C≡C—, or a single bond, and in the case where plural groups are present with respect to each of X¹¹ to X⁷², these may be the same as or different from each other, provided that P—(S—X)— bond does not have a —O—O— bond.

From the viewpoints of easily obtaining raw materials and ease of synthesis, it is preferable that X¹'s to X⁷²'s each independently represent —O—, —S—, —OCH₂—, —CH₂O—, —COO—, —OCO—, —CO—S—, —S—CO—, —O—CO—O—, —CO—NH—, —NH—CO—, —COO—CH₂CH₂—, —OCO—CH₂CH₂—, —CH₂CH₂—COO—, —CH₂CH₂—OCO—, or a single bond in the case where plural groups are present with respect to each of X¹¹ to X⁷² are present, these may be the same as or different from each other, it is more preferable that X¹¹'s to X⁷²'s each independently represent —O—, —OCH₂—, —CH₂O—, —COO—, —OCO—, —COO—CH₂CH₂—, —OCO—CH₂CH₂—, —CH₂CH₂—COO—, —CH₂CH₂—OCO—, or a single bond, and it is particularly preferable that X¹¹'s to X⁷²'s each independently represent —O—, —COO—, —OCO—, or a single bond, in the case where plural groups are present with respect to each of X¹¹ to X⁷², these may be the same as or different from each other.

In General Formula (1) to General Formula (7), A¹¹ and A¹² each independently represent a 1,4-phenylene group, a 1,4-cyclohexylene group, a pyridine-2,5-diyl group, a pyrimidine-2,5-diyl group, a naphthalene-2,6-diyl group, a naphthalene-1,4-diyl group, a tetrahydronaphthalene-2,6-diyl group, a decahydronaphthalene-2,6-diyl group, or a 1,3-dioxane-2,5-diyl group, these groups may be unsubstituted or substituted with one or more L's, and in the case where plural groups are present with respect to each of A¹¹ and A¹², these may be the same as or different from each other.

From the viewpoints of easily obtaining raw materials and ease of synthesis, it is preferable that Aⁿ and A^{2Z} each independently represent a 1,4-phenylene group, a 1,4-cyclohexylene group, or a naphthalene-2,6-diyl group which may be unsubstituted or substituted with one or more L1's, more preferable that A¹¹ and A¹² each independently represent a group selected from groups represented by Formula (A-1) to Formula (A-11), still more preferable that A¹¹ and A¹² each independently represent a group selected from groups represented by Formula (A-1) to Formula (A-8), and particularly preferable that A1 and A¹² each independently represent a group selected from groups represented by Formula (A-1) to Formula (A-4).

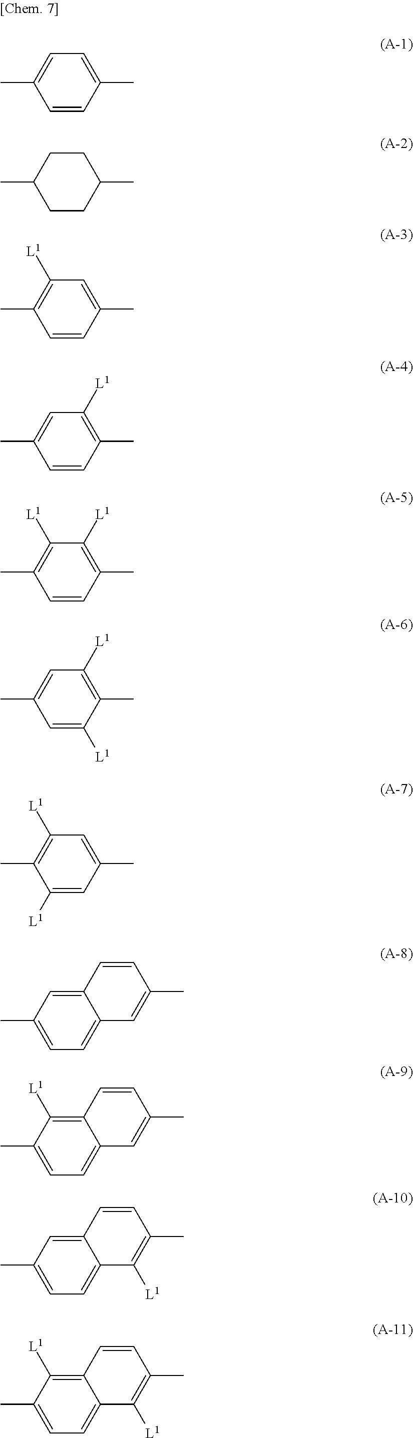

In General Formula (1) to General Formula (7), Z¹¹ and Z¹² each independently represent —O—, —S—, —OCH₂—, —CH₂O—, —CH₂CH₂—, —CO—, —COO—, —OCO—, —CO—S—, —S—CO—, —O—CO—O—, —CO—NH—, —NH—CO—, —OCO—NH—, —NH—COO—, —NH—CO—NH—, —NH—O—, —O—NH—, —SCH₂—, —CH₂S—, —CF₂O—, —OCF₂—, —CF₂S—, —SCF₂—, —CH═CH—COO—, —CH═CH—OCO—, —COO—CH═CH—, —OCO—CH═CH—, —COO—CH₂CH₂—, —OCO—CH₂CH₂—, —CH₂CH₂—COO—, —CH₂CH₂—OCO—, —COO—CH₂—, —OCO—CH₂—, —CH₂—COO—, —CH₂—OCO—, —CH═CH—, —N═N—, —CH—N—, —N—CH—, —CH═N—N═CH—, —CF═CF—, —C≡C—, or a single bond, and in the case where plural groups are present with respect to each of Z¹¹ and Z¹², these may be the same as or different from each other.

From the viewpoints of liquid crystallinity of compounds, easily obtaining raw materials, and ease of synthesis, it is preferable that Z¹¹ and Z¹² each independently represent a single bond, —OCH₂—, —CH₂O—, —COO—, —OCO—, —CF₂O—, —OCF₂—, —CH₂CH₂—, —CF₂CF₂—, —CH═CH—COO—, —CH═CH—OCO—, —COO—CH═CH—, —OCO—CH═CH—, —COO—CH₂CH₂—, —OCO—CH₂CH₂—, —CH₂CH₂—COO—, —CH₂CH₂—OCO—, —CH═CH—, —CF═CF—, —C≡C—, or a single bond, it is more preferable that Z¹¹ and Z¹² each independently represent —OCH₂—, —CH₂O—, —CH₂CH₂—, —COO—, —OCO—, —COO—CH₂CH₂—, —OCO—CH₂CH₂—, —CH₂CH₂—COO—, —CH₂CH₂—OCO—, —CH═CH—, —C≡C—, or a single bond, it is still more preferable that Z¹¹ and Z¹² each independently represent —OCH₂—, —CH₂O—, —CH₂CH₂—, —COO—, —OCO—, —COO—CH₂CH₂—, —OCO—CH₂CH₂—, —CH₂CH₂—COO—, —CH₂CH₂—OCO—, or a single bond, and it is particularly preferable that Z¹¹ and Z¹² each independently represent —OCH₂—, —CH₂O—, —CH₂CH₂—, —COO—, —OCO—, or a single bond.

In General Formula (1) to General Formula (7), M represents a group selected from groups represented by Formula (M-1) to Formula (M-11), and these groups may be unsubstituted or substituted with one or more L¹'s.

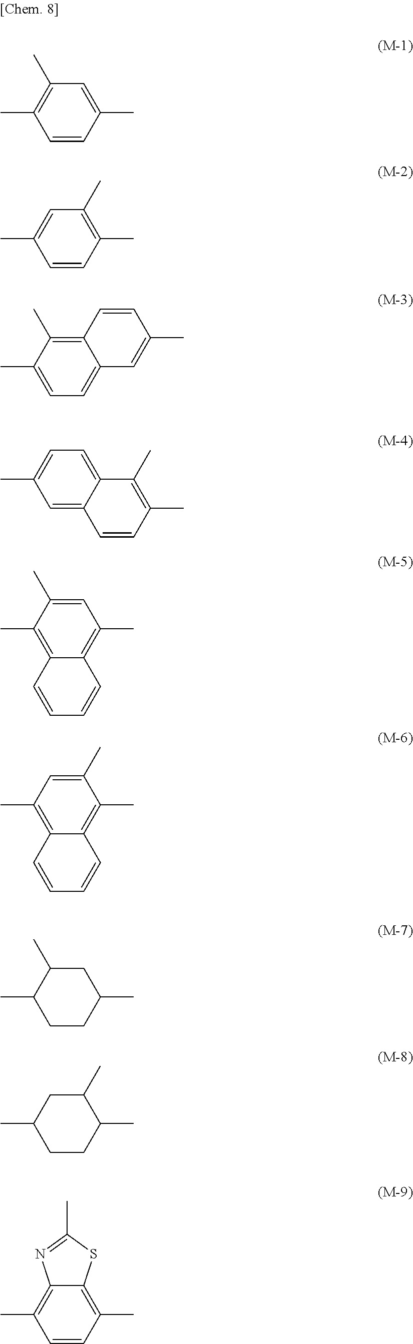

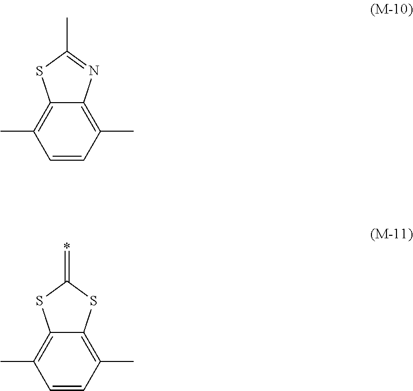

From the viewpoints of easily obtaining raw materials and ease of synthesis, it is preferable that M's each independently represent a group selected from groups represented by Formula (M-1) and Formula (M-2) which may be unsubstituted or substituted with one or more L¹'s or Formula (M-3) to Formula (M-6) which are unsubstituted, it is more preferable that M's each independently represent a group selected from groups represented by Formula (M-1) and Formula (M-2) which may be unsubstituted or substituted with one or more L¹'s, and it is particularly preferable that M's each independently represent a group selected from groups represented by Formula (M-1) and Formula (M-2) which are unsubstituted.

In General Formula (1) to General Formula (7), R¹¹ and R³¹ represent a hydrogen atom, a fluorine atom, a chlorine atom, a bromine atom, an iodine atom, a pentafluorosulfuranyl group, a cyano group, a nitro group, an isocyano group, a thioisocyano group, or a linear or branched alkyl group having 1 to 20 carbon atoms in which one —CH₂— or two or more (—CH₂—)'s which are not adjacent to each other may be each independently substituted with —O—, —S—, —CO—, —COO—, —OCO—, —CO—S—, —S—CO—, —O—CO—O—, —CO—NH—, —NH—CO—, or —C≡C—, and one or more of arbitrary hydrogen atoms in the alkyl group may be substituted with a fluorine atom. From the viewpoint of liquid crystallinity and ease of synthesis, it is preferable that R¹ represents a hydrogen atom, a fluorine atom, a chlorine atom, a cyano group, or a linear or branched alkyl group having 1 to 12 carbon atoms in which one —CH₂— or two or more (—CH₂—)'s which are not adjacent to each other may be each independently substituted with —O—, —COO—, —OCO—, or —O—CO—O—, it is more preferable that R¹ and R³¹ represent a hydrogen atom, a fluorine atom, a chlorine atom, a cyano group, or a linear alkyl group or a linear alkoxy group having 1 to 12 carbon atoms, and it is particularly preferable that R¹ represents a linear alkyl group or a linear alkoxy group having 1 to 12 carbon atoms.

In General Formula (1) to General Formula (7), G represents a group selected from groups represented by Formula (G-1) to Formula (G-6).

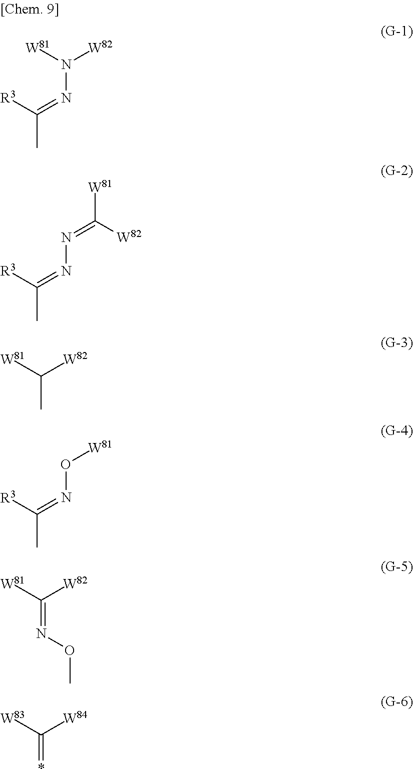

In the formulae, R³ represents a hydrogen atom or an alkyl group having 1 to 20 carbon atoms, the alkyl group may be linear or branched, one or more of arbitrary hydrogen atoms in the alkyl group may be substituted with a fluorine atom, and one —CH₂— or two or more (—CH₂—)'s which are not adjacent to each other in the alkyl group may be each independently substituted with —O—, —S—, —CO—, —COO—, —OCO—, —CO—S—, —S—CO—, —O—CO—O—, —CO—NH—, —NH—CO—, or —C≡C—,

W⁸¹ represents a group having at least one aromatic group and 5 to 30 carbon atoms and the group may be unsubstituted or substituted with one or more L¹'s, and

W⁸² represents a hydrogen atom or an alkyl group having 1 to 20 carbon atoms, the alkyl group may be linear or branched, one or more of arbitrary hydrogen atoms in the alkyl group may be substituted with a fluorine atom and/or —OH, and one —CH₂— or two or more (—CH₂—)'s which are not adjacent to each other in the alkyl group may be each independently substituted with —O—, —S—, —CO—, —COO—, —OCO—, —CO—S—, —S—CO—, —O—CO—O—, —CO—NH—, —NH—CO—, —CH═CH—COO—, —CH═CH—OCO—, —COO—CH═CH—, —OCO—CH═CH—, —CH═CH—, —CF═CF—, or —C≡C—, W⁸² may have the same definition as that for W⁸¹, W⁸¹ and W⁸² may be linked to each other to form a ring structure, or W⁸² may represent a group represented by P⁸—(S⁸—X⁸)ⱼ—, where P⁸ represents a polymerizable group, S⁸ represents a spacer group or a single bond, and in case where a plurality of S⁸'s are present, these may be the same as or different from each other, X⁸ represents —O—, —S—, —OCH₂—, —CH₂O—, —CO—, —COO—, —OCO—, —CO—S—, —S—CO—, —O—CO—O—, —CO—NH—, —NH—CO—, —SCH₂—, —CH₂S—, —CF₂O—, —OCF₂—, —CF₂S—, —SCF₂—, —CH═CH—COO—, —CH═CH—OCO—, —COO—CH═CH—, —OCO—CH═CH—, —COO—CH₂CH₂—, —OCO—CH₂CH₂—, —CH₂CH₂—COO—, —CH₂CH₂—OCO—, —COO—CH₂—, —OCO—CH₂—, —CH₂—COO—, —CH₂—OCO—, —CH═CH—, —N═N—, —CH—N—N—CH—, —CF═CF—, —C≡C—, or a single bond, and in the case where a plurality of X's are present, these may be the same as or different from each other, provided that P⁸—(S⁸—X⁸)ⱼ— bonds does not have —O—O—, and j represents an integer of 0 to 10.

The aromatic group included in the group as W⁸¹ may be an aromatic hydrocarbon group or an aromatic heterocyclic group and the group may include both of an aromatic hydrocarbon group and an aromatic heterocyclic group. These aromatic groups may be bonded to each other through a single bond or a linking group (—OCO—, —COO—, —CO—, —O—) and may form a fused ring. Further, in addition to an aromatic group, the group as W⁸¹ may further have an acyclic structure and/or a cyclic structure other than aromatic group. From the viewpoints of easily obtaining raw materials and ease of synthesis, the aromatic group included in the group as W⁸¹ is a group represented by any of Formulae (W-1) to (W-19) which may be unsubstituted or substituted with one or more L¹'s.

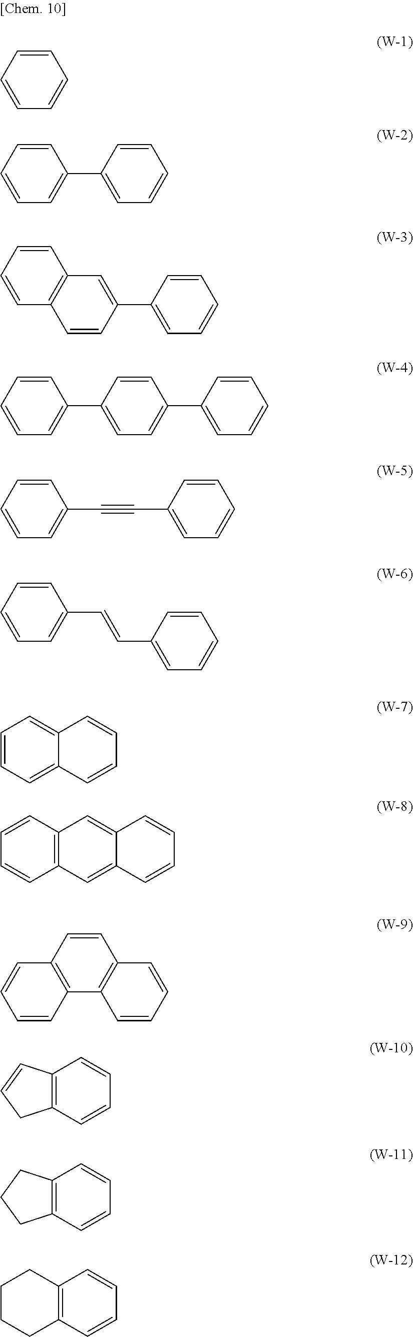

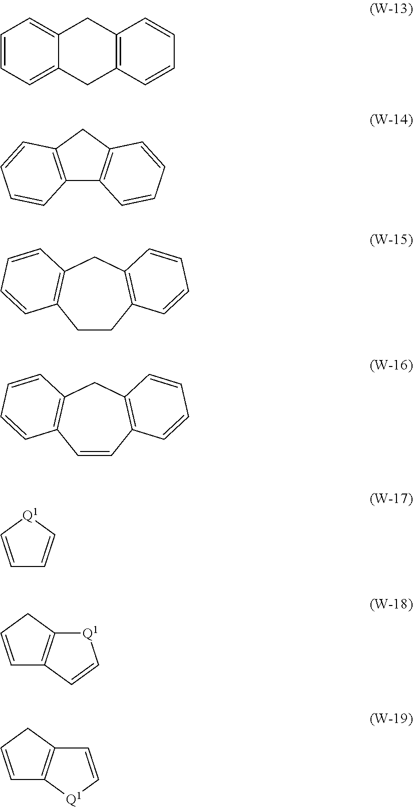

(In the formulae, these groups may have a binding site at an arbitrary position, a group formed by linking two or more aromatic groups selected from these groups with a single bond may be formed, and Q¹ represents —O—, —S—, —NR⁴— (where R⁴ represents a hydrogen atom or an alkyl group having 1 to 8 carbon atoms), or —CO—. (—CH═)'s in these aromatic groups may be each independently substituted with —N—, (—CH₂—)'s may be each independently substituted with —O—, —S—, —NR⁴— (where R⁴ represents a hydrogen atom or an alkyl group having 1 to 8 carbon atoms), or —CO—, provided that a —O—O— bond is not formed.) It is preferable that the group represented by Formula (W-1) is a group selected from groups represented by Formula (W-1-1) to Formula (W-1-8) which may be unsubstituted or substituted with one or more L¹'s.

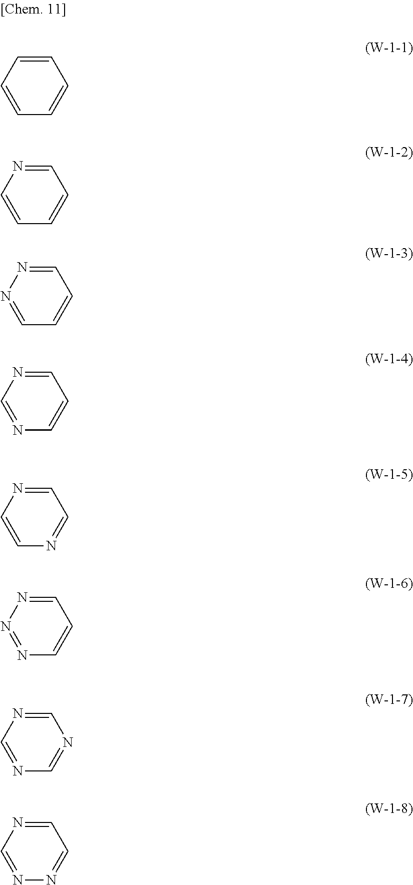

(In the formulae, these groups may have a binding site at an arbitrary position.) It is preferable that the group represented by Formula (W-7) is a group selected from groups represented by Formula (W-7-1) to Formula (W-7-7) which may be unsubstituted or substituted with one or more L¹'s.

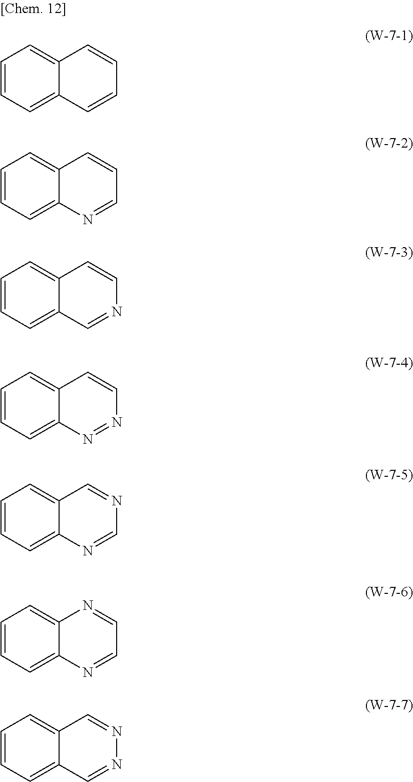

(In the formulae, these groups may have a binding site at an arbitrary position.) It is preferable that the group represented by Formula (W-10) is a group selected from groups represented by Formula (W-10-1) to Formula (W-10-8) which may be unsubstituted or substituted with one or more L¹'s.

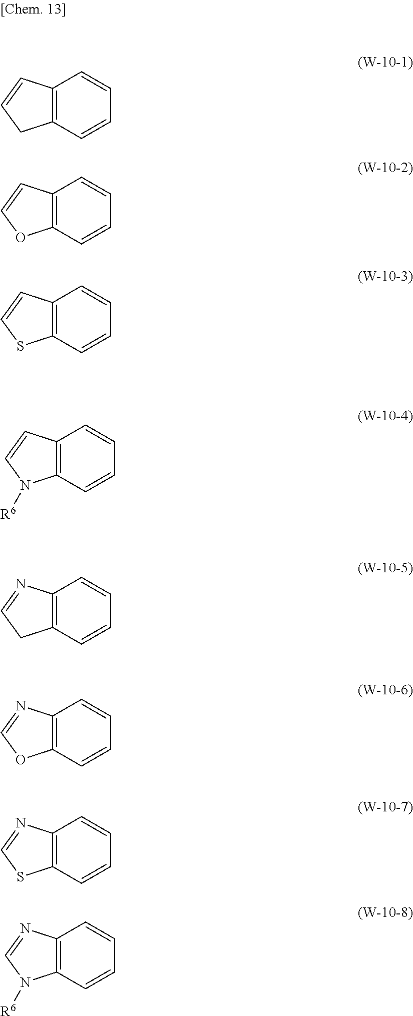

(In the formulae, these groups may have a binding site at an arbitrary position and R⁶ represents a hydrogen atom or an alkyl group having 1 to 8 carbon atoms.) It is preferable that the group represented by Formula (W-11) is a group selected from groups represented by Formula (W-11-1) to Formula (W-11-13) which may be unsubstituted or substituted with one or more L¹'s.

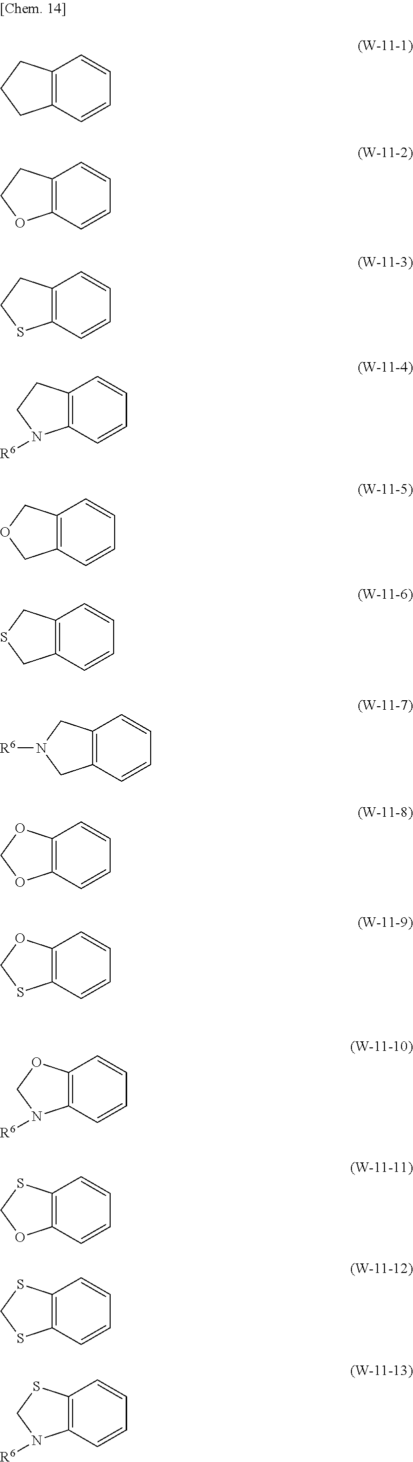

(In the formulae, these groups may have a binding site at an arbitrary position and R⁶ represents a hydrogen atom or an alkyl group having 1 to 8 carbon atoms.) It is preferable that the group represented by Formula (W-12) is a group selected from groups represented by Formula (W-12-1) to Formula (W-12-19) which may be unsubstituted or substituted with one or more L¹'s.

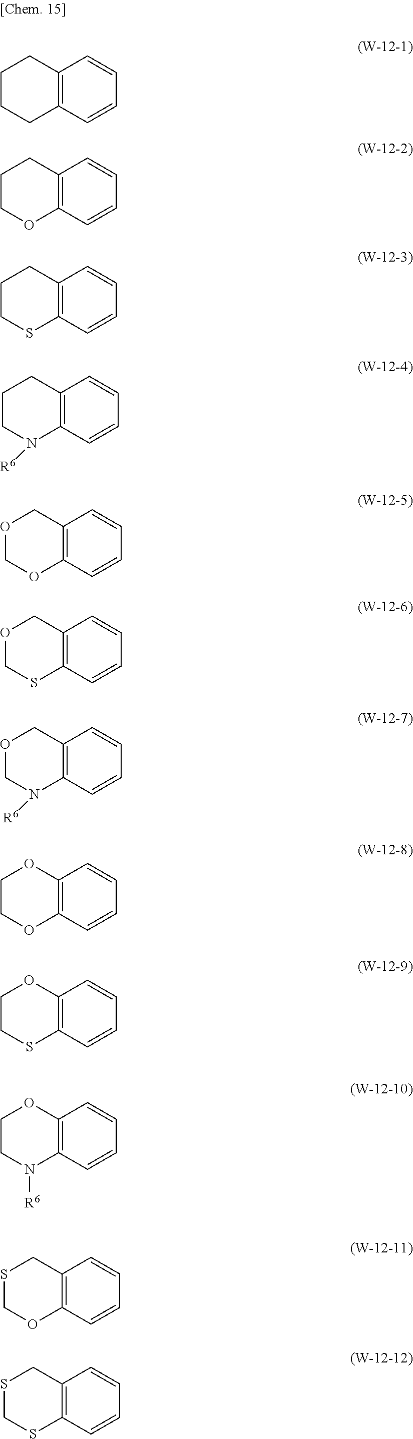

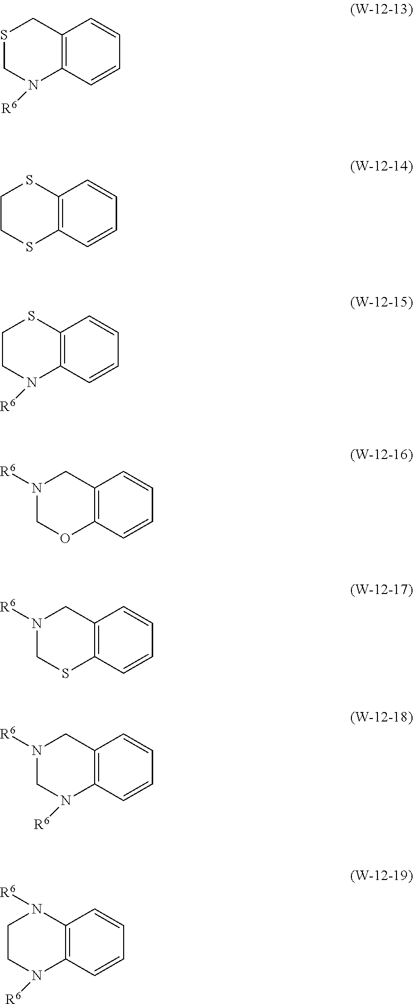

(In the formulae, these groups may have a binding site at an arbitrary position, R⁶ represents a hydrogen atom or an alkyl group having 1 to 8 carbon atoms, and in the case where, a plurality of R⁶ are present, these may be the same as or different from each other.) It is preferable that the group represented by Formula (W-13) is a group selected from groups represented by Formula (W-13-1) to Formula (W-13-10) which may be unsubstituted or substituted with one or more L¹'s.

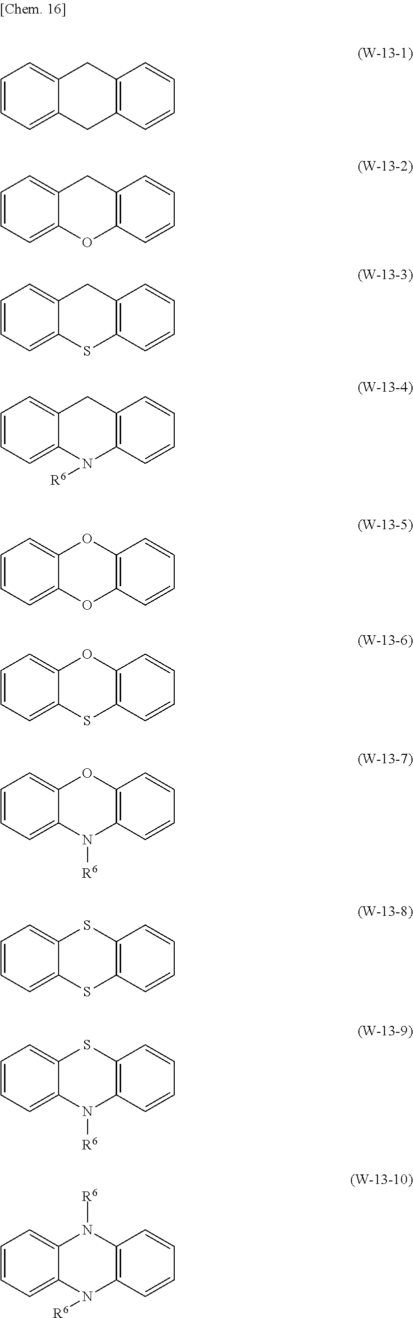

(In the formulae, these groups may have a binding site at an arbitrary position and R⁶ represents a hydrogen atom or an alkyl group having 1 to 8 carbon atoms, and in the case where, a plurality of R⁶ are present, these may be the same as or different from each other.) It is preferable that the group represented by Formula (W-14) is a group selected from groups represented by Formula (W-14-1) to Formula (W-14-4) which may be unsubstituted or substituted with one or more L1's.

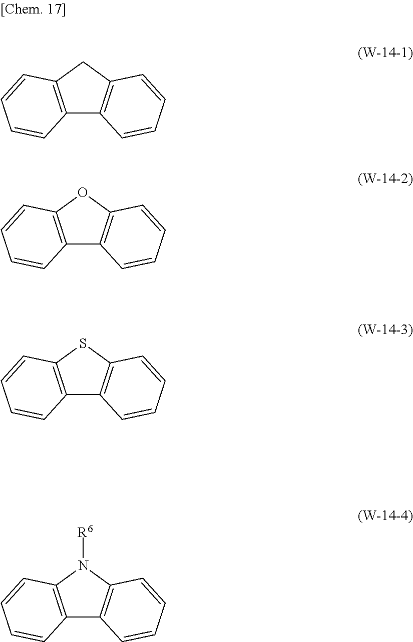

(In the formulae, these groups may have a binding site at an arbitrary position and R⁶ represents a hydrogen atom or an alkyl group having 1 to 8 carbon atoms.) It is preferable that the group represented by Formula (W-15) is a group selected from groups represented by Formula (W-15-1) to Formula (W-15-18) which may be unsubstituted or substituted with one or more L¹'s.

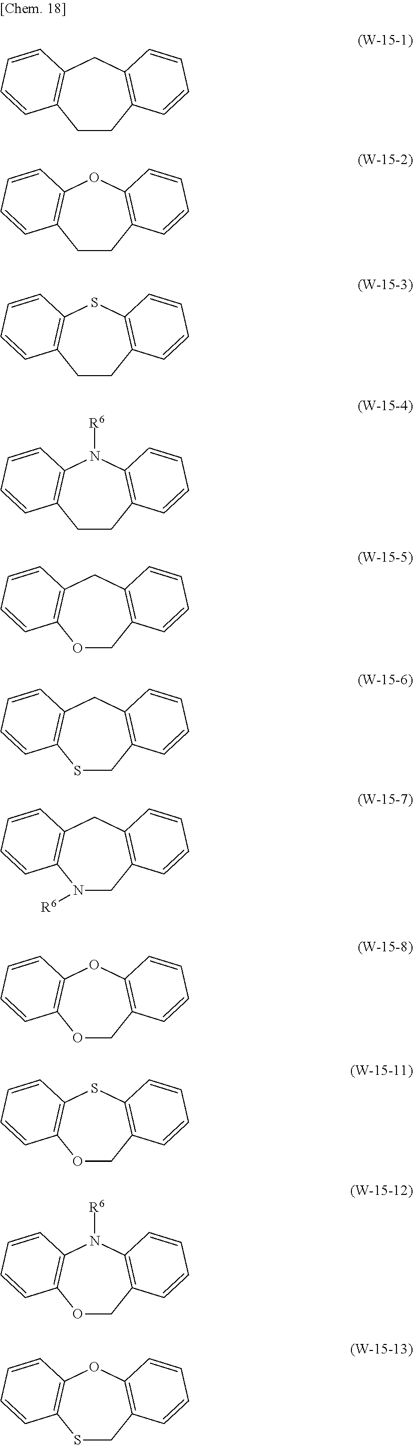

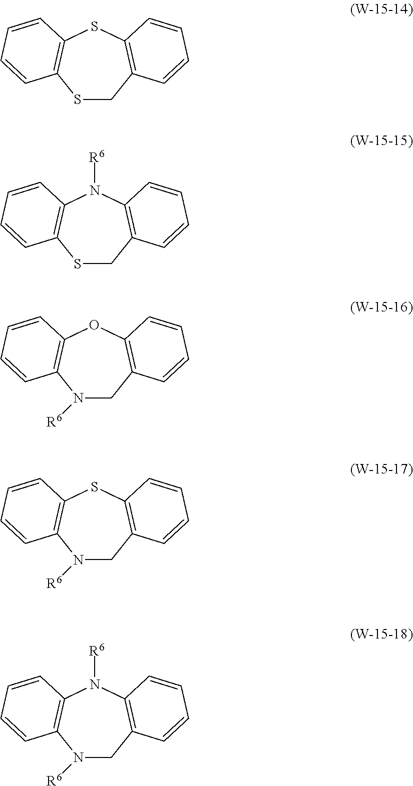

(In the formulae, these groups may have a binding site at an arbitrary position and R⁶ represents a hydrogen atom or an alkyl group having 1 to 8 carbon atoms.) It is preferable that the group represented by Formula (W-16) is a group selected from groups represented by Formula (W-16-1) to Formula (W-16-4) which may be unsubstituted or substituted with one or more L¹'s.

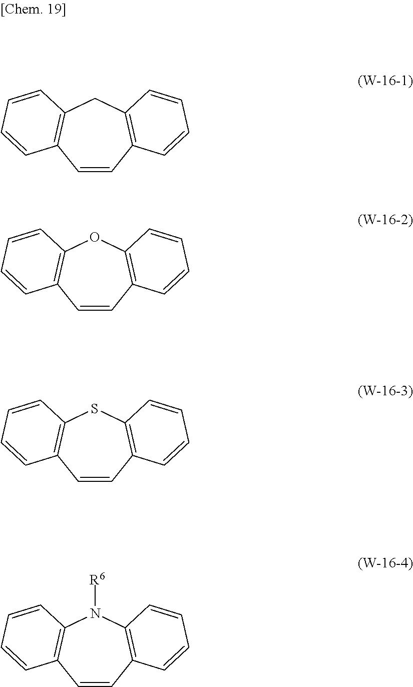

(In the formulae, these groups may have a binding site at an arbitrary position and R⁶ represents a hydrogen atom or an alkyl group having 1 to 8 carbon atoms.) It is preferable that the group represented by Formula (W-17) is a group selected from groups represented by Formulae (W-17-1) to (W-17-6) which may be unsubstituted or substituted with one or more L¹'s.

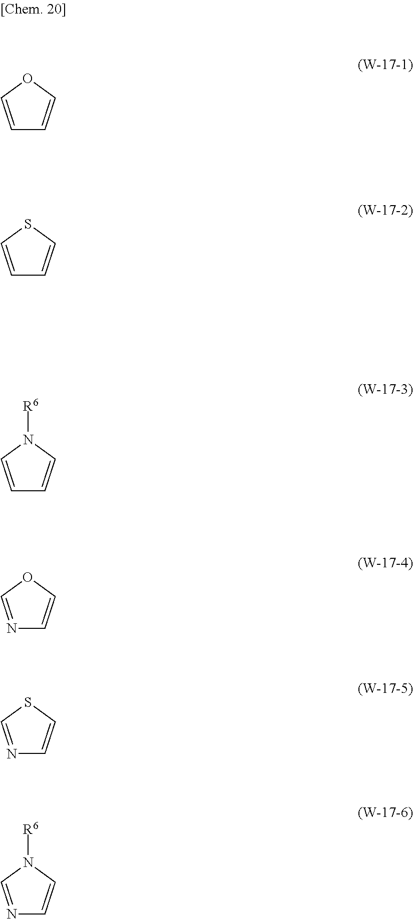

(In the formulae, these groups may have a binding site at an arbitrary position and R⁶ represents a hydrogen atom or an alkyl group having 1 to 8 carbon atoms.) It is preferable that the group represented by Formula (W-18) is a group selected from groups represented by Formula (W-18-1) to Formula (W-18-6) which may be unsubstituted or substituted with one or more L¹'s.

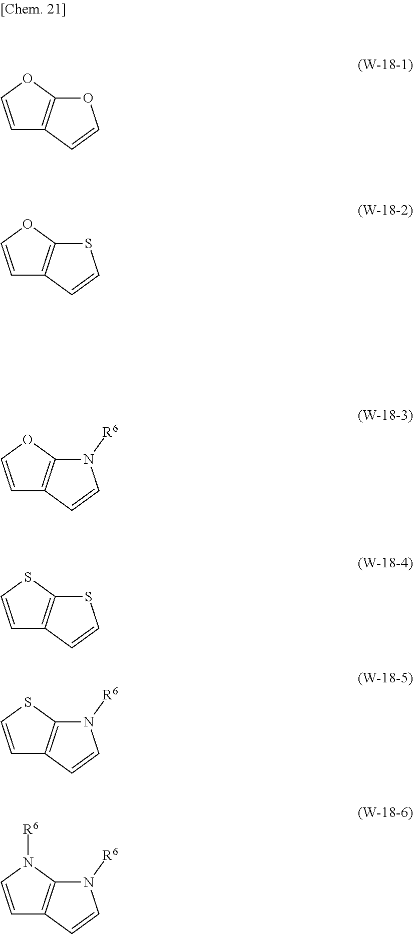

(In the formulae, these groups may have a binding site at an arbitrary position and R⁶ represents a hydrogen atom or an alkyl group having 1 to 8 carbon atoms, and in the case where a plurality of R⁶'s are present, these may be the same as or different from each other.) It is preferable that the group represented by Formula (W-19) is a group selected from groups represented by Formula (W-19-1) to Formula (W-19-9) which may be unsubstituted or substituted with one or more L¹'s.

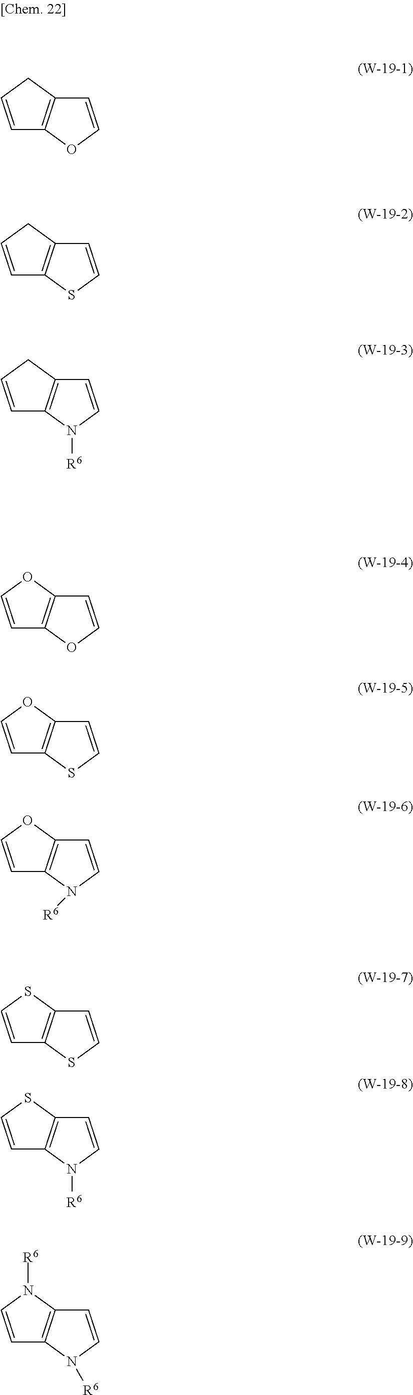

(In the formulae, these groups may have a binding site at an arbitrary position and R⁶ represents a hydrogen atom or an alkyl group having 1 to 8 carbon atoms, and in the case where a plurality of R⁶'s are present, these may be the same as or different from each other.) It is more preferable that the aromatic group included in the group represented by W⁸¹ is a group selected from groups represented by Formulae (W-1-1), (W-7-1), (W-7-2), (W-7-7), (W-8), (W-10-6), (W-10-7), (W-10-8), (W-11-8), (W-11-9), (W-11-10), (W-11-11), (W-11-12), and (W-11-13) which may be unsubstituted or substituted with one or more L¹'s and it is particularly preferable that the aromatic group included in the group represented by W⁸¹ is a group selected from groups represented by Formulae (W-1-1), (W-7-1), (W-7-2), (W-7-7), (W-10-6), (W-10-7), and (W-10-8) which may be unsubstituted or substituted with one or more L¹'s. Further, it is particularly preferable that W⁸¹ represents a group selected from groups represented by Formulae (W-a-1) to (W-a-6).

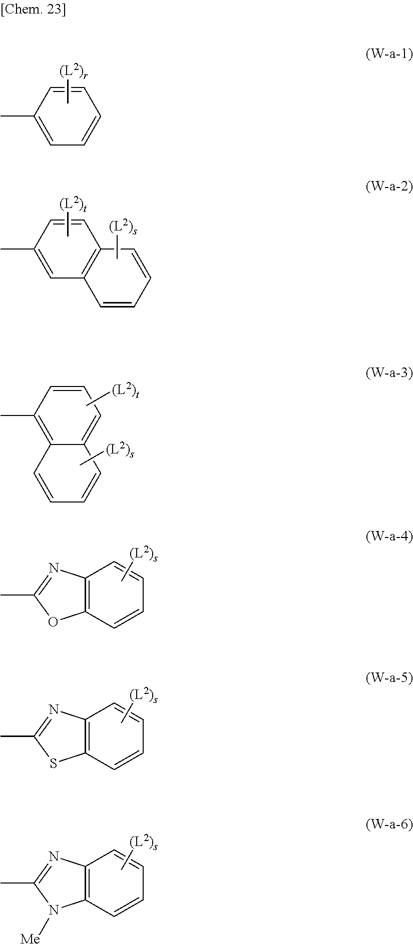

(In the formulae, r represents an integer of 0 to 5, s represents an integer of 0 to 4, and t represents an integer of 0 to 3.)

W⁸² represents a hydrogen atom or a linear or branched alkyl group having 1 to 20 carbon atoms in which one —CH₂— or two or more (—CH₂—)'s which are not adjacent to each other may be each independently substituted with —O—, —S—, —CO—, —COO—, —OCO—, —CO—S—, —S—CO—, —O—CO—O—, —CO—NH—, —NH—CO—, —CH═CH—COO—, —CH═CH—OCO—, —COO—CH═CH—, —OCO—CH═CH—, —CH═CH—, —CF—CF—, or —C≡C—, one or more of arbitrary hydrogen atoms in the alkyl group may be substituted with a fluorine atom, W⁸² may have the same definition as that for W⁸¹, W⁸¹ and W⁸² may be linked to each other to form a ring structure.

From the viewpoints of easily obtaining raw materials and ease of synthesis, it is preferable that W⁸² represents a hydrogen atom or a linear or branched alkyl group having 1 to 20 carbon atoms in which one or more of arbitrary hydrogen atoms may be substituted with a fluorine atom and/or —OH and one —CH₂— or two or more (—CH₂—)'s which are not adjacent to each other may be each independently substituted with —O—, —CO—, —COO—, —OCO—, —O—CO—O—, —CH═CH—COO—, —CH═CH—OCO—, —COO—CH═CH—, —OCO—CH═CH—, —CH═CH—, —CF═CF—, or —C≡C—, or W⁸² represents a group represented by P⁸—(S⁸—X⁸)ⱼ—, it is more preferable that W⁸² represents a hydrogen atom or a linear or branched alkyl group having 1 to 20 carbon atoms in which one or more of arbitrary hydrogen atoms may be substituted with a fluorine atom and one —CH₂— or two or more (—CH₂—)'s which are not adjacent to each other may be each independently substituted with —O—, —CO—, —COO—, or —OCO—, or W⁸² represents a group represented by P⁸—(S⁸—X⁸)ⱼ—, it is still more preferable that W⁸² represents a hydrogen atom or a linear alkyl group having 1 to 12 carbon atoms in which one —CH₂— or two or more (—CH₂—)'s which are not adjacent to each other may be each independently substituted with —O—, or W⁸² represents a group represented by P⁸—(S⁸—X⁸)ⱼ—, and it is still more preferable that W⁸² represents a hydrogen atom or a linear alkyl group having 1 to 12 carbon atoms in which one —CH₂— or two or more (—CH₂—)'s which are not adjacent to each other may be each independently substituted with —O—, or W⁸² represents a group represented by P⁸—(S⁸—X⁸)ⱼ—.

Further, in the case where W⁸² represents a group having at least one aromatic group and 2 to 30 carbon atoms, W² preferably represents a group selected from Formula (W-1) to Formula (W-18). In that case, a more preferable structure is the same as the above.

Further, in the case where W⁸² is a group represented by P⁸—(S⁸—X⁸)ⱼ—, preferable structures of groups represented by P⁸, S⁸, and X⁸ are the same as those of the groups represented by P¹¹ to P⁷⁴, S¹¹ to S⁷², and X¹¹ to X⁷², respectively. j is preferably an integer of 0 to 3, and more preferably 0 or 1.

A terminal group of W⁸² may be a OH group.

Further, in the case where W⁸¹ and W⁸² are linked to each other to form a ring structure, it is preferable that the cyclic group represented by —NW⁸¹W⁸² is a group selected from groups represented by Formulae (W-b-1) to (W-b-42) which may be unsubstituted or substituted with one or more L¹'s.

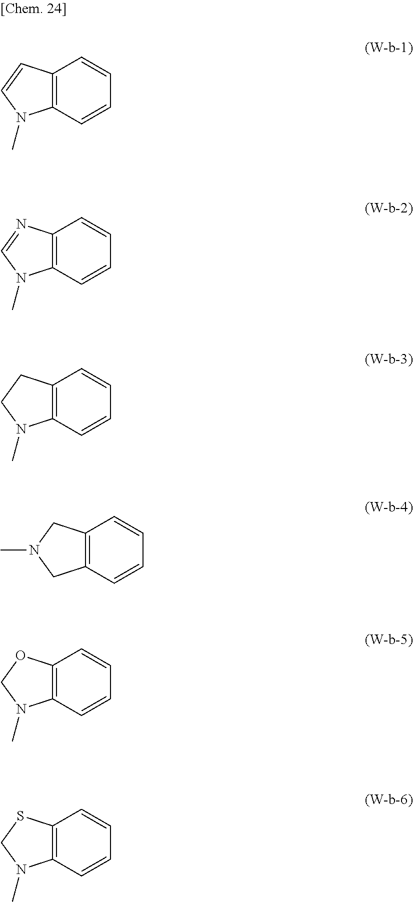

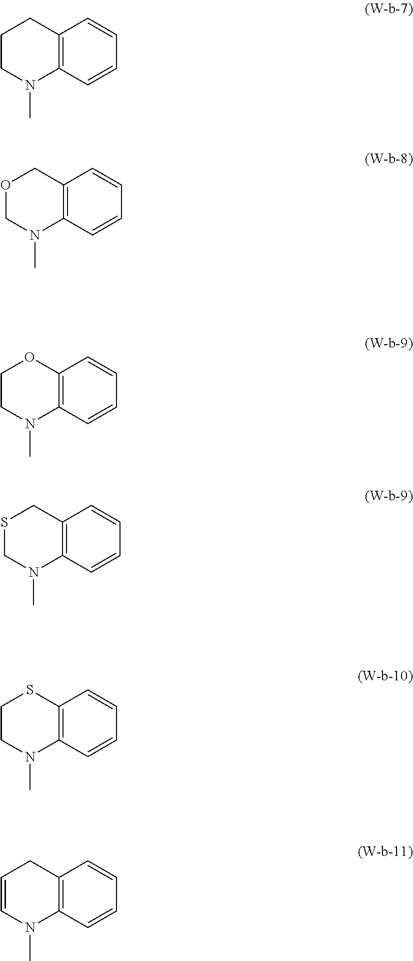

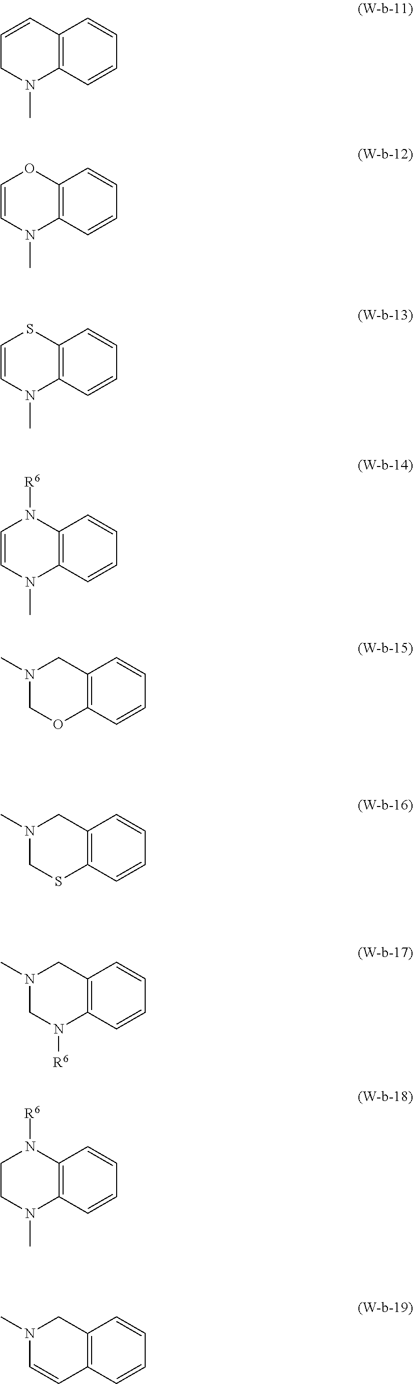

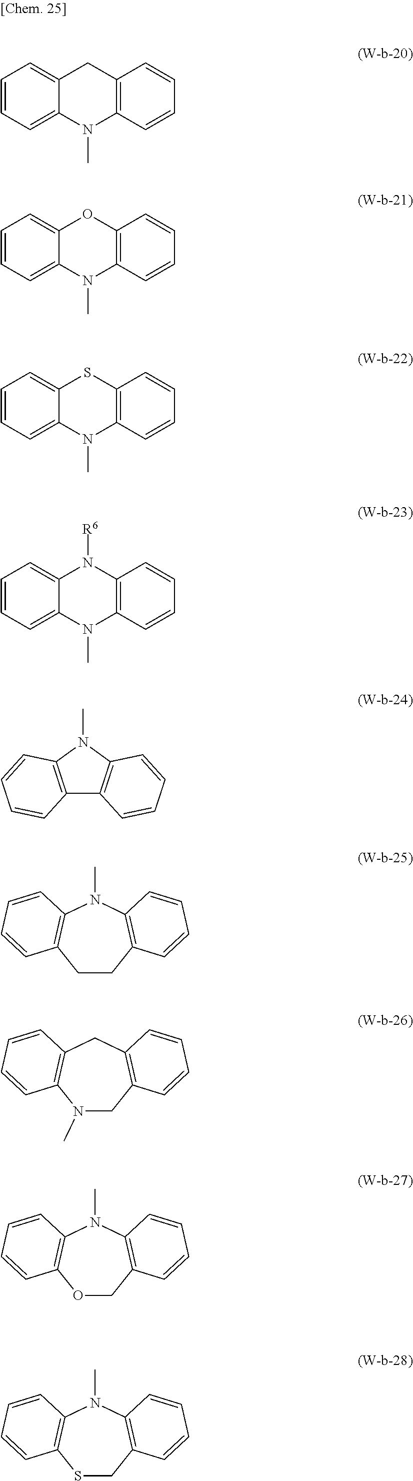

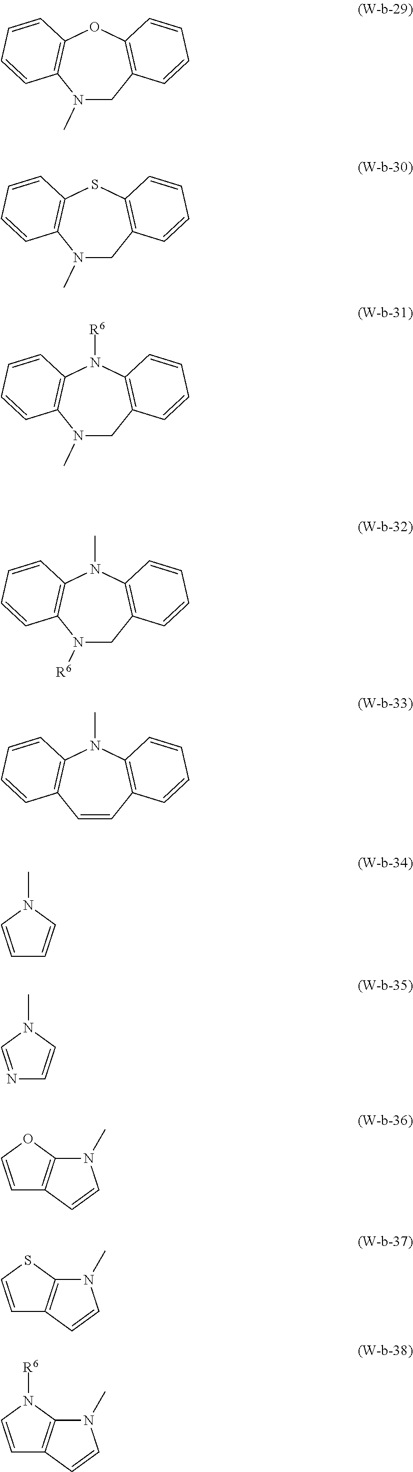

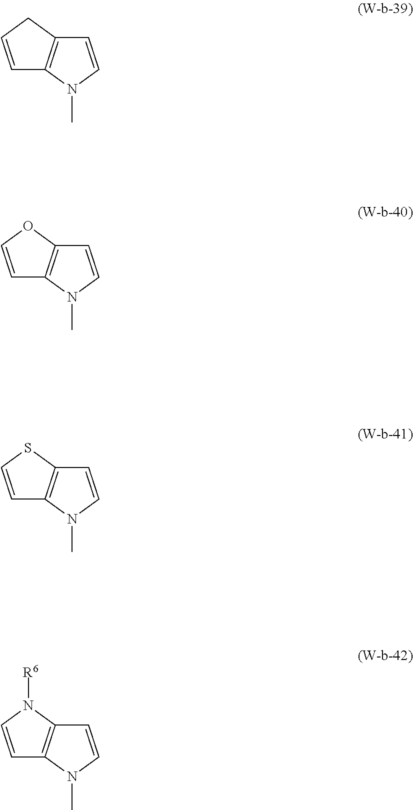

(In the formulae, R⁶ represents a hydrogen atom or an alkyl group having 1 to 8 carbon atoms.) From the viewpoints of easily obtaining raw materials and ease of synthesis, it is particularly preferable that the cyclic group represented by —NW⁸¹W⁸² is a group selected from groups represented by Formulae (W-b-20), (W-b-21), (W-b-22), (W-b-23), (W-b-24), (W-b-25), and (W-b-33) which may be unsubstituted or substituted with one or more L¹'s. Further, it is preferable that the cyclic group represented by ═CW⁸¹W⁸² is a group selected from groups represented by Formulae (W-c-1) to (W-c-81) which may be unsubstituted or substituted with one or more L¹'s.

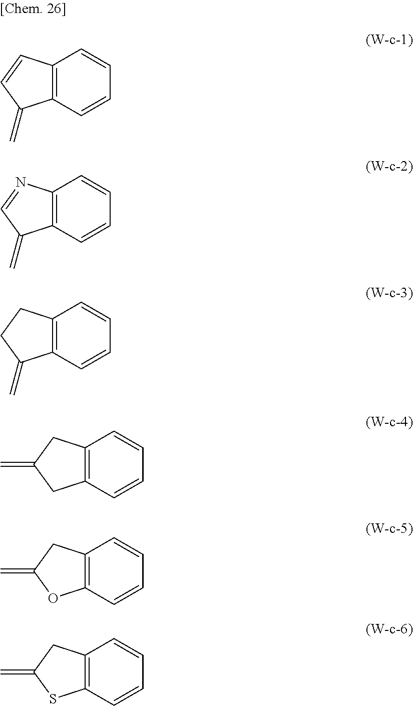

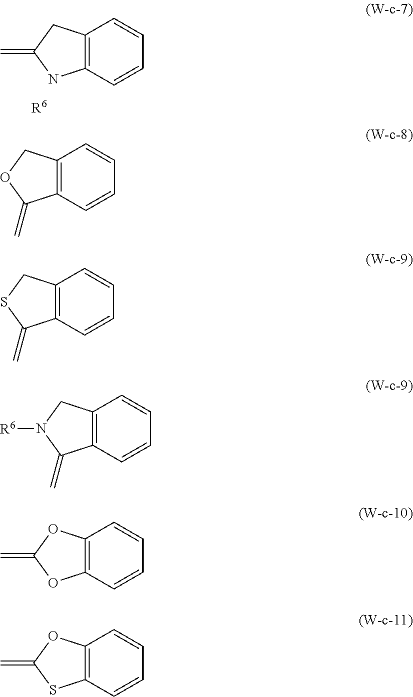

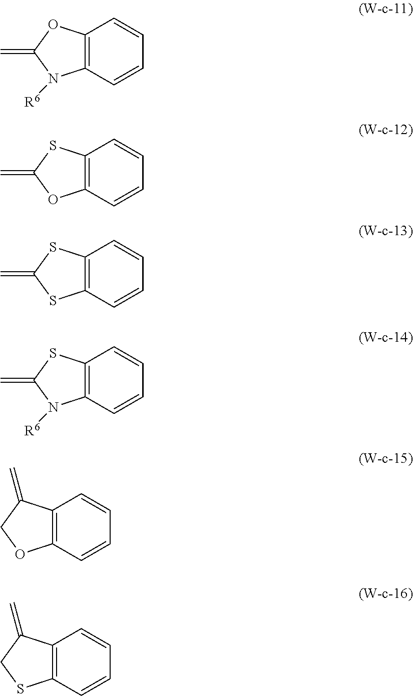

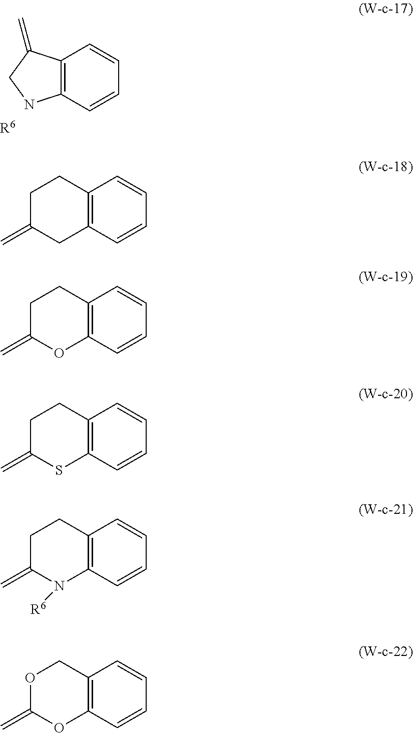

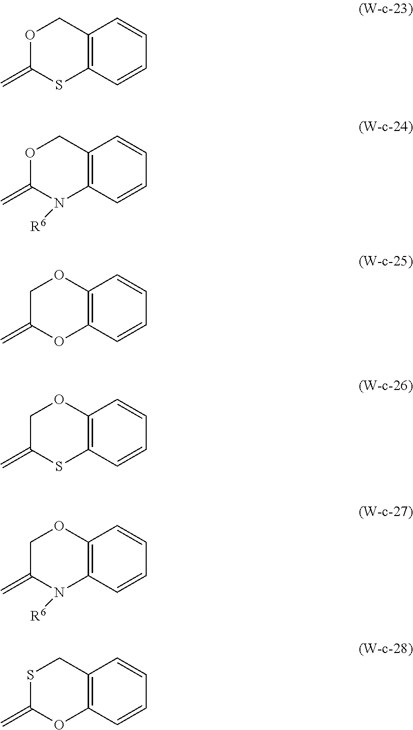

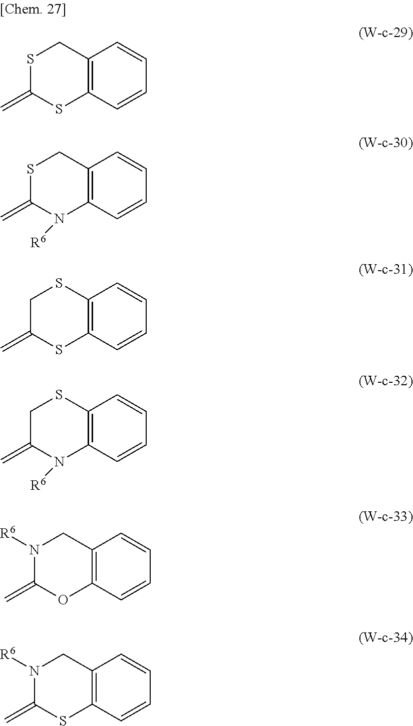

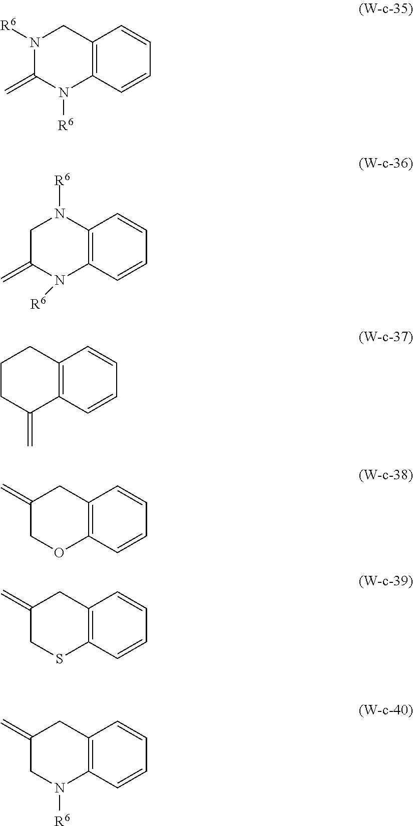

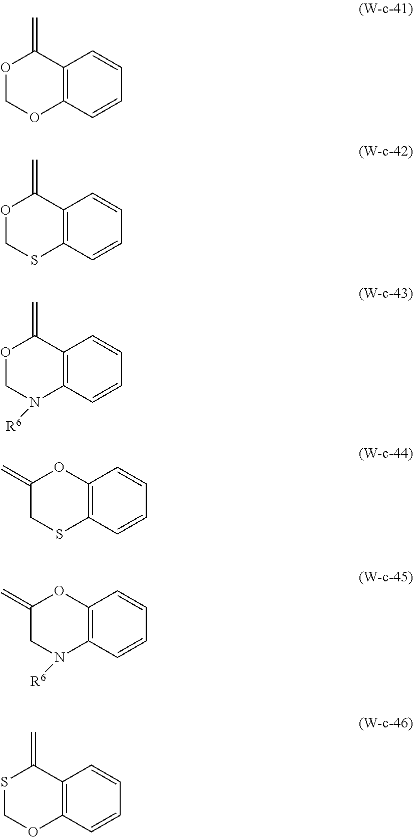

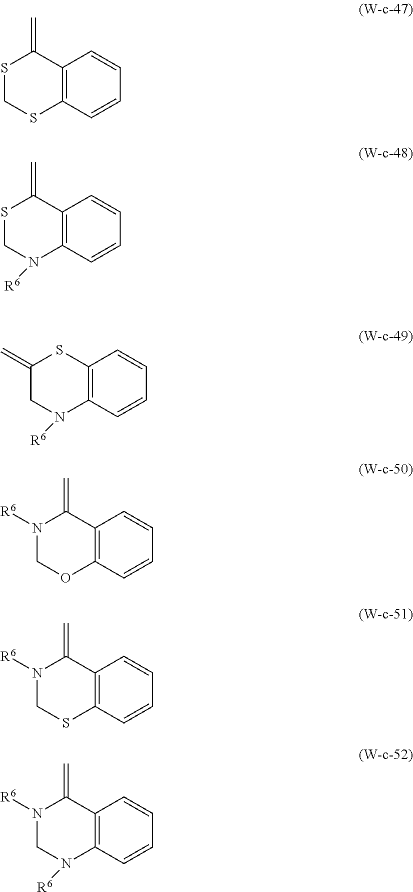

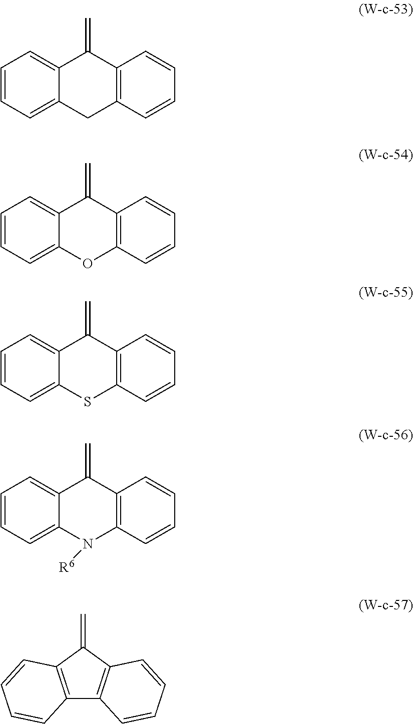

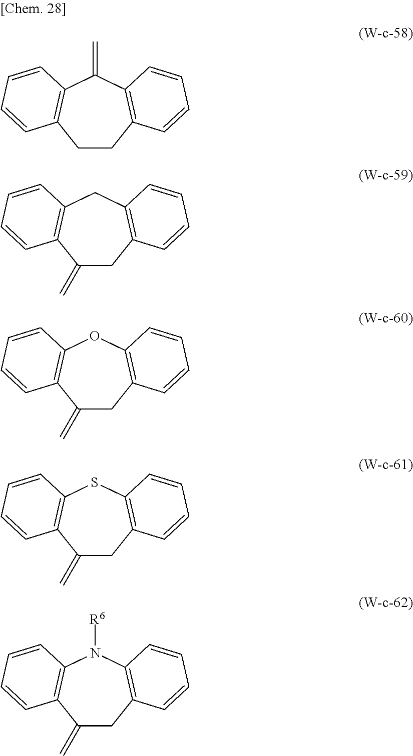

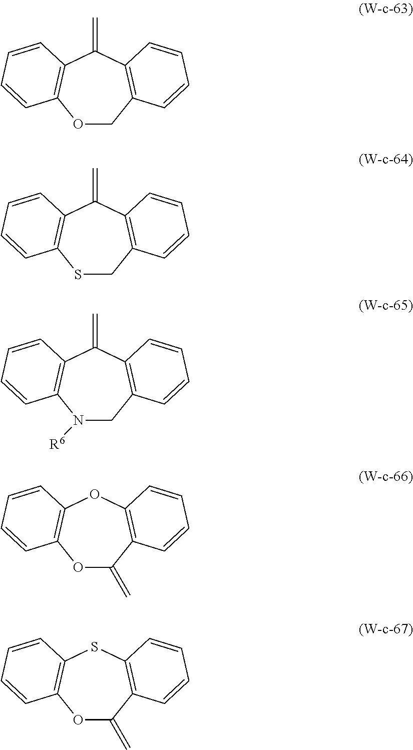

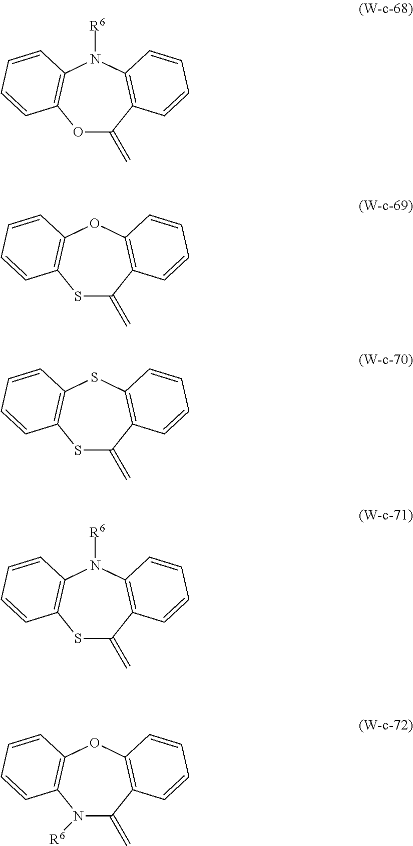

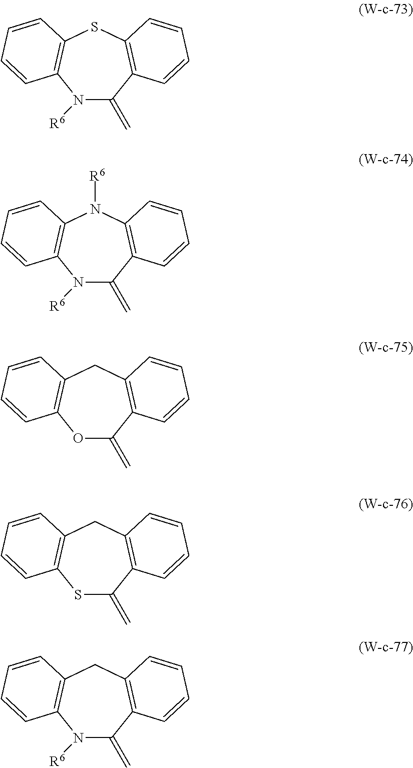

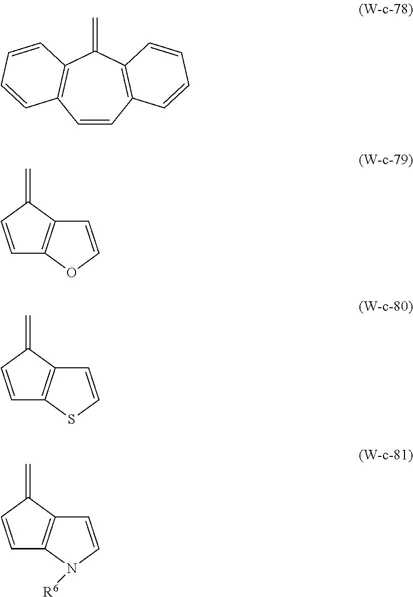

(In the formulae, R⁶ represents a hydrogen atom or an alkyl group having 1 to 8 carbon atoms, and in the case where, a plurality of R⁶ are present, these may be the same as or different from each other.) From the viewpoints of easily obtaining raw materials and ease of synthesis, it is particularly preferable that the cyclic group represented by ═CW⁸¹W⁸² is a group selected from groups represented by Formulae (W-c-11), (W-c-12), (W-c-13), (W-c-14), (W-c-53), (W-c-54), (W-c-55), (W-c-56), (W-c-57), and (W-c-78) which may be unsubstituted or substituted with one or more L¹'s.

The total number of π electrons included in the group represented by W⁸¹ and W⁸² is preferably 4 to 24 from the viewpoints of wavelength dispersion characteristics, storage stability, liquid crystallinity, and ease of synthesis. W⁸³ and W⁸⁴ each independently represent a group selected from a halogen atom, a cyano group, a hydroxy group, a nitro group, a carboxyl group, a carbamoyloxy group, an amino group, a sulfamoyl group, a group having at least one aromatic group and 5 to 30 carbon atoms, an alkyl group having 1 to 20 carbon atoms, a cycloalkyl group having 3 to 20 carbon atoms, an alkenyl group having 2 to 20 carbon atoms, a cycloalkenyl group having 3 to 20 carbon atoms, an alkoxy group having 1 to 20 carbon atoms, an acyoxy group having 2 to 20 carbon atoms, or an alkylcarbonyloxy group having 2 to 20 carbon atoms and, the cycloalkyl group, the alkenyl group, the cycloalkenyl group, the alkoxy group, the acyloxy group and the alkylcarbonyloxy group, in which one —CH₂— or two or more (—CH₂—)'s which are not adjacent to each other in the alkyl group may each independently be substituted with —O—, —S—, —CO—, —COO—, —OCO—, —CO—S—, —S—CO—, —O—CO—O—, —CO—NH—, —NH—CO—, or —C≡C—. It is more preferable that W⁸³ represents a group selected from a cyano group, a nitro group, a carboxyl group, and an alkyl group having 1 to 20 carbon atoms, an alkenyl group, an acyloxy group, and an alkylcarbonyloxy group, in which one —CH₂— or two or more (—CH₂—)'s that are not adjacent to each other, may each independently be substituted with —O—, —S—, —CO—, —COO—, —OCO—, —CO—S—, —S—CO—, —O—CO—O—, —CO—NH—, —NH—CO—, or —C≡C—, it is particularly preferable that W⁸³ represents a group selected from a cyano group, a carboxyl group, and an alkyl group having 1 to 20 carbon atoms, an alkenyl group, an acyloxy group, and an alkylcarbonyloxy group, in which one —CH₂— or two or more (—CH₂—)'s which are not adjacent to each other may each be independently substituted with —CO—, —COO—, —OCO—, —O—CO—O—, —CO—NH—, —NH—CO—, or —C≡C—. It is more preferable that W⁸⁴ represents a group selected from a cyano group, a nitro group, a carboxyl group, and an alkyl group having 1 to 20 carbon atoms, an alkenyl group, an acyloxy group, and an alkylcarbonyloxy group, in which one —CH₂— or two or more (—CH₂—)'s that are not adjacent to each other may each independently be substituted with —O—, —S—, —CO—, —COO—, OCO—, —CO—S—, —S—CO—, —O—CO—O—, —CO—NH—, —NH—CO—, or —C≡C—, it is particularly preferable that W⁸⁴ represents a group selected from a cyano group, a carboxyl group, and an alkyl group having 1 to 20 carbon atoms, an alkenyl group, an acyloxy group, and an alkylcarbonyloxy group, in which one —CH₂— or two or more (—CH₂—)'s that are not adjacent to each other may each be independently substituted with —CO—, —COO—, —OCO—, —O—CO—O—, —CO—NH—, —NH—CO—, or —C≡C—.

L¹ represents a fluorine atom, a chlorine atom, a bromine atom, an iodine atom, a pentafluorosulfuranyl group, a nitro group, an isocyano group, an amino group, a hydroxy group, a mercapto group, a methylamino group, a dimethylamino group, a diethylamino group, a diisopropylamino group, a trimethylsilyl group, a dimethylsilyl group, a thioisocyano group, or a linear or branched alkyl group having 1 to 20 carbon atoms in which one —CH₂— or two or more (—CH₂—)'s which are not adjacent to each other may be each independently substituted with —O—, —S—, —CO—, —COO—, —OCO—, —CO—S—, —S—CO—, —O—CO—O—, —CO—NH—, —NH—CO—, —CH═CH—COO—, —CH═CH—OCO—, —COO—CH═CH—, —OCO—CH═CH—, —CH═CH—, —CF═CF—, or —C≡C—, and one or more of arbitrary hydrogen atoms in the alkyl group may be substituted with a fluorine atom.

From the viewpoints of liquid crystallinity and ease of synthesis, it is preferable that L¹ represents a fluorine atom, a chlorine atom, a pentafluorosulfuranyl group, a nitro group, a methylamino group, a dimethylamino group, a diethylamino group, a diisopropylamino group, or a linear or branched alkyl group having 1 to 20 carbon atoms in which one or more of arbitrary hydrogen atoms may be substituted with a fluorine atom and one —CH₂— or two or more (—CH₂—)'s which are not adjacent to each other may be each independently substituted with a group selected from —O—, —S—, —CO—, —COO—, —OCO—, —O—CO—O—, —CH═CH—, —CF═CF—, and —C≡C—, it is more preferable that that L¹ represents a fluorine atom, a chlorine atom, or a linear or branched alkyl group having 1 to 12 carbon atoms in which one or more of arbitrary hydrogen atoms may be substituted with a fluorine atom and one —CH₂— or two or more (—CH₂—)'s which are not adjacent to each other may be each independently substituted with a group selected from —O—, —COO—, and —OCO—, it is still more preferable that L¹ represents a fluorine atom, a chlorine atom, or a linear or branched alkyl group or alkoxy group having 1 to 12 carbon atoms in which one or more of arbitrary hydrogen atoms may be substituted with a fluorine atom, and it is particularly preferable that L¹ represents a fluorine atom, a chlorine atom, or a linear alkyl group or a linear alkoxy group having 1 to 8 carbon atoms. In General Formula (1) to General Formula (7), substituents bonded to MG¹¹ to MG⁷¹ are bonded to A¹¹ and/or A¹² in General Formula (a).

In General Formula (1), m11 represents an integer of 0 to 8. From the viewpoints of liquid crystallinity, easily obtaining raw materials, and ease of synthesis, m11 represents preferably an integer of 0 to 4, more preferably an integer of 0 to 2, still more preferably 0 or 1, and particularly preferably 1.

In General Formula (2) to General formula (7), m2 to m7, n2 to n7, 14 to 16, and k6 each independently represent an integer of 0 to 5. From the viewpoints of liquid crystallinity, easily obtaining raw materials, and ease of synthesis, m2 to m7, n2 to n7, 14 to 16, and k6 represent preferably an integer of 0 to 4, more preferably an integer of 0 to 2, still more preferably 0 or 1, and particularly preferably 1.

In General Formula (a), j11 and J12 each independently represent an integer of 1 to 5, provided that j11+j12 represents an integer of 2 to 5. From the viewpoints of liquid crystallinity, ease of synthesis, and storage stability, j11 and j12 each independently represent preferably an integer of 1 to 4, more preferably an integer of 1 to 3, and particularly preferably 1 or 2. It is preferable that j11+j12 represents an integer of 2 to 4.

Preferred specific examples of the compound represented by General Formula (1) include compounds represented by Formula (1-a-1) to Formula (1-a-93).

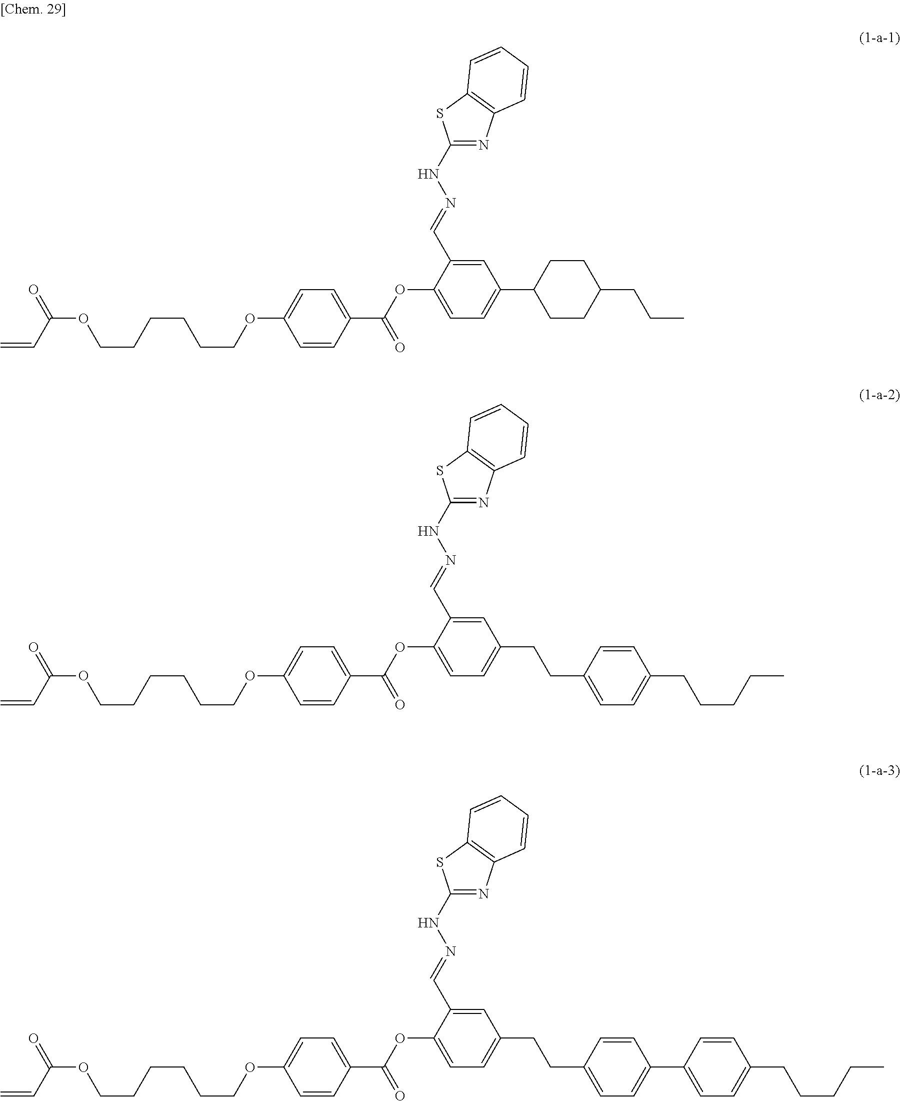

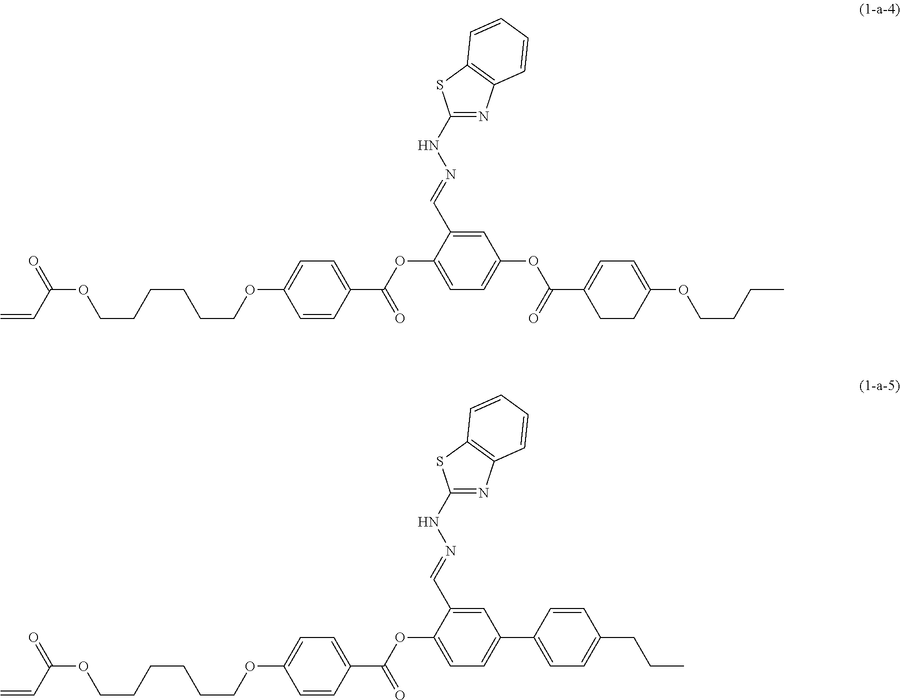

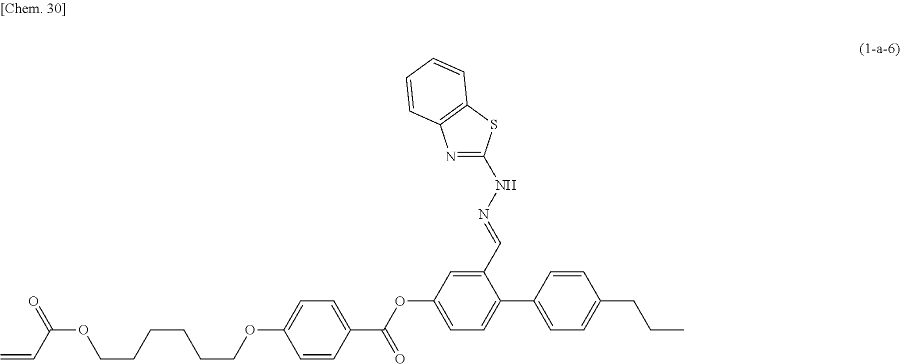

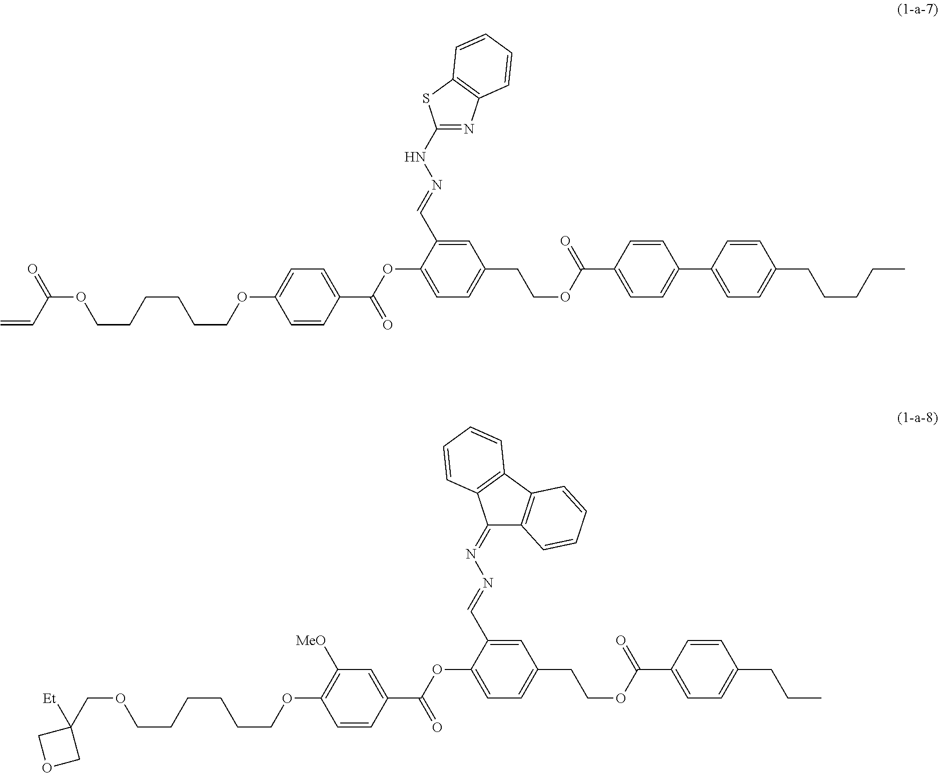

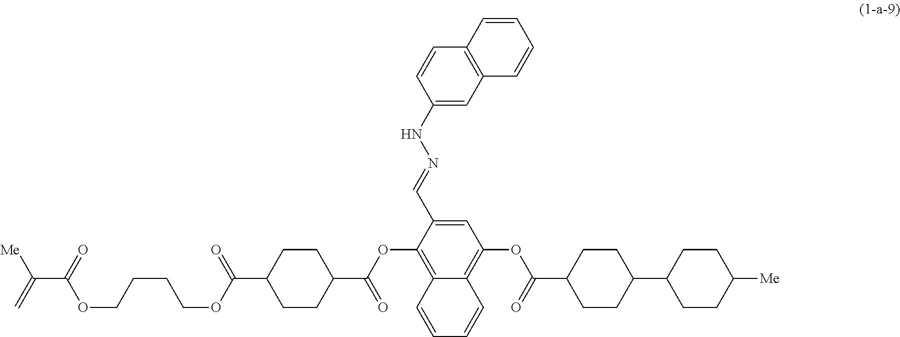

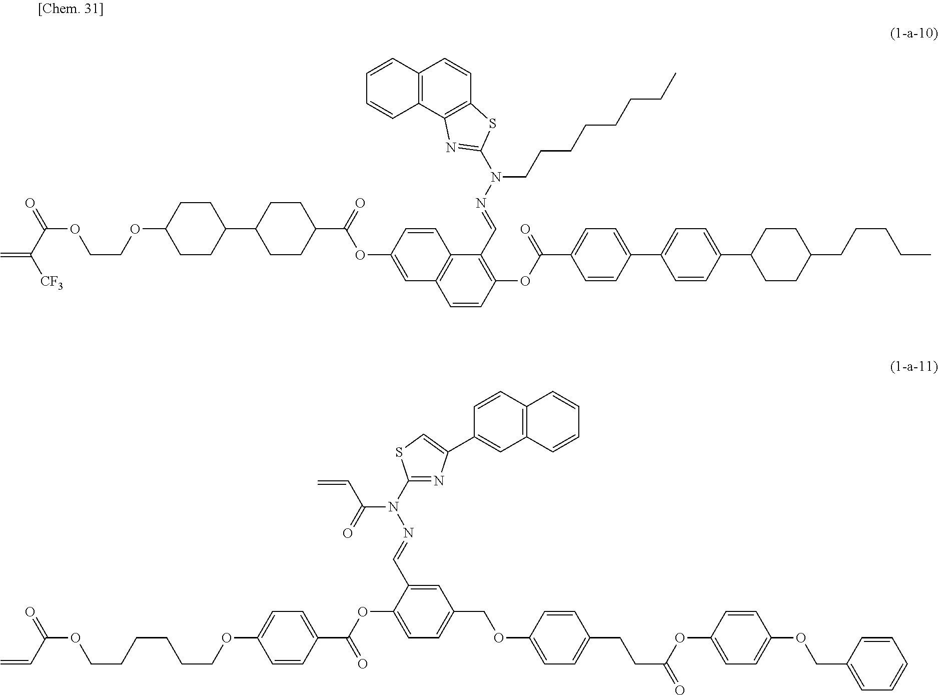

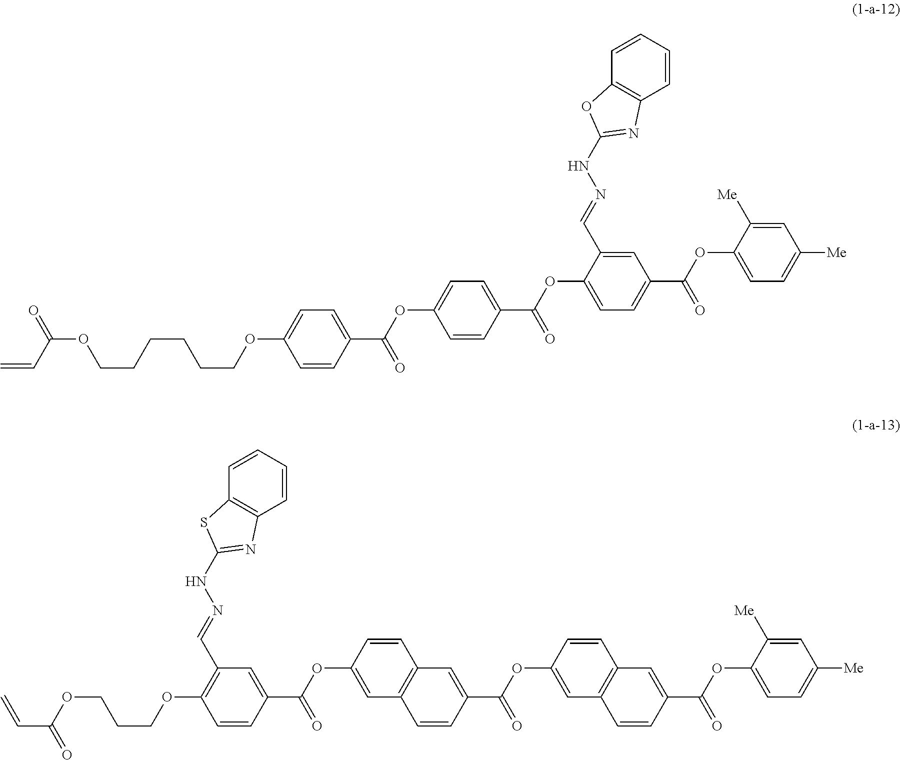

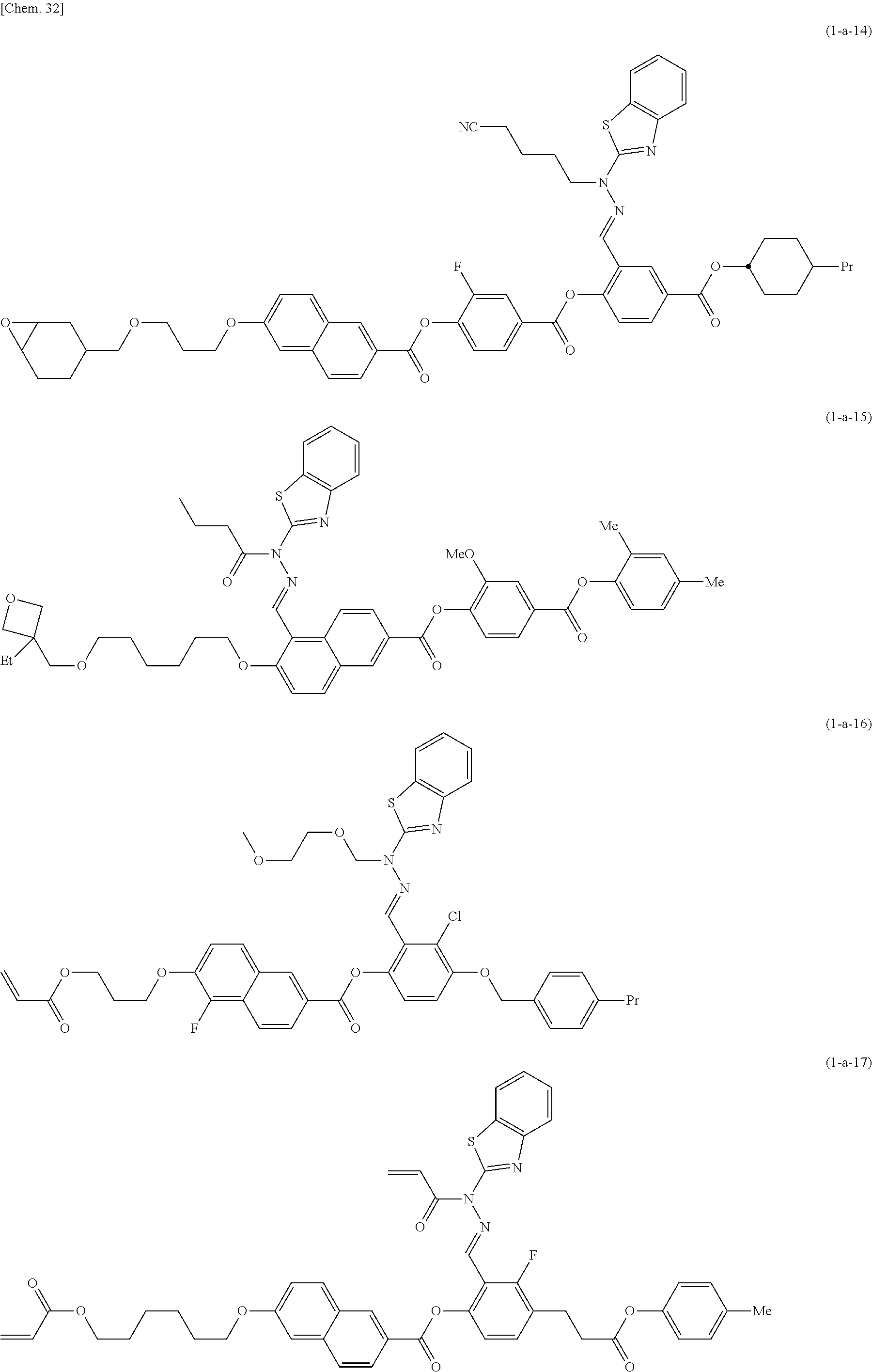

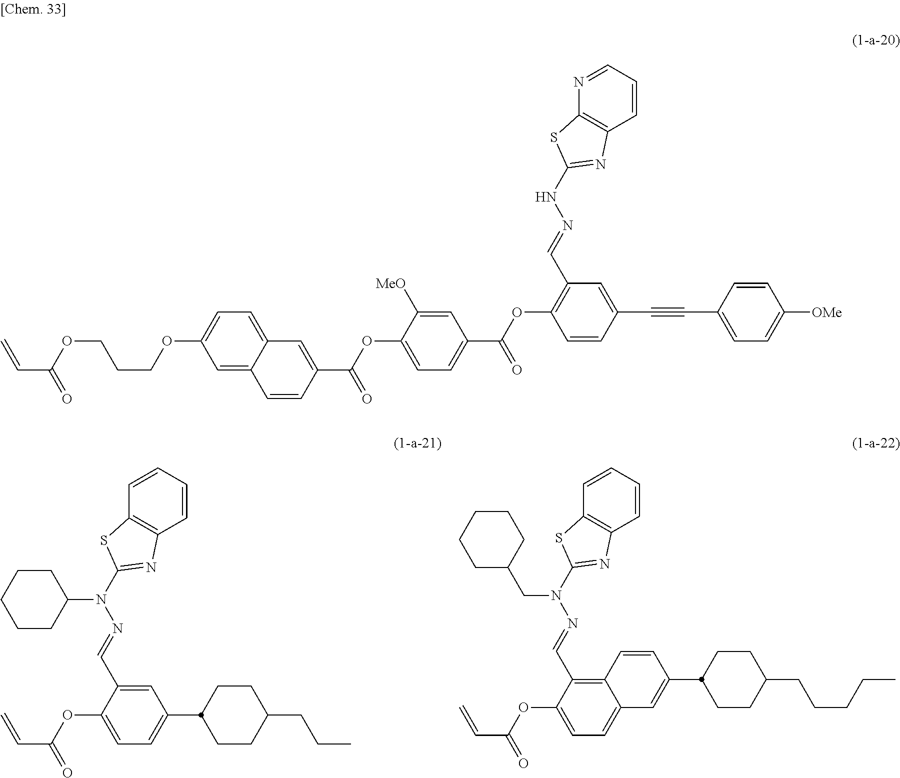

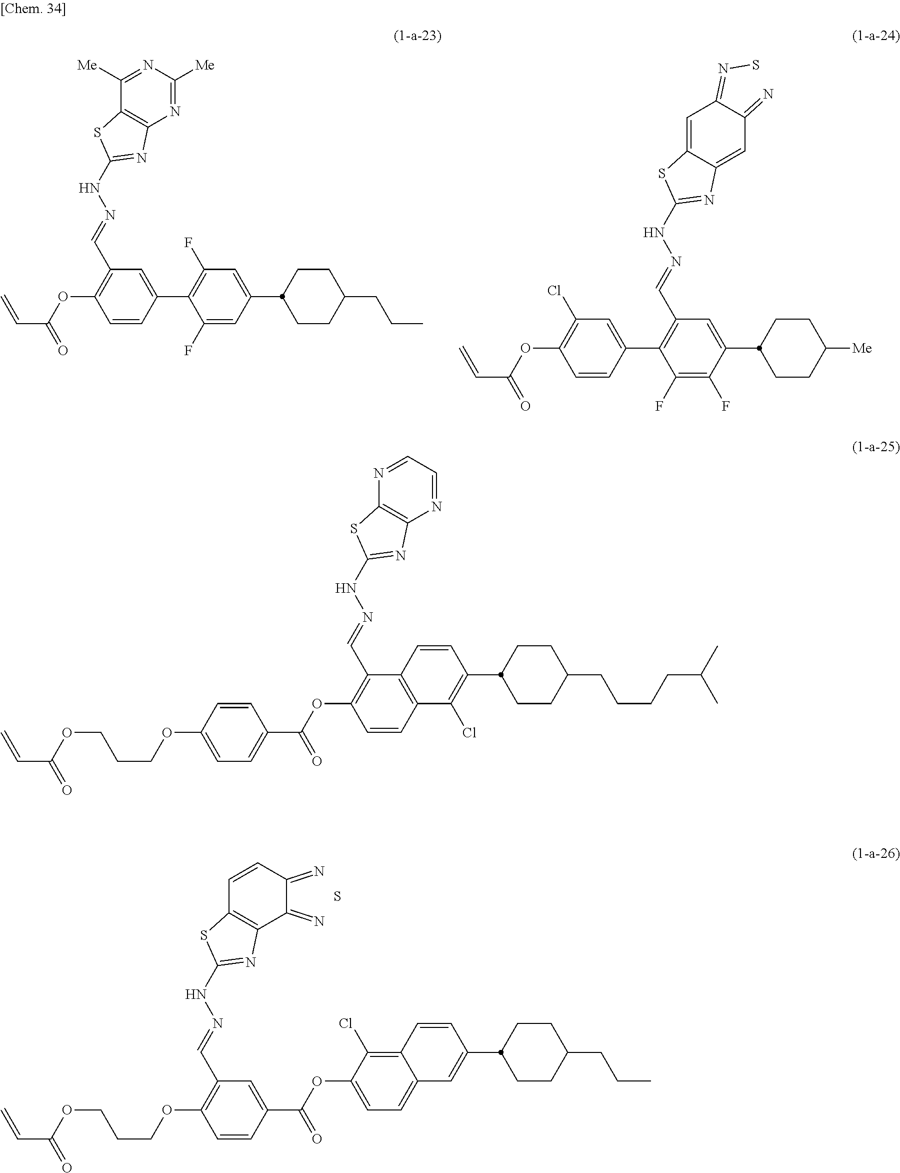

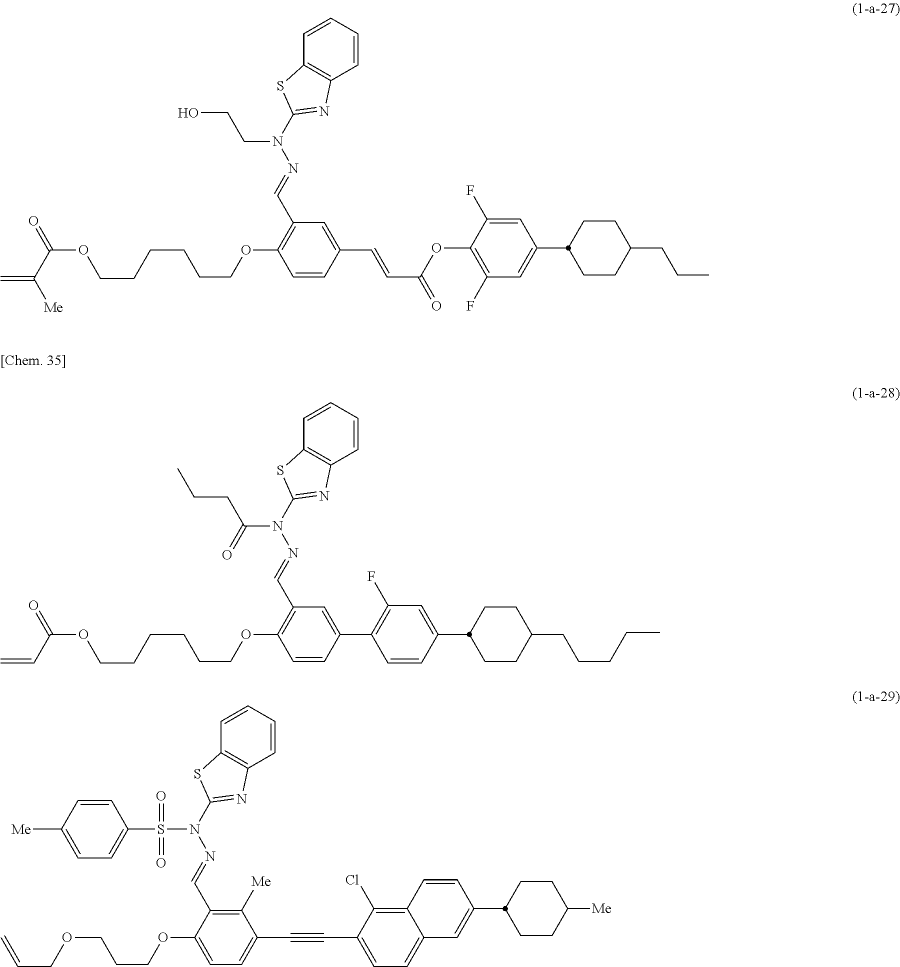

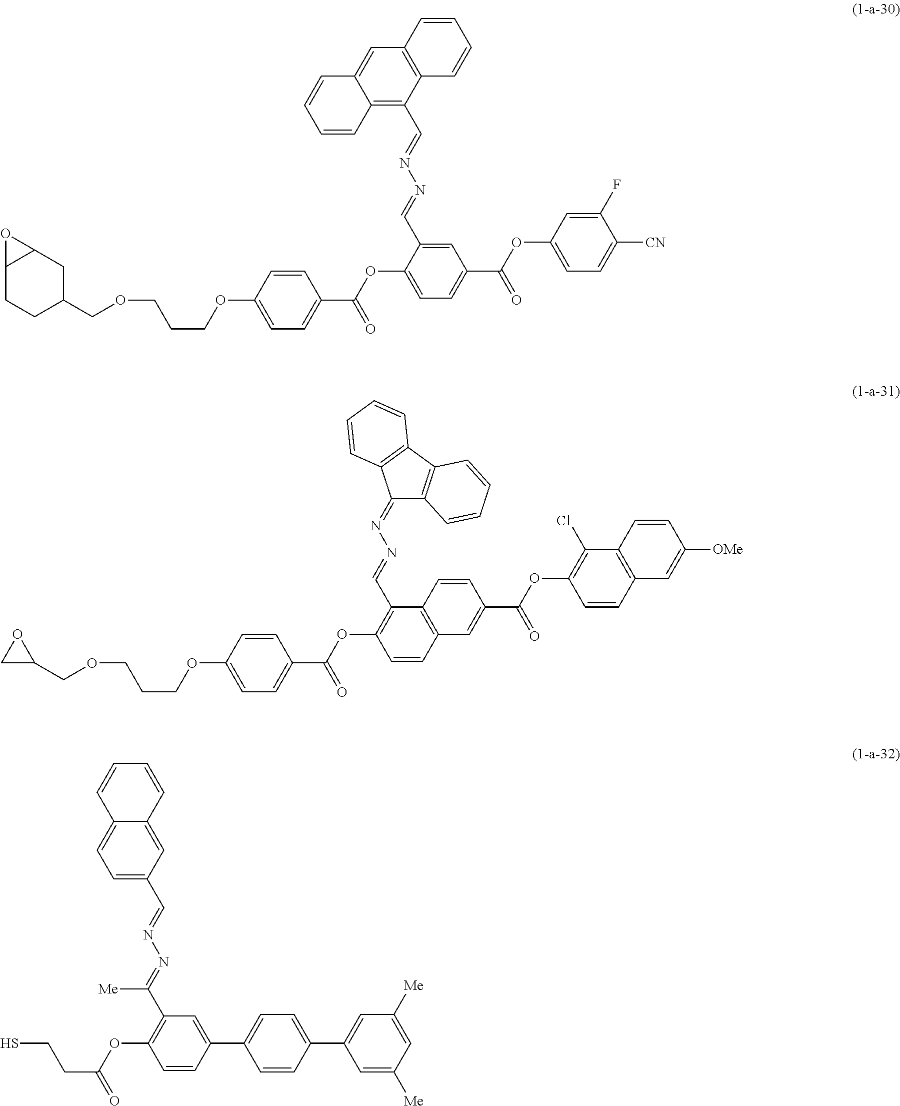

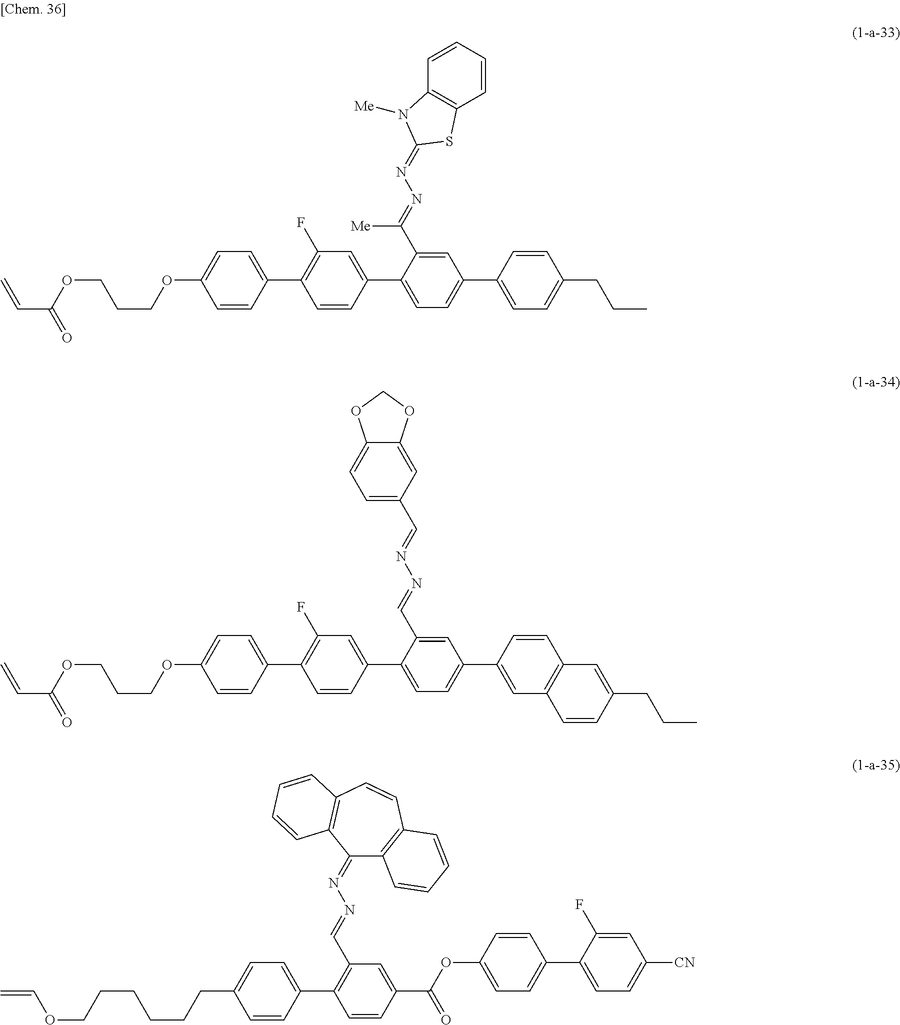

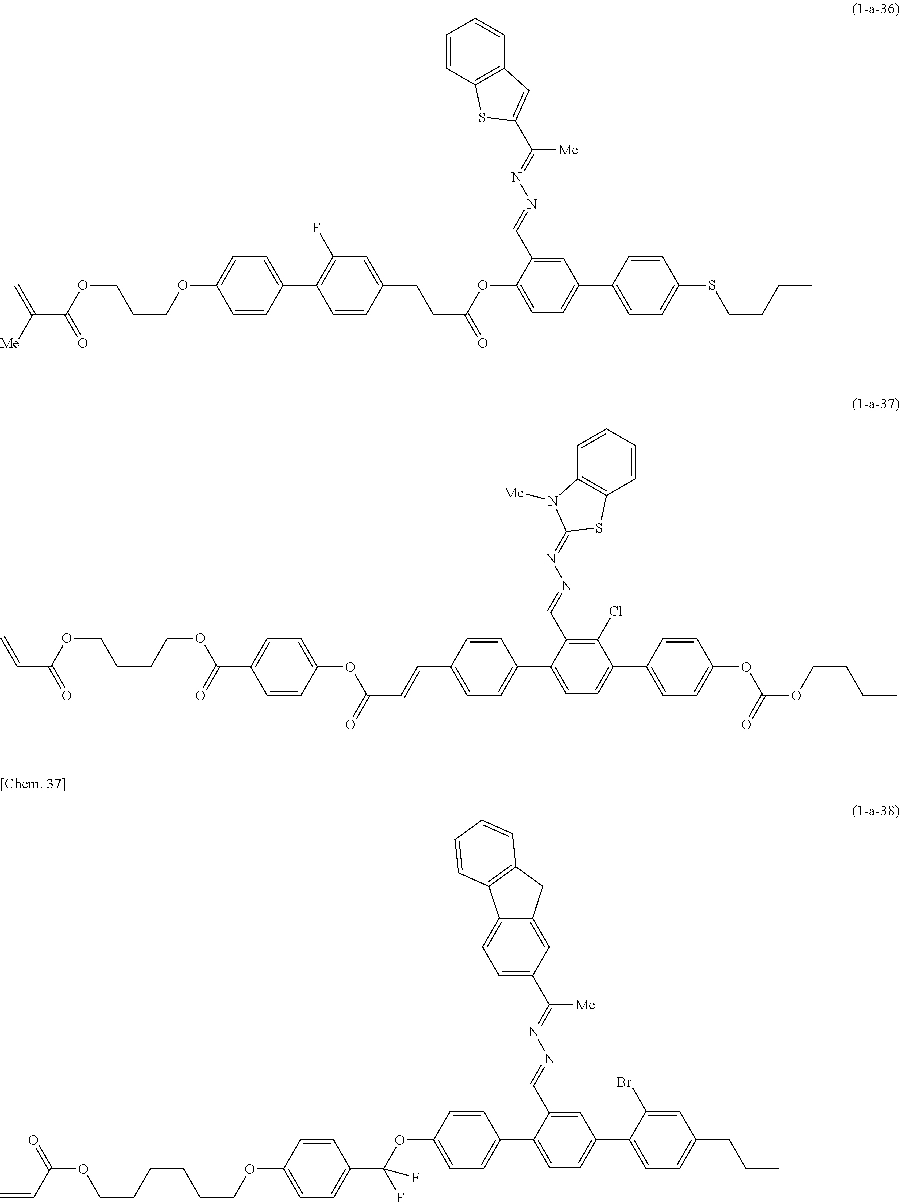

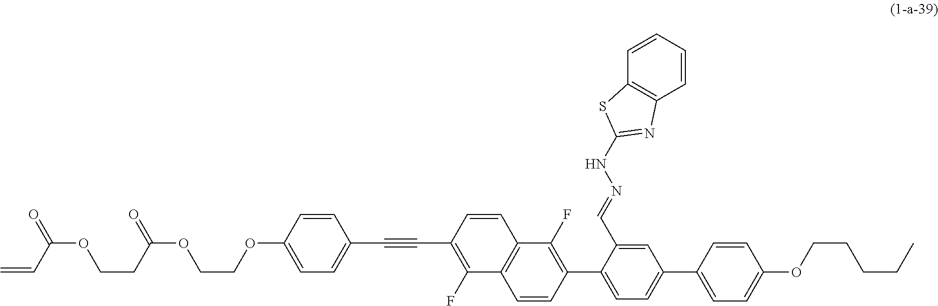

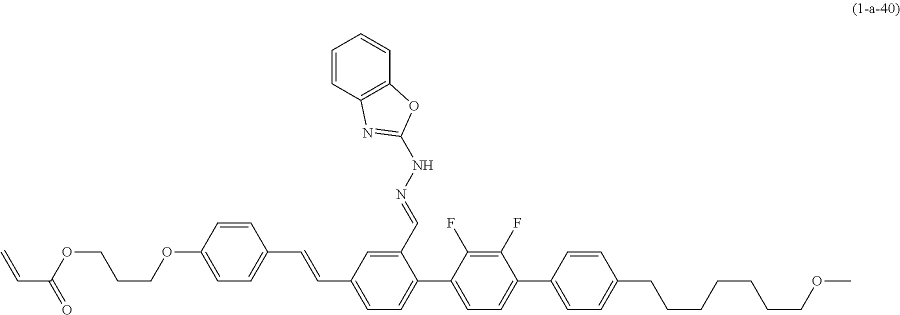

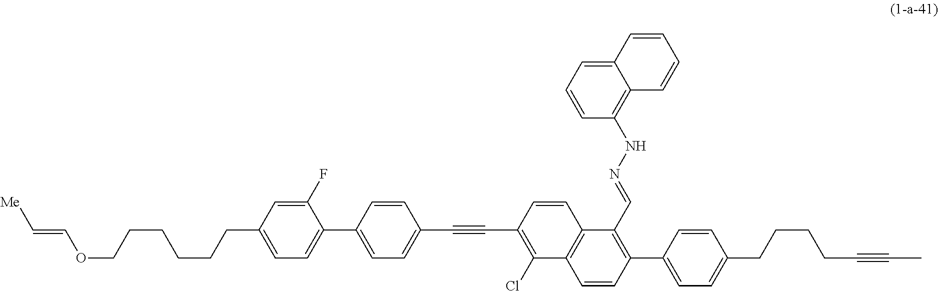

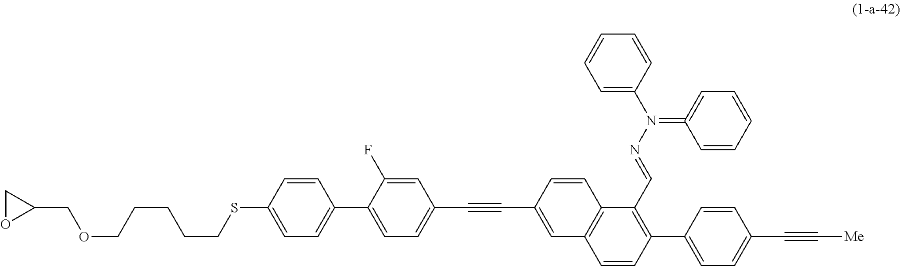

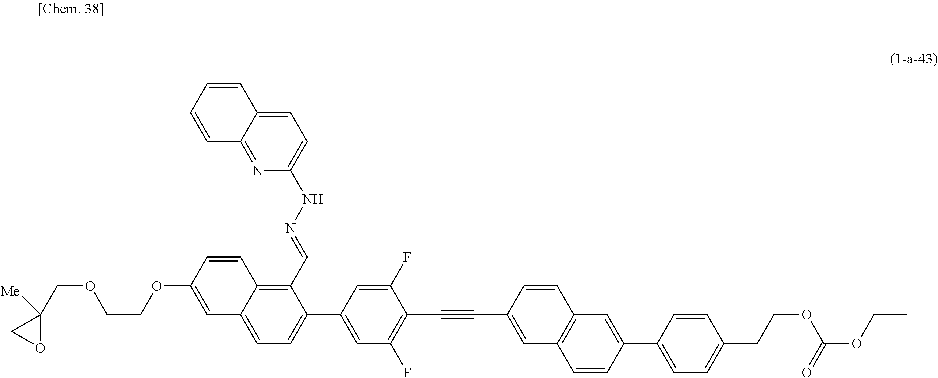

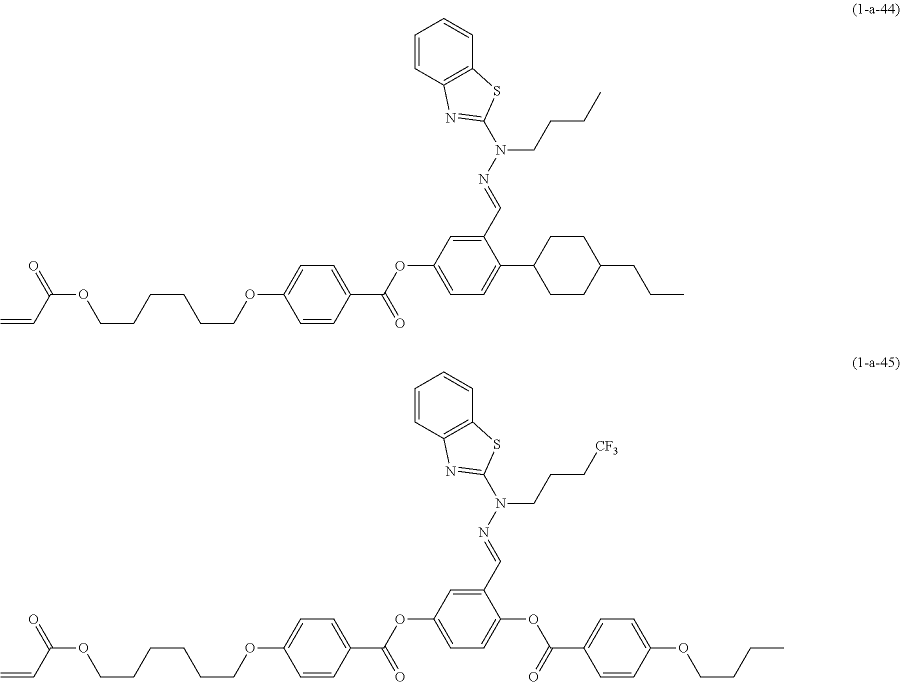

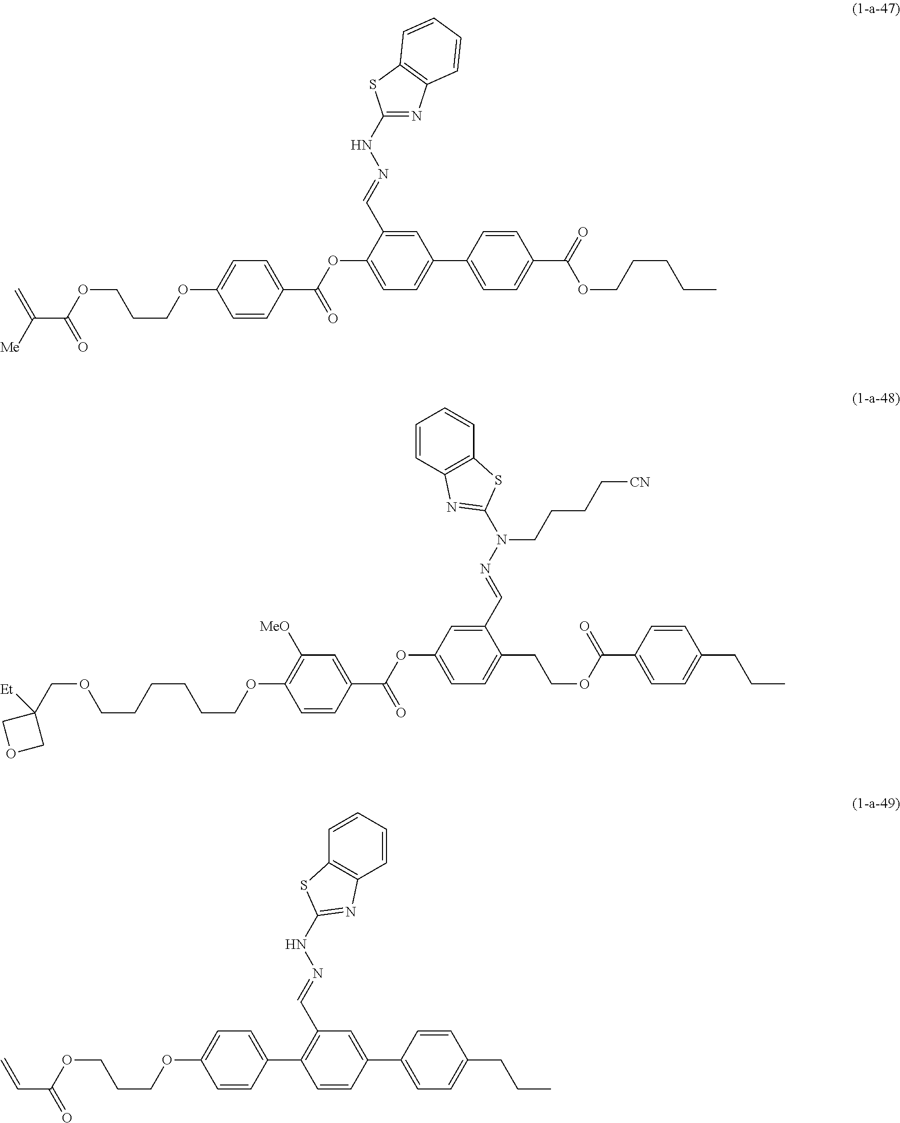

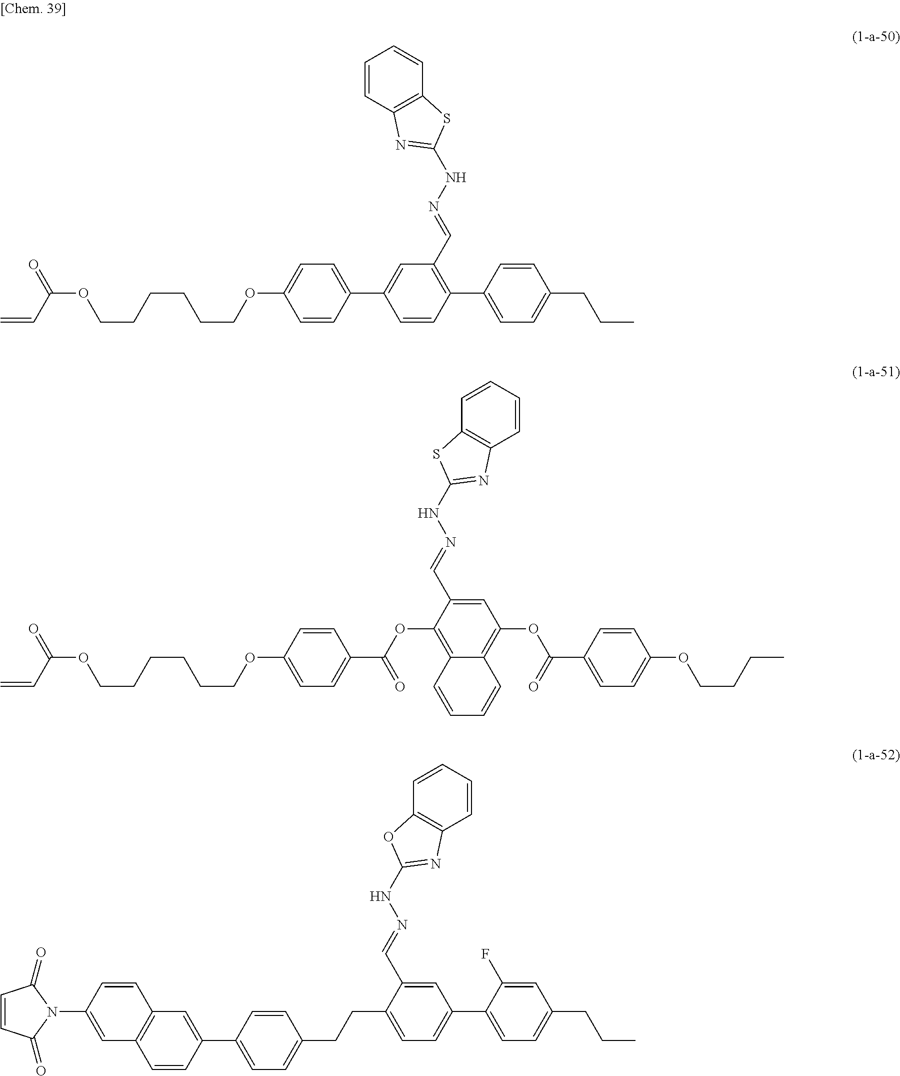

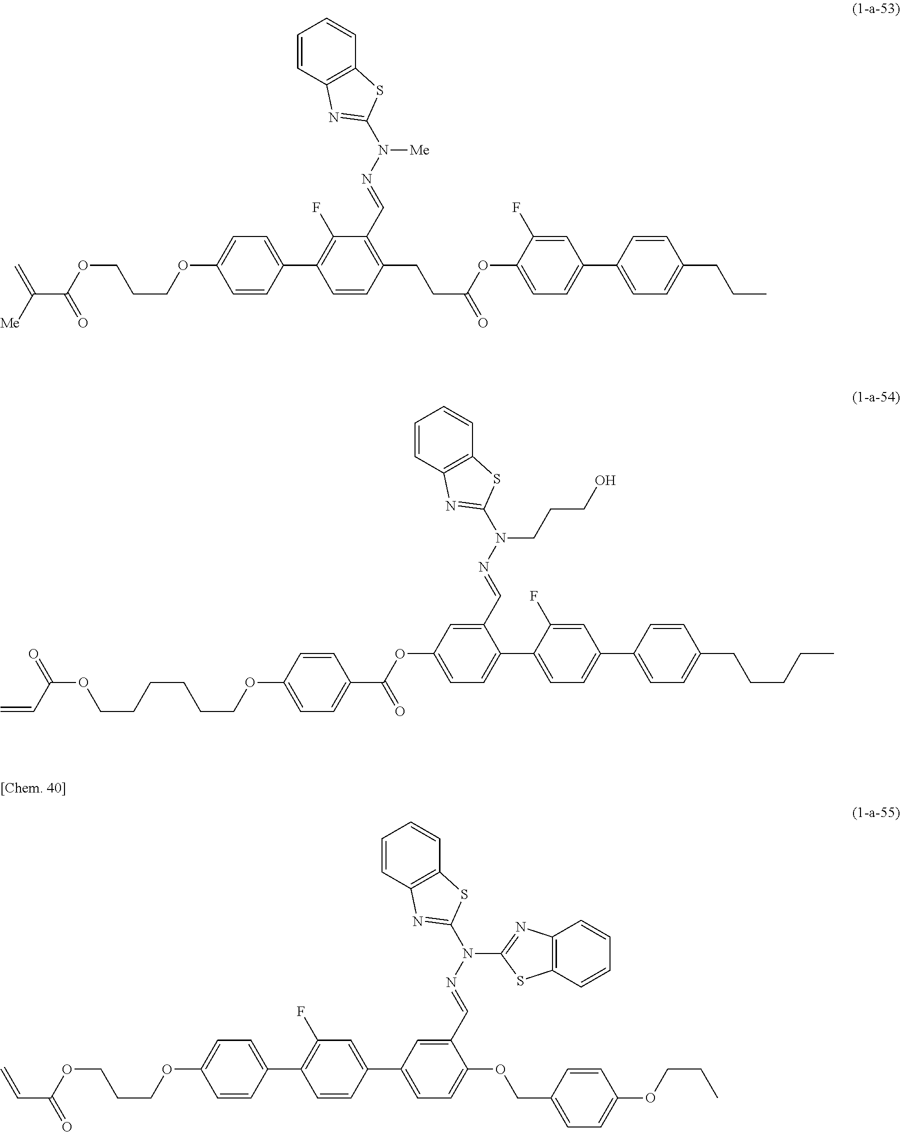

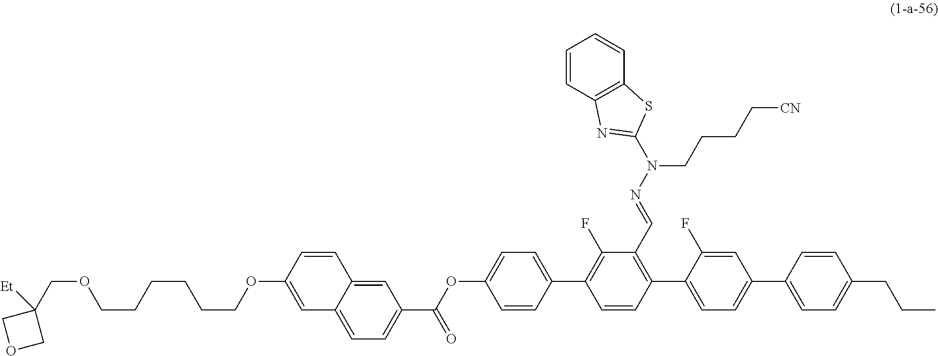

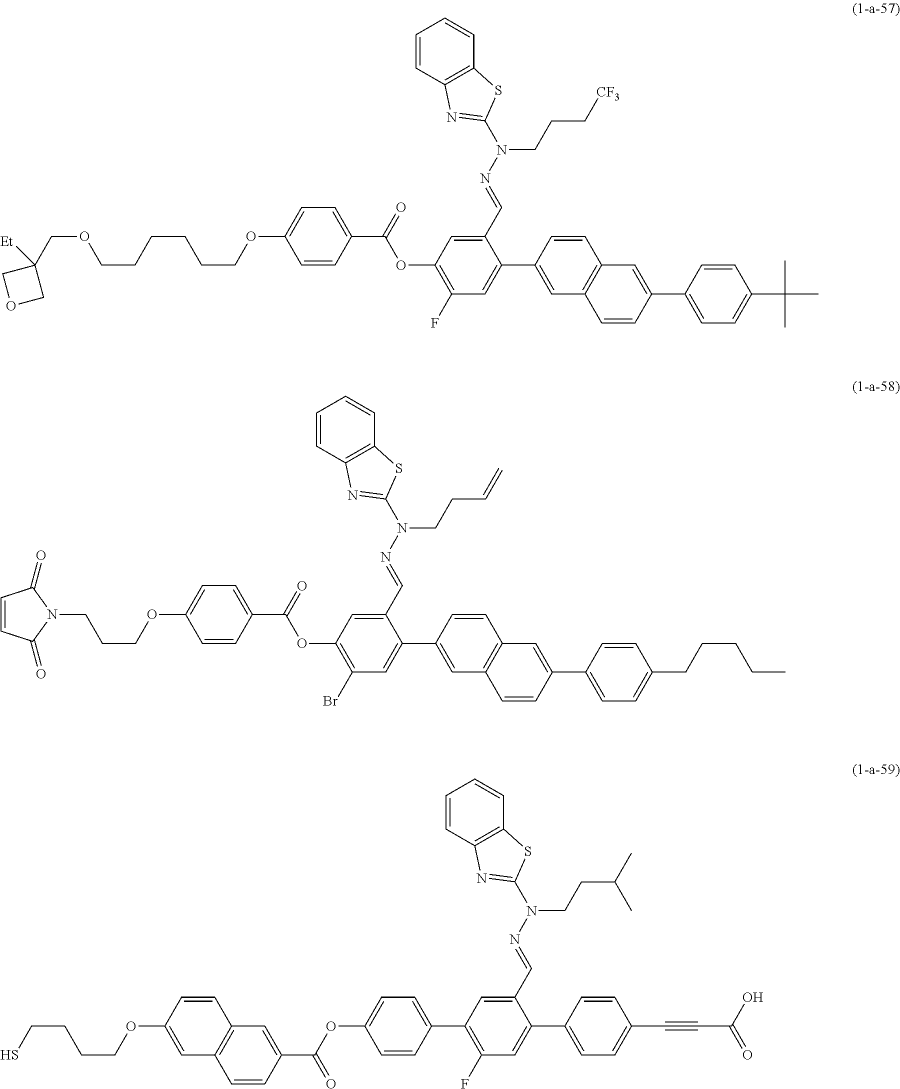

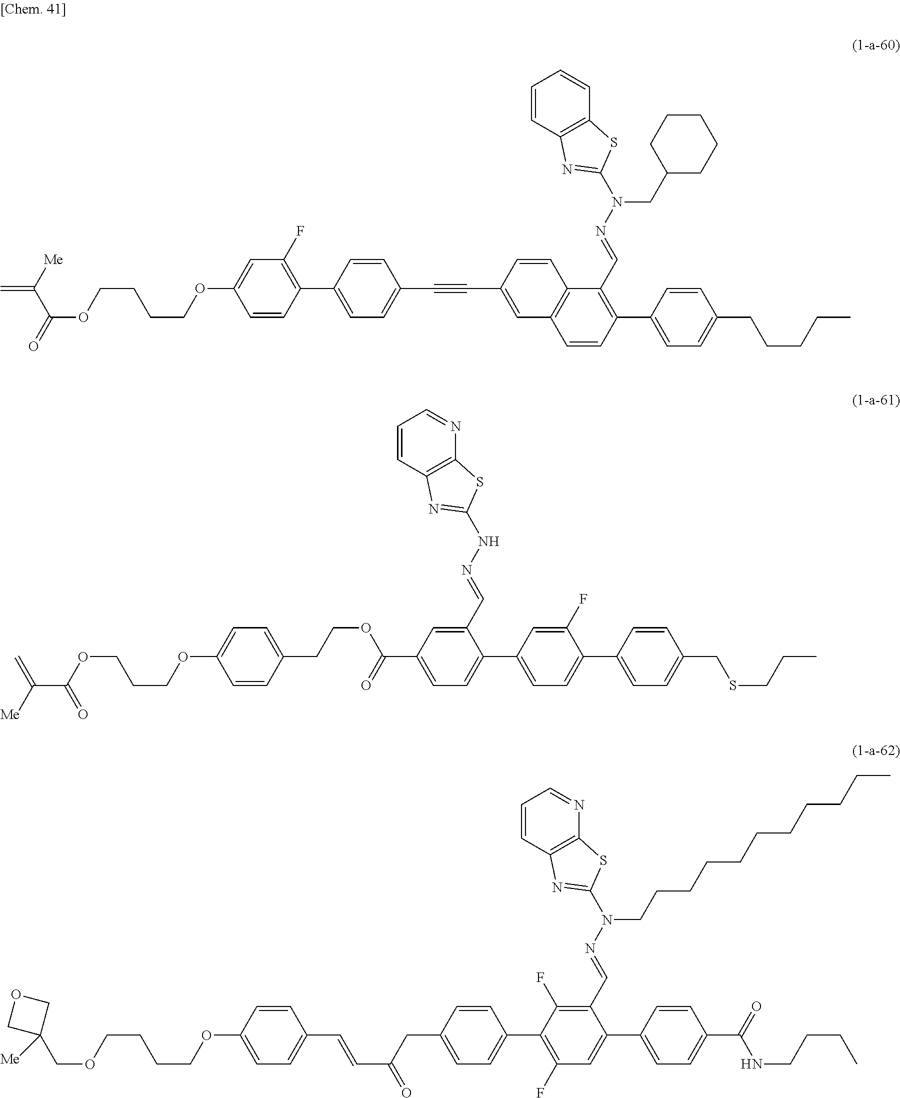

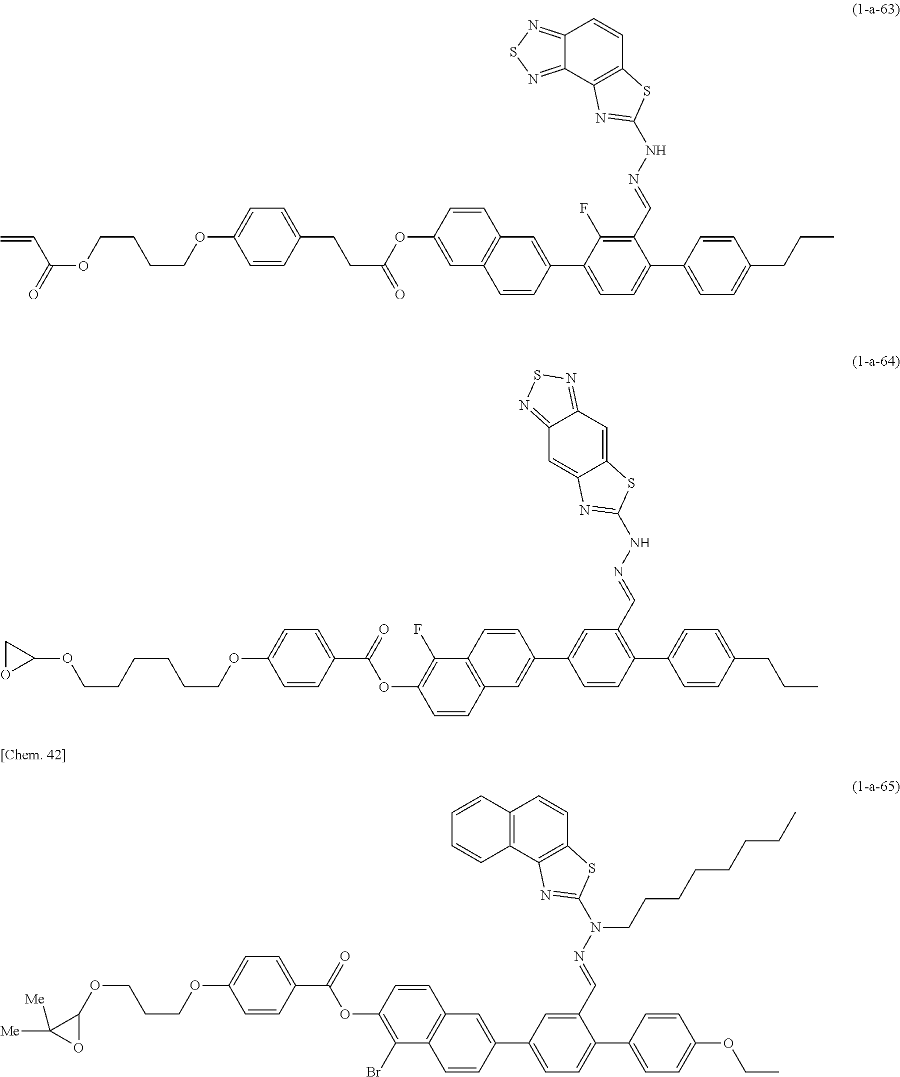

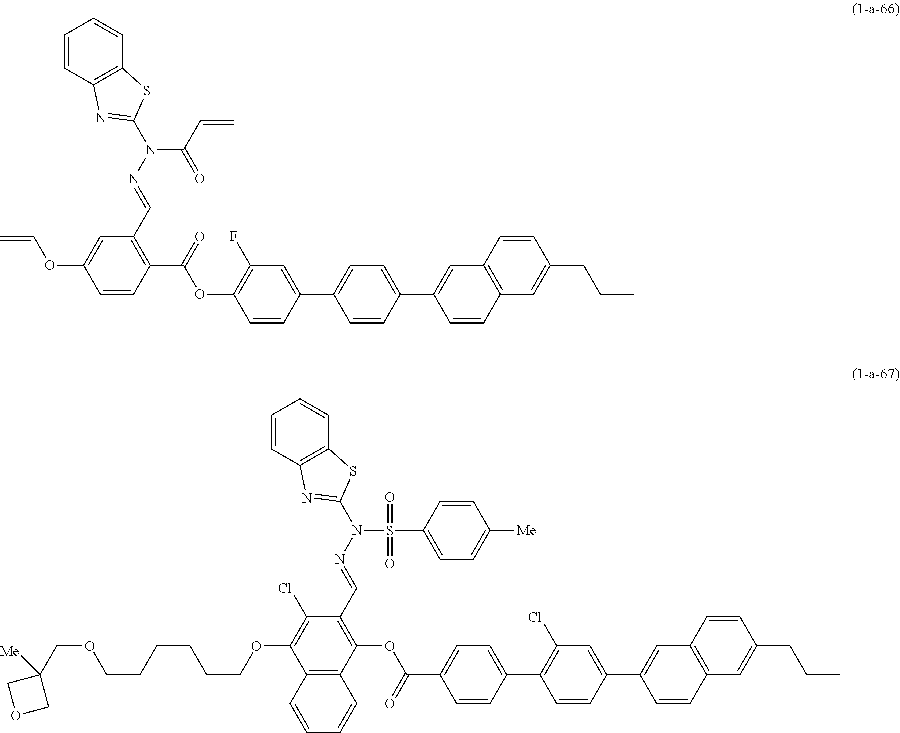

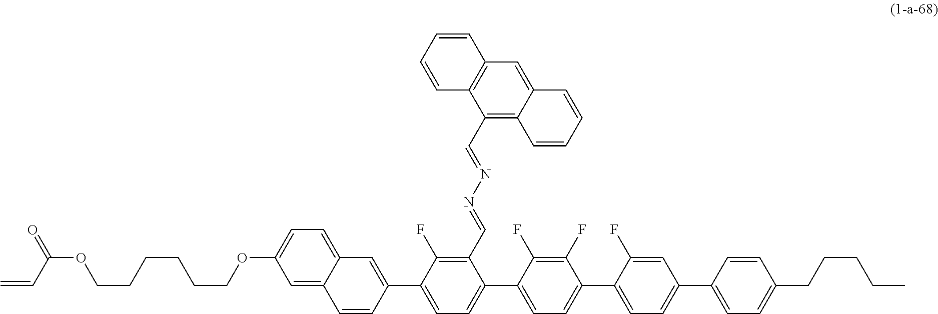

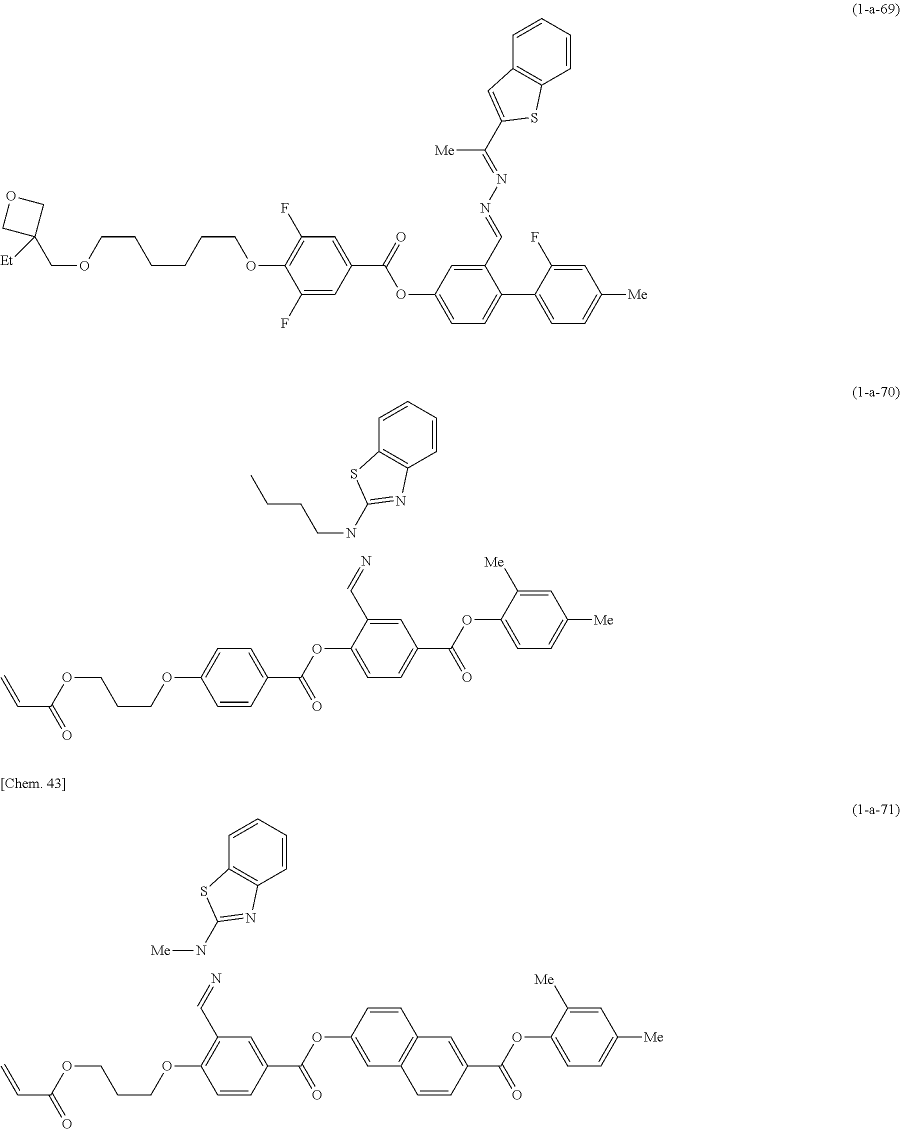

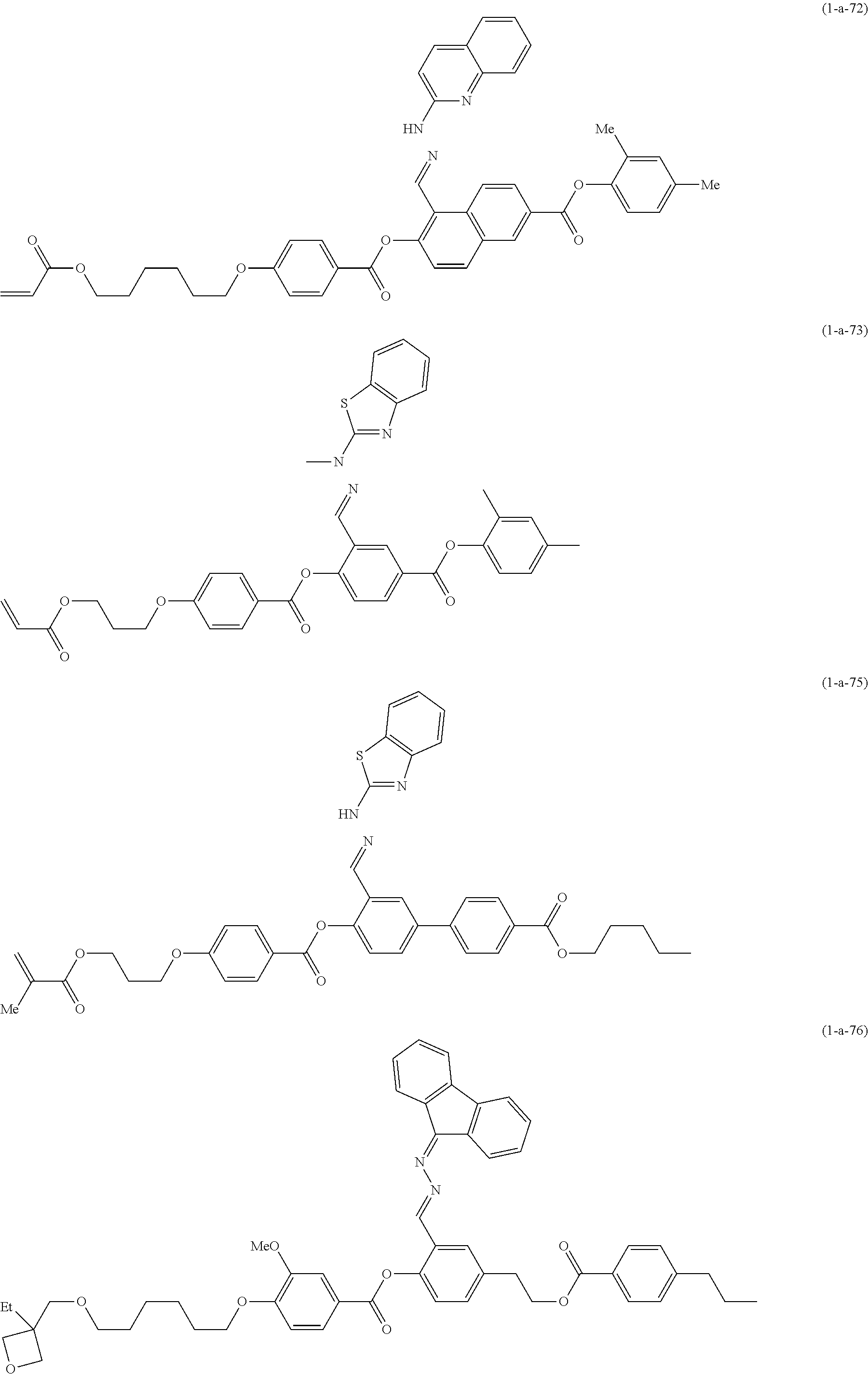

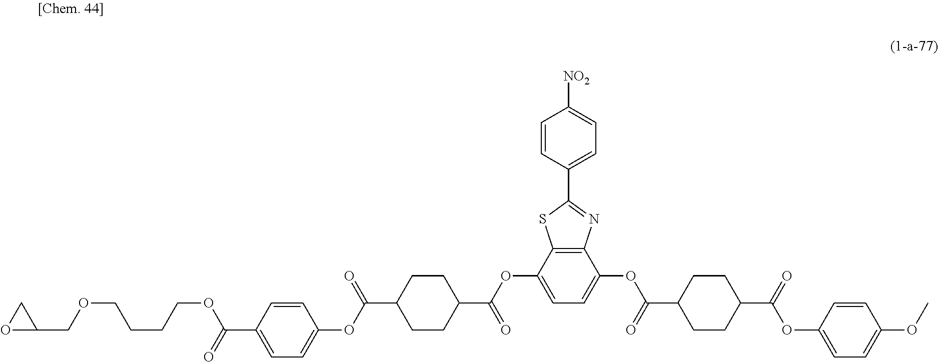

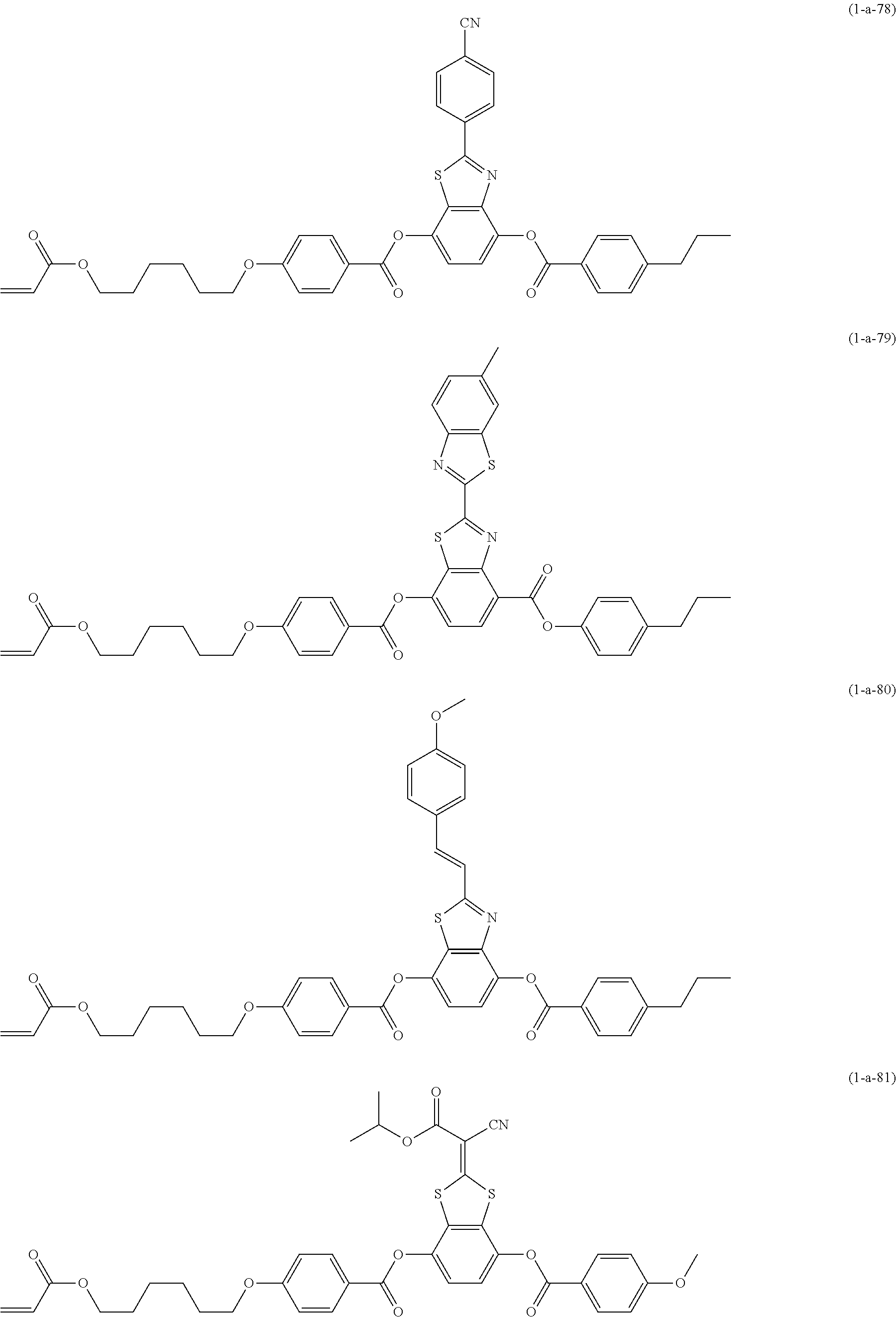

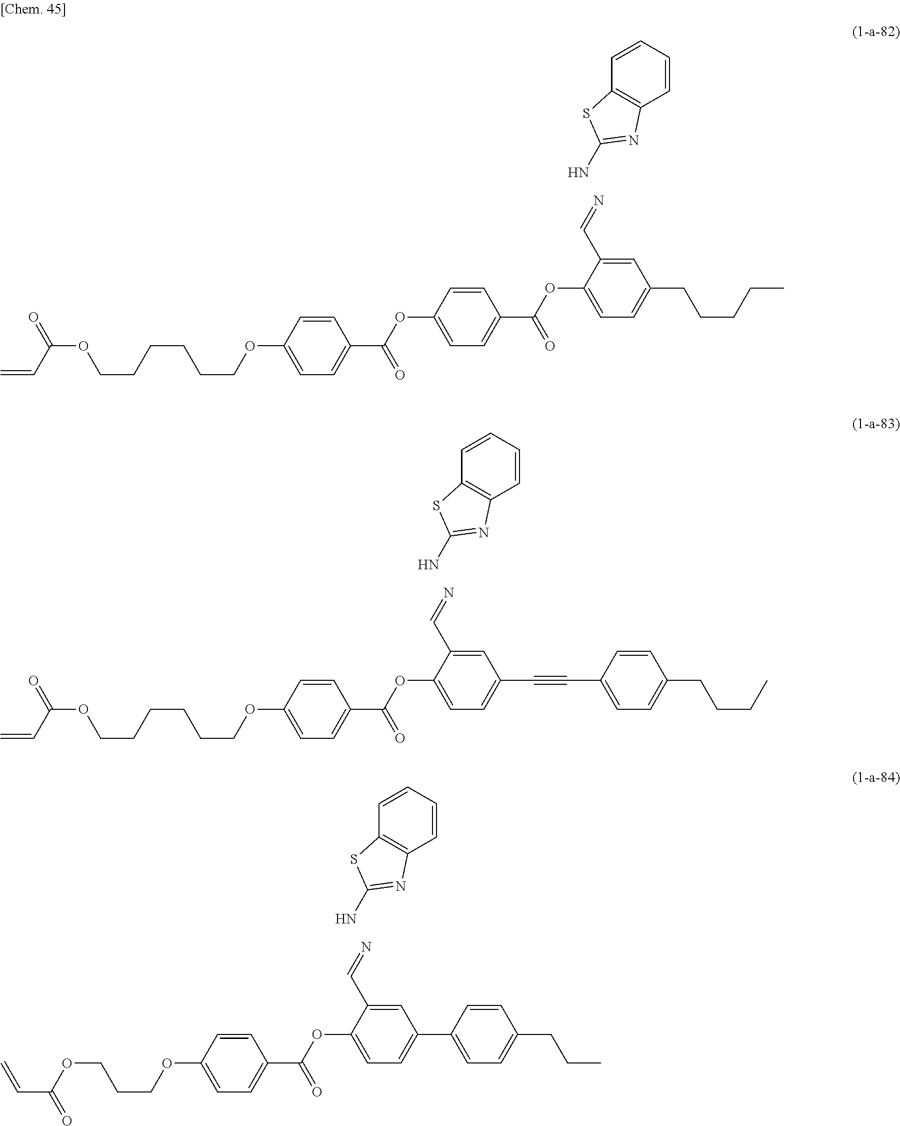

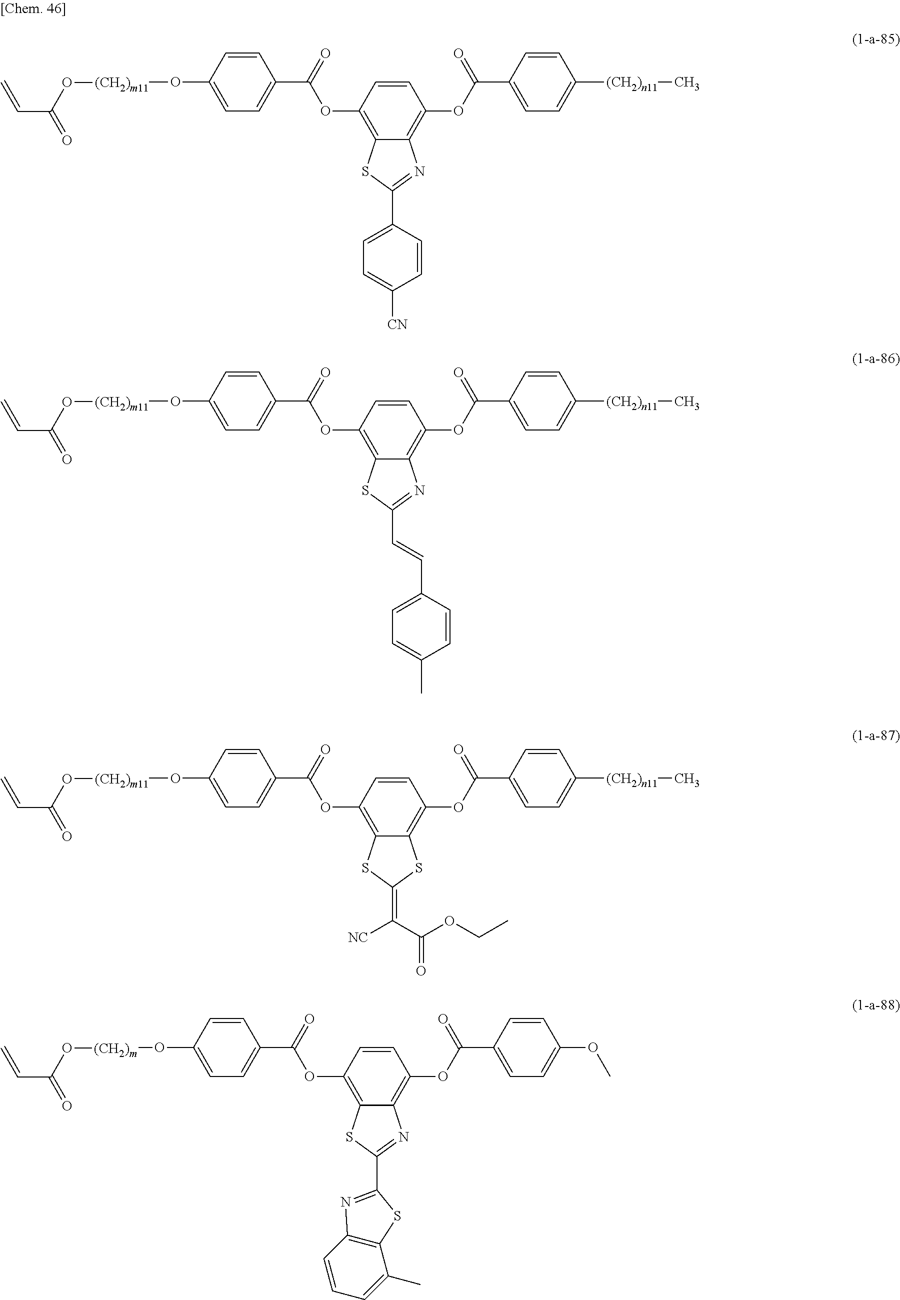

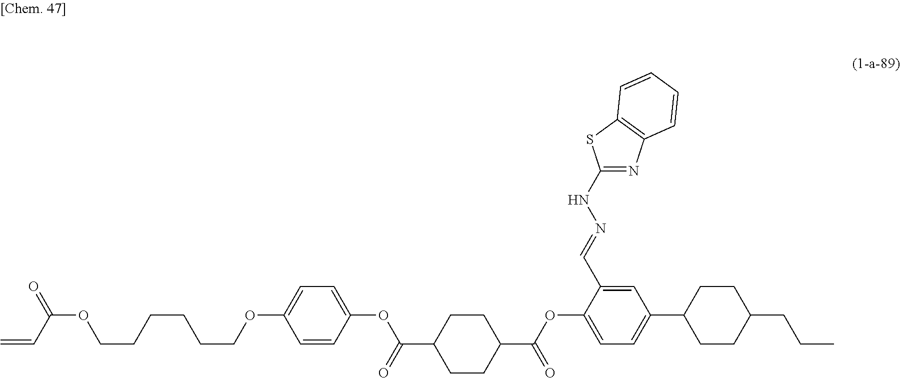

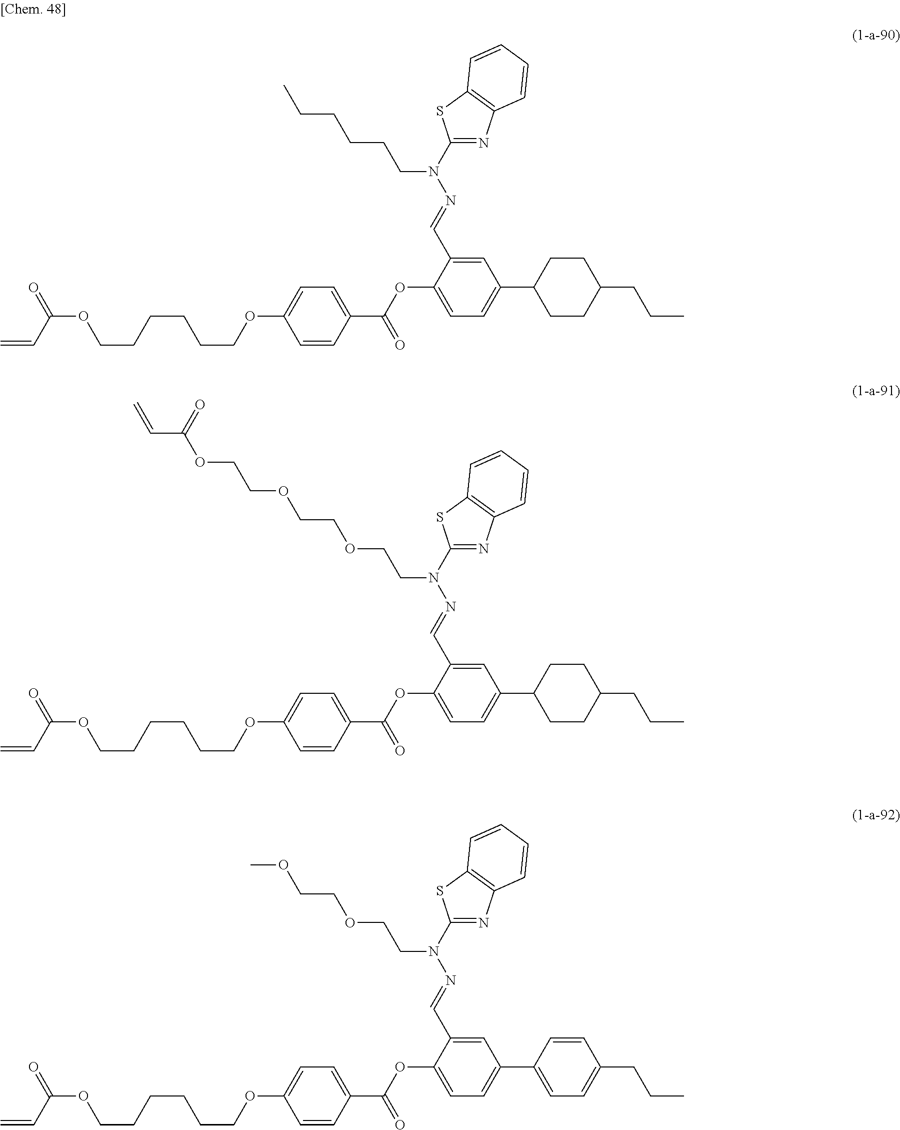

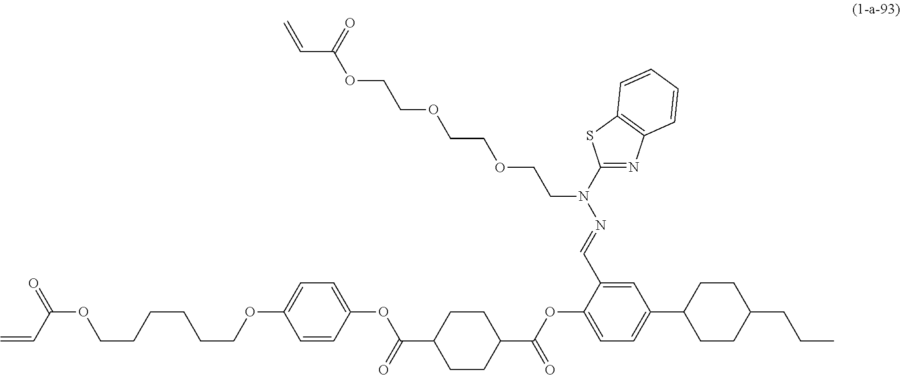

These liquid crystalline compounds may be used singly or two or more thereof may be mixed to be used.

Preferred specific examples of the compound represented by General Formula (2) include compounds represented by Formula (2-a-1) to Formula (2-a-69).

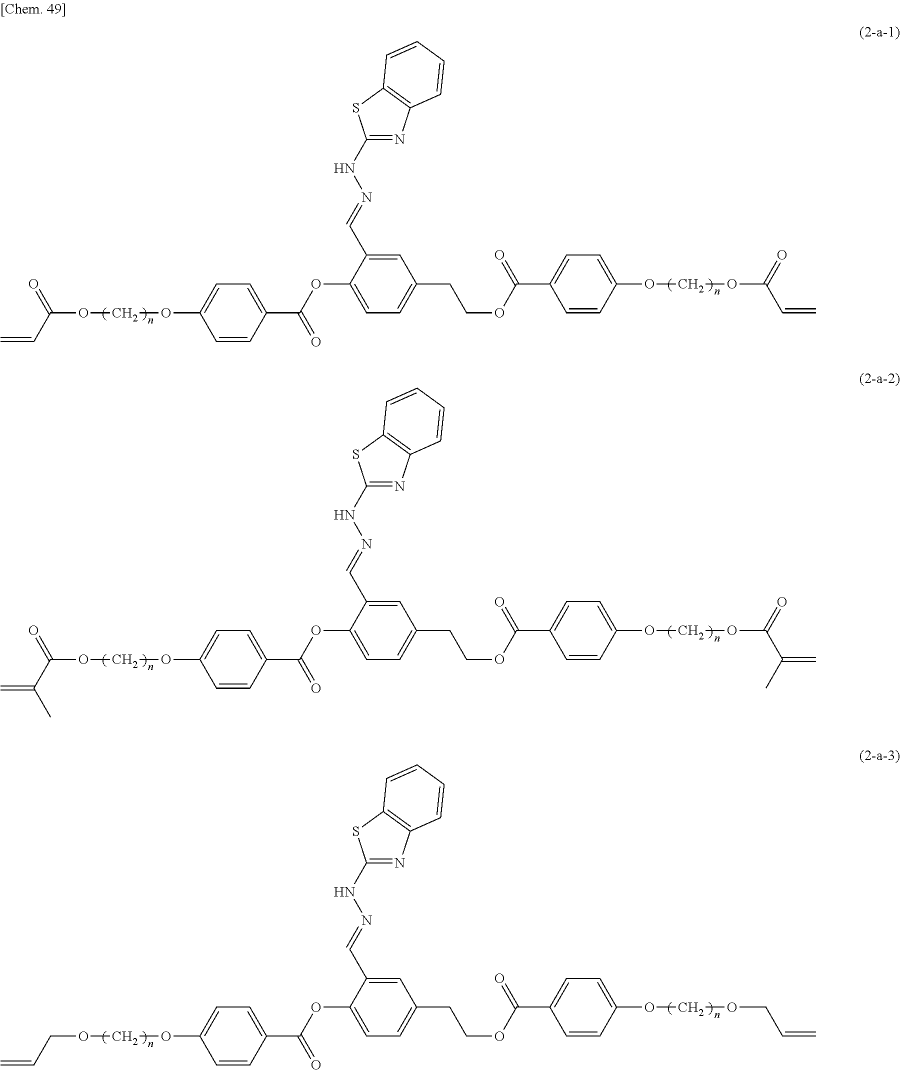

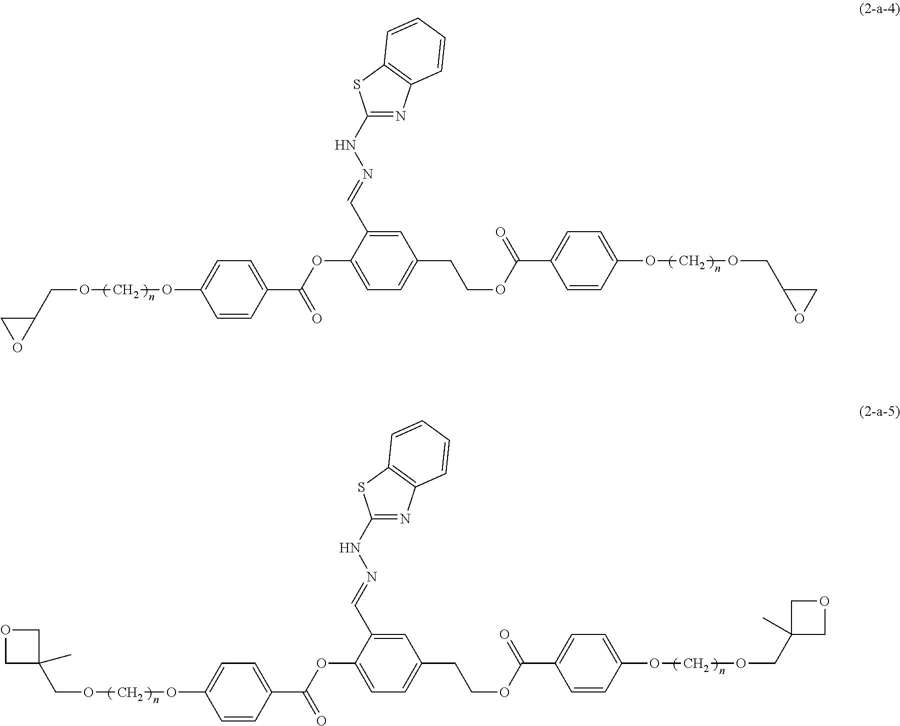

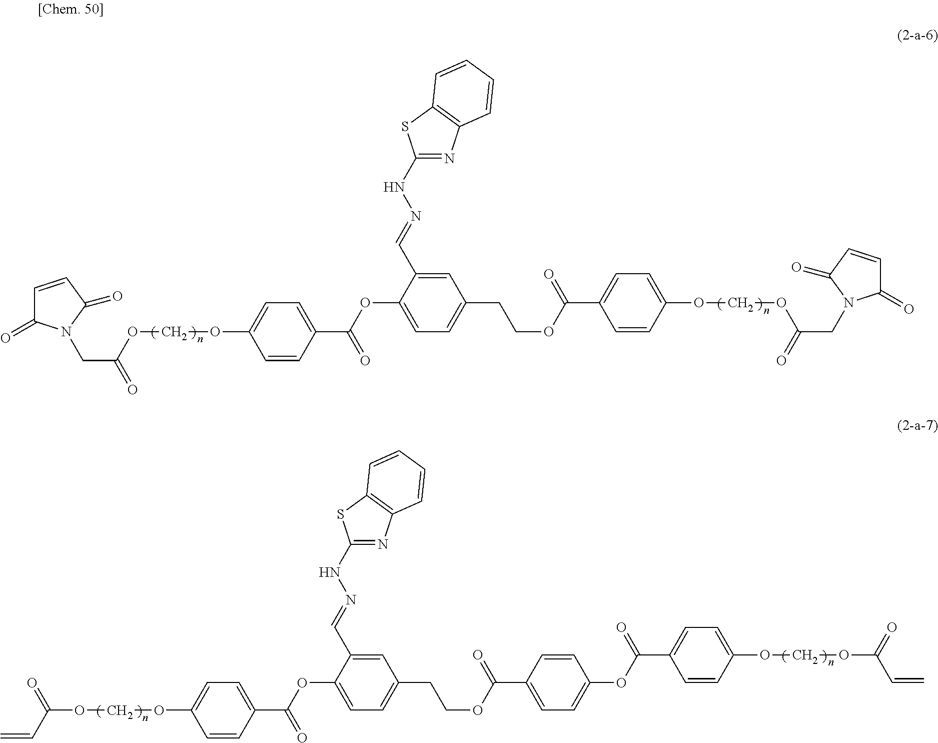

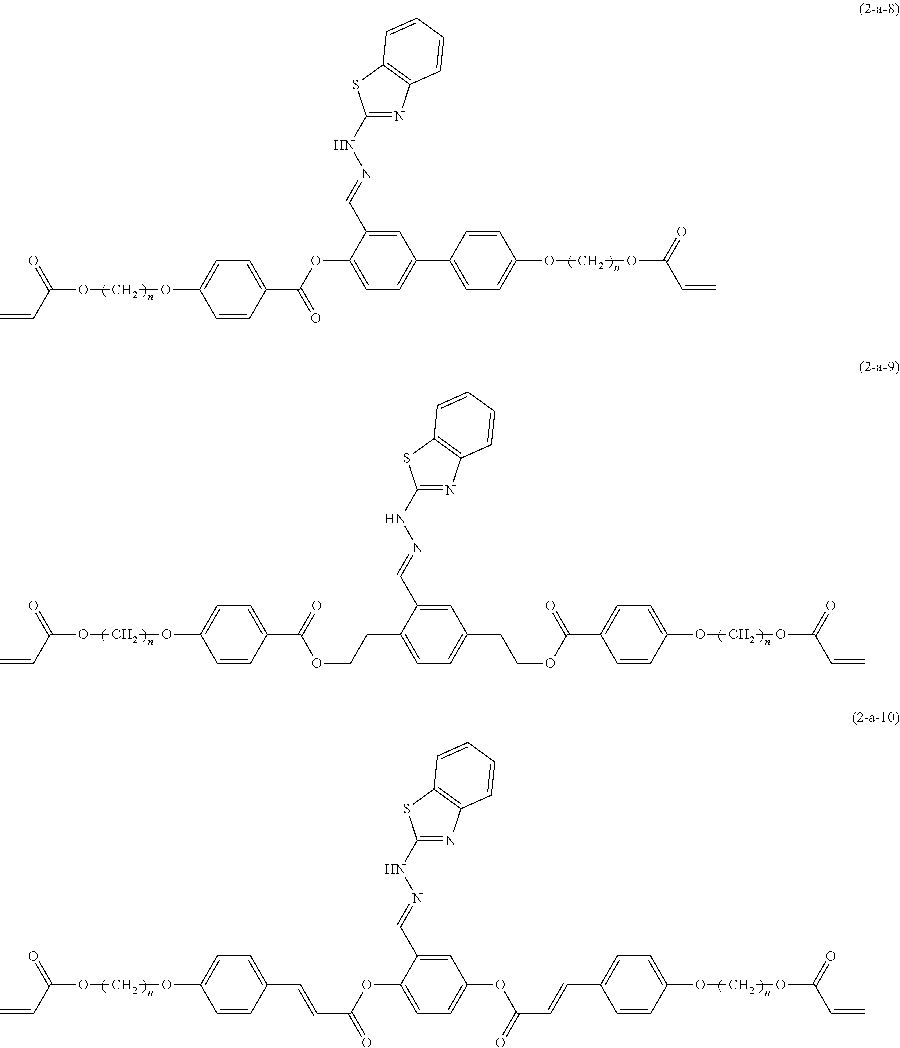

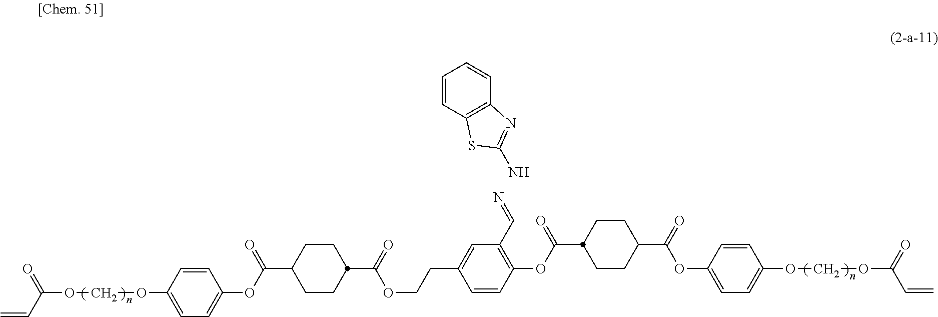

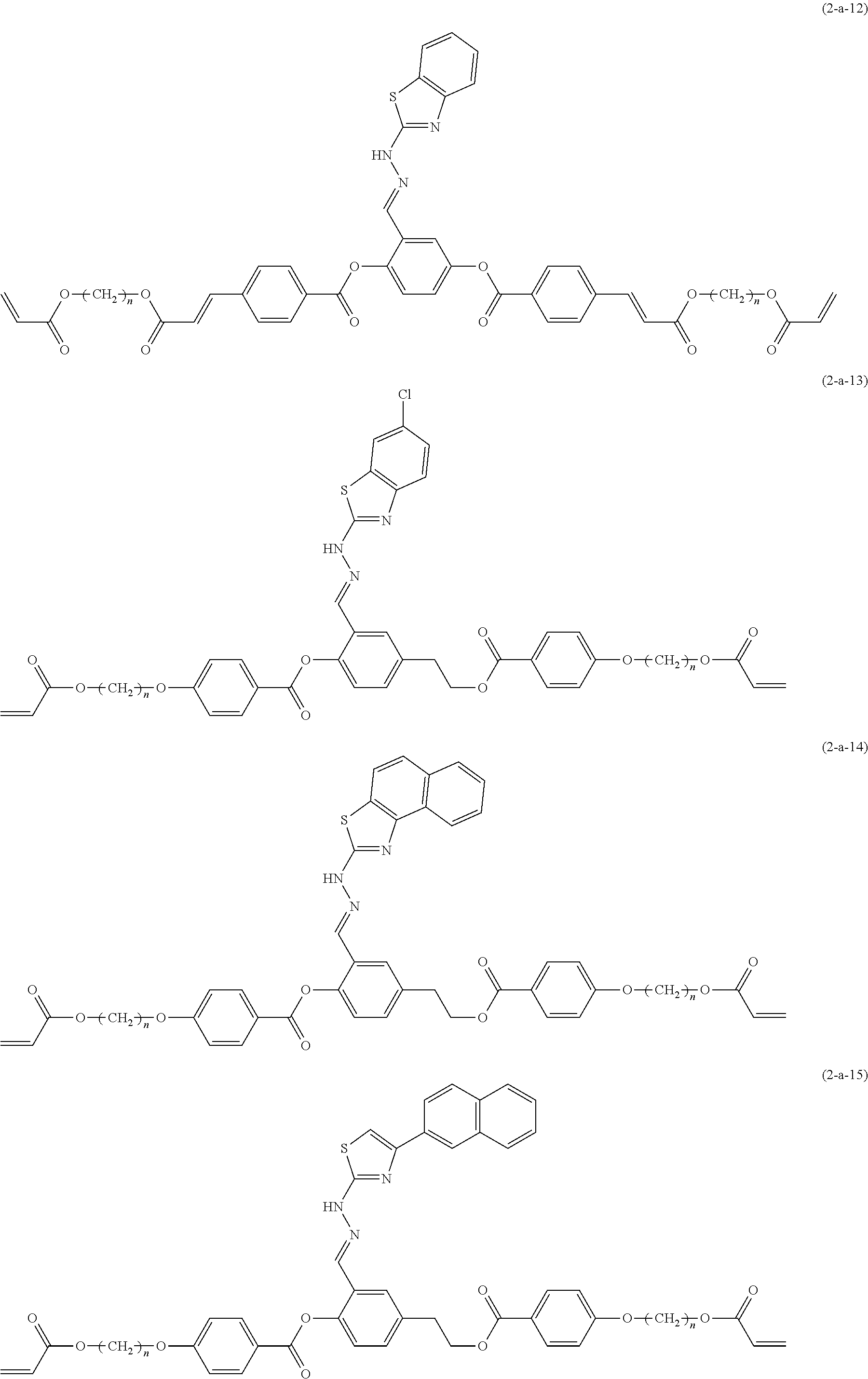

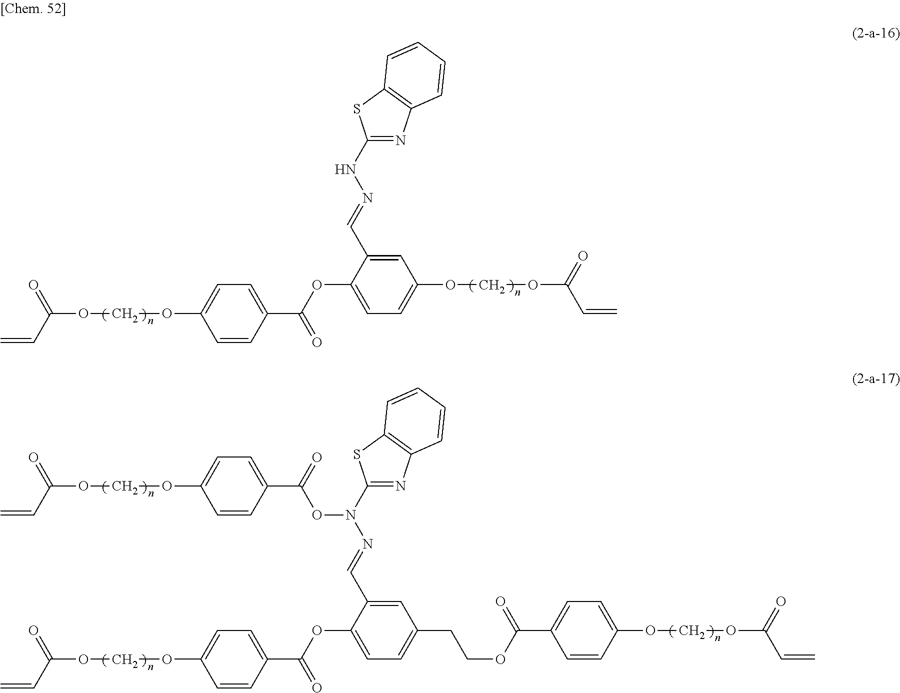

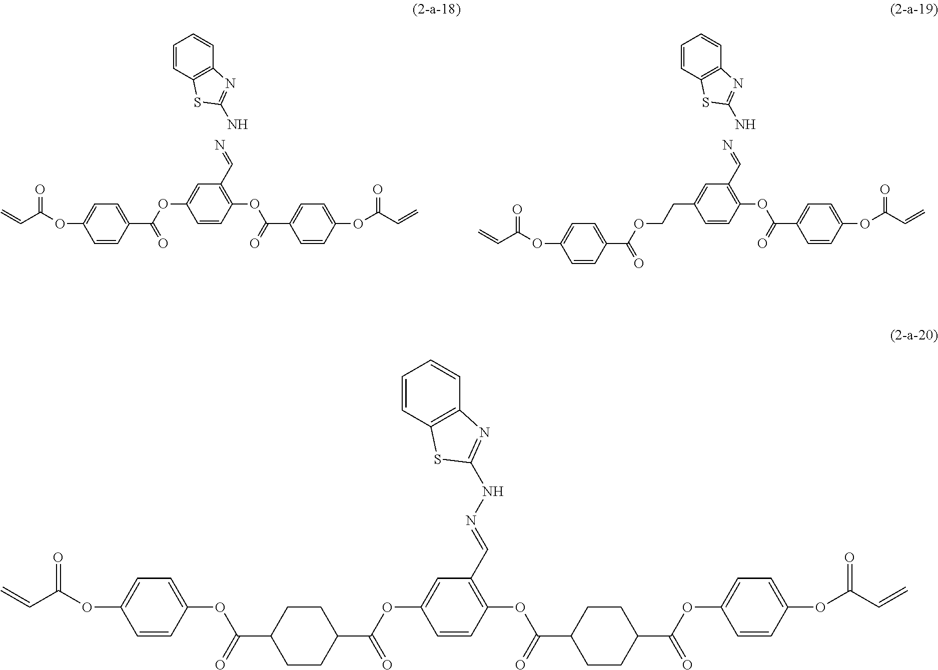

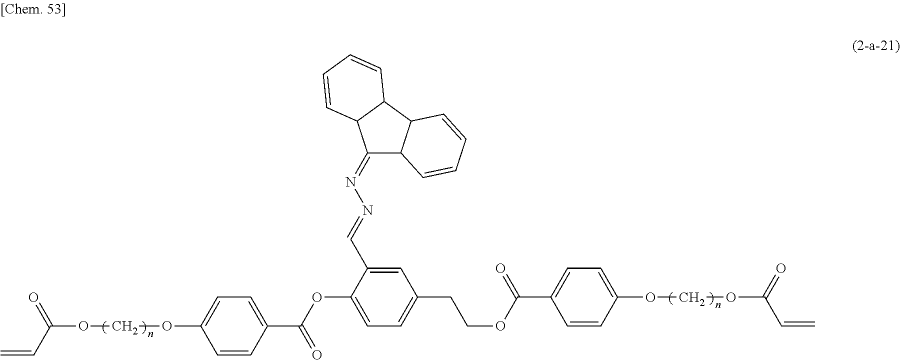

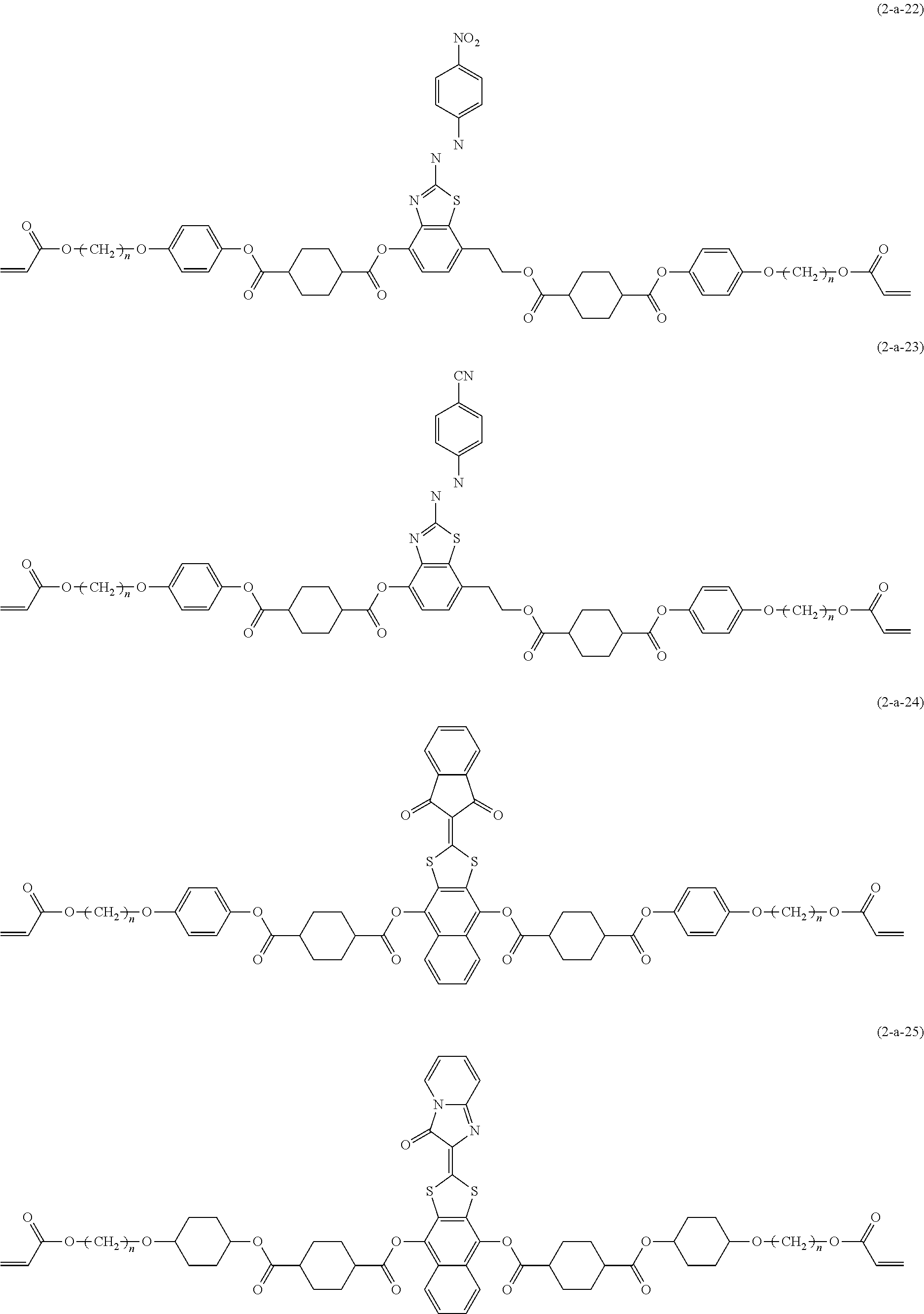

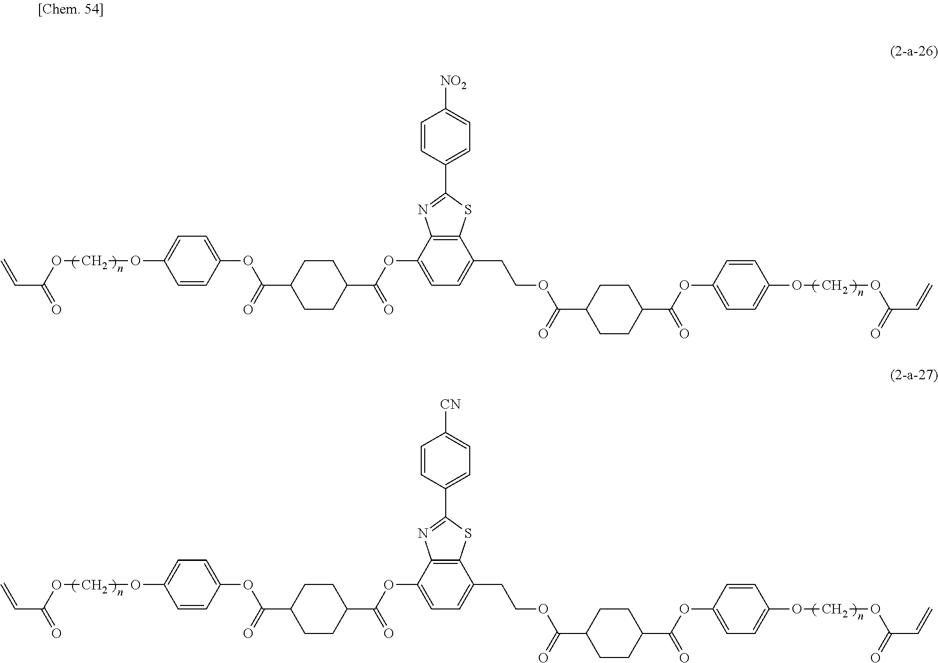

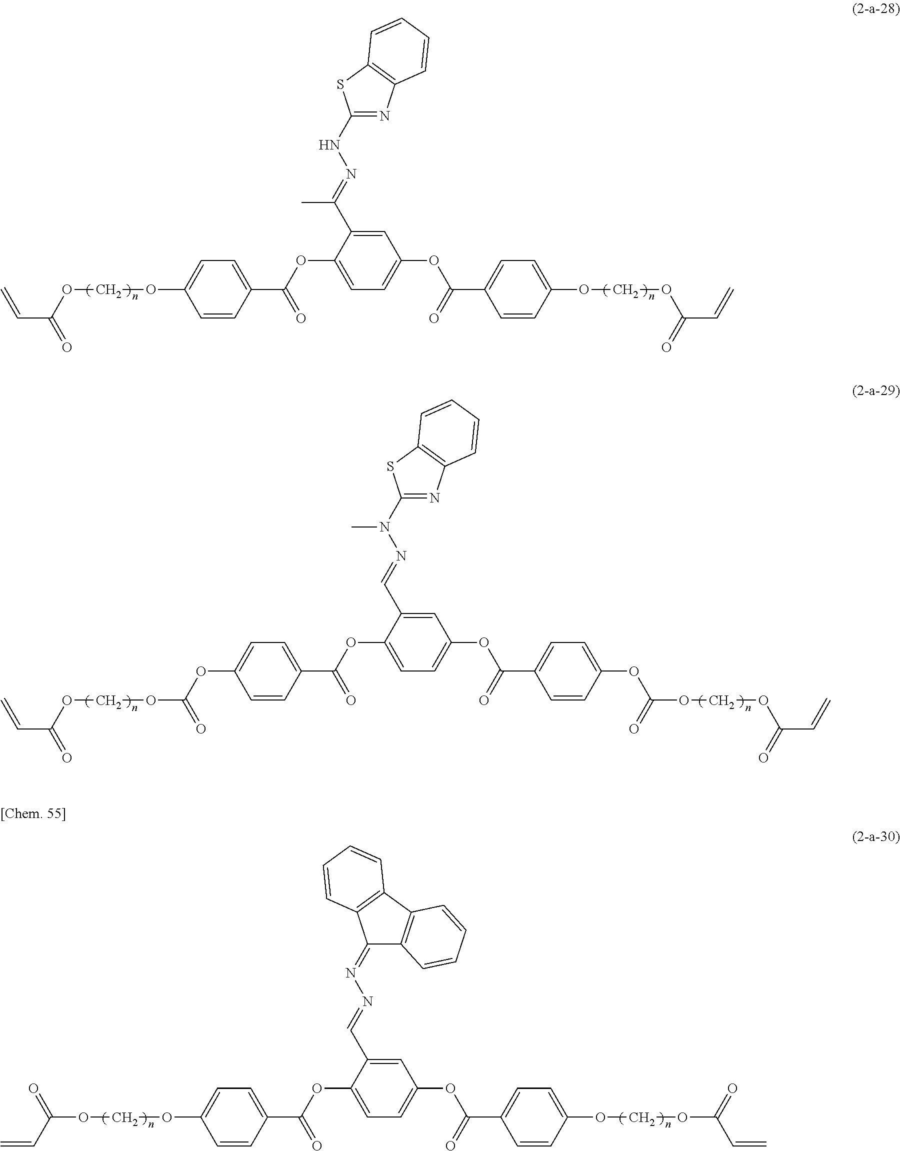

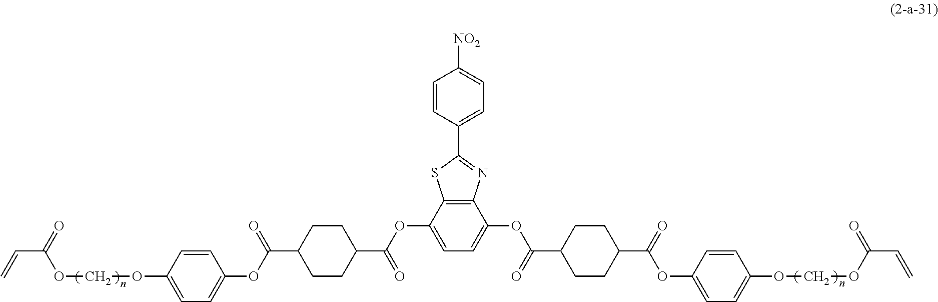

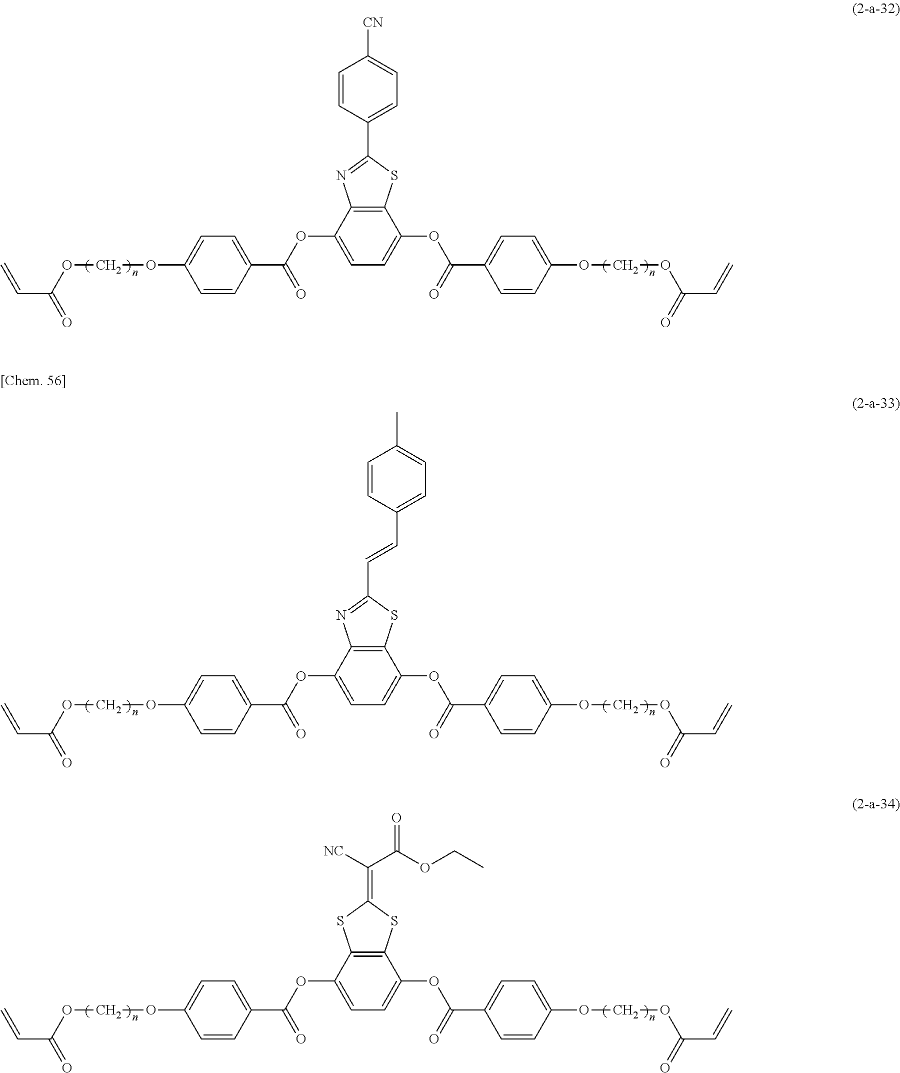

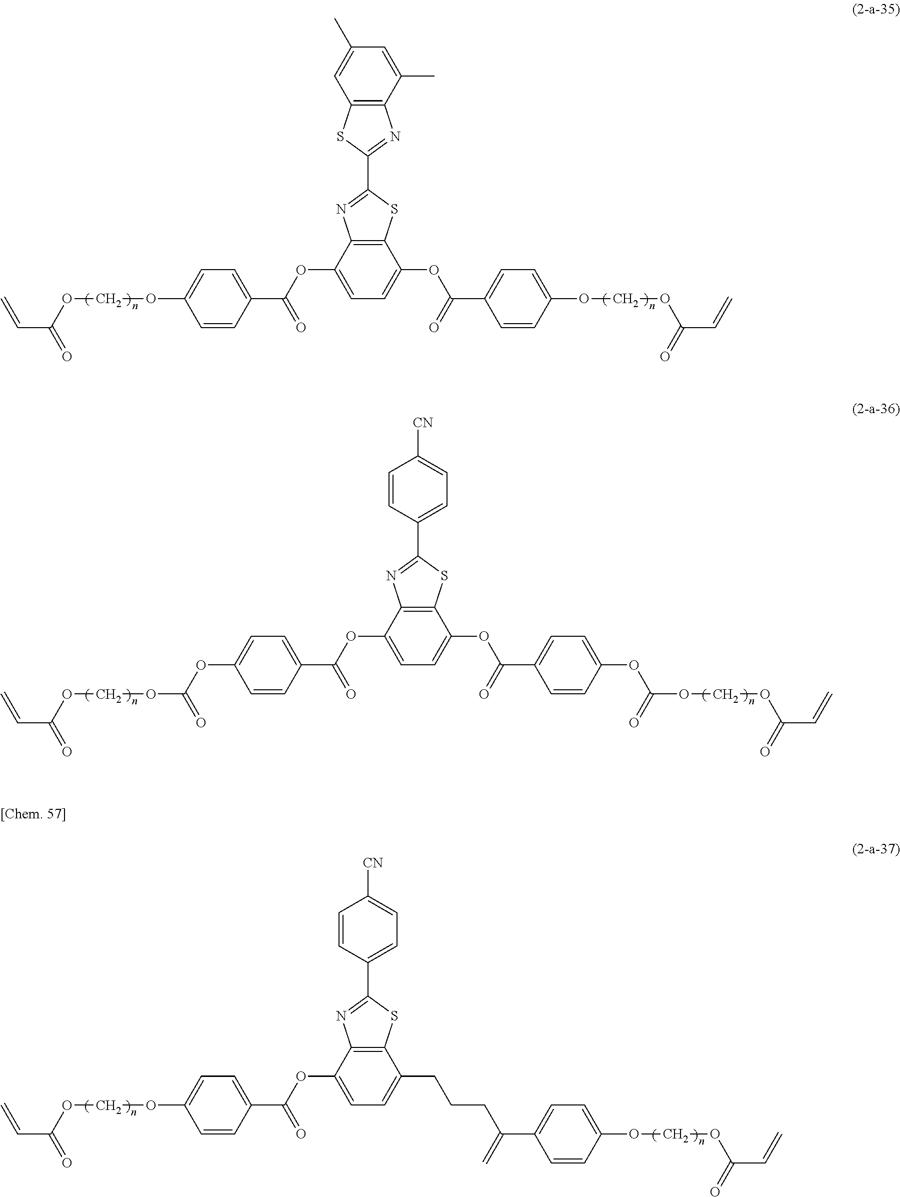

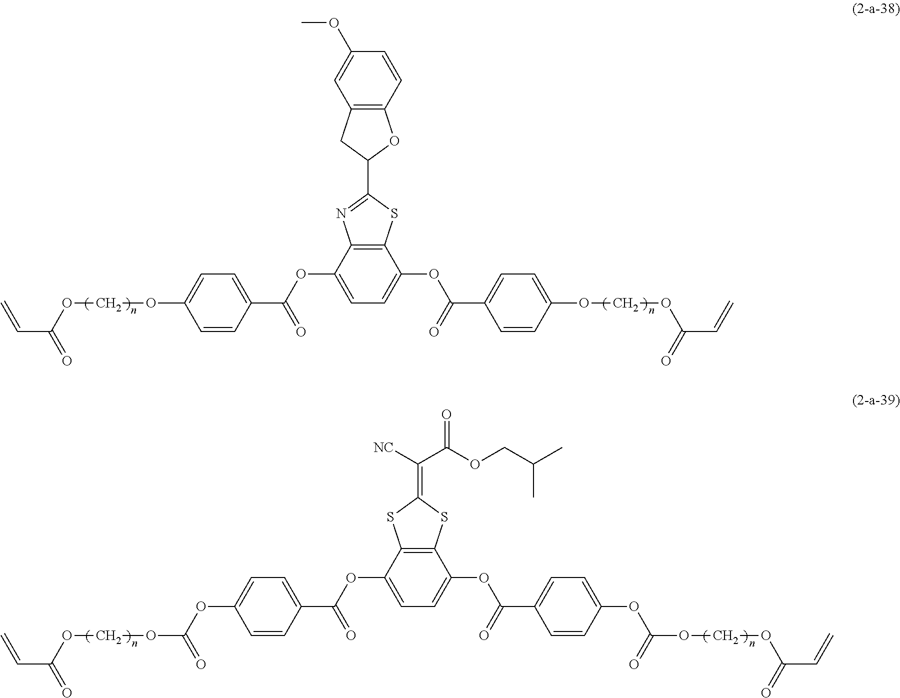

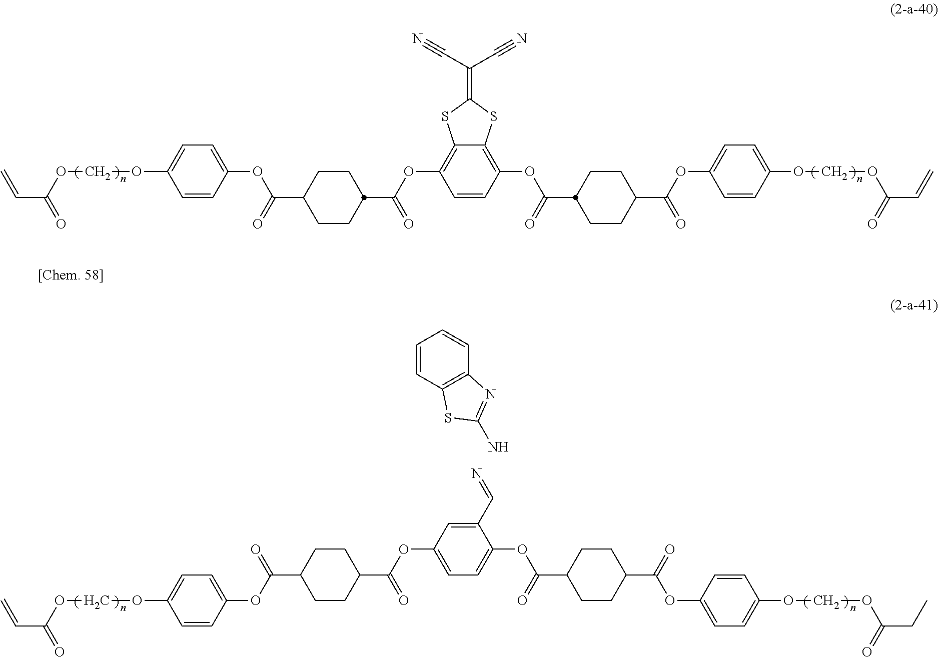

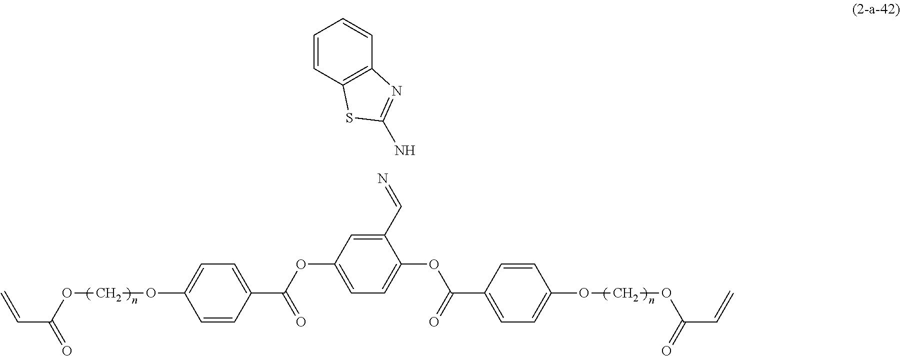

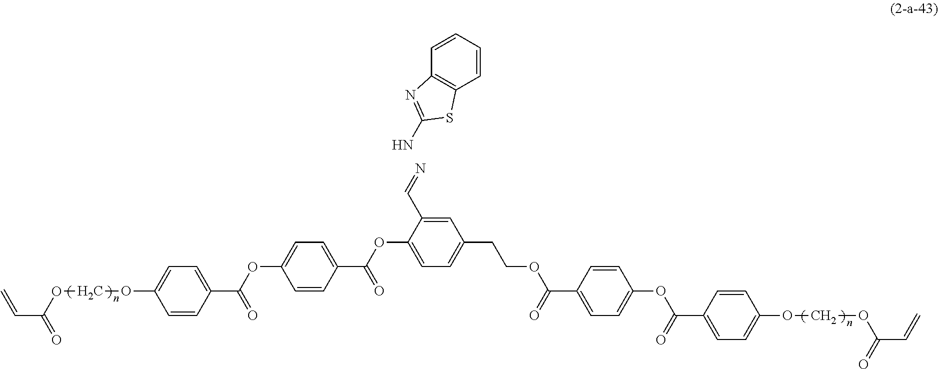

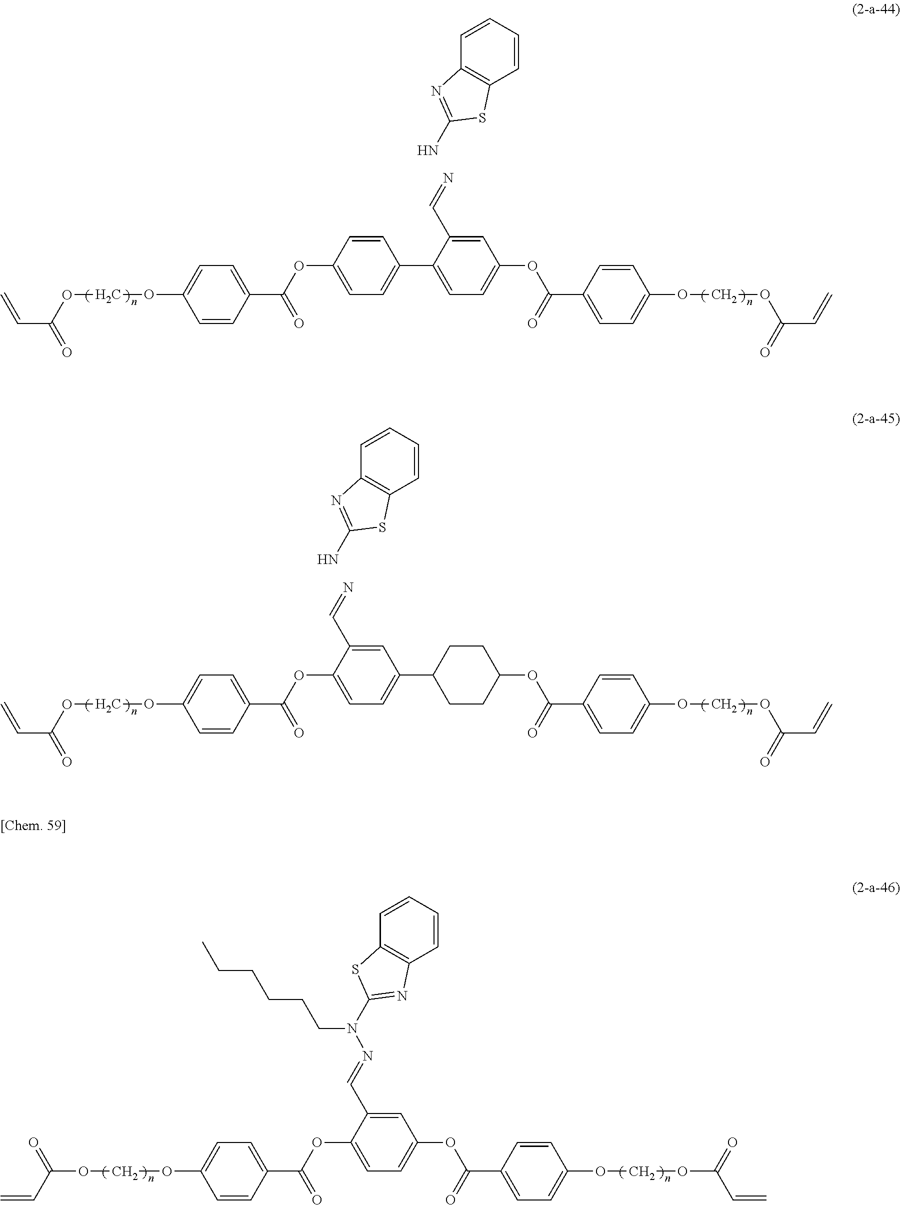

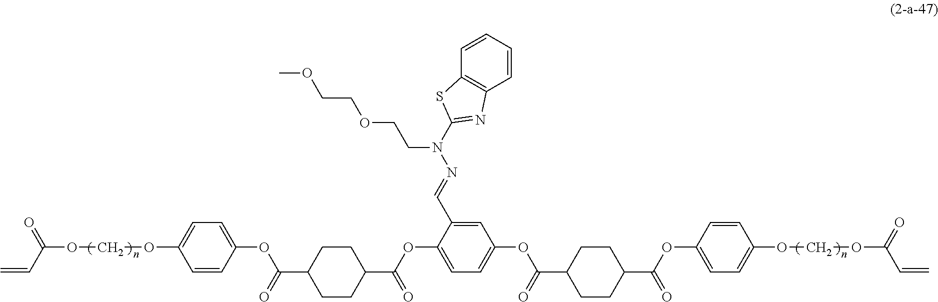

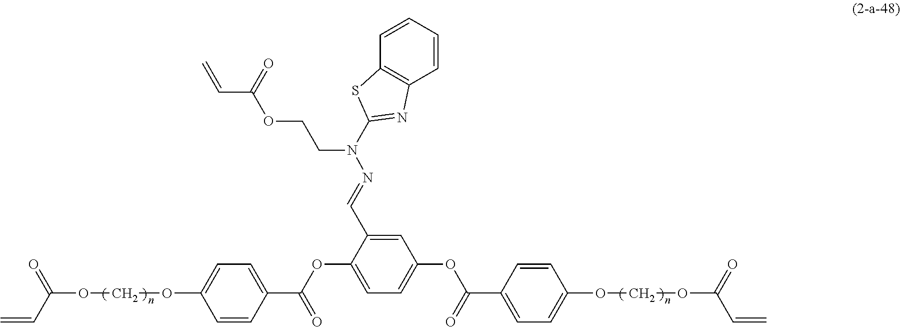

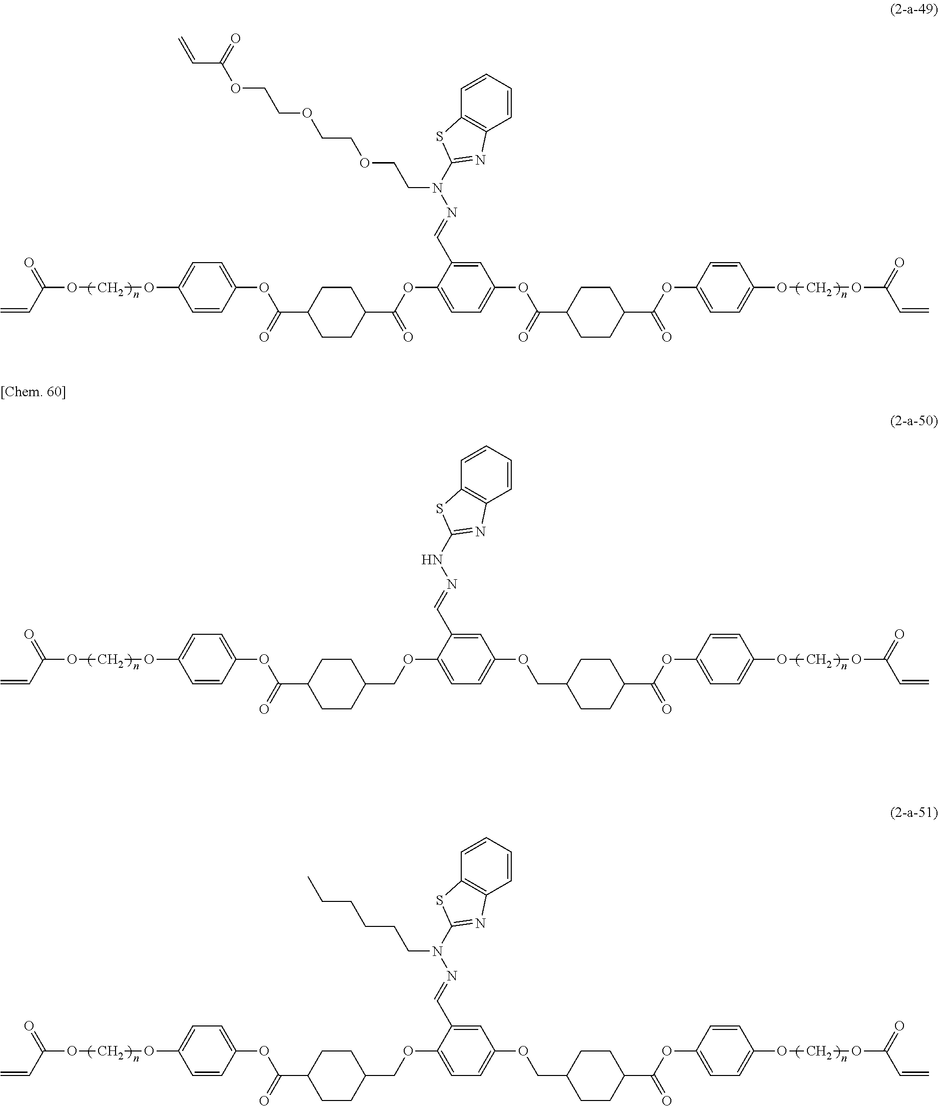

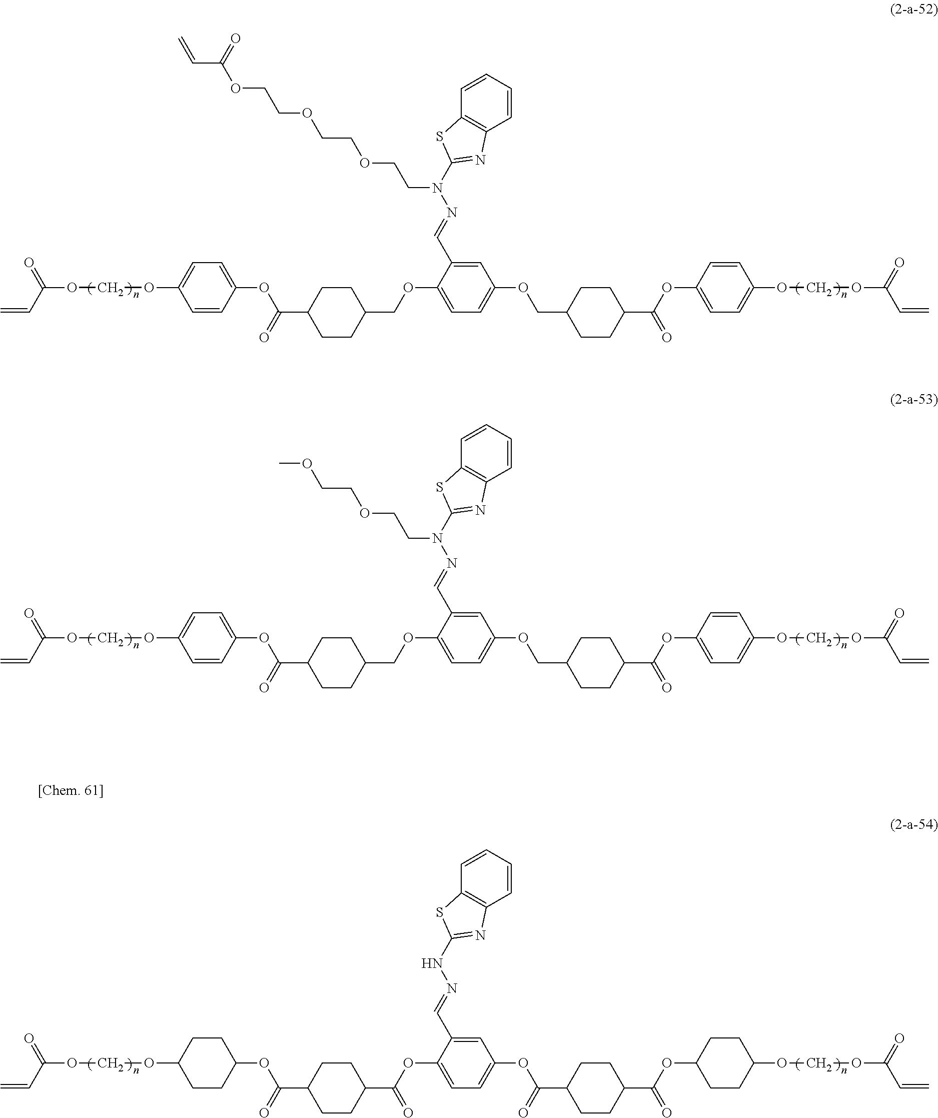

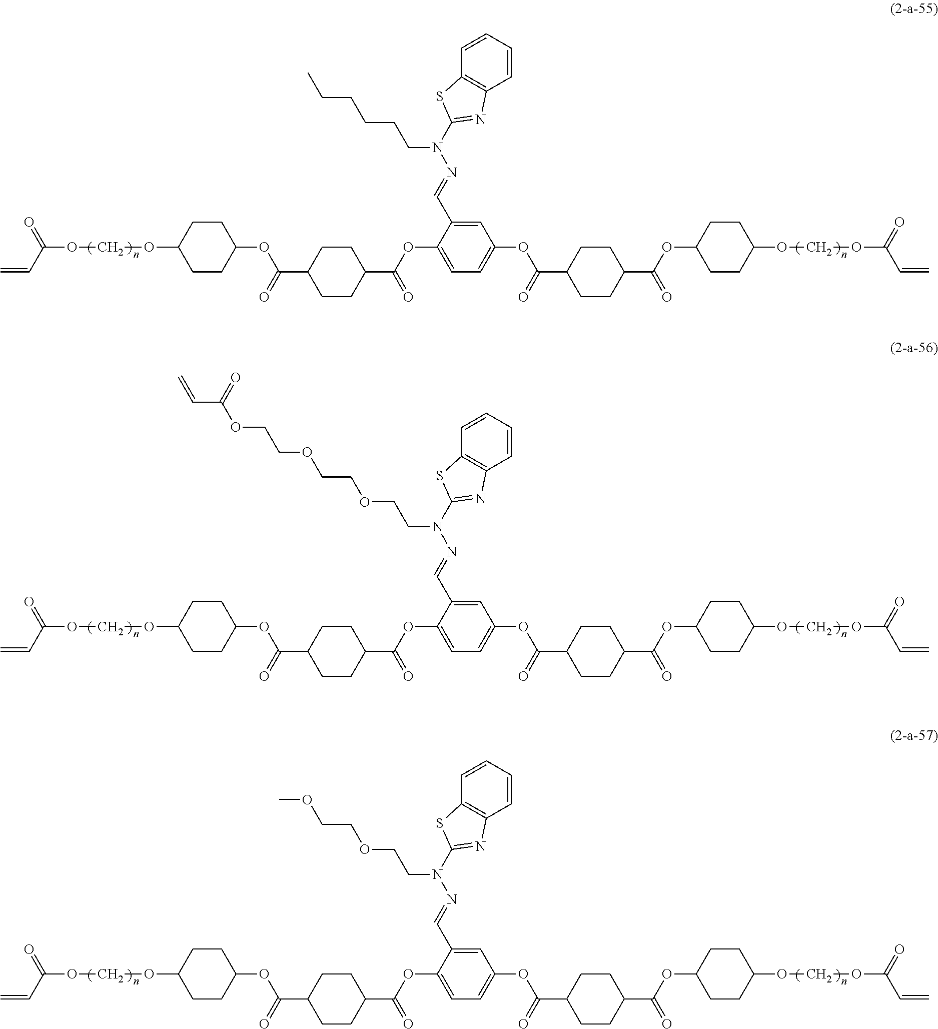

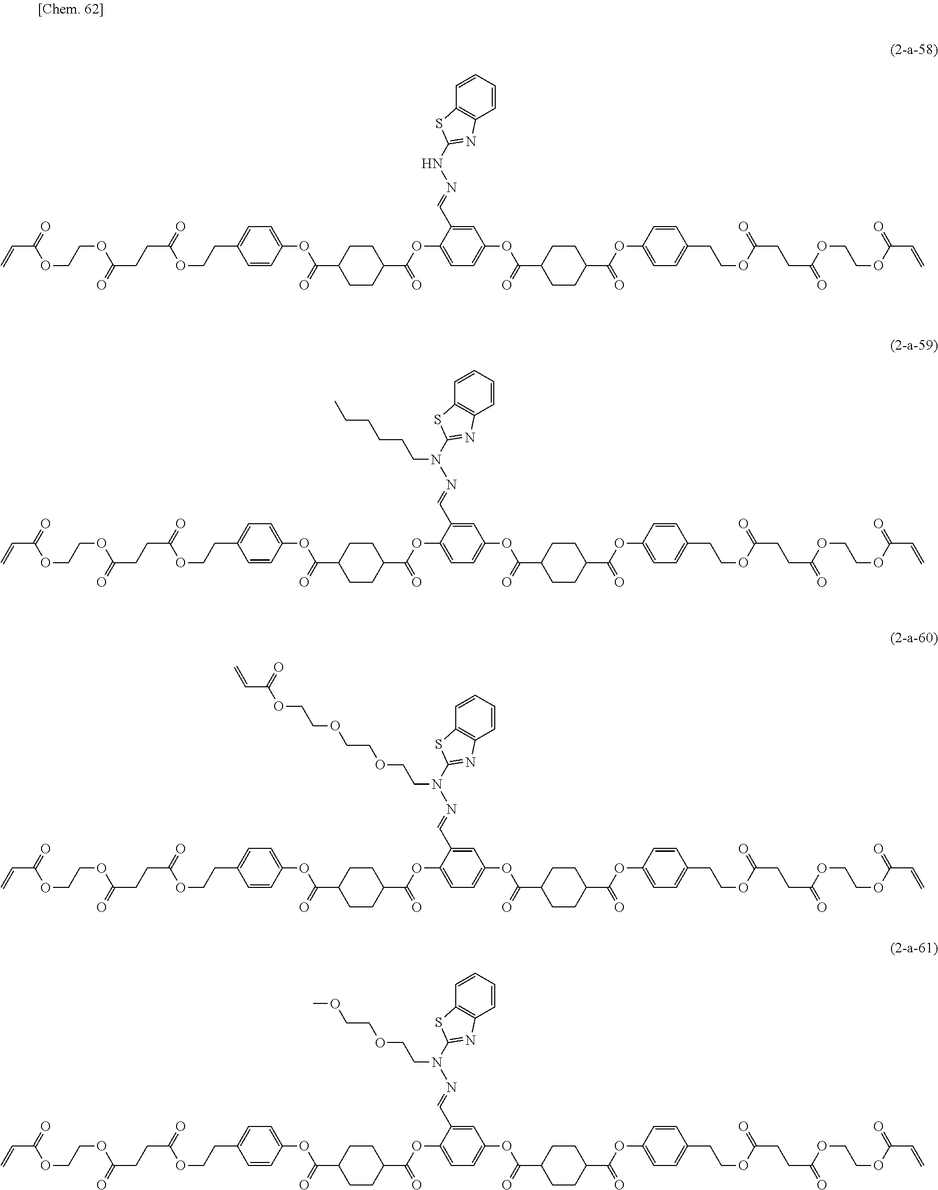

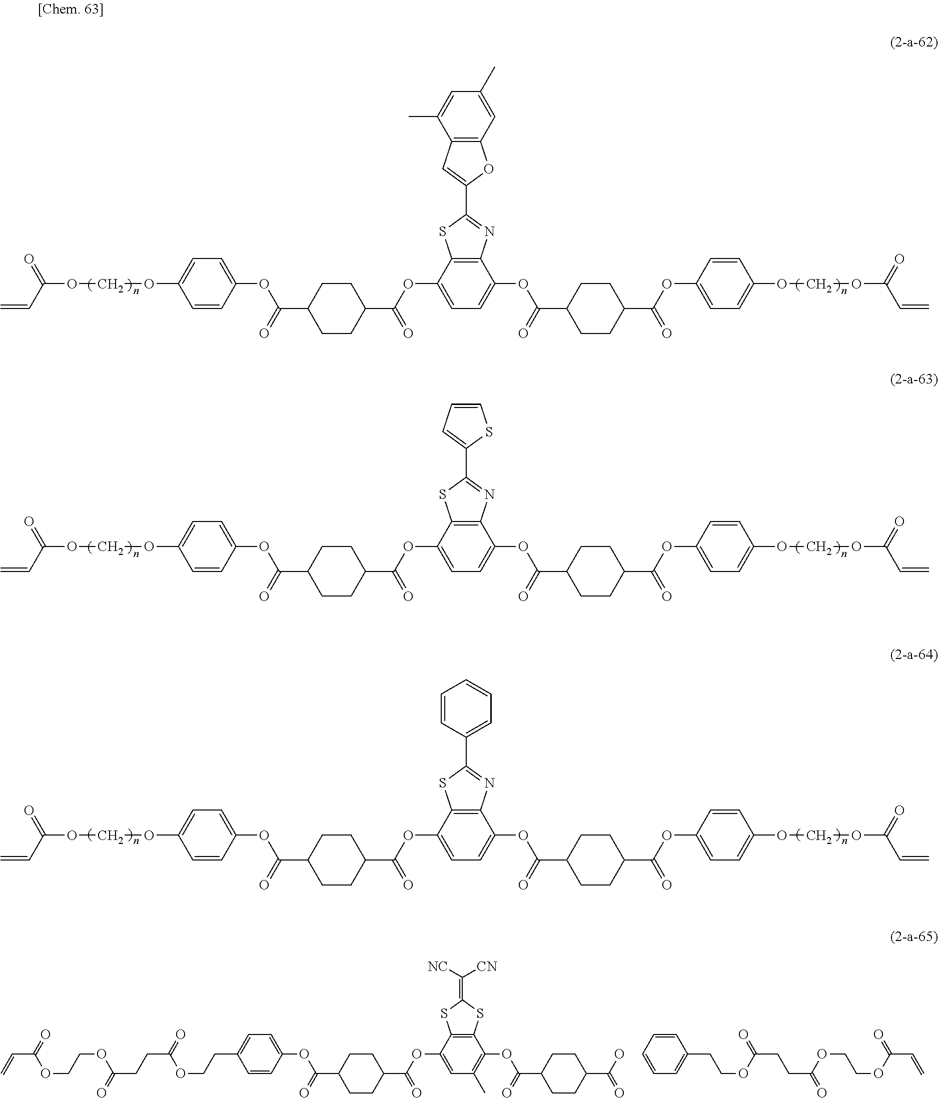

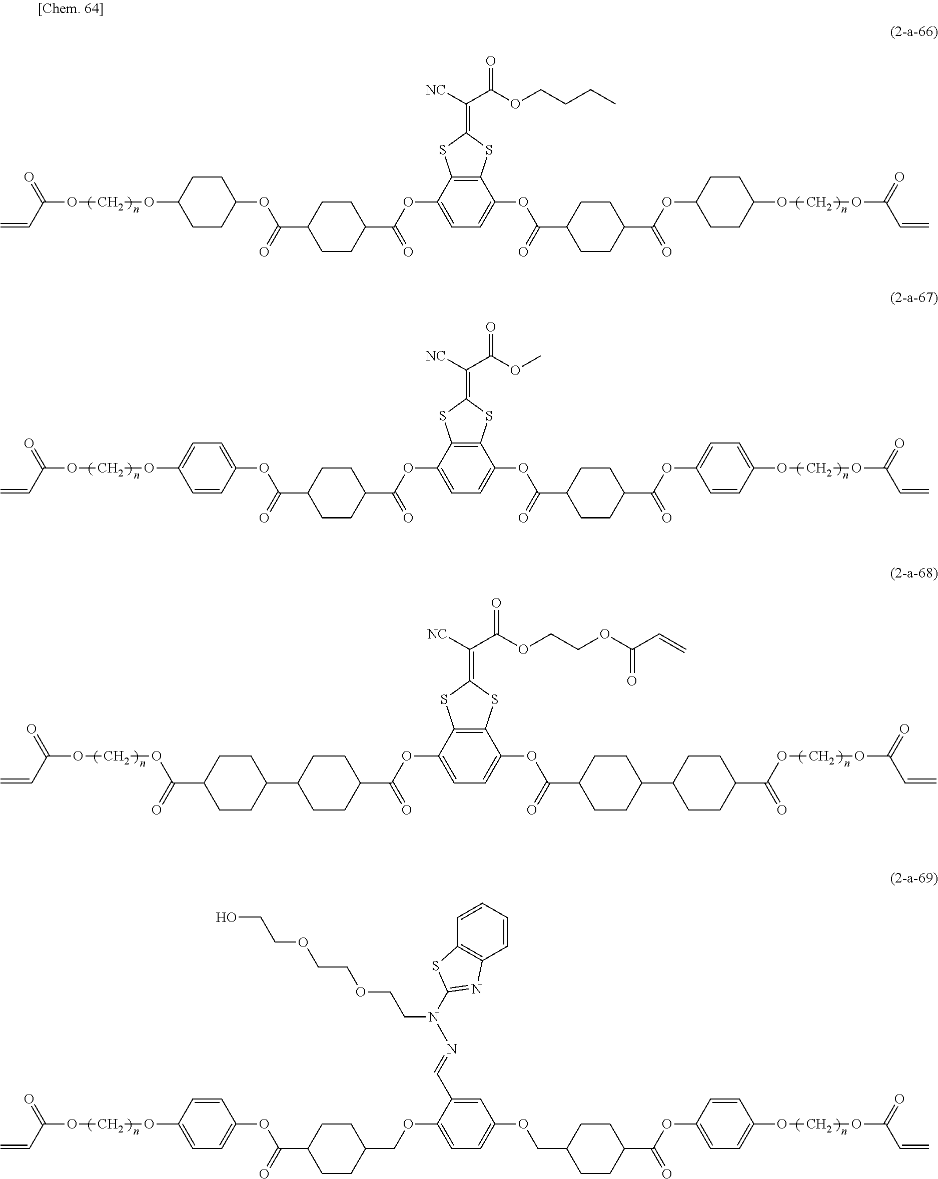

(In the formulae, n represents an integer of 1 to 10.) These liquid crystalline compounds may be used singly or two or more thereof may be mixed to be used.

Preferred specific examples of the compound represented by General Formula (3) include compounds represented by Formula (3-a-1) to Formula (3-a-17).

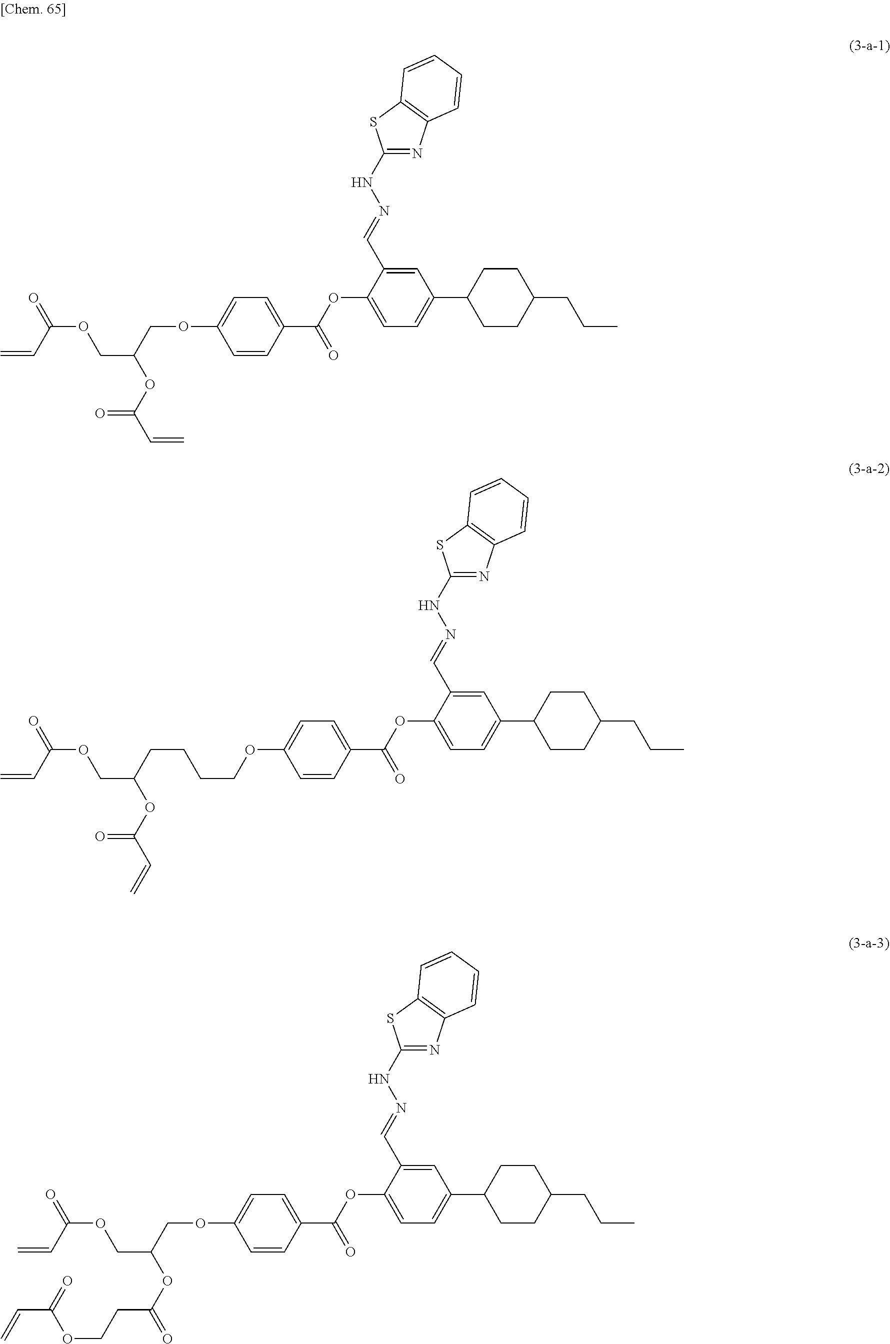

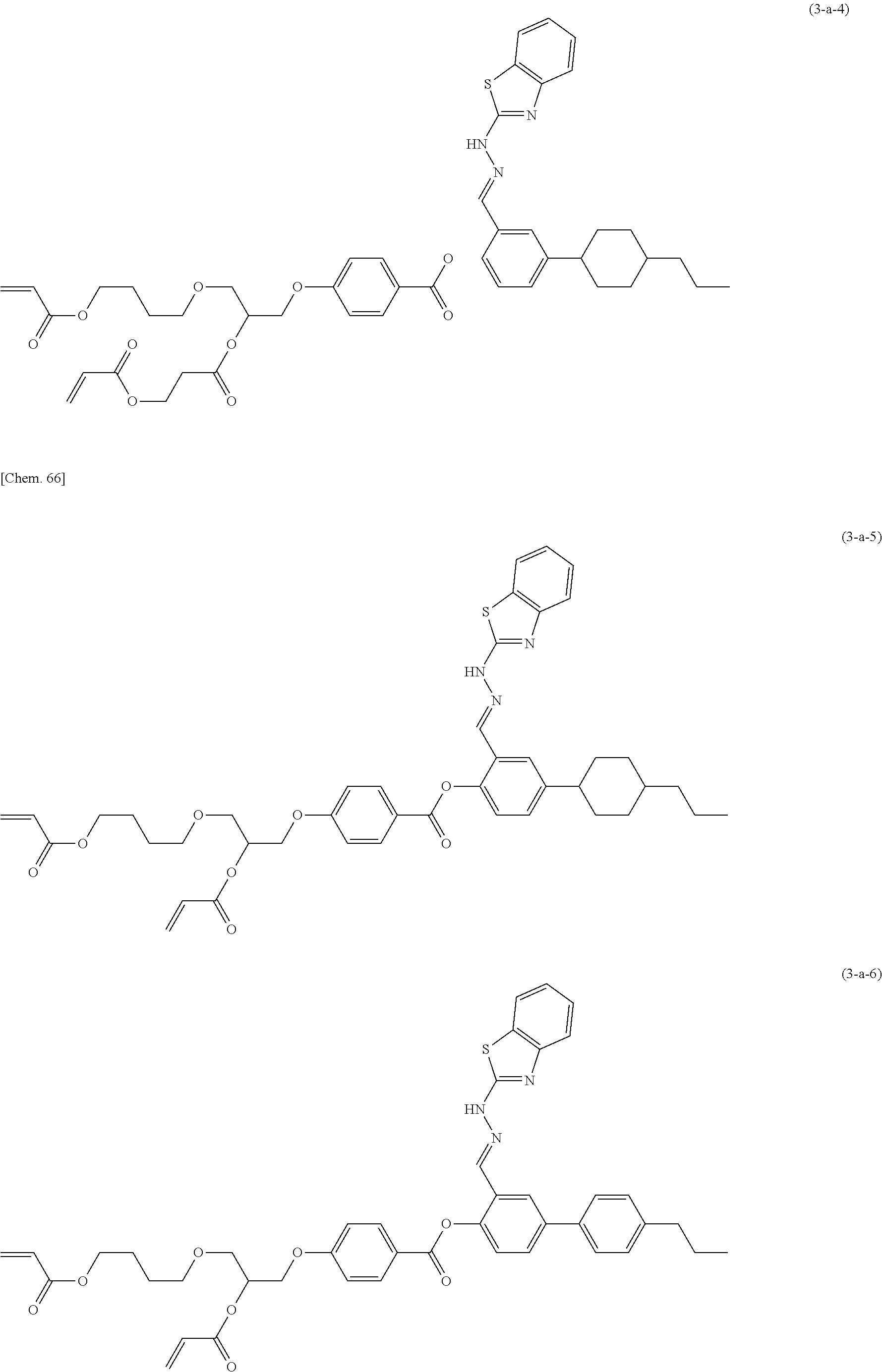

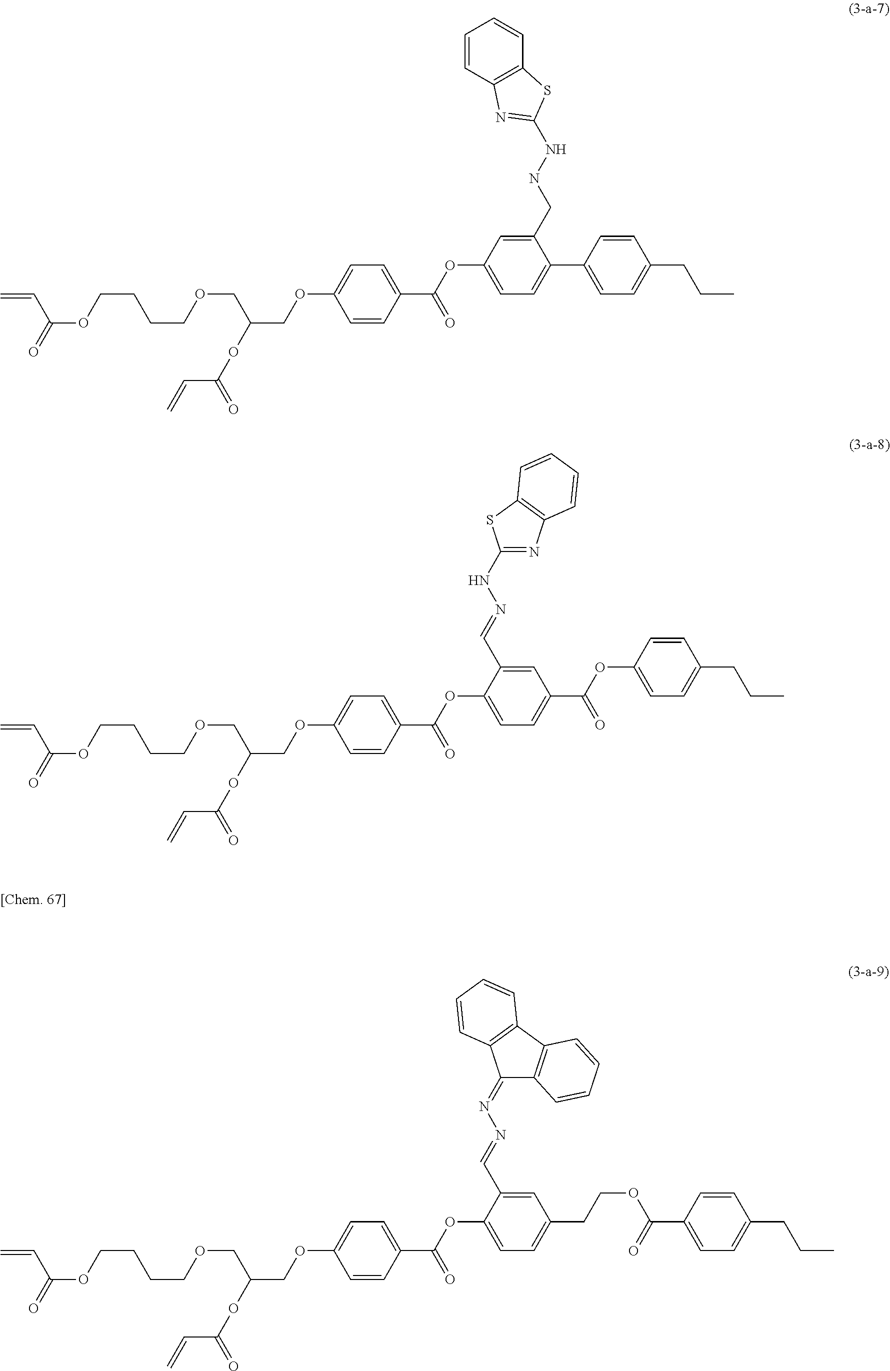

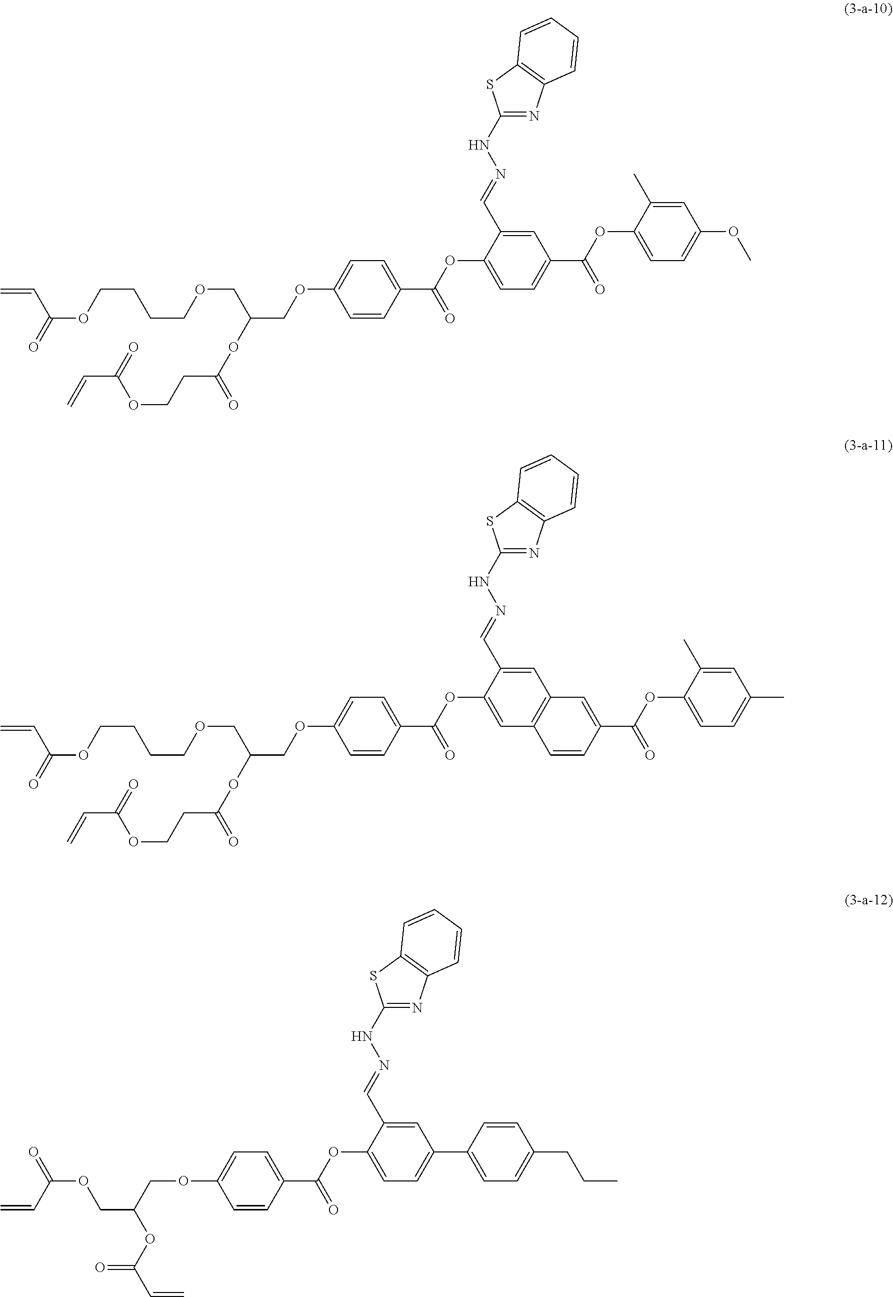

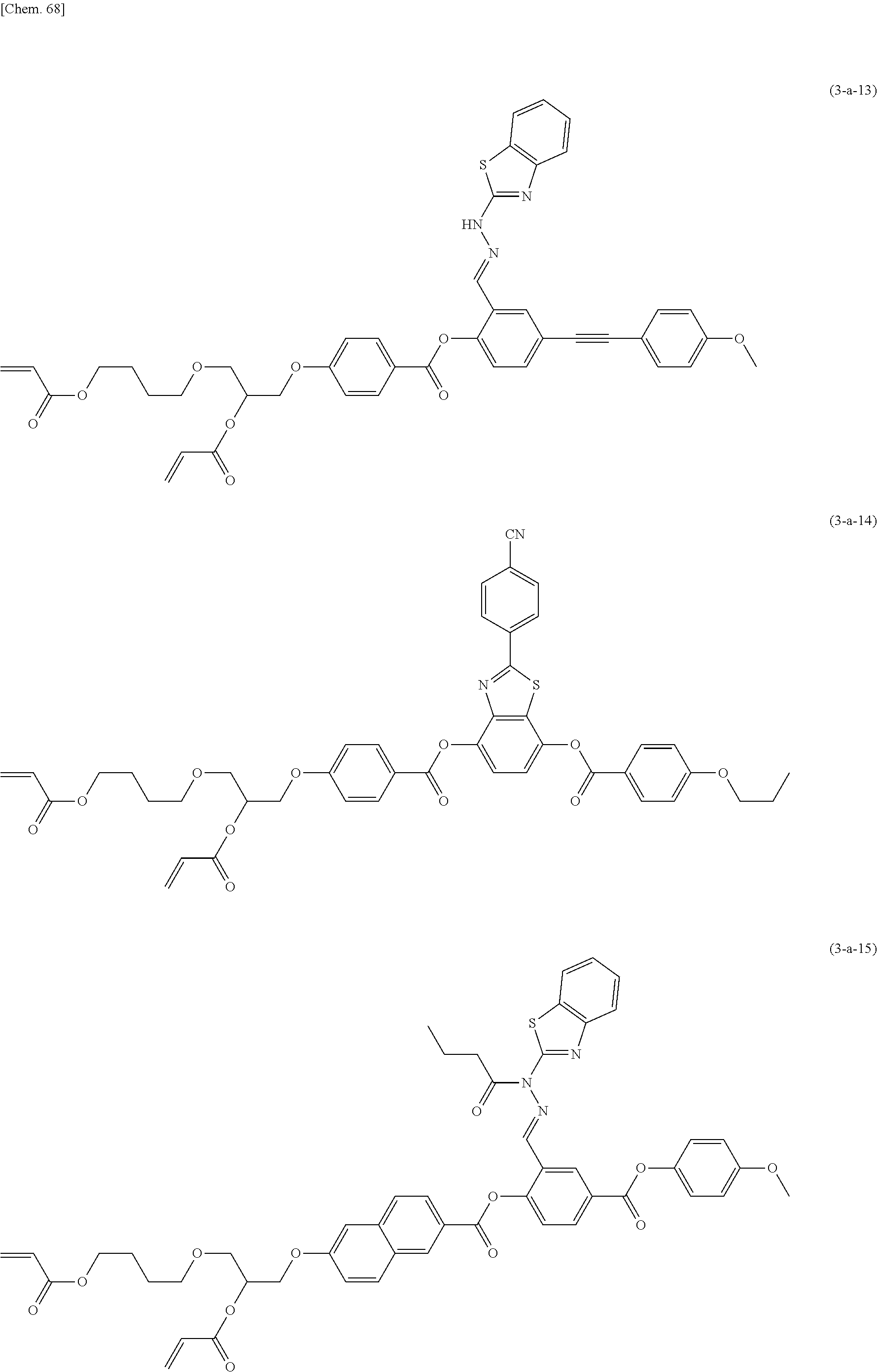

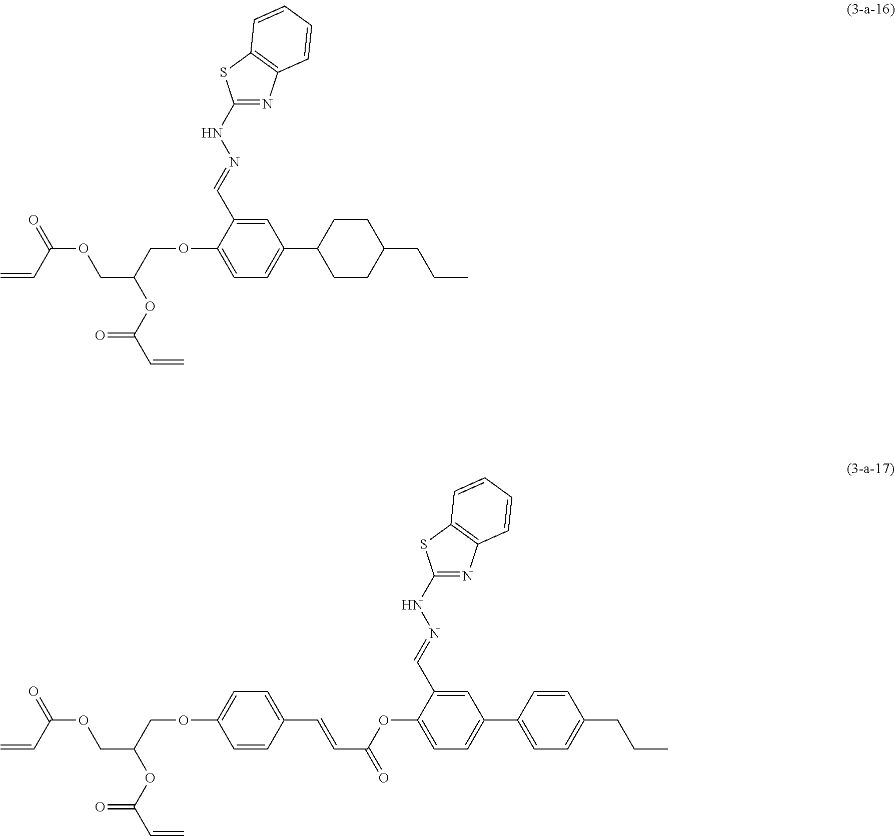

These liquid crystalline compounds may be used singly or two or more thereof may be mixed to be used.

Preferred specific examples of the compound represented by General Formula (4) include compounds represented by Formula (4-a-1) to Formula (4-a-26).

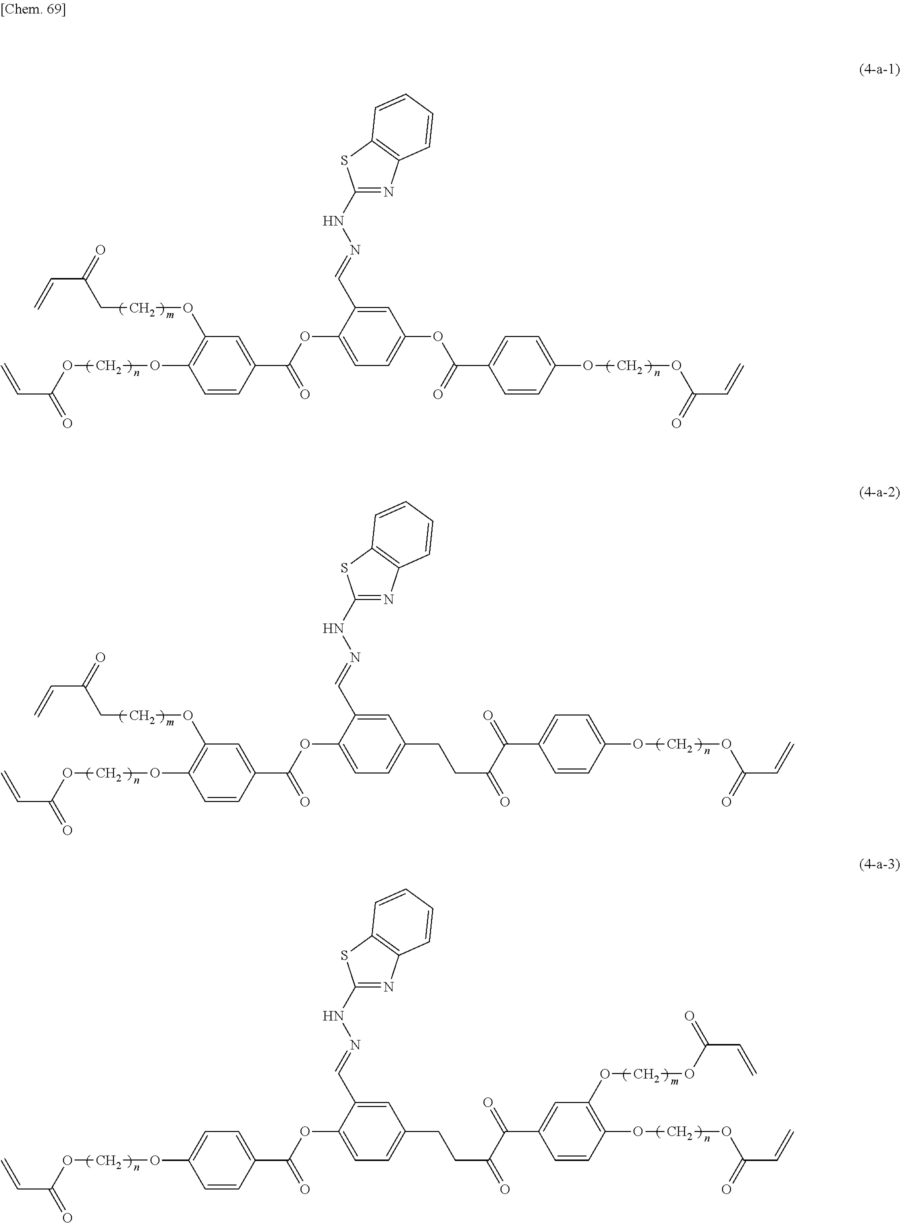

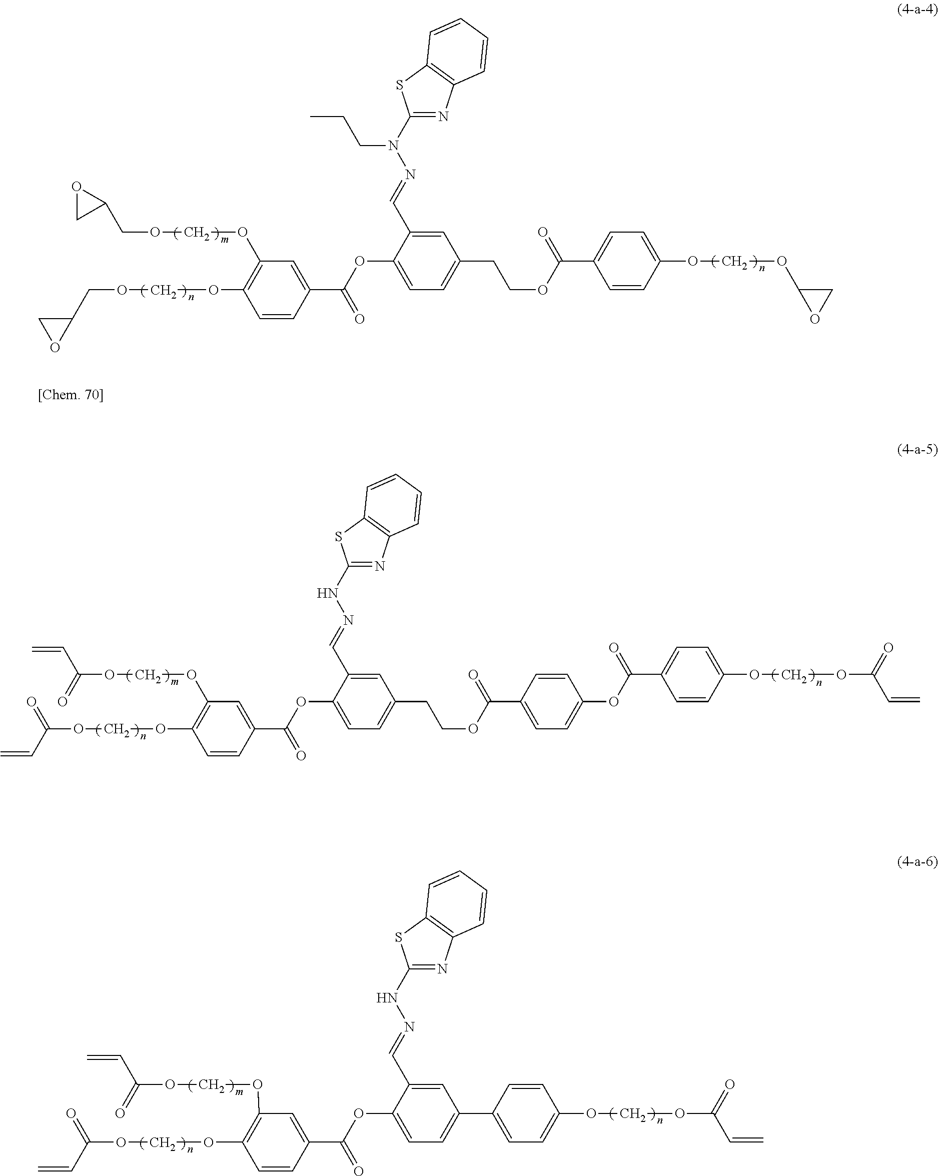

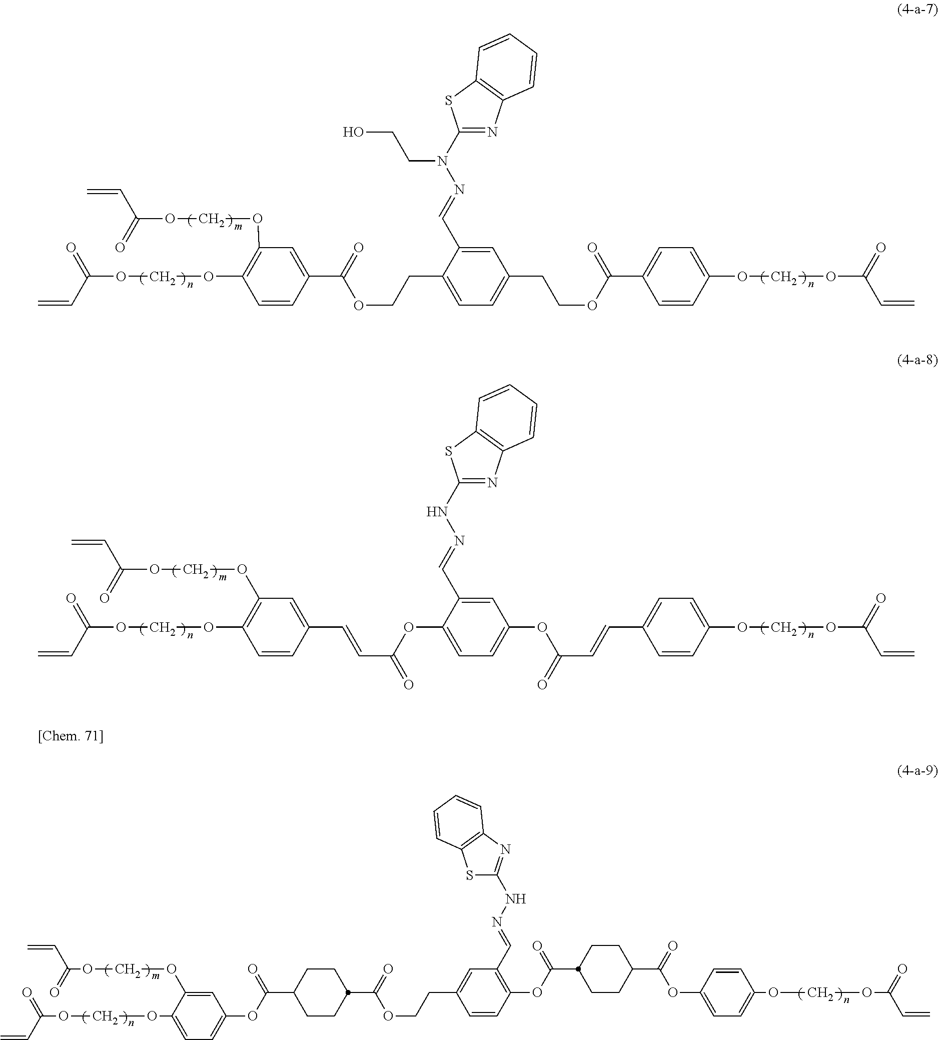

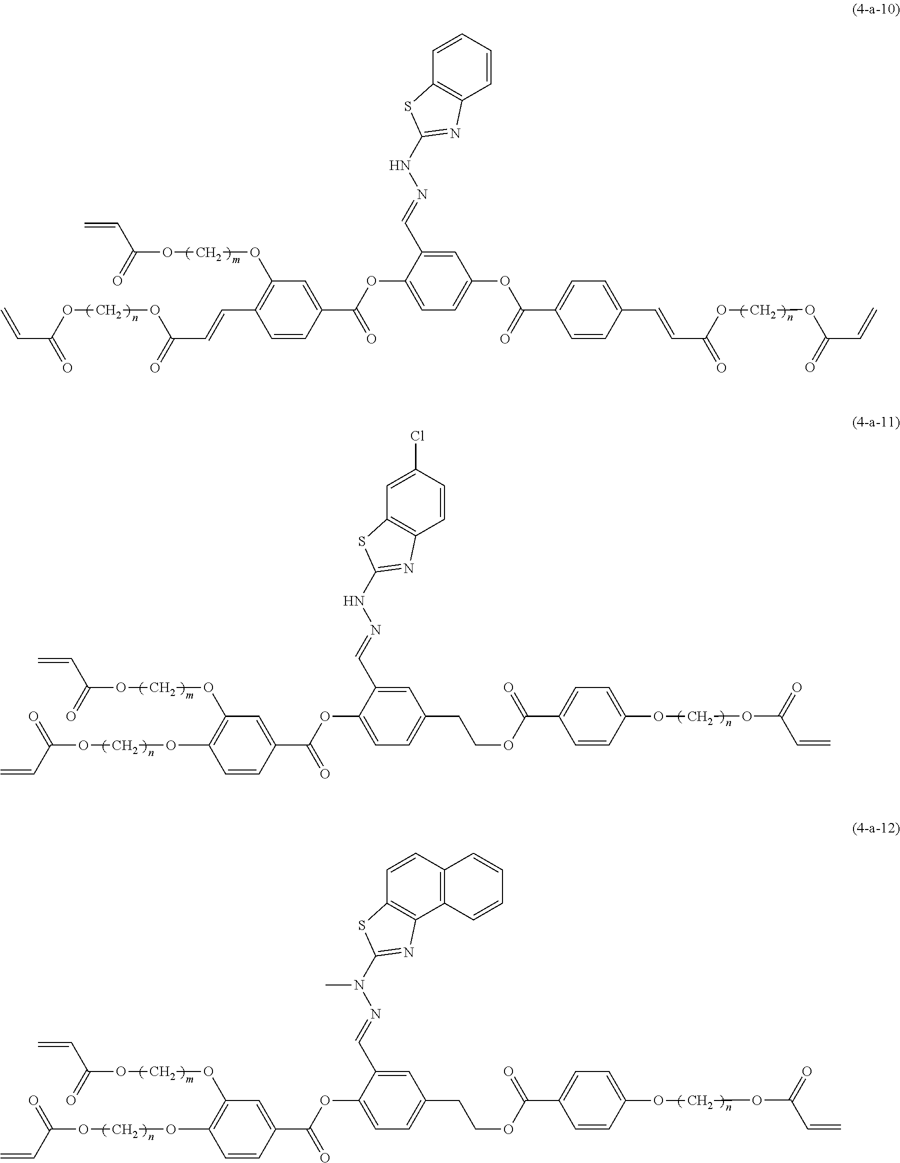

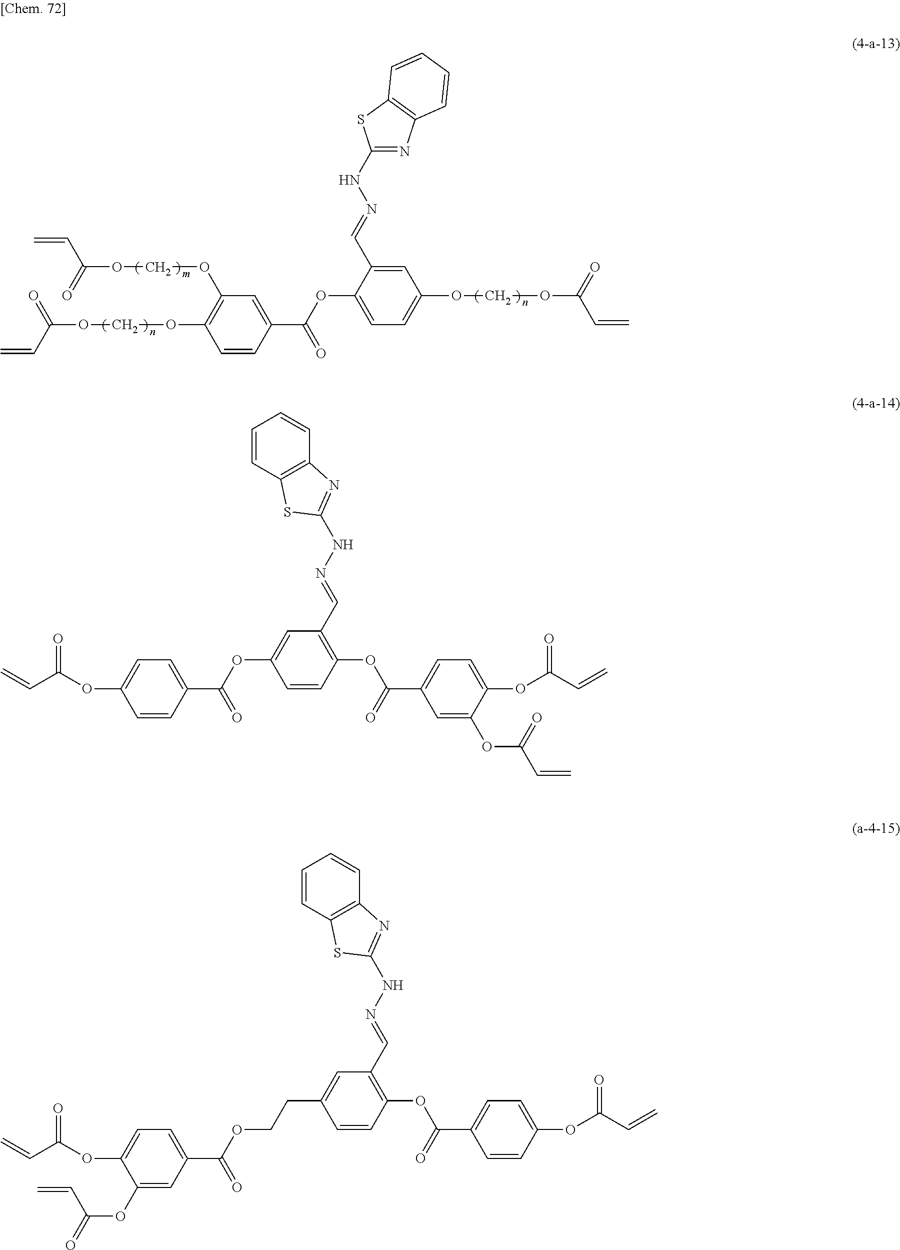

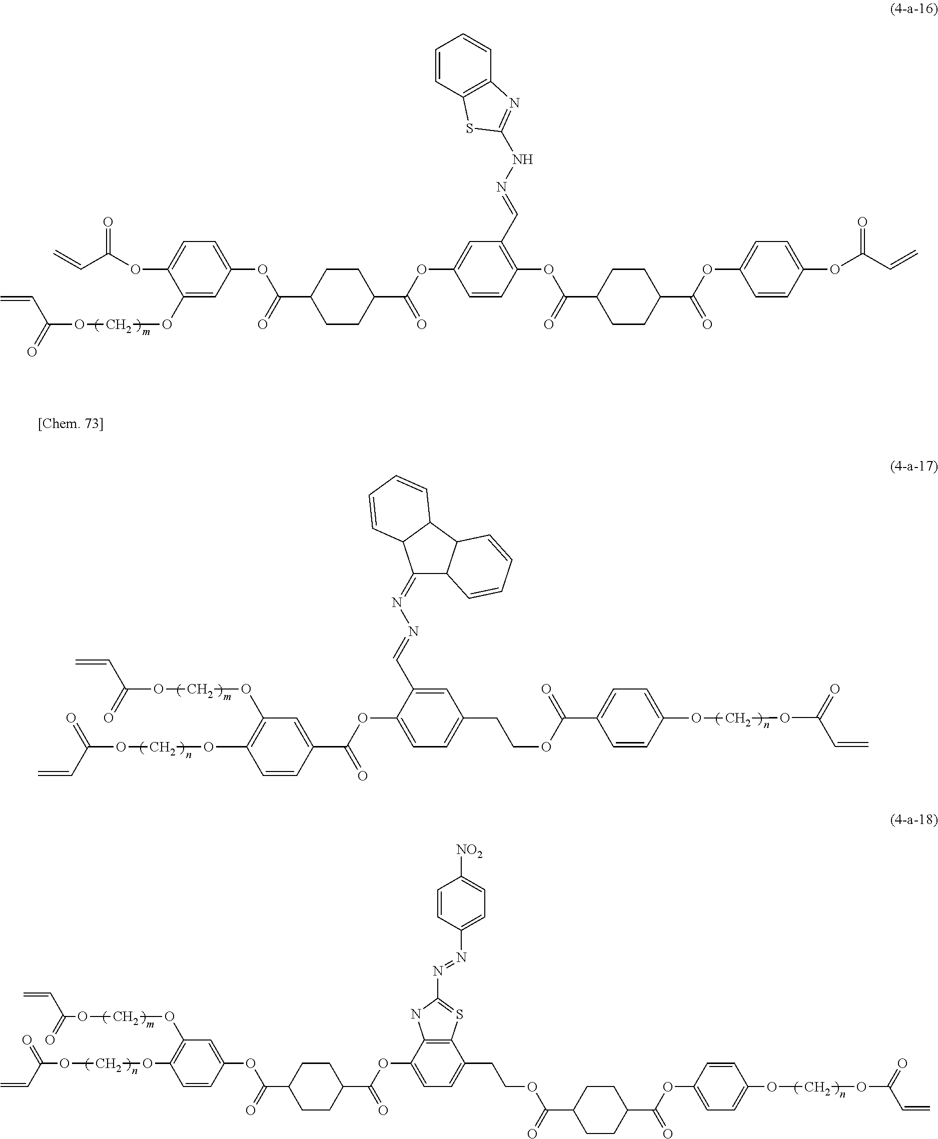

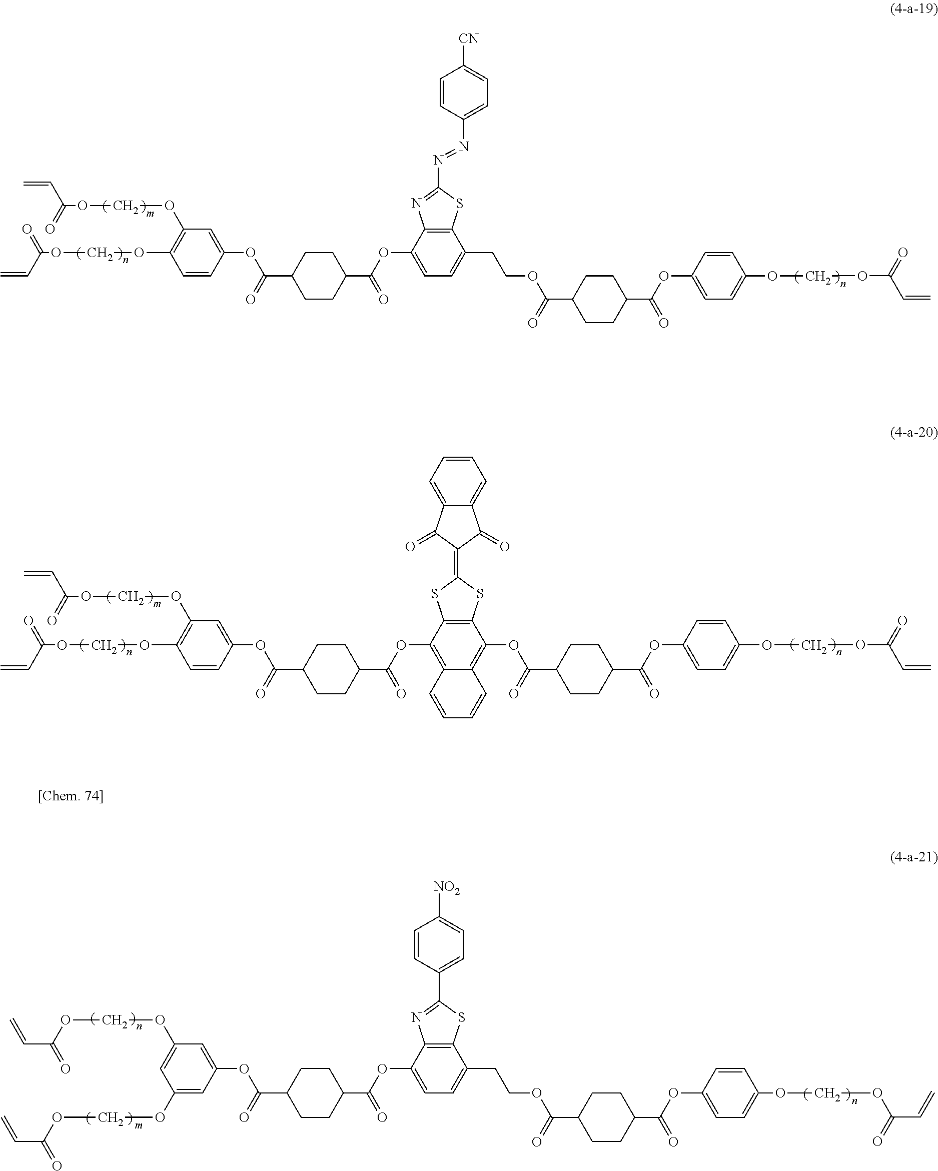

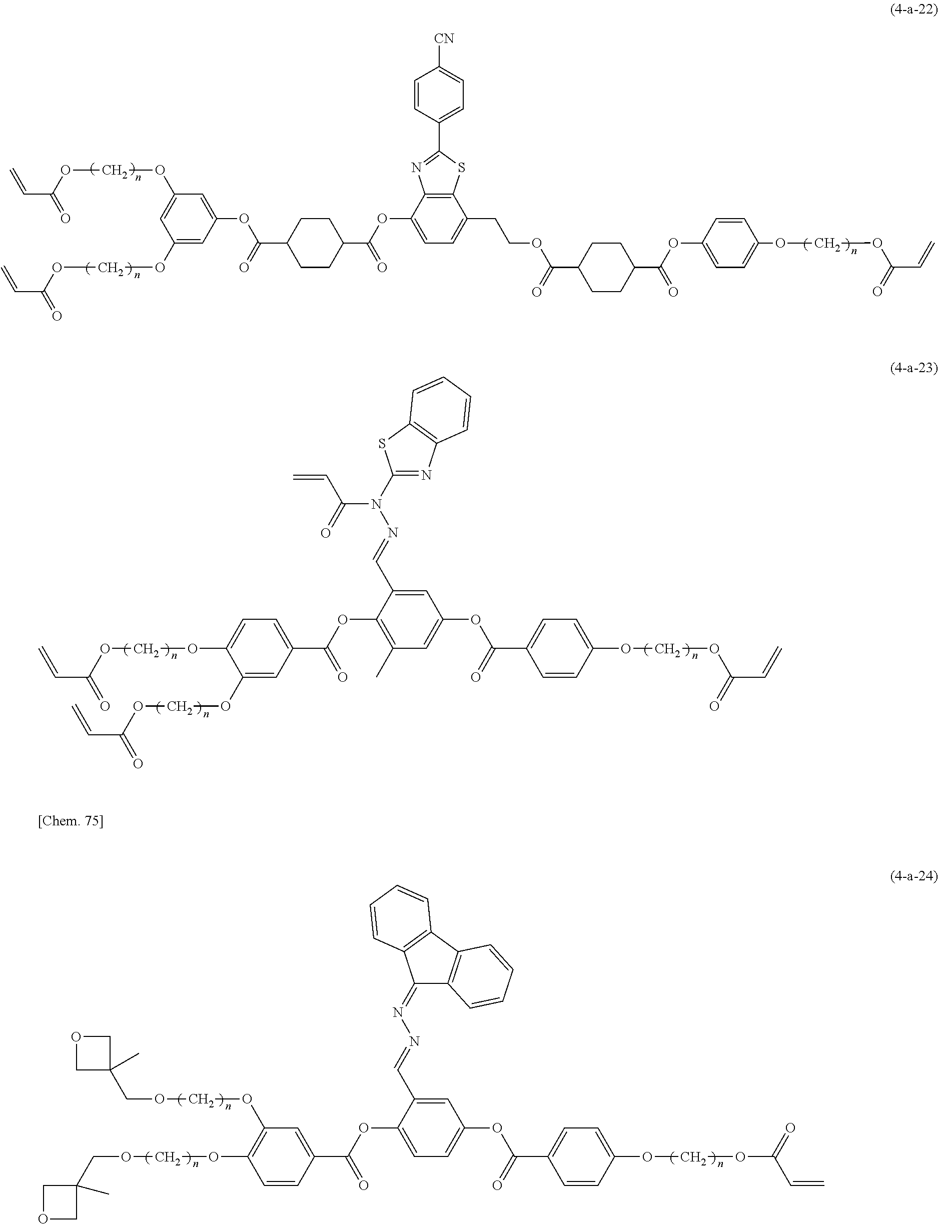

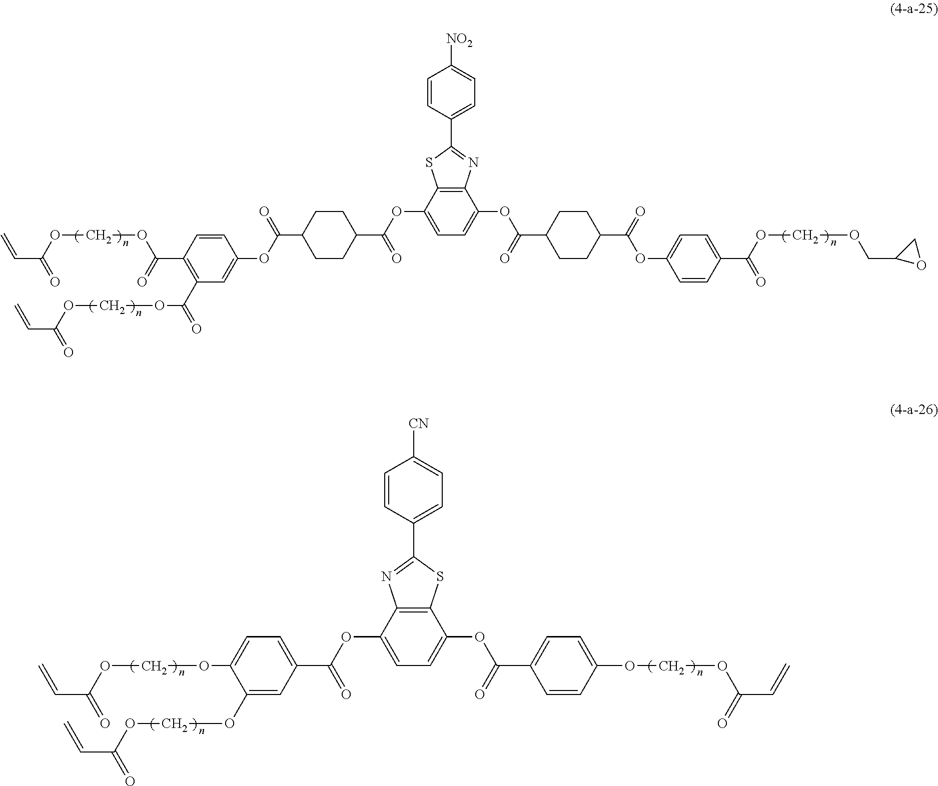

(In the formulae, m and n each independently represent an integer of 1 to 10.) These liquid crystalline compounds may be used singly or two or more thereof may be mixed to be used.

Preferred specific examples of the compound represented by General Formula (5) include compounds represented by Formula (5-a-1) to Formula (5-a-29).

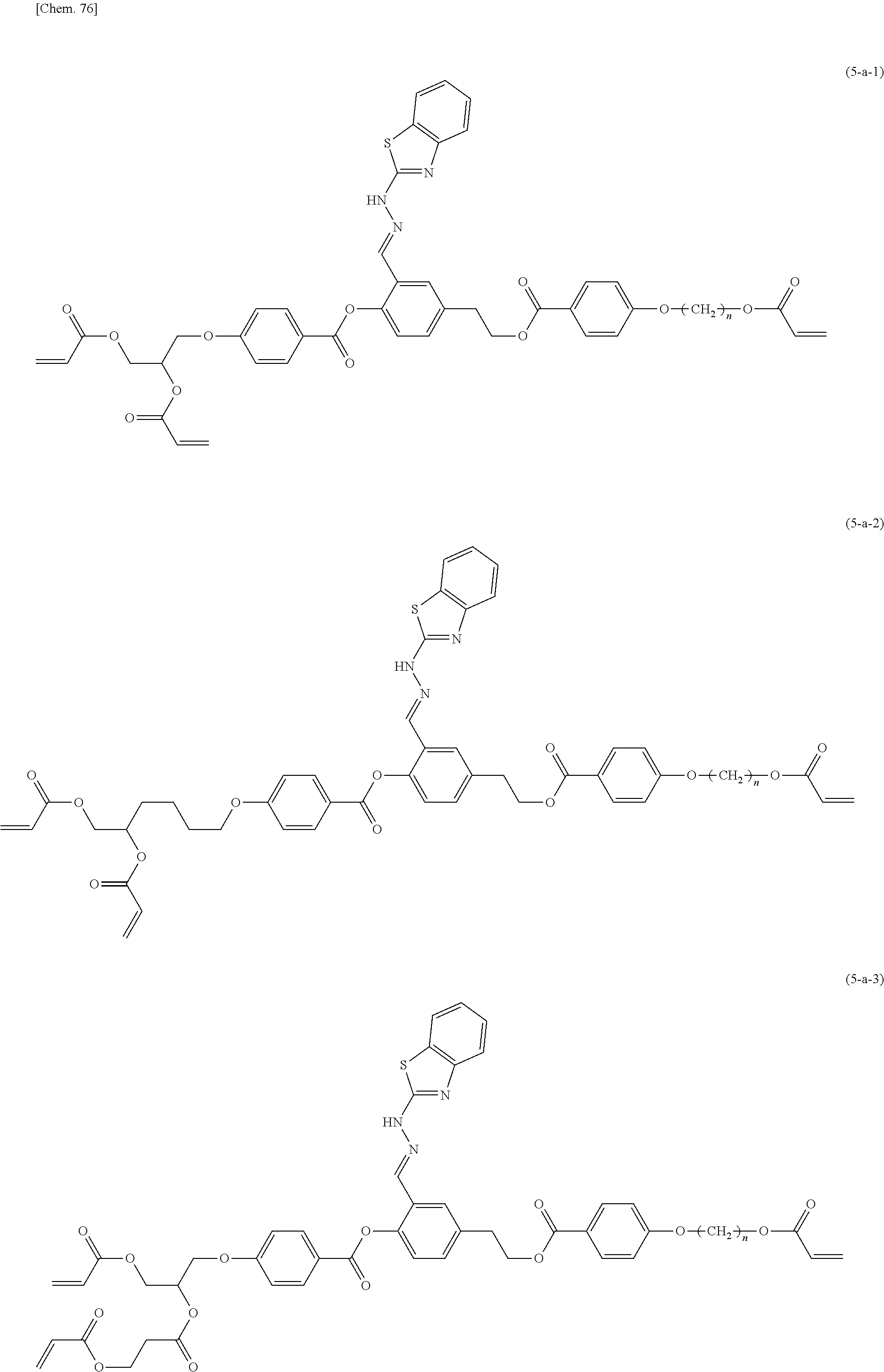

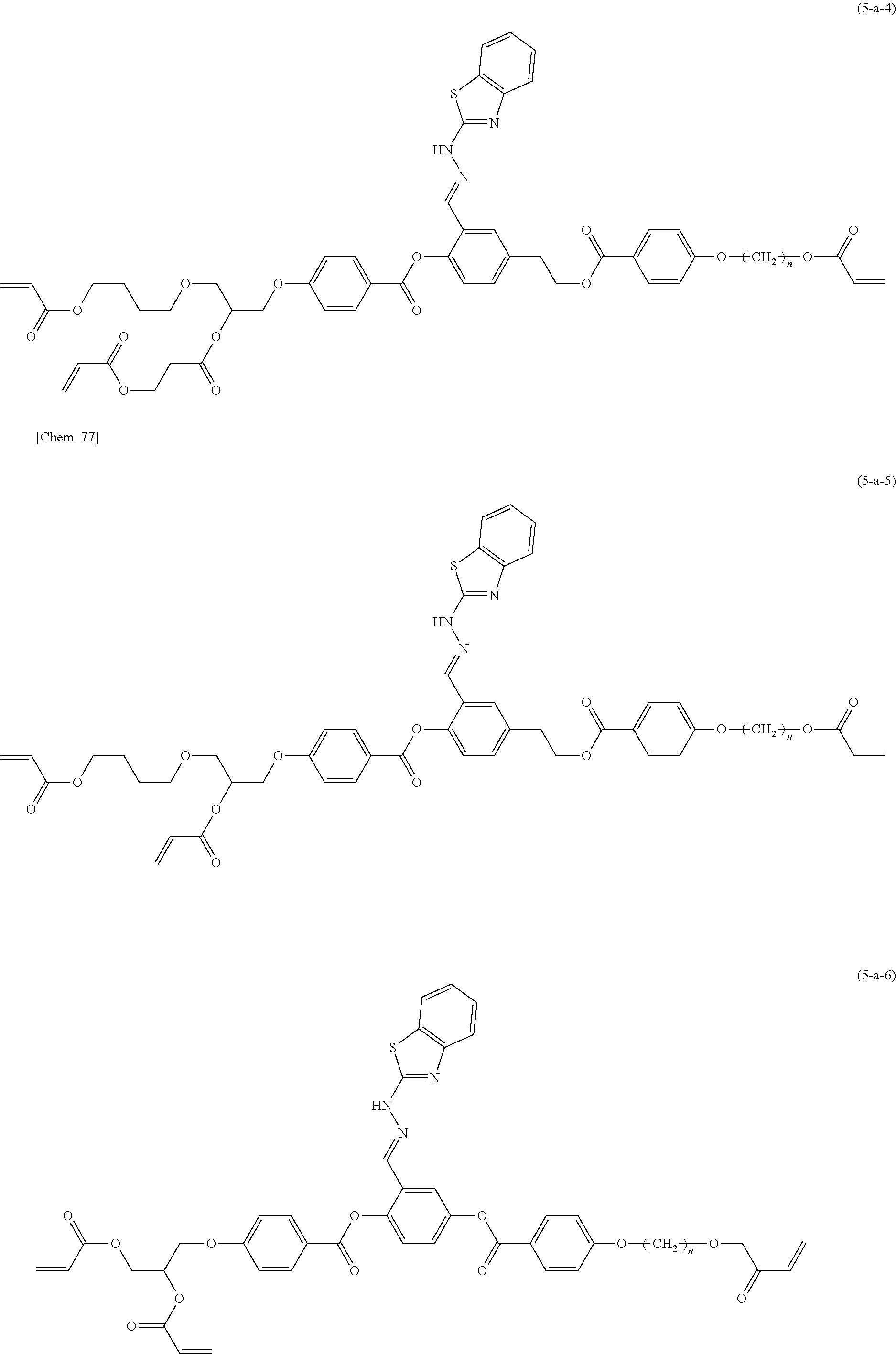

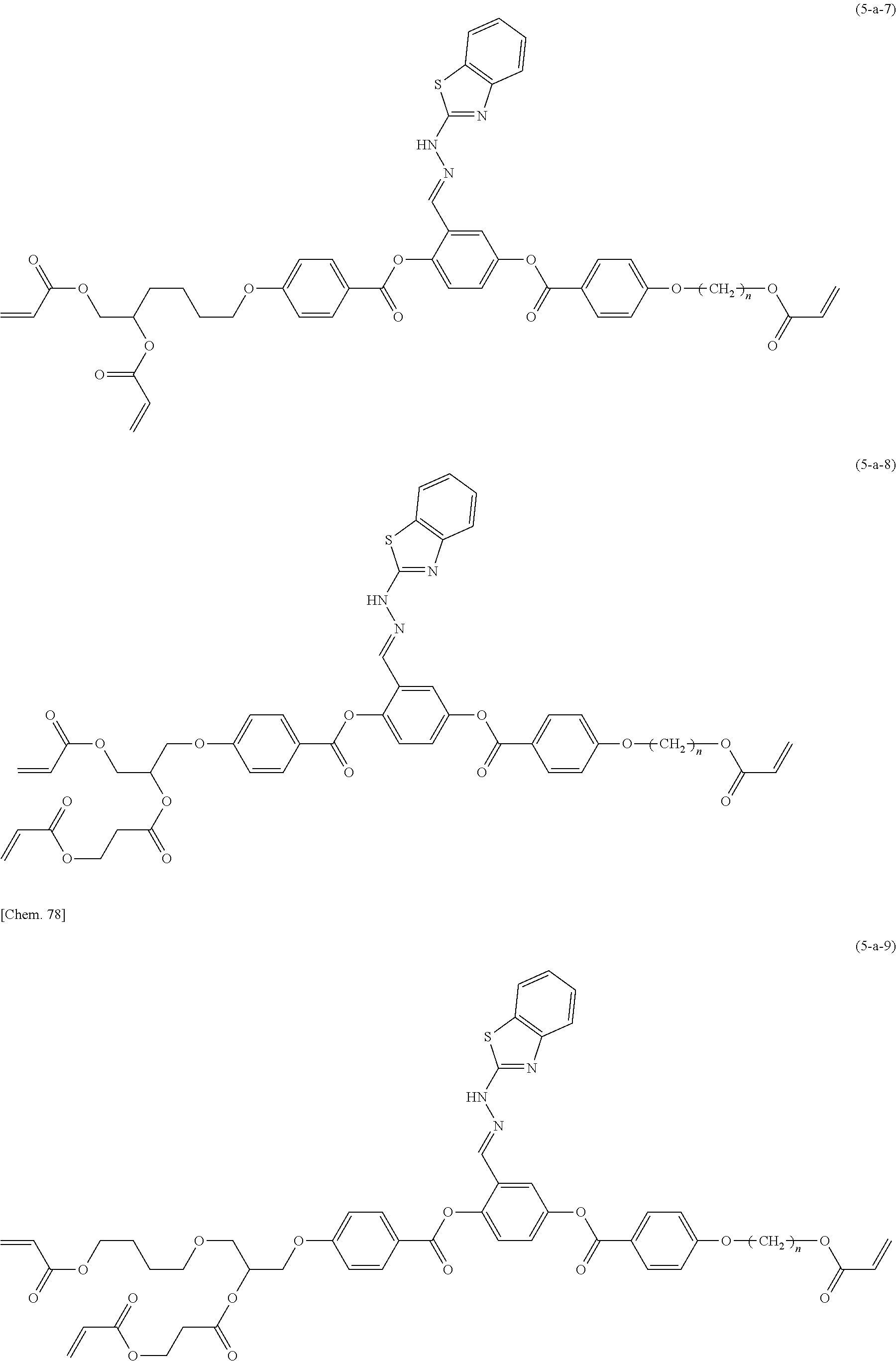

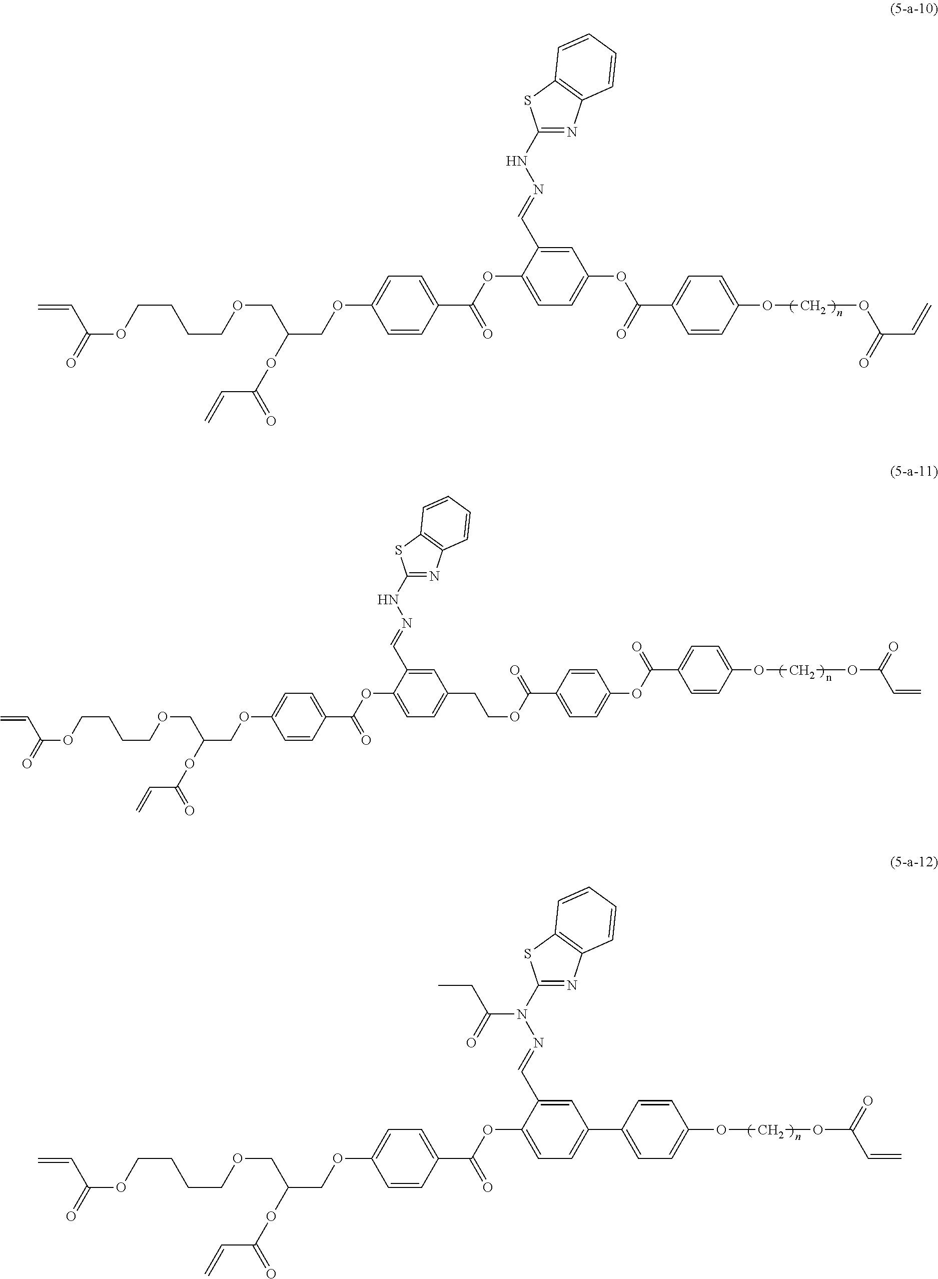

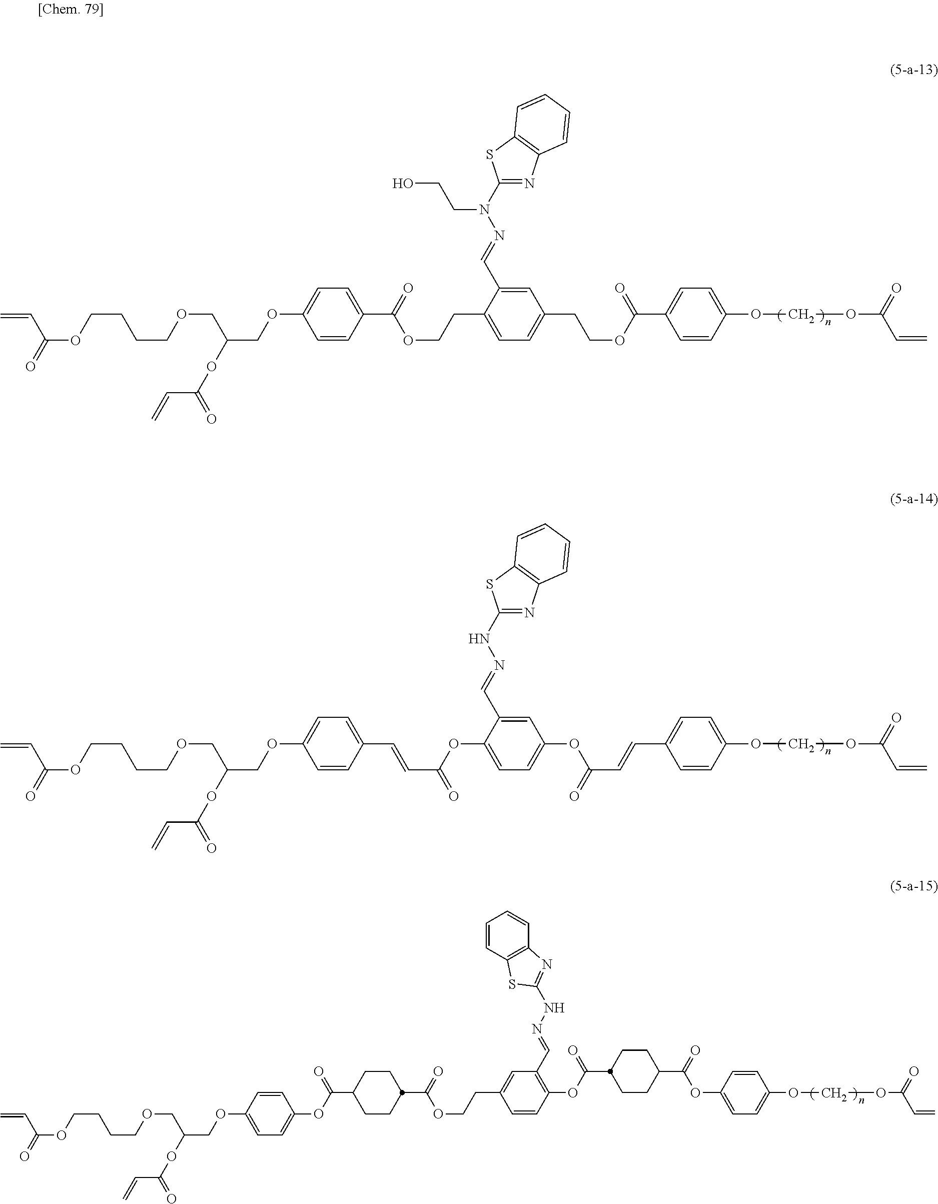

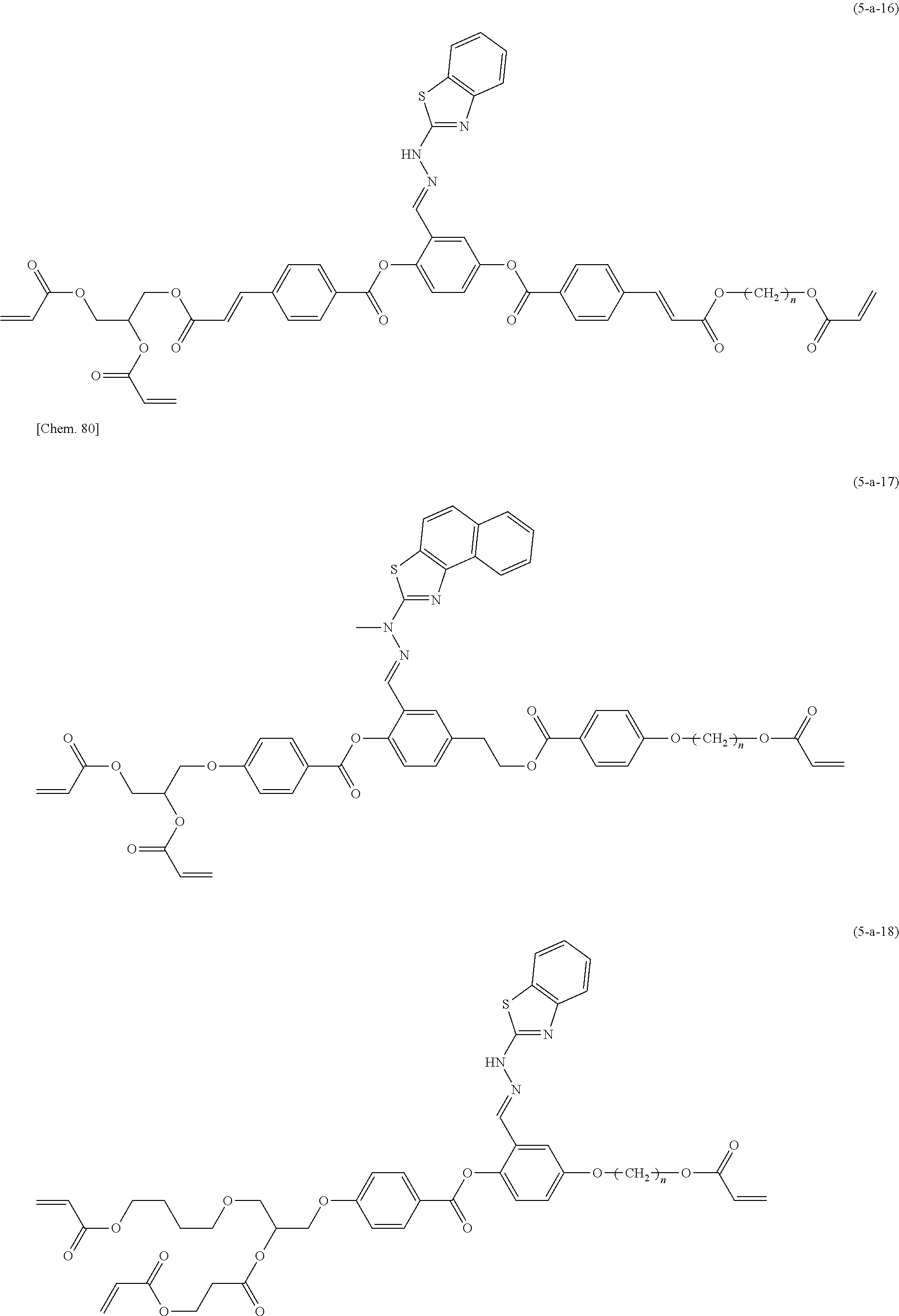

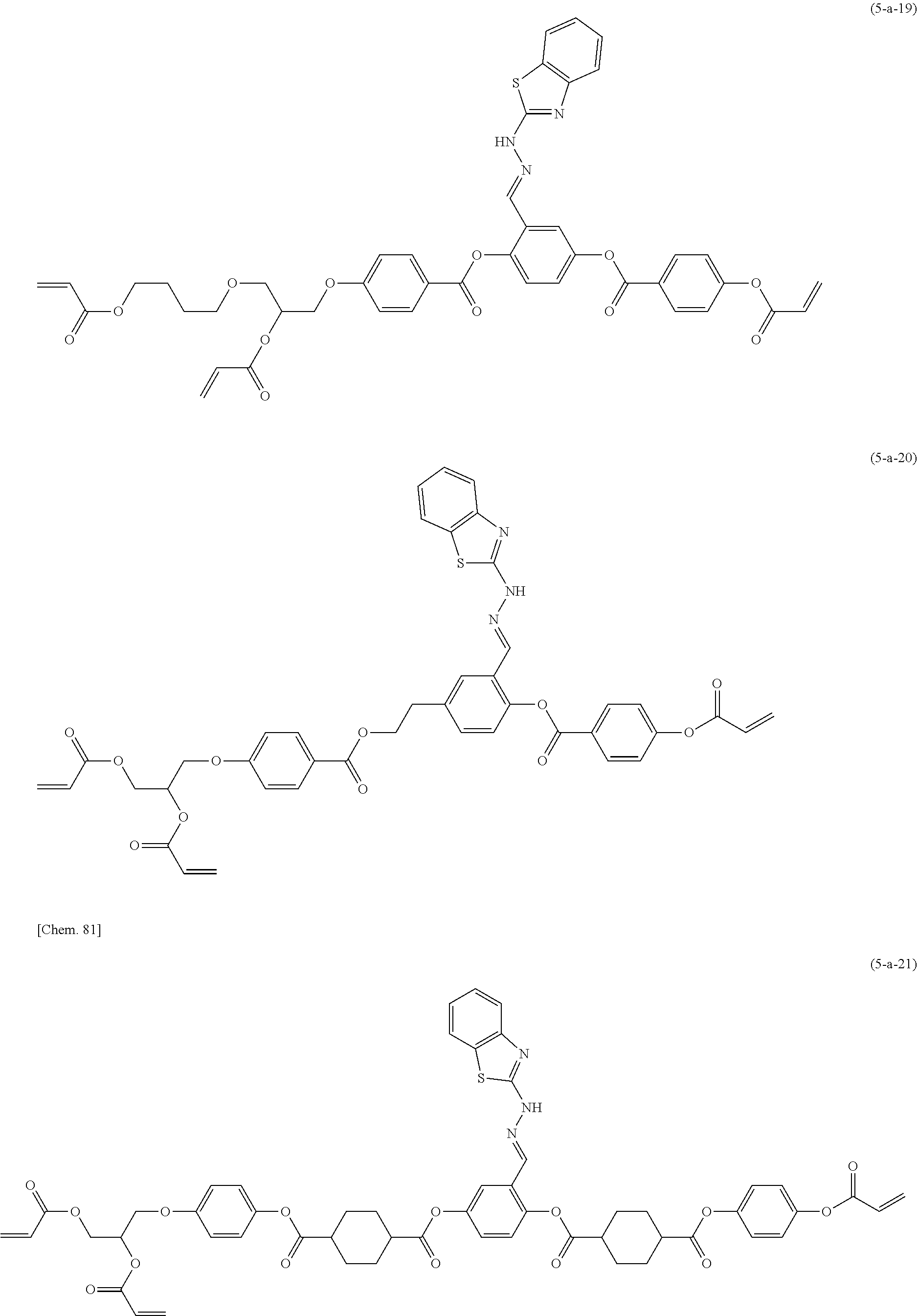

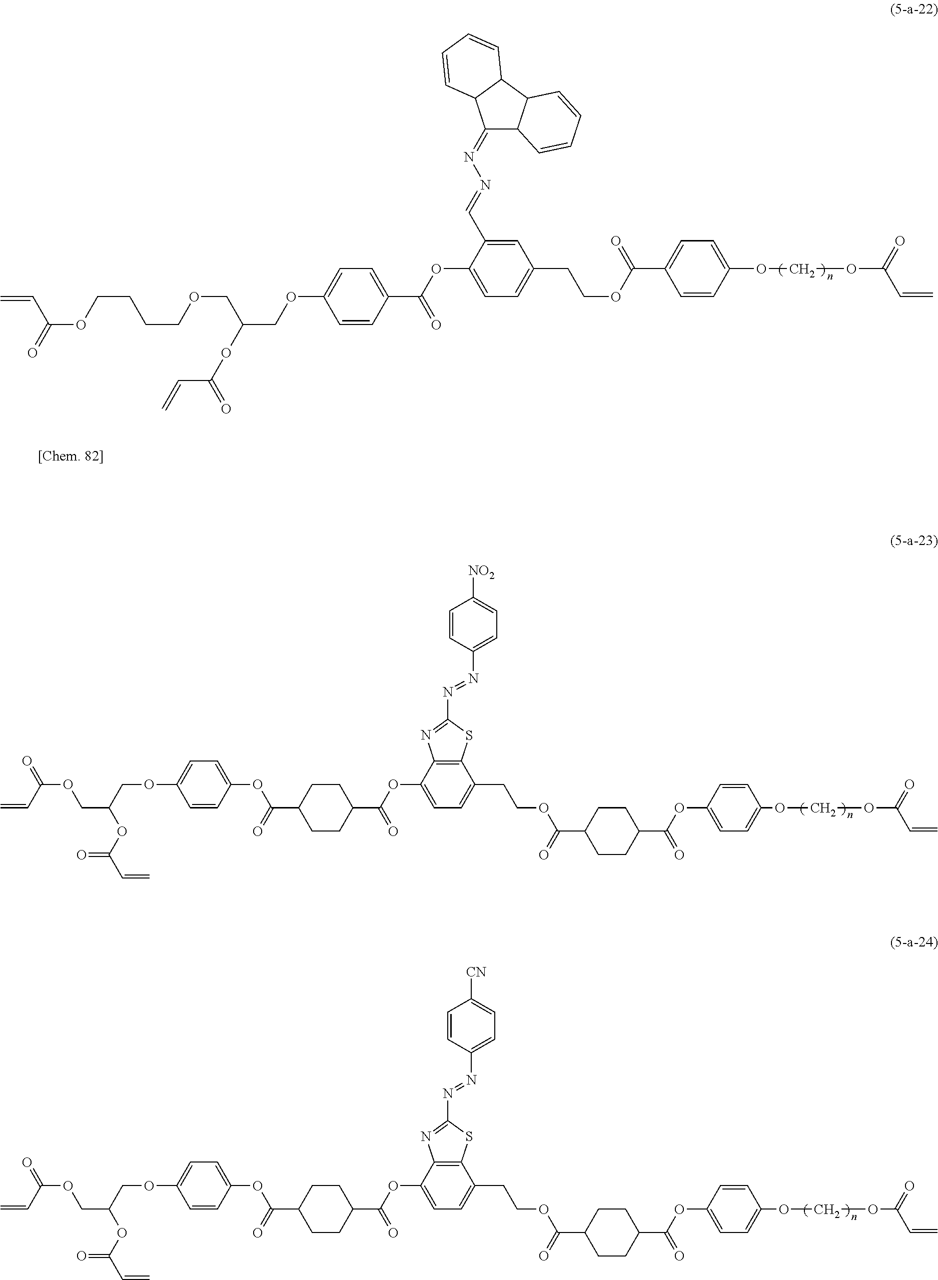

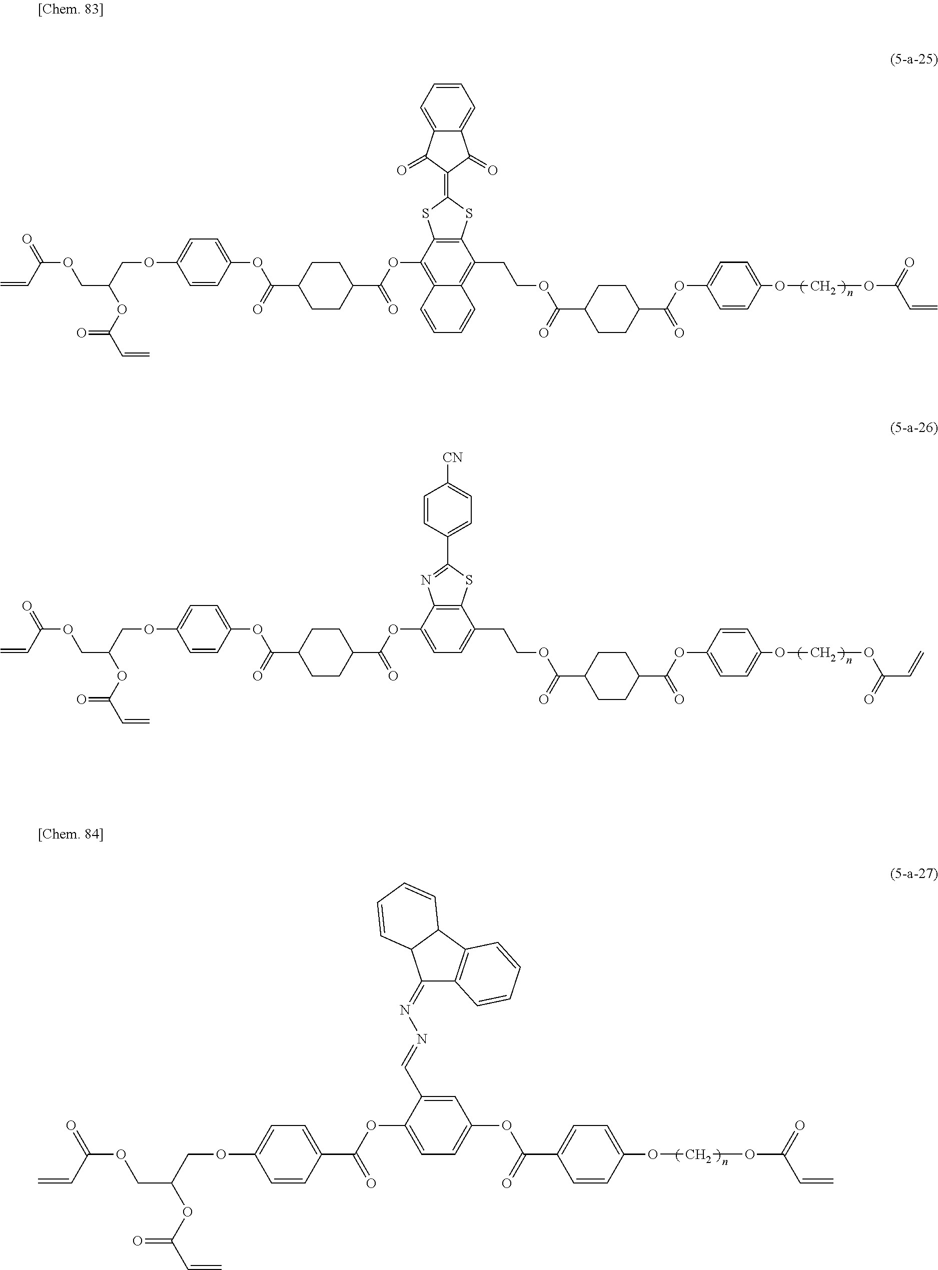

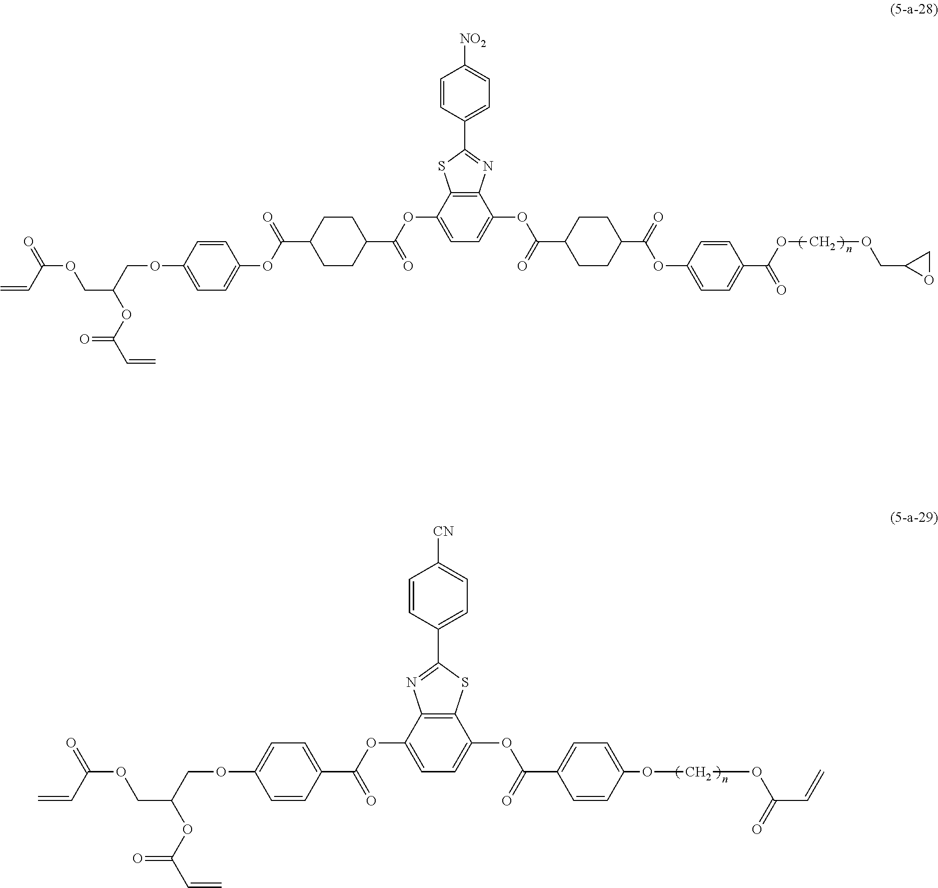

(In the formulae, n represents 1 to 10 in terms of a carbon atom number.) These liquid crystalline compounds may be used singly or two or more thereof may be mixed to be used.

Preferred specific examples of the compound represented by General Formula (6) include compounds represented by Formula (6-a-1) to Formula (6-a-25).

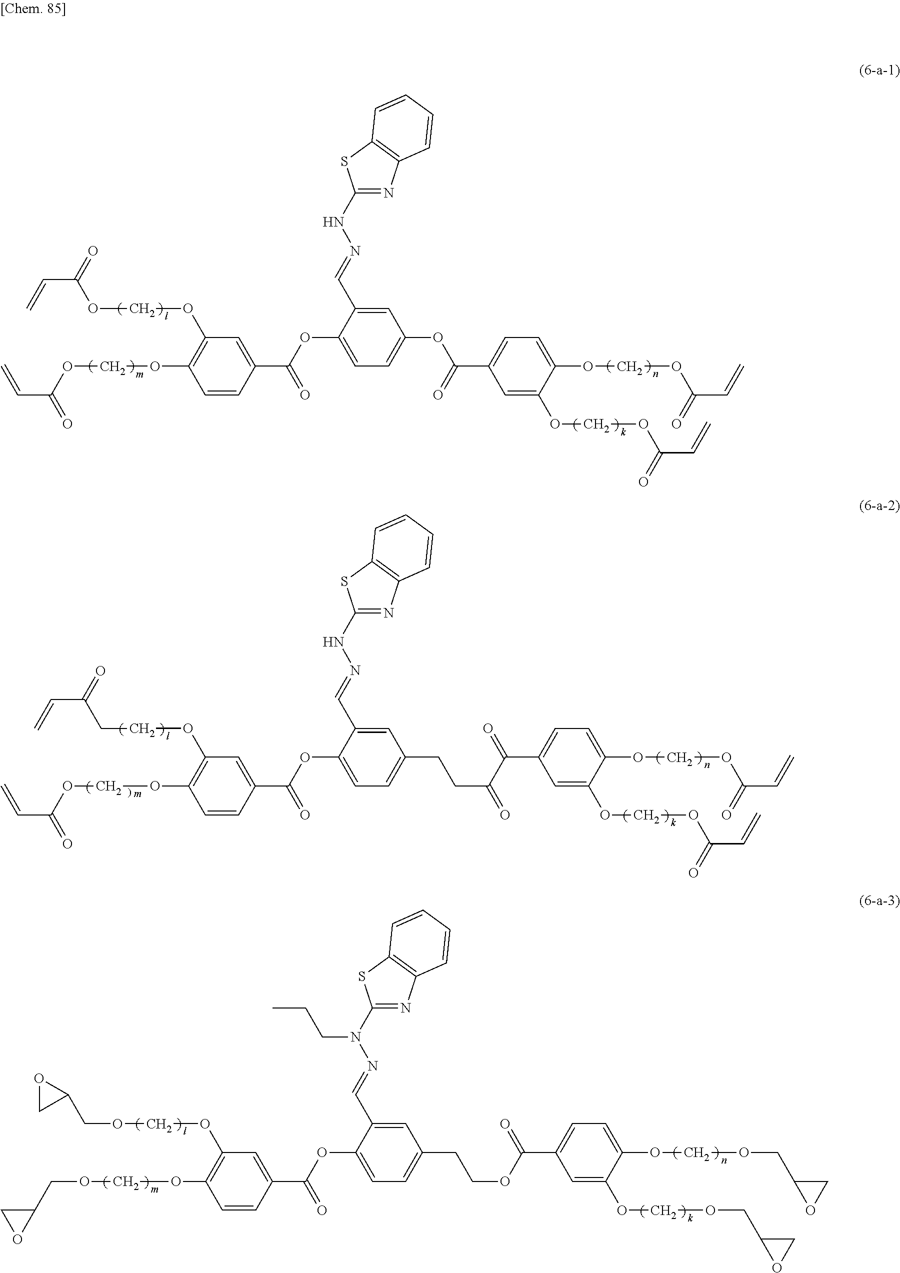

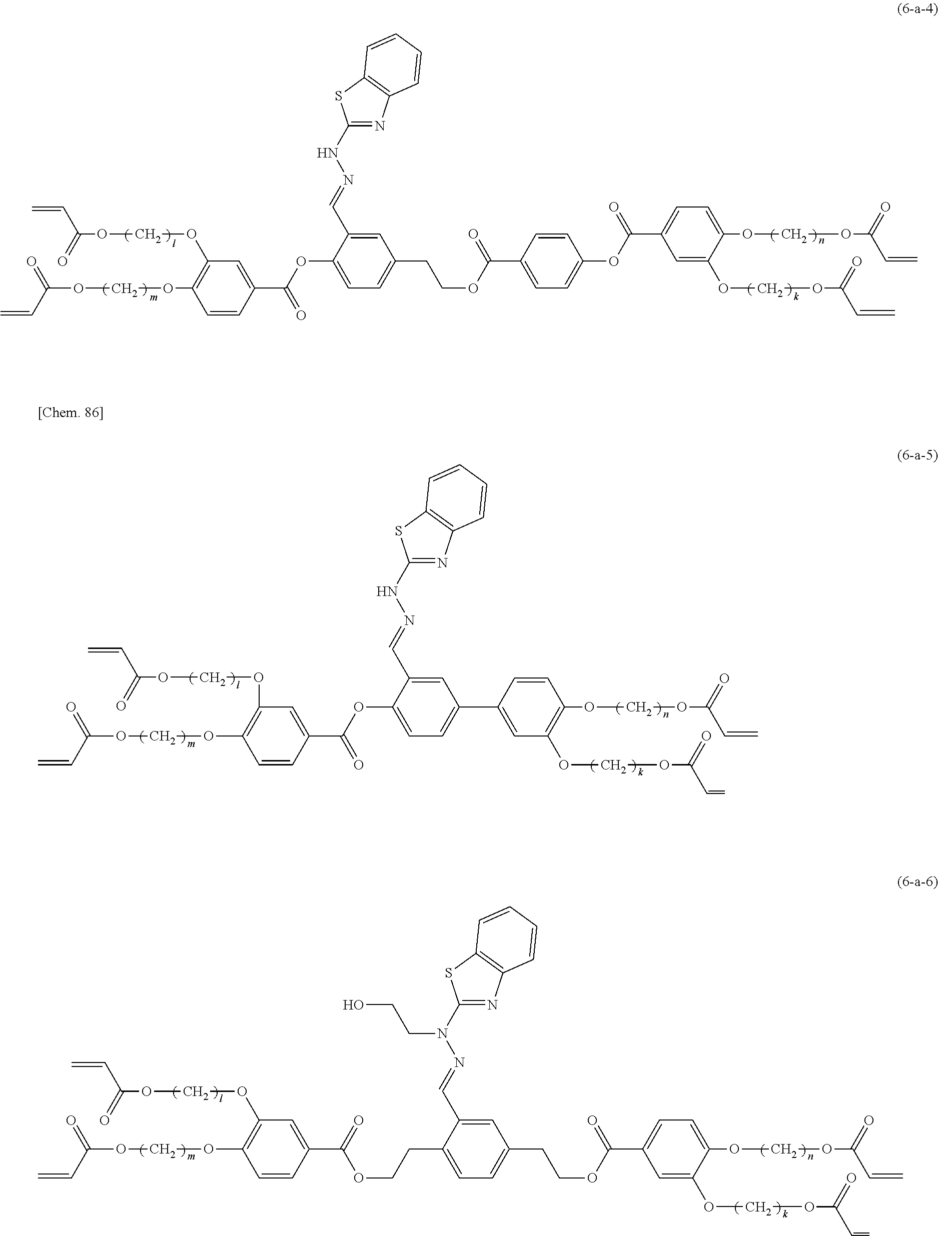

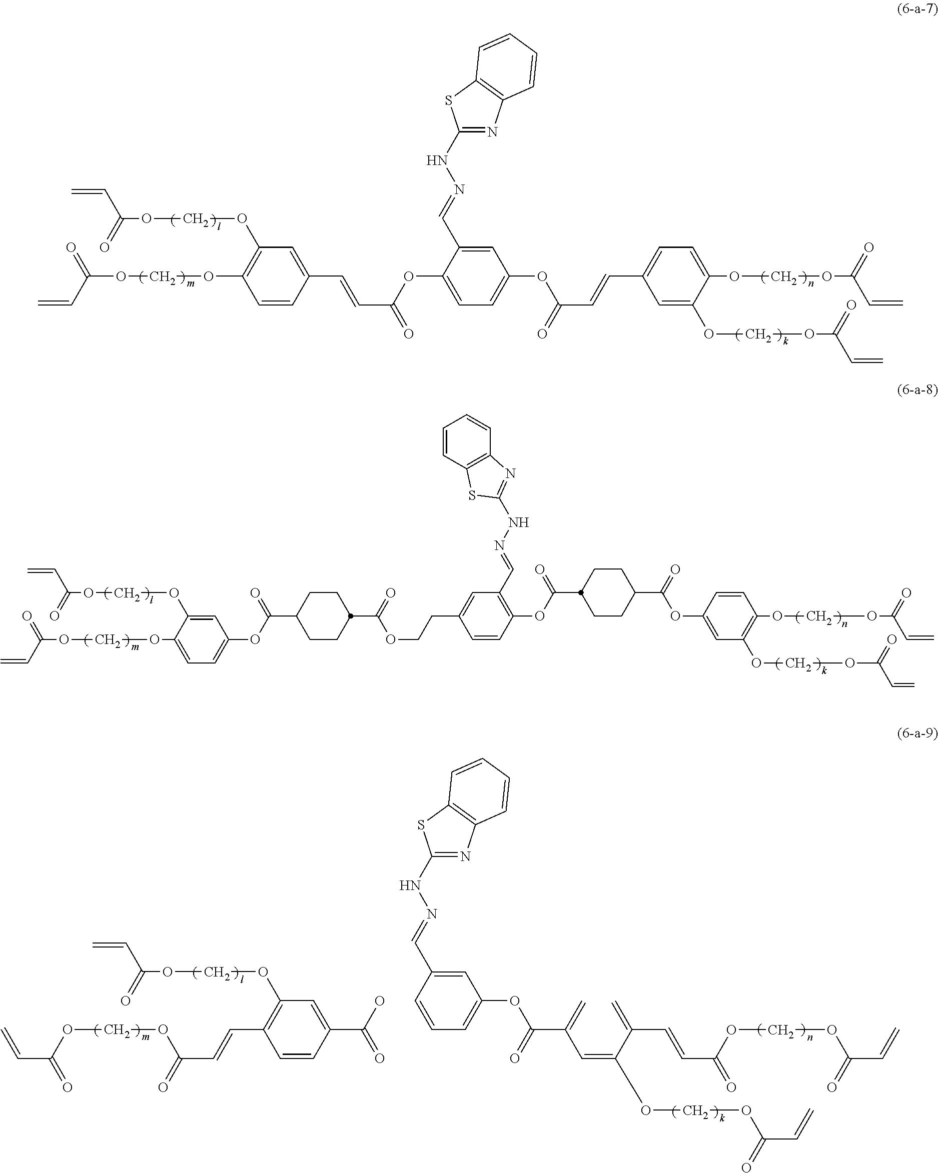

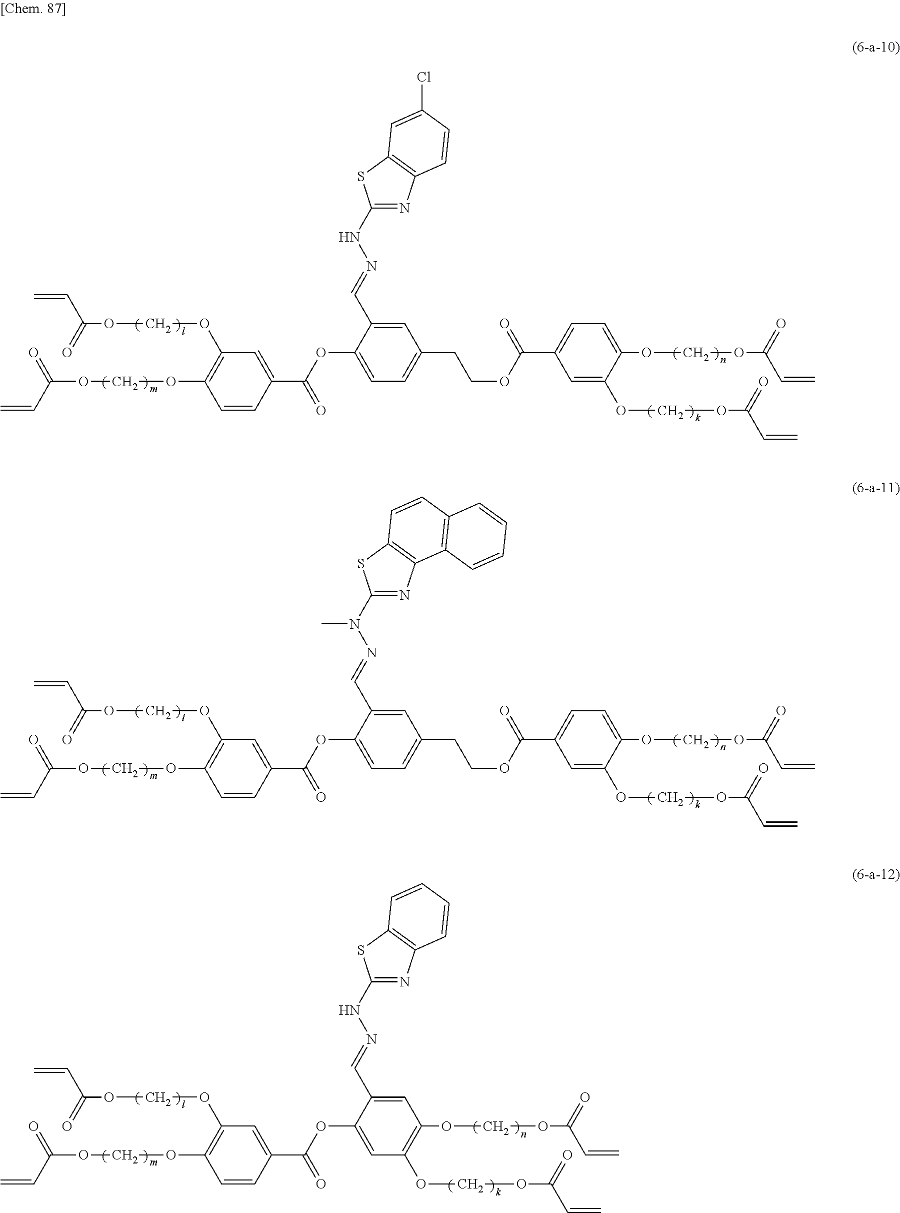

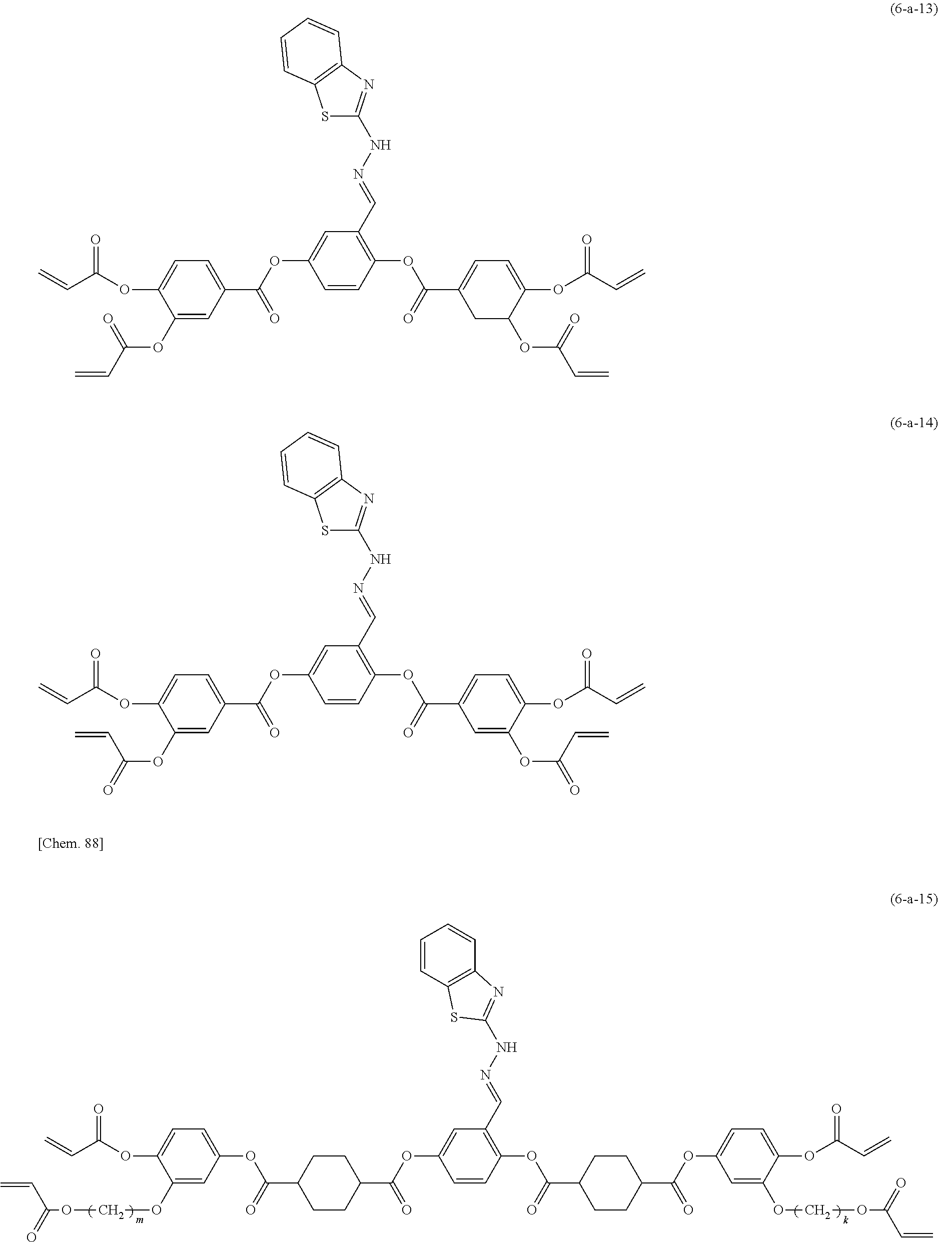

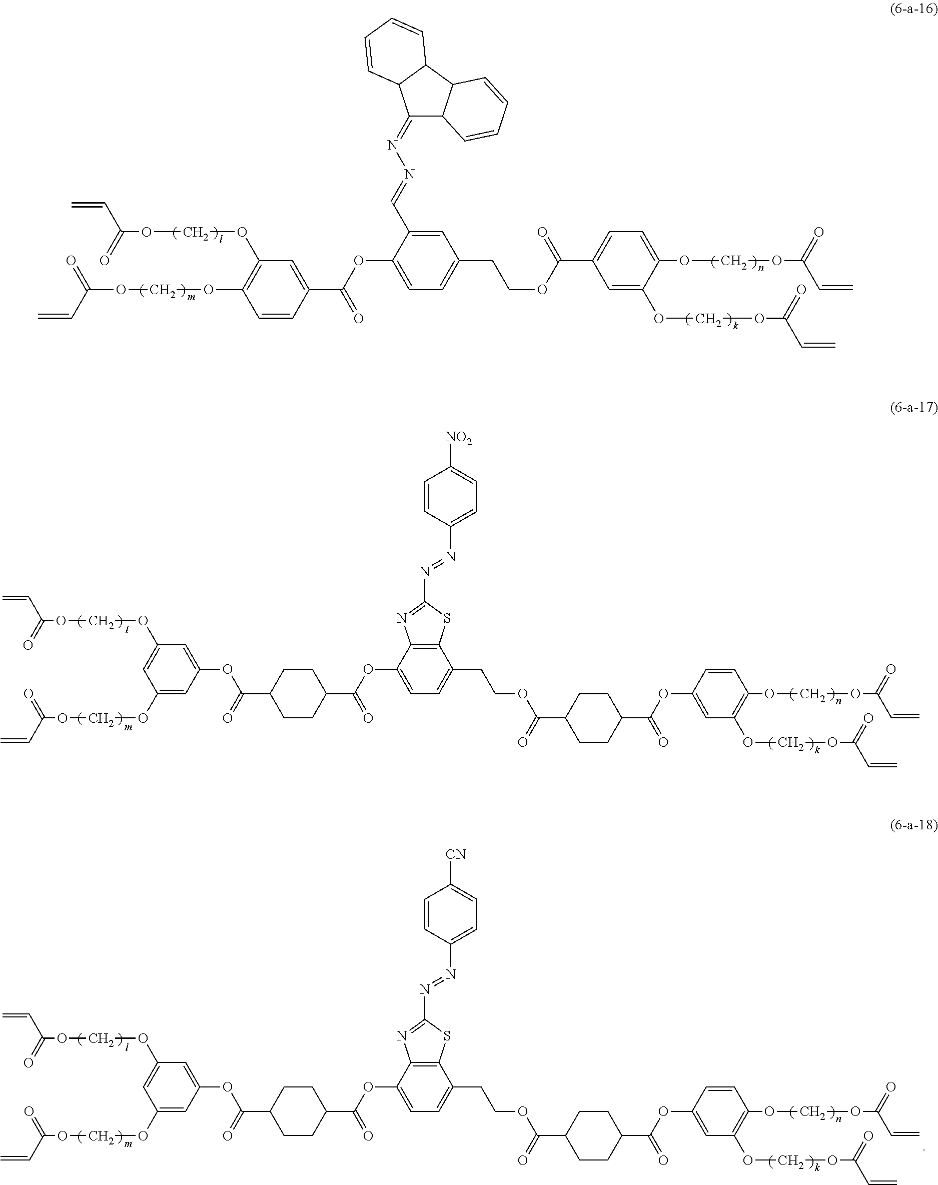

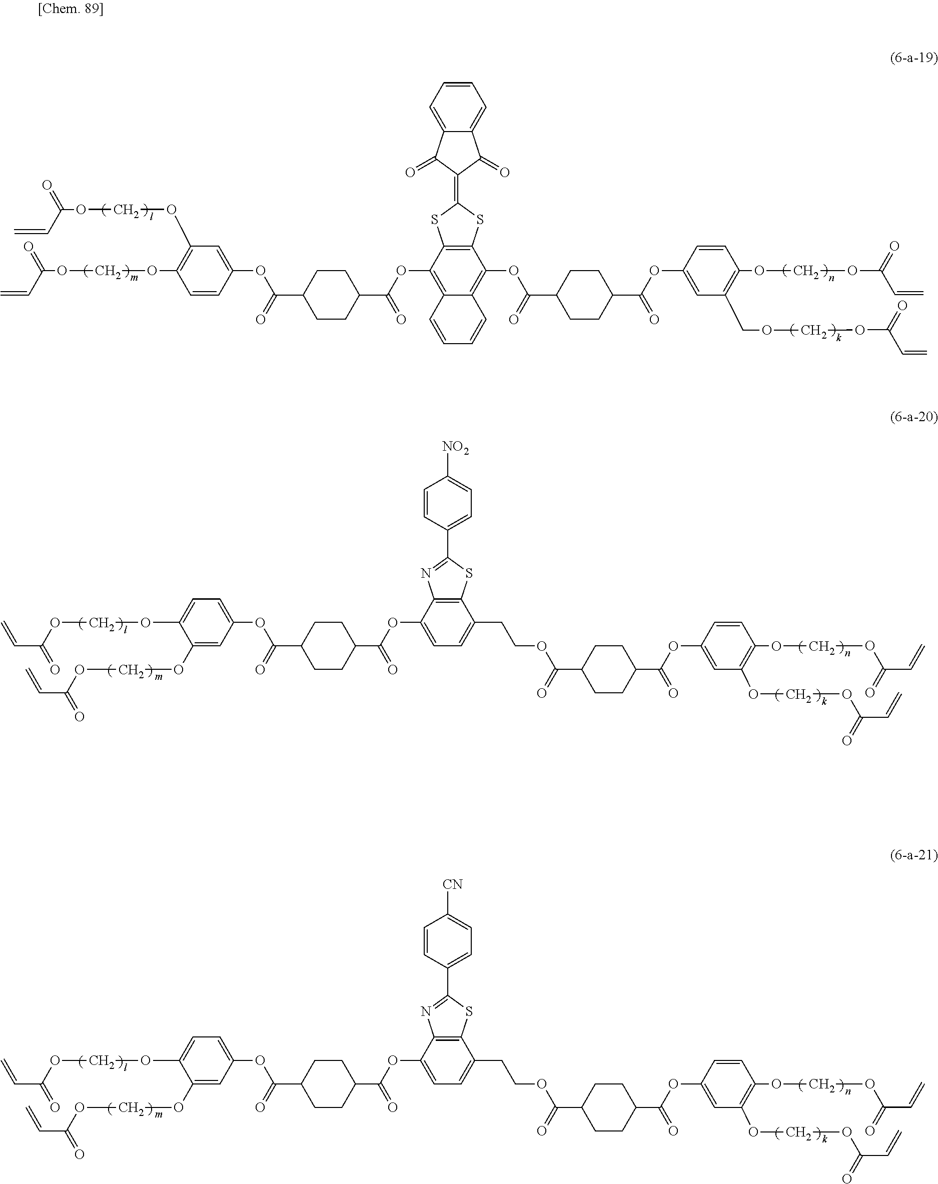

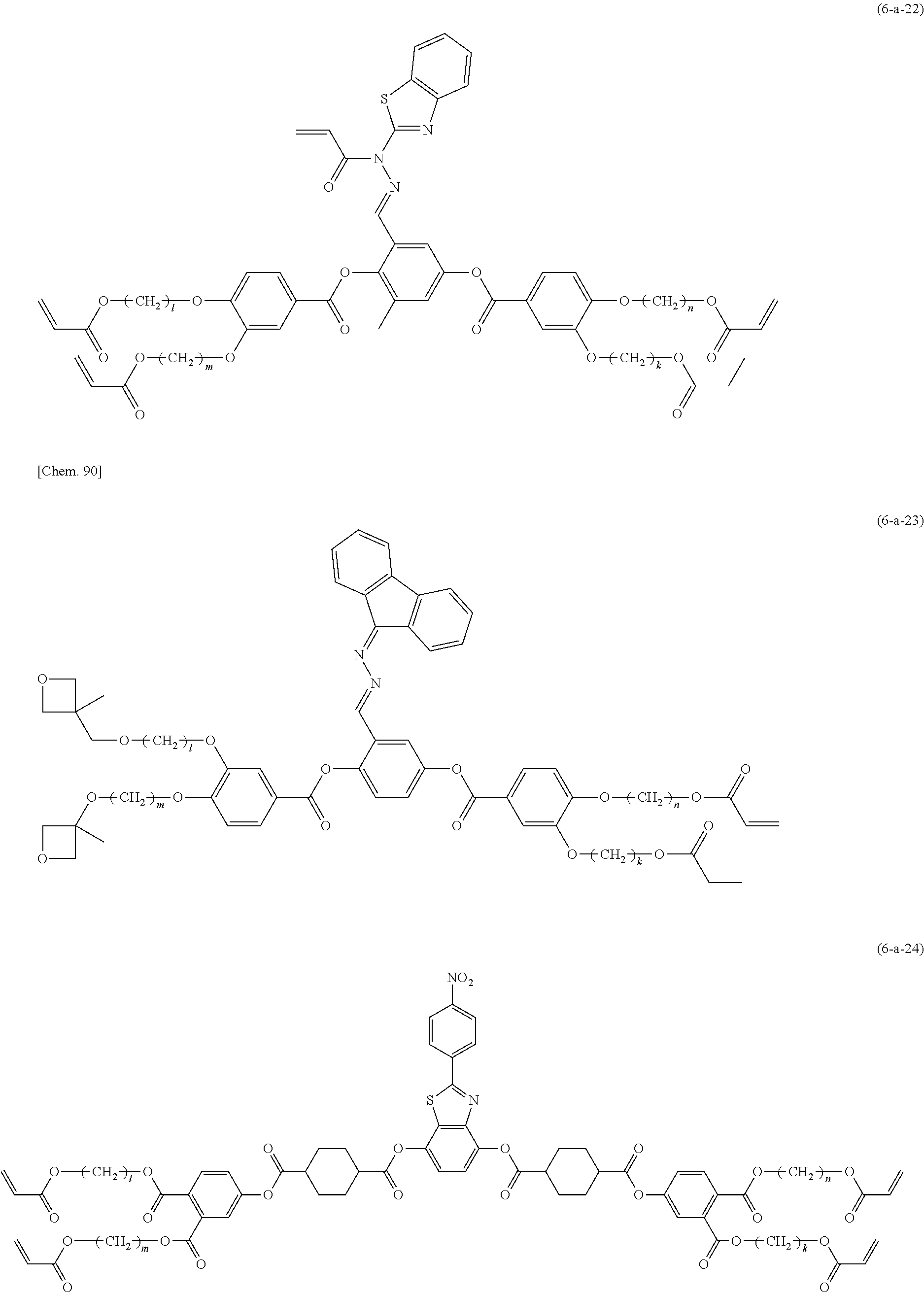

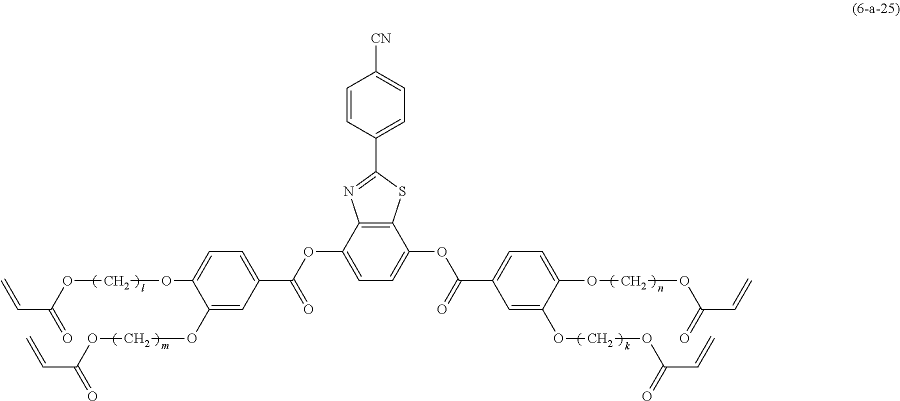

(In the formulae, k, l, m and n each independently represent 1 to 10 in terms of carbon atom number.) These liquid crystalline compounds may be used singly or two or more thereof may be mixed to be used.

Preferred specific examples of the compound represented by General Formula (7) include compounds represented by Formula (7-a-1) to Formula (7-a-26).

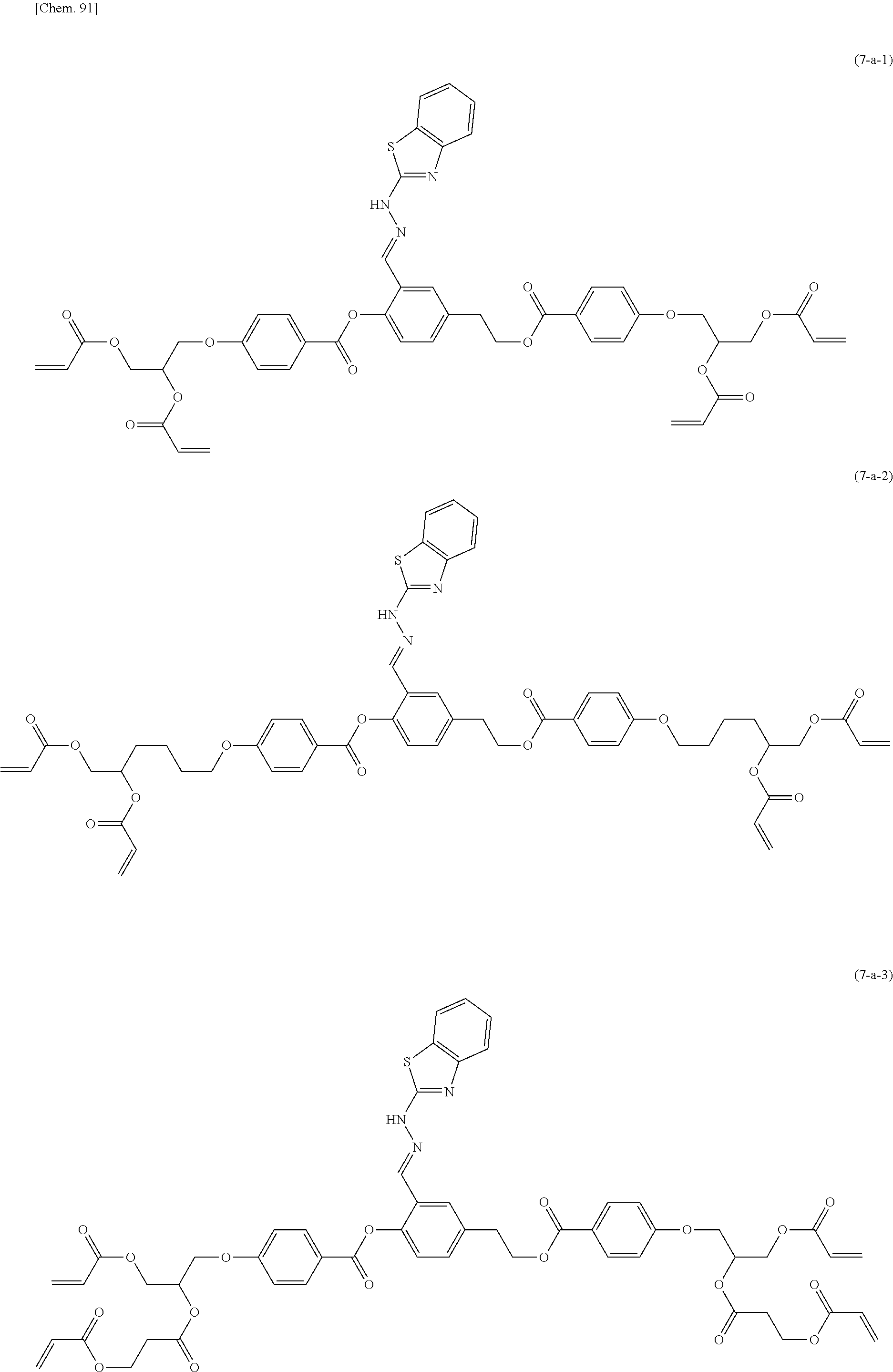

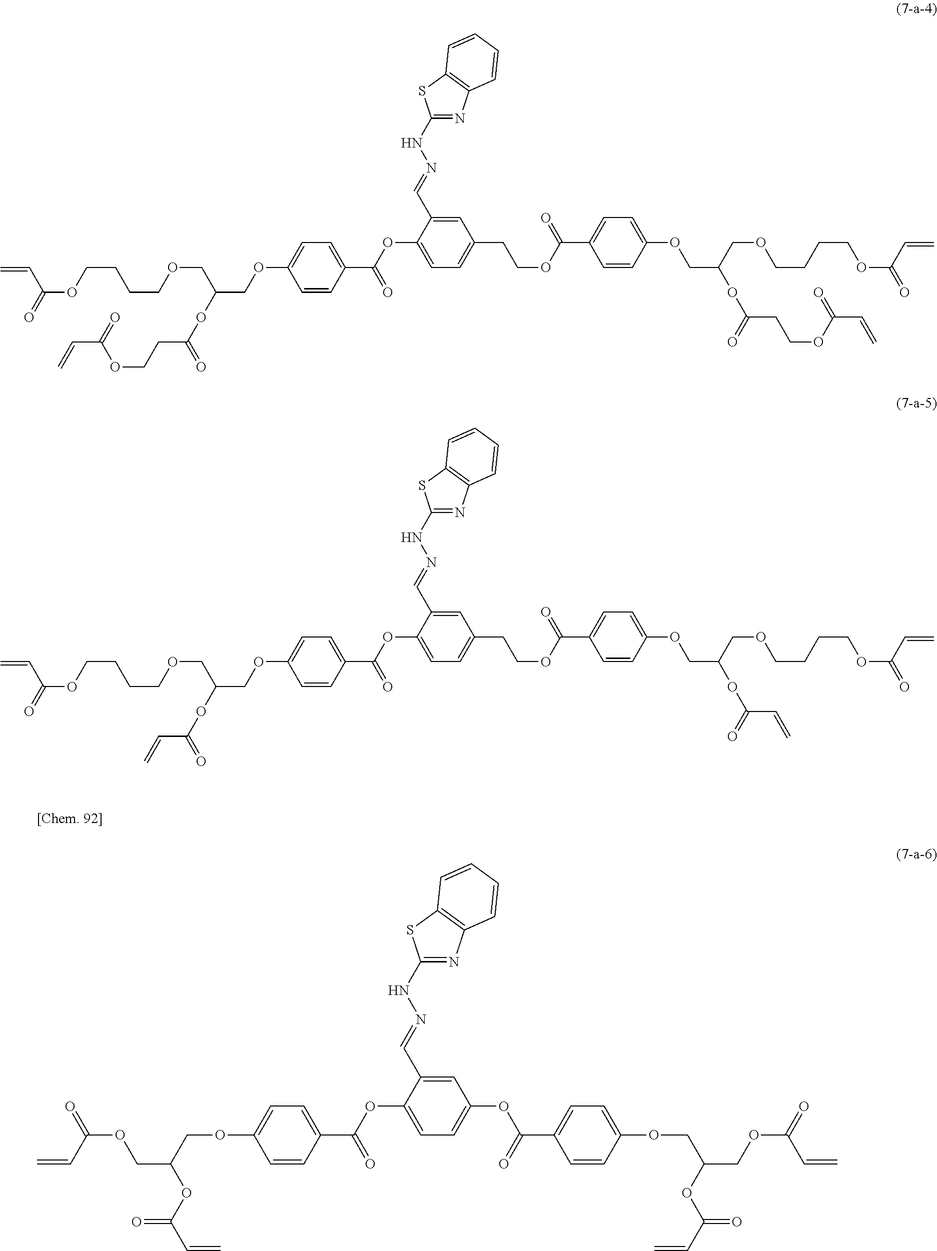

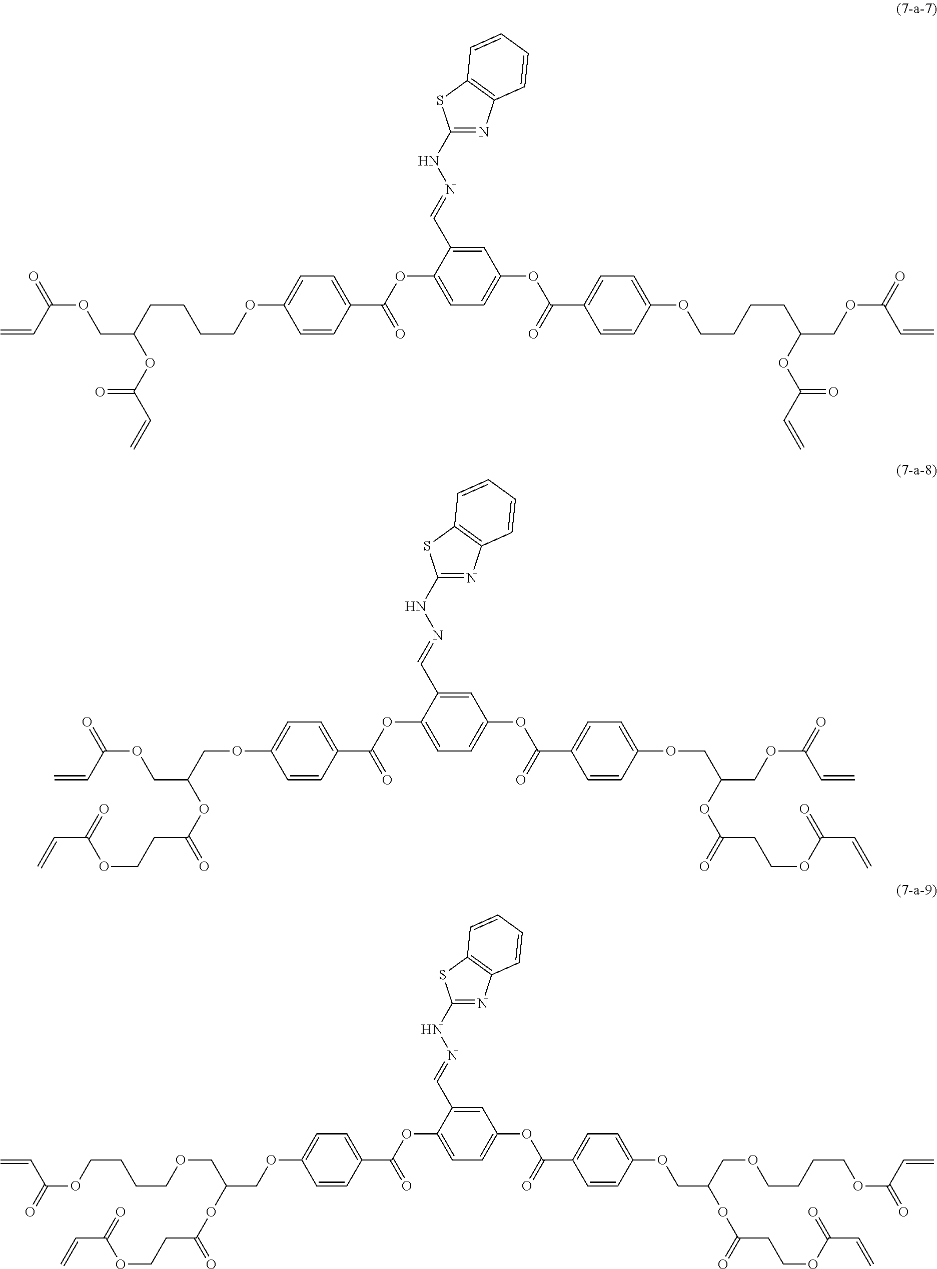

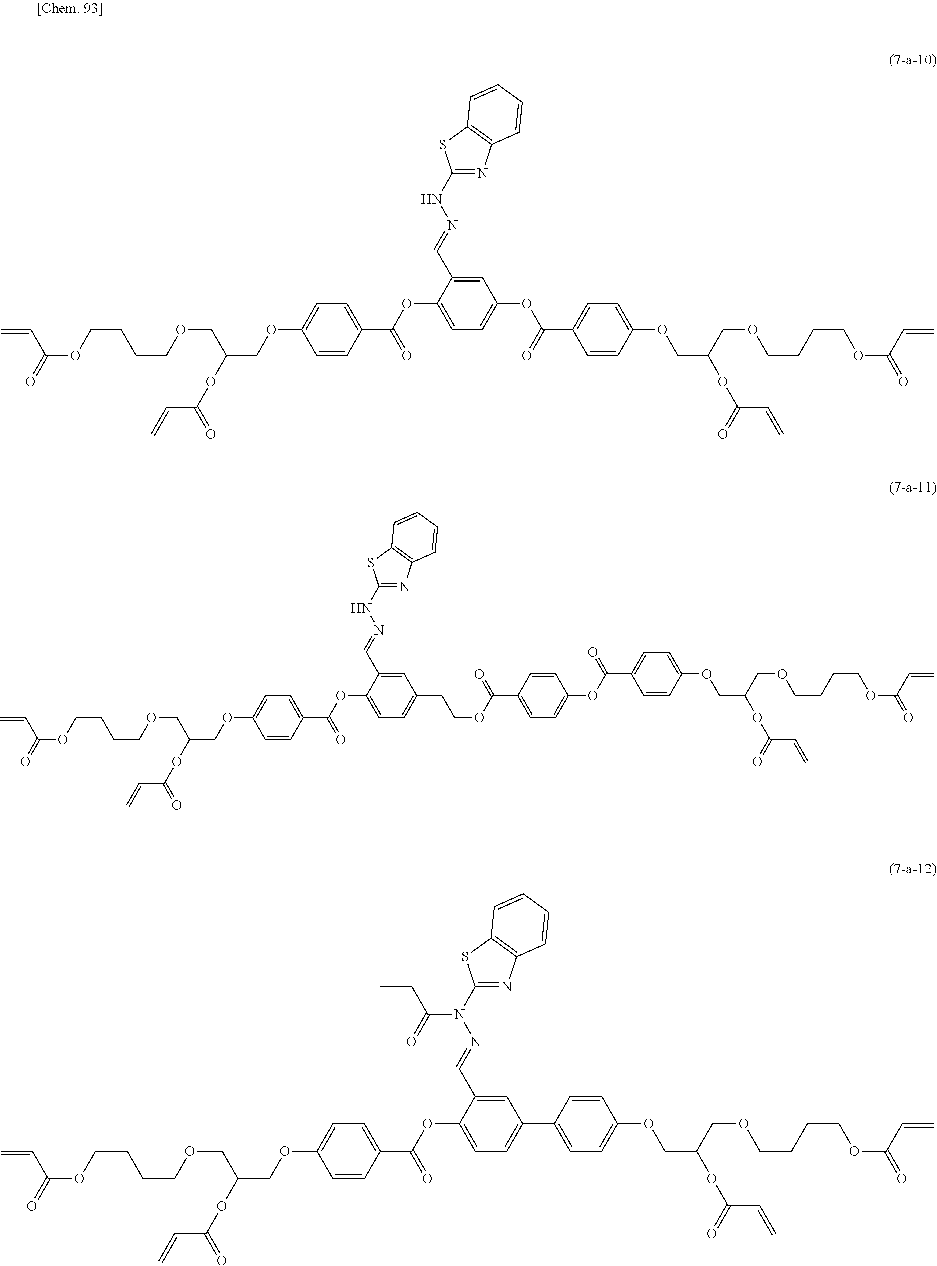

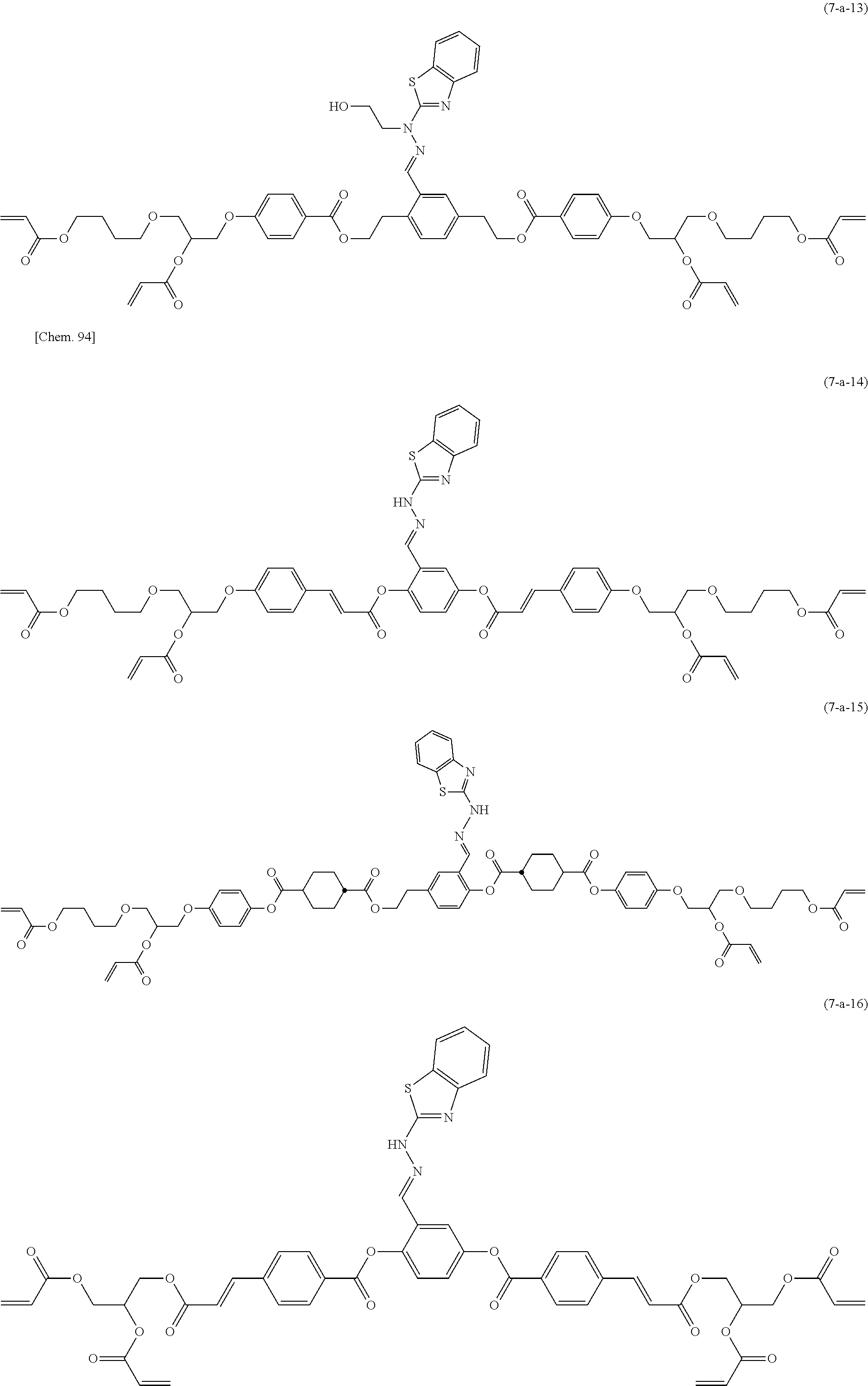

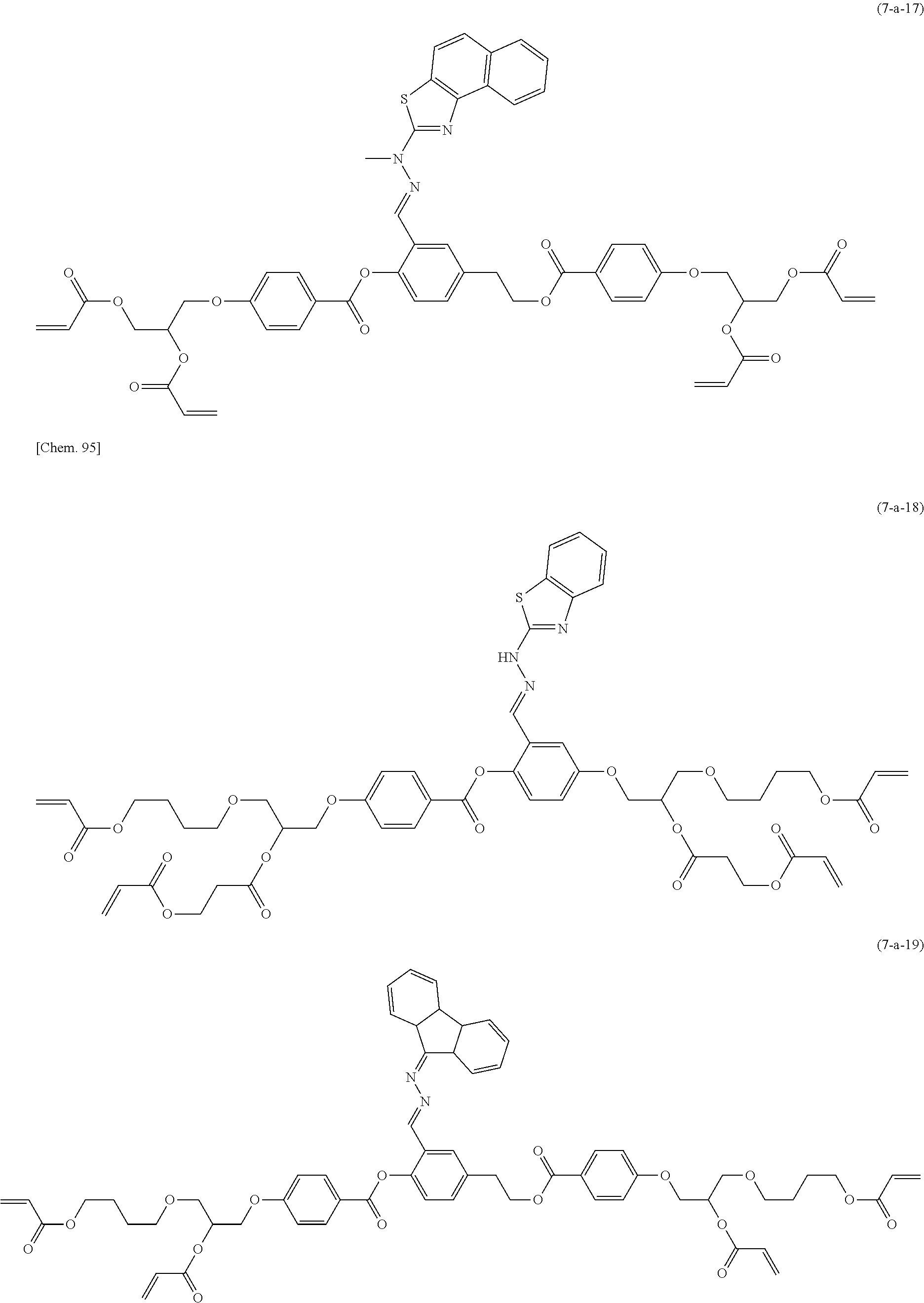

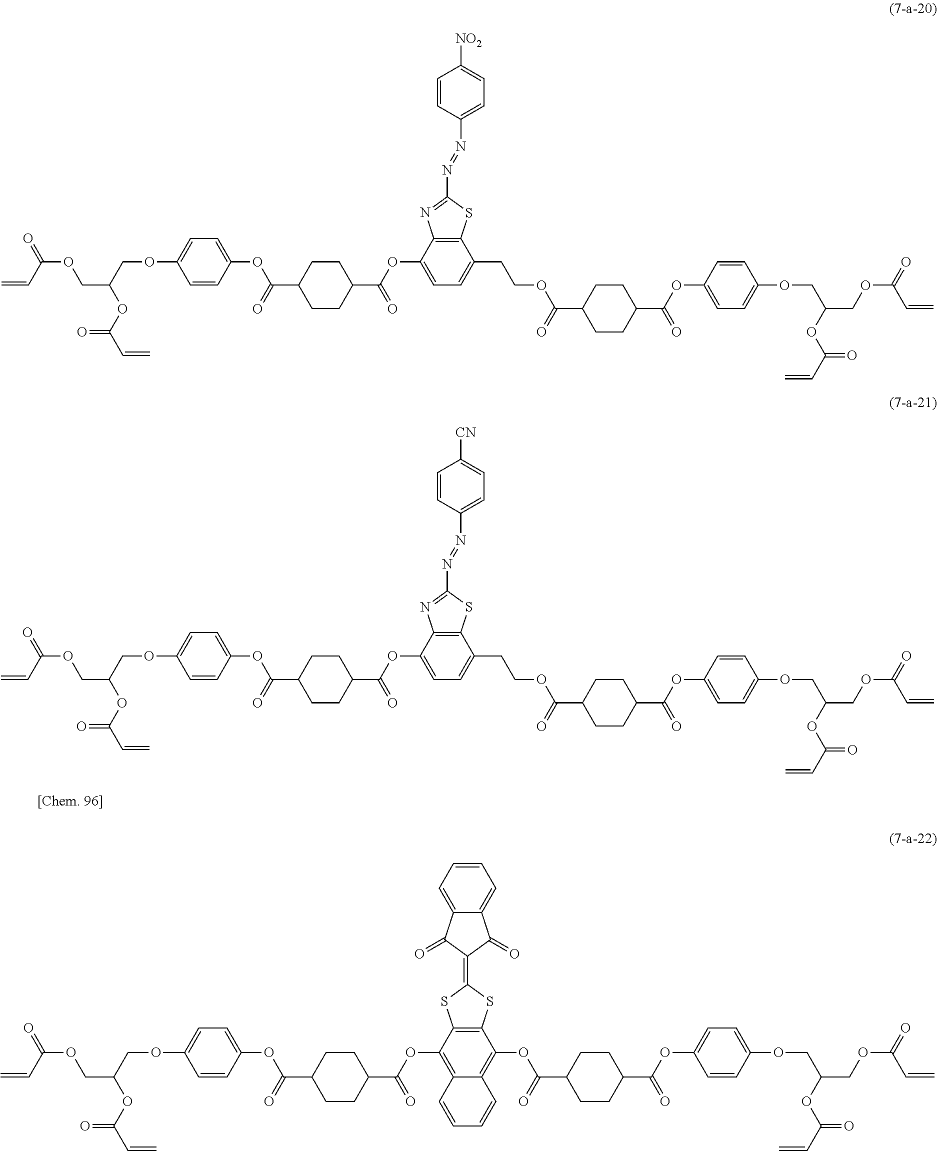

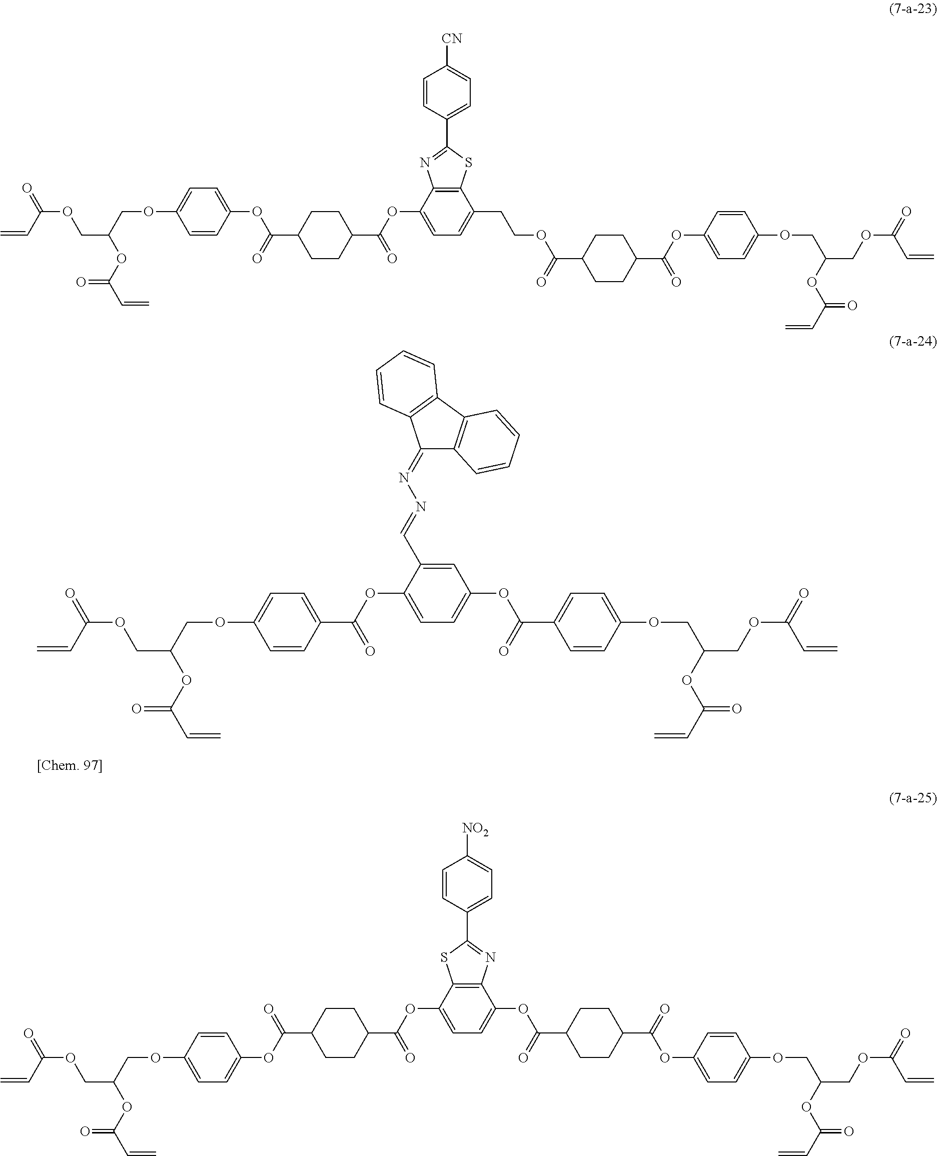

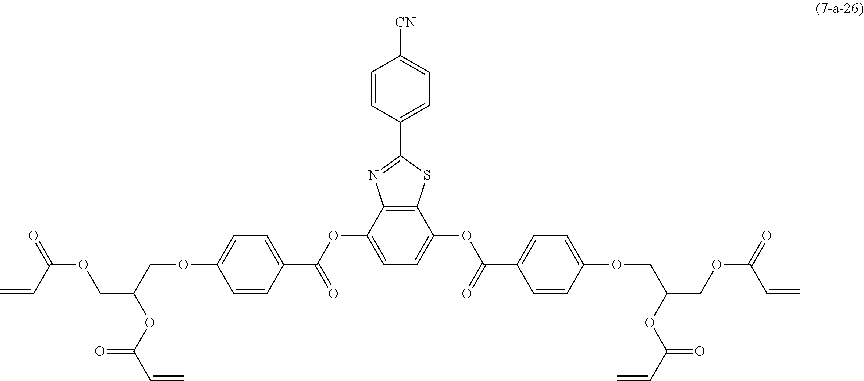

These liquid crystalline compounds may be used singly or two or more thereof may be mixed to be used.

The total content of the polymerizable compound which contains one or two or more polymerizable groups is preferably 60% to 100% by mass with respect to the total amount of the polymerizable compound used in the polymerizable composition, and the lower limit is preferably 65% by mass or more, and more preferably 70% by mass or more, and the higher limit is preferably 95% by mass or less, and more preferably 90% by mass or less.

(Surfactant)

The polymerizable composition of the present invention contains a surfactant having a weight average molecular weight of 5,000 or more. The surfactant is segregated on the surface of the polymerizable composition, allows the alignment state of the liquid crystalline compound represented by the general formulae (1) to (7) at the air interface to be controlled, and improves the leveling properties of the interface. In the case of a liquid crystal composition containing a liquid crystalline compound, presence of the non-liquid crystalline compound in the composition affects and disturbs the alignment. Therefore, the surfactant which is a non-liquid crystalline compound is preferably separated from the liquid crystal composition and segregated on the surface, and it is preferable that the segregation degree is high. For that purpose, it is preferable that the weight average molecular weight is large and the compatibility with the liquid crystal composition is poor. The weight-average molecular weight is 5,000 or more, preferably 8,000 or more, and more preferably 10,000 or more. If the surfactant has too large weight-average molecular weight, difficulty in movement of the molecules to the surface is caused, and thus the weight-average molecular weight is preferably 10,000,000 or less, more preferably 1,000,000 or less, even more preferably 100,000, and most preferably 30,000 or less.

Meanwhile, too high degree of the surfactant segregation causes cissing. To avoid this, viscosity of the liquid crystalline composition is preferably high, preferably 10 Pa·s or more at 80° C., more preferably 100 Pa·s or more at 80° C., even more preferably 500 Pa·s or more at 80° C., and even more preferably 1,000 Pa·s or more at 80° C. Further, since too high viscosity of the liquid crystalline composition causes difficulties in the alignment thereof, it is preferable that the viscosity thereof is preferably 10,000,000 Pa·s or less, more preferably 1,000,000 Pa·s or less, and even more preferably 100,000 Pa·s or less.

The viscosity was measured using a rheometer Physica MCR101 (manufactured by Anton Paar Co.) and a cone plate CP 50-1 at a temperature of 80° C. and a rotation speed of 1 rpm. The result from one against which the viscosity measurement was impossible at 80° C. was obtained by calculating by substituting the values of a plurality of points measured at other temperatures to Andrade's viscosity equation.

A silicone surfactant or an acrylic surfactant is preferably used as a surfactant.

The silicone surfactant lowers surface tension and thus preferably used for increasing leveling properties of the surface. The acrylic surfactant does not lower surface tension and thus preferably used for enhancing the adhesion to other films.

Preferred examples of the silicone surfactant include a surfactant represented by General Formula (B).

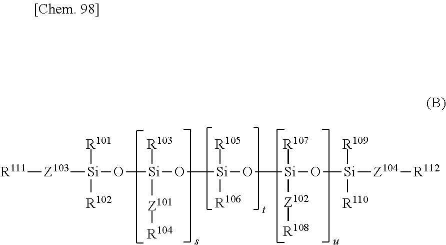

(In the formula, Z¹⁰¹ to Z¹⁰⁴ each independently represent a single bond, an oxygen atom, an alkylene group, a polyether group, a polyester group, other organic modifying groups, and combinations thereof, R¹⁰¹, R¹⁰², R¹⁰³, R¹⁰⁵, R¹⁰⁶, R¹⁰⁷, R¹⁰⁹, and R¹¹⁰ each independently represent an alkyl group, an aryl group, or aralkyl group having 1 to 14 carbon atoms, R¹⁰⁴, R¹⁰⁸, R¹¹¹ and R¹¹² each independently represent a hydrogen atom, an alkyl group, an aryl group, an aralkyl group, an amine group, an epoxy group, OH group, a mercapto group, a carboxyl group, a phenol group, an acryl group, a methacryl group, a fluoroalkyl group, and other organic modifying groups, s represents 0 to 50, t represents 2 to 500, and u represents an integer of 0 to 50.)

More preferably, at least one of R¹⁰¹, R¹⁰², R¹⁰³, R¹⁰⁵, R¹⁰⁶, R¹⁰⁷, R¹⁰⁹, and R¹¹⁰ is an aralkyl group.

Preferred examples of the acrylic surfactant include a surfactant represented by General Formula (C).

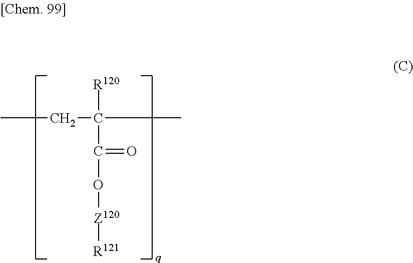

(In the formula, R¹²⁰'s each independently represent a hydrogen atom or a methyl group, Z¹²⁰'s each independently represent a single bond, alkylene group, a polyether group, a polyester group, and combinations thereof, and R¹²¹'s each independently represent a hydrogen atom, an alkyl group, an aryl group, an aralkyl group, an amine group, an epoxy group, an OH group, a mercapto group, a carboxy group, a phenol group, a fluoroalkyl group, and other organic modifying groups. q represents an integer of 10 to 1000.)

Specific examples of the surfactant include BYK-320, BYK-322, BYK-323, BYK-325, BYK-315, BYK-331, BYK-354, BYK-375 (manufactured by BYK Japan KK), TEGO-Glide 420, TEGO Glide B 1484, TEGO Glide TZG 400, TEGO Glide A 115, TEGO RAD 2600, TEGO RAD 2650, TEGO RAD 2700, TEGO FLOW ZFS 460 (manufactured by Evonik), EFKA-3030, EFKA-3236 (manufactured by BASF), FS 126556 ADDITIVE (manufactured by Dow Corning Toray Co., Ltd.), and KP-326 (manufactured by Shin-Etsu Chemical Co., Ltd.).

The weight average molecular weight (Mw) is a value converted to polystyrene based on GPC (gel permeation chromatography) measurement. Measurement conditions of GPC are as follows.

[GPC Measurement Condition]

Measuring apparatus: “HLC-8220 GPC” manufactured by Tosoh Corporation, Column: guard column “HHR-H” (6.0 mmI.D.×4 cm) manufactured by Tosoh Corporation+“TSK-GEL GMHHR-N” (7.8 mmI.D.×30 cm) manufactured by Tosoh Corporation+“TSK-GEL GMHHR-N” (7.8 mmI.D.×30 cm) manufactured by Tosoh Corporation+“TSK-GEL GMHHR-N” (7.8 mmI.D.×30 cm) manufactured by Tosoh Corporation+“TSK-GEL GMHHR-N” (7.8 mmI.D.×30 cm) manufactured by Tosoh Corporation.

Measurement conditions: column temperature 40° C., Developing solvent: tetrahydrofuran (THF), Flow rate 1.0 ml/min

Sample: a solution (5 μl) obtained by filtering a 1.0 mass % tetrahydrofuran solution in terms of resin solid content with a microfilter.

Standard sample: The following monodispersed polystyrene whose molecular weight is known was used in accordance with the measurement manual of “GPC-8020 Model II data analysis version 4.30”

[Dispersed Polystyrene]

“A-500” manufactured by Tosoh Corporation, “A-1000” manufactured by Tosoh Corporation, “A-2500” manufactured by Tosoh Corporation

“A-5000” manufactured by Tosoh Corporation, “F-1” manufactured by Tosoh Corporation, “F-2” manufactured by Tosoh Corporation

“F-4” manufactured by Tosoh Corporation, “F-10” manufactured by Tosoh Corporation, “F-20” manufactured by Tosoh Corporation

“F-40” manufactured by Tosoh Corporation, “F-80” manufactured by Tosoh Corporation, “F-128” manufactured by Tosoh Corporation

“F-288” manufactured by Tosoh Corporation, “F-550” manufactured by Tosoh Corporation

The polymerizable compound may include one or two or more surfactants.

The add amount of the surfactant is preferably 0.005 to 5 mass %, more preferably 0.01 to 3 mass %, and even more preferably 0.03 to 1.0 mass % with respect to the total amount of the polymerizable compound.

(Polymerization Initiator)

The polymerizable composition of the present invention may contain an initiator as necessary. A polymerization initiator used in the polymerizable composition of the present invention is used for polymerizing the polymerizable composition of the present invention. A photopolymerization initiator used in the case where the polymerization is performed by irradiation with light is not particularly limited, and conventionally known initiators can be used to the extent that does not inhibit the alignment state of the polymerizable composition of the present invention.

Examples of the conventionally known initiators include 1-hydroxycyclohexylphenylketone “IRGACURE 184”, 1-(4-isopropylphenyl)-2-hydroxy-2-methylpropane-1-one “DAROCURE 1116”, 2-methyl-1-[(methylthio)phenyl]-2-morpholinopropane-1 “IRGACURE 907”, 2,2-dimethoxy-1,2-diphenylethane-1-one “IRGACURE 651”, 2-benzyl-2-dimethylamino-1-(4-morpholinophenyl)-butanone “IRGACURE 369”, 2-dimethylamino-2-(4-methylbenzyl)-1-(4-morpholino-phenyl)butane-1-one “IRGACURE 379”, 2,2-dimethoxy-1,2-diphenylethane-1-one, bis(2,4,6-trimethylbenzoyl)-diphenylphosphine oxide “LUCIRIN TPO”, 2,4,6-trimethylbenzoyl-phenyl-phosphine oxide “IRGACURE 819”, 1,2-octanedione, 1-[4-(phenylthio)-,2-(O-benzoyloxime)], ethanone “IRGACURE OXE01”, 1-[9-ethyl-6-(2-methylbenzoyl)-9H-carbazole-3-yl]-, 1-(O-acetyloxime) “IRGACURE OXE02” (all manufactured by BASF SE), a mixture of 2,4-diethylthioxanthone (“KAYACURE DETX”, manufactured by Nippon Kayaku Co., Ltd.) and ethyl p-dimethylamino benzoate (“KAYACURE EPA”, manufactured by Nippon Kayaku Co., Ltd.), a mixture of isopropylthioxanthone (“QUANTACURE ITX”, manufactured by Ward Blenkinsop Co., Ltd.) and ethyl p-dimethylamino benzoate, “ESACURE ONE”, “ESACURE KIP150”, “ESACURE KIP160”, “ESACURE 1001M”, “ESACURE A198”, “ESACURE KIP IT”, “ESACURE KTO46”, “ESACURE TZT” (all manufactured by Fratelli-Lamberti SpA”), “SPEEDCURE BMS”, “SPEEDCURE PBZ”, and “benzophenone” (manufactured by LAMBSON Ltd.). In addition, a photoacid generator can be used as a photocationic initiator. Examples of the photoacid generator include a diazodisulfone-based compound, a triphenylsulfonium-based compound, a phenylsulfone-based compound, a sulfonylpyridine-based compound, a triazine-based compound, and a diphenyliodonium compound.

The content of the photopolymerization initiator is preferably 0.1% to 10% and particularly preferably 1% to 6% by mass with respect to the total content of the polymerizable compound contained in the polymerizable composition. These may be used alone or in combination of two or more kinds thereof.

Further, as a thermal polymerization initiator used for thermal polymerization, conventionally known initiators can be used, and examples thereof include an organic peroxide such as methyl acetoacetate peroxide, cumene hydroperoxide, benzoyl peroxide, bis(4-t-butylcyclohexyl)peroxy dicarbonate, t-butylperoxy benzoate, methyl ethyl ketone peroxide, 1,1-bis(t-hexylperoxy) 3,3,5-trimethylcyclohexane, p-pentahydroperoxide, t-butylhydroperoxide, dicumyl peroxide, isobutyl peroxide, di(3-methyl-3-methoxybutyl)peroxy dicarbonate, or 1,1-bis(t-butylperoxy)cyclohexane; an azonitrile compound such as 2,2′-azobisisobutyronitrile or 2,2′-azobis(2,4-dimethylvaleronitrile); an azoamidine compound such as 2,2′-azobis(2-methyl-N-phenylpropion-amidine)dihydrochloride; an azoamide compound such as 2,2′ azobis(2-methyl-N-[1,1-bis(hydroxymethyl)-2-hydroxyethyl]propionamide); and an alkylazo compound such as 2,2′ azobis(2,4,4-trimethylpentane). The content of the thermal polymerization initiator is preferably 0.1% to 10% and particularly preferably 1% to 6% by mass. These may be used alone or in combination of two or more kinds thereof.

(Organic Solvent)

The polymerizable composition of the present invention may contain an organic solvent as necessary. The organic solvent to be used is not particularly limited, but an organic solvent that satisfactorily dissolves the polymerizable compound is preferable and an organic solvent which can be dried at a temperature of 100° C. or lower is preferable. Examples of such solvents include aromatic hydrocarbon such as toluene, xylene, cumene, or mesitylene, an ester-based solvent such as methyl acetate, ethyl acetate, propyl acetate, butyl acetate, cyclohexyl acetate, 3-butoxymethyl acetate, or ethyl lactate, a ketone-based solvent such as methyl ethyl ketone, methyl isobutyl ketone, cyclohexanone, or cyclopentanone, an ether-based solvent such as tetrahydrofuran, 1,2-dimethoxyethane, or anisole, an amide-based solvent such as N,N-dimethylformamide or N-methyl-2-pyrrolidone, ethylene glycol monomethyl ether acetate, propylene glycol monomethyl ether acetate, propylene glycol monomethyl ether, propylene glycol diacetate, propylene glycol monomethyl propyl ether, diethylene glycol monomethyl ether acetate, γ-butyrolactone, and chlorobenzene. These may be used alone or in combination of two or more kinds thereof. From the viewpoint of solution stability, it is preferable to use one or more solvents selected from a ketone-based solvent, an ether-based solvent, an ester-based solvent, and an aromatic hydrocarbon-based solvent.

Since the polymerizable composition used in the present invention is typically used by application, the proportion of the organic solvent to be used is not particularly limited as long as the applied state is not significantly impaired, but the content of the organic solvent is preferably used such that the ratio of the total content of the polymerizable compound contained in the polymerizable composition is 0.1% to 99% by mass, more preferably 5% to 60% by mass, and particularly preferably 10% to 50% by mass.

Further, it is preferable that the polymerizable liquid crystalline compound is dissolved in the organic solvent by heating and stirring the solution in order for the compound to be uniformly dissolved therein. The heating temperature during the heating and the stirring may be adjusted as appropriate by considering the dissolution of the polymerizable liquid crystal composition in the organic solvent, but is preferably 15° C. to 130° C., more preferably 30° C. to 110° C., and particularly preferably 50° C. to 100° C. from the viewpoint of productivity.

(Additive)

The polymerizable composition of the present invention may include general-purpose additives depending on various purposes thereof. For example, additives such as a polymerization inhibitor, an antioxidant, an ultraviolet absorbing agent, an alignment controlling agent, a chain transfer agent, an infrared absorbing agent, a thixotropic agent, an antistatic agent, a dye, a filler, a chiral compound, a non-liquid crystalline compound having a polymerizable group, a liquid crystal compound, and an alignment material can be added to the extent that does not significantly degrade alignment properties of liquid crystals.

(Polymerization Inhibitor)

The polymerizable composition of the present invention may contain a polymerization inhibitor as necessary. The polymerization inhibitor to be used is not particularly limited, and conventionally known polymerization inhibitors can be used.

Examples thereof include a phenol-based compound such as p-methoxyphenol, cresol, t-butyl catechol, 3,5-di-t-butyl-4-hydroxytoluene, 2,2′-methylenebis(4-methyl-6-t-butylphenol), 2,2′-methylenebis(4-ethyl-6-t-butylphenol), 4,4′-thiobis(3-methyl-6-t-butylphenol), 4-methoxy-1-naphthol, or 4,4′-dialkoxy-2,2′-bi-1-naphthol; a quinone-based compound such as hydroquinone, methylhydroquinone, tert-butylhydroquinone, p-benzoquinone, methyl-p-benzoquinone, tert-butyl-p-benzoquinone, 2,5-diphenylbenzoquinone, 2-hydroxy-1,4-naphthoquinone, 1,4-naphthoquinone, 2,3-dichloro-1,4-naphthoquinone, anthraquinone, or diphenoquinone; an amine-based compound such as p-phenylenediamine, 4-aminodiphenylamine, N,N′-diphenyl-p-phenylenediamine, N-1-propyl-N′-phenyl-p-phenylenediamine, N-(1,3-dimethylbutyl)-N′-phenyl-p-phenylenediamine, N,N′-di-2-naphthyl-p-phenylenediamine, diphenylamine, N-phenyl-β-naphthylamine, 4,4′-dicumyl-diphenylamine, or 4,4′-dioctyl-diphenylamine; a thioether-based compound such as phenothiazine or distearyl thiodipropionate; and a nitroso compound such as N-nitrosodiphenylamine, N-nitrosophenylnaphthylamine, N-nitrosodinaphthylamine, p-nitrosophenol, nitrosobenzene, p-nitrosodiphenylamine, α-nitroso-β-naphthol, N,N-dimethyl p-nitrosoaniline, p-nitrosodiphenylamine, p-nitronedimethylamine, p-nitrone-N,N-diethylamine, N-nitrosoethanolamine, N-nitrosodi-n-butylamine, N-nitroso-N-n-butyl-4-butanolamine, N-nitroso-diisopropanolamine, N-nitroso-N-ethyl-4-butanolamine, 5-nitroso-8-hydroxyquinoline, N-nitrosomorpholine, N-nitroso-N-phenylhydroxyamine ammonium salt, nitrosobenzene, 2,4,6-tri-tert-butylnitrobenzene, N-nitroso-N-methyl-p-toluenesulfonamide, N-nitroso-N-ethylurethane, N-nitroso-N-n-propylurethane, 1-nitroso-2-naphthol, 2-nitroso-1-naphthol, sodium 1-nitroso-2-naphthol-3,6-sulfonate, sodium 2-nitroso-1-naphthol-4-sulfonate, 2-nitroso-5-methylaminophenol hydrochloride, or 2-nitroso-5-methylaminophenol hydrochloride.

The amount of the polymerization inhibitor to be added is preferably 0.01% to 1.0% by mass and more preferably 0.05% to 0.5% by mass with respect to the total amount of the polymerizable compound contained in the polymerizable composition.

(Antioxidant)

The polymerizable composition of the present invention may contain an antioxidant as necessary. Examples of such a compound include a hydroquinone derivative, a nitrosoamine-based polymerization inhibitor, and a hindered phenol-based antioxidant, and more specific examples thereof include tert-butylhydroquinone, “Q-1300” and “Q-1301” (both manufactured by Wako Pure Chemical Industries, Ltd.), pentaerythritol tetrakis[3-(3,5-di-tert-butyl-4-hydroxyphenyl)propionate “IRGANOX 1010”, thiodiethylene bis[3-(3,5-di-tert-butyl-4-hydroxyphenyl)propionate “IRGANOX 1035”, octadecyl-3-(3,5-di-tert-butyl-4-hydroxyphenyl)propionate “IRGANOX 1076”, “IRGANOX 1135”, “IRGANOX 1330”, 4,6-bis(octylthiomethyl)-o-cresol “IRGANOX 1520L”, “IRGANOX 1726”, “IRGANOX 245”, “IRGANOX 259”, “IRGANOX 3114”, “IRGANOX 3790”, “IRGANOX 5057”, “IRGANOX 565” (all manufactured by BASF SE), ADEKA STAB AO-20, AO-30, AO-40, AO-50, AO-60, AO-80 (all manufactured by ADEKA CORPORATION), SUMILIZER BHT, SUMILIZER BBM-S, and SUMILIZER GA-80 (manufactured by Sumitomo Chemical Industries Co., Ltd.).

The amount of the antioxidant to be added is preferably 0.01% to 2.0% by mass and more preferably 0.05% to 1.0% by mass with respect to the total amount of the polymerizable compound contained in the polymerizable composition.

(Ultraviolet Absorbing Agent)

The polymerizable composition of the present invention may contain an ultraviolet absorbing agent and a light stabilizer as necessary. The ultraviolet absorbing agent or the light stabilizer to be used is not particularly limited, but it is preferable to use an optically anisotropic body or an optical film in order to improve light resistance.

Examples of the ultraviolet absorbing agent include 2-(2-hydroxy-5-t-butylphenyl)-2H-benzotriazole “TINUVIN PS”, “TINUVIN 99-2”, “TINUVIN 109”, “TINUVIN 213”, “TINUVIN 234”, “TINUVIN 326”, “TINUVIN 328”, “TINUVIN 329”, “TINUVIN 384-2”, “TINUVIN 571”, 2-(2H-benzotriazole-2-yl)-4,6-bis(1-methyl-1-phenylethyl) phenol “TINUVIN 900”, 2-(2H-benzotriazole-2-yl)-6-(1-methyl-1-phenylethyl)-4-(1,1,3,3-tetramethylbutyl)phenol “TINUVIN 928”, “TINUVIN 1130”, “TINUVIN 400”, “TINUVIN 405”, 2,4-bis[2-hydroxy-4-butoxyphenyl]-6-(2,4-dibutoxyphenyl)-1,3,5-triazine “TINUVIN 460”, “TINUVIN 479”, “TINUVIN 5236” (all manufactured by BASF SE), “ADEKA STAB LA-32”, “ADEKA STAB LA-34”, “ADEKA STAB LA-36”, “ADEKA STAB LA-31”, “ADEKA STAB LA-1413”, and “ADEKA STAB LA-51” (all manufactured by ADEKA CORPORATION).

Examples of the light stabilizer include “TINUVIN 111FDL”, “TINUVIN 123”, “TINUVIN 144”, “TINUVIN 152”, “TINUVIN 292”, “TINUVIN 622”, “TINUVIN 770”, “TINUVIN 765”, “TINUVIN 780”, “TINUVIN 905”, “TINUVIN 5100”, “TINUVIN 5050”, “TINUVIN 5060”, “TINUVIN 5151”, “CHIMASSORB 119FL”, “CHIMASSORB 944FL”, “CHIMASSORB 944LD” (all manufactured by BASF SE), “ADEKA STAB LA-52”, “ADEKA STAB LA-57”, “ADEKA STAB LA-62”, “ADEKA STAB LA-67”, “ADEKA STAB LA-63P”, “ADEKA STAB LA-68LD”, “ADEKA STAB LA-77”, “ADEKA STAB LA-82”, and “ADEKA STAB LA-87” (all manufactured by ADEKA CORPORATION).

(Alignment Controlling Agent)

The polymerizable composition of the present invention may contain an alignment controlling agent in order to control the alignment state of the liquid crystalline compound. As the alignment controlling agent to be used, agents used for substantial horizontal alignment, substantial vertical alignment, or substantial hybrid alignment of the liquid crystalline compound with respect to the base material may be exemplified. Further, in the case where a chiral compound is added, agents used for substantial plane alignment of the liquid crystalline compound with respect to the base material may be exemplified. As described above, horizontal alignment or plane alignment may be induced by a surfactant in some cases, the alignment controlling agent is not particularly limited as long as the alignment state of each liquid crystalline compound is induced, and conventionally known ones can be used.

As such an alignment controlling agent, a compound which has an effect of effectively reducing the tilt angle between the interface of the air and an optically anisotropic body in the case where an optically anisotropic body is used as the polymerizable liquid crystal composition, has a repeating unit represented by Formula (8), and has a weight-average molecular weight of 100 to 1,000,000 may be exemplified.

[Chem. 100]

CR¹¹R¹²—CR¹³R¹⁴ (8)

(In the formula, R¹¹, R¹², R¹³, and R¹⁴ each independently represent a hydrogen atom, a halogen atom, or a hydrocarbon group having 1 to 20 carbon atoms, and the hydrogen atoms in the hydrocarbon group may be substituted with one or more halogen atoms.)

In addition, examples of the compound include a rod-like liquid crystalline compound modified with a fluoroalkyl group, a discotic liquid crystalline compound, and a polymerizable compound containing a long-chain aliphatic alkyl group which may have a branched structure.

Examples of the compound which has an effect of effectively increasing the tilt angle between the interface of the air and an optically anisotropic body in the case where an optically anisotropic body is used as the polymerizable liquid crystal composition include cellulose nitrate, cellulose acetate, cellulose propionate, cellulose butyrate, a rod-like liquid crystalline compound modified with a heteroaromatic ring salt, a cyano group, and a rod-like liquid crystalline compound modified with a cyanoalkyl group.

(Chain Transfer Agent)

The polymerizable composition of the present invention may contain a chain transfer agent in order to further improve adhesiveness among the polymer, the optically anisotropic body, and the base material. Examples of the chain transfer agent include aromatic hydrocarbons, halogenated hydrocarbons such as chloroform, carbon tetrachloride, carbon tetrabromide, and bromotrichloromethane, a mercaptan compound such as octyl mercaptan, n-butyl mercaptan, n-pentyl mercaptan, n-hexadecyl mercaptan, n-tetradecyl, n-dodecyl mercaptan, t-tetradecyl mercaptan, or t-dodecyl mercaptan, a thiol compound such as hexanedithiol, decanedithiol, 1,4-butanediol bisthiopropionate, 1,4-butanediol bisthioglycolate, ethylene glycol bisthioglycolate, ethylene glycol bisthiopropionate, trimethylolpropane tristhioglycolate, trimethylolpropane tristhiopropionate, trimethylolpropane tris(3-mercaptobutyrate), pentaerythritol tetrakisthioglycolate, pentaerythritol tetrakisthiopropionate, trimercaptopropionic acid tris(2-hydroxyethyl)isocyanurate, 1,4-dimethyl mercaptobenzene, 2,4,6-trimercapto-s-triazine, or 2-(N,N-dibutylamino)-4,6-dimercapto-s-triazine, a sulfide compound such as dimethyl xanthogen disulfide, diethyl xanthogen disulfide, diisopropyl xanthogen disulfide, tetramethyl thiuram disulfide, tetraethyl thiuram disulfide, or tetrabutyl thiuram disulfide, N,N-dimethylaniline, N,N-divinylaniline, pentaphenylethane, an α-methylstyrene dimer, acrolein, allyl alcohol, terpineol, α-terpinene, γ-terpinene, and dipentene. Among these, 2,4-diphenyl-4-methyl-1-pentene and a thiol compound are more preferable.

Specifically, compounds represented by General Formulae (9-1) to (9-12) are preferable.

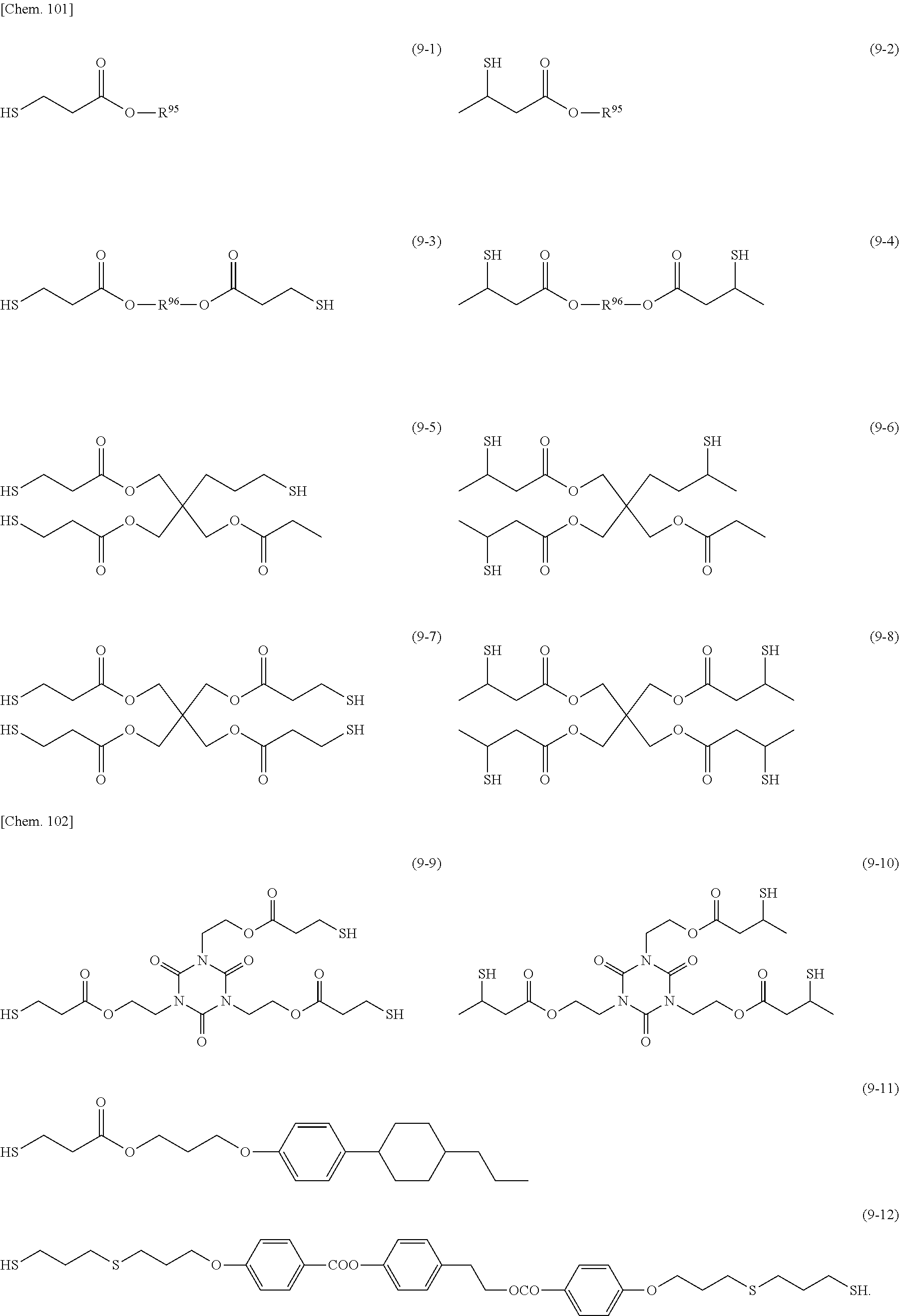

In the formulae, R⁹⁵ represents an alkyl group having 2 to 18 carbon atoms, the alkyl group may be linear or branched, one or more methylene groups in the alkyl group may be substituted with an oxygen atom, a sulfur atom, —CO—, —OCO—, —COO—, or —CH═CH— by assuming that an oxygen atom and a sulfur atom are not directly bonded to each other, R⁹⁶ represents an alkylene group having 2 to 18 carbon atoms, and one or more methylene groups in the alkylene group may be substituted with an oxygen atom, a sulfur atom, —CO—, —OCO—, —COO—, or —CH═CH— by assuming that an oxygen atom and a sulfur atom are not directly bonded to each other.

It is preferable that the chain transfer agent is added during a step of preparing a polymerizable solution by mixing the polymerizable liquid crystal compound in an organic solvent and heating and stirring the solution, but the chain transfer agent may be added during the subsequent step of mixing a polymerization initiator into the polymerizable solution or may be added during both steps.

The amount of the chain transfer agent to be added is preferably 0.5% to 10% by mass and more preferably 1.0% to 5.0% by mass with respect to the total amount of the polymerizable compound contained in the polymerizable composition.

Further, a liquid crystal compound or the like which is not polymerizable can be added as necessary for the purpose of adjusting physical properties. It is preferable that the polymerizable compound which does not have liquid crystallinity is added during a step of preparing a polymerizable solution by mixing the polymerizable compound in an organic solvent and heating and stirring the solution, but the liquid crystal compound which is not polymerizable may be added during the subsequent step of mixing a polymerization initiator into the polymerizable solution or may be added during both steps. The amount of these compounds to be added is preferably 20% by mass or less, more preferably 10% by mass or less, and still more preferably 5% by mass or less with respect to the polymerizable composition.

(Infrared Absorbing Agent)

The polymerizable composition of the present invention may contain an infrared absorbing agent as necessary. The infrared absorbing agent to be used is not particularly limited and the polymerizable liquid crystal composition may contain conventionally known ones within the range that does not impair the alignment properties.

Examples of the infrared absorbing agent include a cyanine compound, a phthalocyanine compound, a naphthoquinone compound, a dithiol compound, a diimmonium compound, an azo compound, and an ammonium salt.

Specific examples thereof include diimmonium salt type “NIR-IM1”, ammonium salt type “NIR-AM1” (both manufactured by Nagase ChemteX Corporation), “KARENZ IR-T”, “KARENZ IR-13F” (both manufactured by SHOWA DENKO K.K.), “YKR-2200”, “YKR-2100” (both manufactured by Yamamoto Chemicals Inc.), “IRA908”, “IRA931”, “IRA955”, and “IRA1034” (all manufactured by INDECO Co., Ltd.).

(Antistatic Agent)

The polymerizable composition of the present invention may contain an antistatic agent as necessary. The antistatic agent to be used is not particularly limited and the polymerizable liquid crystal composition may contain conventionally known ones within the range that does not impair the alignment properties.

Examples of such an antistatic agent include a polymer compound containing at least one or more sulfonate groups or phosphate groups in a molecule, a compound containing a quaternary ammonium salt, and a surfactant containing a polymerizable group.

Among these, a surfactant containing a polymerizable group is preferable, and examples of an anionic surfactant containing a polymerizable group include alkyl ether-based surfactants such as “ANTOX SAD”, “ANTOX MS-2N” (both manufactured by Nippon Nyukazai Co., Ltd.), “AQUALON KH-05”, “AQUALON KH-10”, “AQUALON KH-20”, “AQUALON KH-0530”, “AQUALON KH-1025” (all manufactured by Dai-ichi Kogyo Seiyaku Co., Ltd.), “ADEKA REASOAP SR-10N”, “ADEKA REASOAP SR-20N” (both manufactured by ADEKA CORPORATION), and “LATEMUL PD-104” (manufactured by Kao Corporation), sulfosuccinic acid ester-based surfactants such as “LATEMUL S-120”, “LATEMUL S-120A”, “LATEMUL S-180P”, “LATEMUL S-180A” (manufactured by Kao Corporation), and “ELEMINOL JS-2” (manufactured by Sanyo Chemical Industries, Ltd.), alkylphenylether-based or alkylphenylester-based surfactants such as “AQUALON H-2855A”, “AQUALON H-3855B”, “AQUALON H-3855C”, “AQUALON H-3856”, “AQUALON HS-05”, “AQUALON HS-10”, “AQUALON HS-20”, “AQUALON HS-30”, “AQUALON HS-1025”, “AQUALON BC-05”, “AQUALON BC-10”, “AQUALON BC-20”, “AQUALON BC-1025”, and “AQUALON BC-2020” (all manufactured by Dai-ichi Kogyo Seiyaku Co., Ltd.), “ADEKA REASOAP SDX-222”, “ADEKA REASOAP SDX-223”, “ADEKA REASOAP SDX-232”, “ADEKA REASOAP SDX-233”, “ADEKA REASOAP SDX-259”, “ADEKA REASOAP SE-10N”, and “ADEKA REASOAP SE-20N” (all manufactured by ADEKA CORPORATION), (meth)acrylate sulfuric acid ester-based surfactants such as “ANTOX MS-60”, “ANTOX MS-2N” (both manufactured by Nippon Nyukazai Co., Ltd.), “ELEMINOL RS-30” (manufactured by Sanyo Chemical Industries, Ltd.), and phosphoric acid ester-based surfactants such as “H-3330P” (manufactured by Dai-ichi Kogyo Seiyaku Co., Ltd.) and “ADEKA REASOAP PP-70” (manufactured by ADEKA CORPORATION).

Among the surfactants containing a polymerizable group, examples of a non-ionic surfactant include alkyl ether-based surfactants such as “ANTOX LMA-20”, “ANTOX LMA-27”, “ANTOX EMH-20”, “ANTOX LMH-20”, “ANTOX SMH-20” (all manufactured by Nippon Nyukazai Co., Ltd.), “ADEKA REASOAP ER-10”, “ADEKA REASOAP ER-20”, “ADEKA REASOAP ER-30”, “ADEKA REASOAP ER-40” (all manufactured by ADEKA CORPORATION), “LATEMUL PD-420”, “LATEMUL PD-430”, and “LATEMUL PD-450” (all manufactured by Kao Corporation), alkyl phenyl ether-based or alkyl phenyl ester-based surfactants such as “AQUALON RN-10”, “AQUALON RN-20”, “AQUALON RN-30”, “AQUALON RN-50”, “AQUALON RN-2025” (all manufactured by Dai-ichi Kogyo Seiyaku Co., Ltd.), “ADEKA REASOAP NE-10”, “ADEKA REASOAP NE-20”, “ADEKA REASOAP NE-30”, and “ADEKA REASOAP NE-40” (all manufactured by ADEKA CORPORATION), and (meth)acrylate sulfuric acid ester-based surfactants such as “RMA-564”, “RMA-568”, and “RMA-1114” (all manufactured by Nippon Nyukazai Co., Ltd.).

Other examples of antistatic agents include polyethylene glycol (meth)acrylate, methoxy polyethylene glycol (meth)acrylate, ethoxy polyethylene glycol (meth)acrylate, propoxy polyethylene glycol (meth)acrylate, n-butoxy polyethylene glycol (meth)acrylate, n-pentaxy polyethylene glycol (meth)acrylate, phenoxy polyethylene glycol (meth)acrylate, polypropylene glycol (meth)acrylate, methoxy polypropylene glycol (meth)acrylate, ethoxy polypropylene glycol (meth)acrylate, propoxy polypropylene glycol (meth)acrylate, n-butoxy polypropylene glycol (meth)acrylate, n-pentaxy polypropylene glycol (meth)acrylate, phenoxy polypropylene glycol (meth)acrylate, polytetramethylene glycol (meth)acrylate, methoxy polytetramethylene glycol (meth)acrylate, phenoxy tetraethylene glycol (meth)acrylate, hexaethylene glycol (meth)acrylate, and methoxy hexaethylene glycol (meth)acrylate.

The antistatic agent can be used alone or in combination of two or more kinds thereof. The amount of the antistatic agent to be added is preferably 0.001% to 10% by weight and more preferably 0.01% to 5% by weight with respect to the total amount of the polymerizable compound contained in the polymerizable composition.

(Dye)

The polymerizable composition of the present invention may contain a dye as necessary. The dye to be used is not particularly limited and the polymerizable liquid crystal composition may contain conventionally known ones within the range that does not impair the alignment properties.

Examples of the dye include dichroic dyes and fluorescent dyes. Examples of such dyes include a polyazo dye, an anthraquinone dye, a cyanine dye, a phthalocyanine dye, a perylene dye, and a perinone dye, and a squarylium dye. From the viewpoint of addition, a dye exhibiting liquid crystallinity is preferable as the dye.

For example, dyes described in U.S. Pat. No. 2,400,877, Dreyer J. F., Phys. and Colloid Chem., 1948, 52, 808., “The Fixing of Molecular Orientation”, Dreyer J. F., Journal de Physique, 1969, 4, 114., “Light Polarization from Films of Lyotropic Nematic Liquid Crystals”, J. Lydon; “Chromonics” in “Handbook of Liquid Crystals Vol. 2B: Low Molecular Weight Liquid Crystals II”, D. Demus, J. Goodby, G. W. Gray, H. W. Spiessm, V. Vill ed, Willey-VCH, pp. 981-1007 (1998), Dichroic Dyes for Liquid Crystal Display A. V. Ivashchenko CRC Press, 1994, and “New Development of Functional Dye Market”, Chapter 1, pp. 1, 1994, published by CMC Corporation can be used.

Examples of the dichroic dyes include dyes represented by Formulae (d-1) to (d-8). The amount of the dichroic dye to be added is preferably 0.001% to 10% by weight and more preferably 0.01% to 5% by weight with respect to the total amount of the polymerizable compound contained in the polymerizable composition.

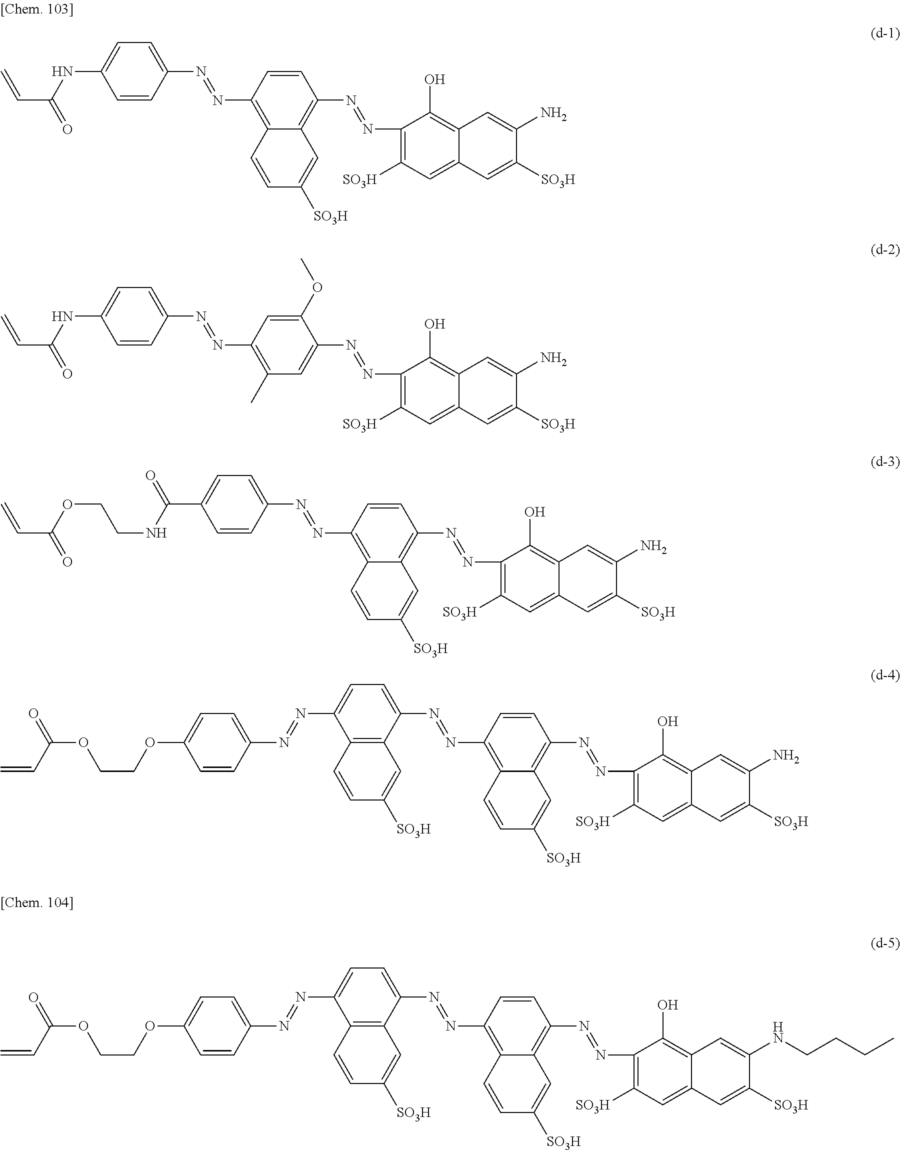

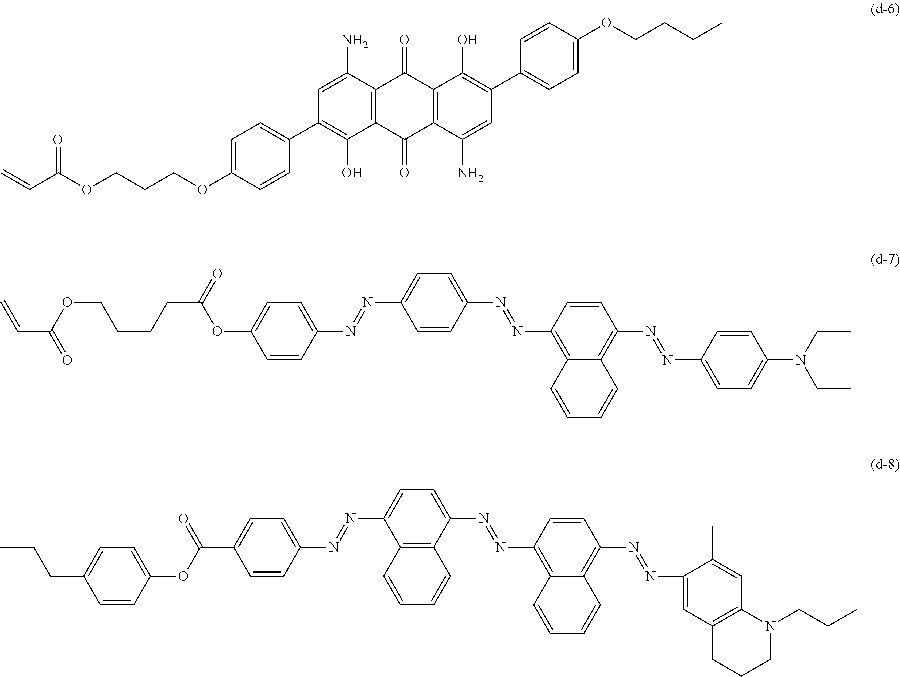

(Filler)

The polymerizable composition of the present invention may contain a filler as necessary. The filler to be used is not particularly limited, and the polymerizable liquid crystal composition may contain conventionally known ones within the range that does not degrade the thermal conductivity of the obtained polymer.

Examples of the filler include inorganic fillers such as alumina, titanium white, aluminum hydroxide, talc, clay, mica, barium titanate, zinc oxide, and glass fibers, thermally conductive fillers such as metal powder, for example, silver powder or copper powder, aluminum nitride, boron nitride, silicon nitride, gallium nitride, silicon carbide, magnesia (aluminum oxide), silica, crystalline silica (silicon oxide), fused silica (silicon oxide), graphite, and carbon fibers containing carbon nanofibers, and silver nanoparticles.

(Chiral Compound)

The polymerizable composition of the present invention may contain a chiral compound for the purpose of obtaining a chiral nematic phase. The chiral compound itself does not need to exhibit liquid crystallinity and may or may not contain a polymerizable group. Further, the orientation of the spiral of the chiral compound can be appropriately selected depending on the applications of the polymer.

The chiral compound containing a polymerizable group is not particularly limited, and conventionally known compounds can be used. Among those, a chiral compound with large helical twisting power (HTP) is preferable. Further, as the polymerizable group, a vinyl group, a vinyloxy group, an allyl group, an allyloxy group, an acryloyloxy group, a methacryloyloxy group, a glycidyl group, and an oxetanyl group are preferable and an acryloyloxy group, a glycidyl group, and an oxetanyl group are particularly preferable.

It is necessary that the amount of the chiral compound to be blended is adjusted as appropriate by the spiral inductive force of the compound, and the amount thereof is preferably 0.5% to 80% by mass, more preferably 3% to 50% by mass, and particularly preferably 5% to 30% by mass with respect to the total amount of the liquid crystalline compound containing a polymerizable group and the chiral compound containing a polymerizable group.

Specific examples of the chiral compound include compounds represented by General Formulae (10-1) to (10-4), but the examples are not limited to the compounds represented by the following general formulae.

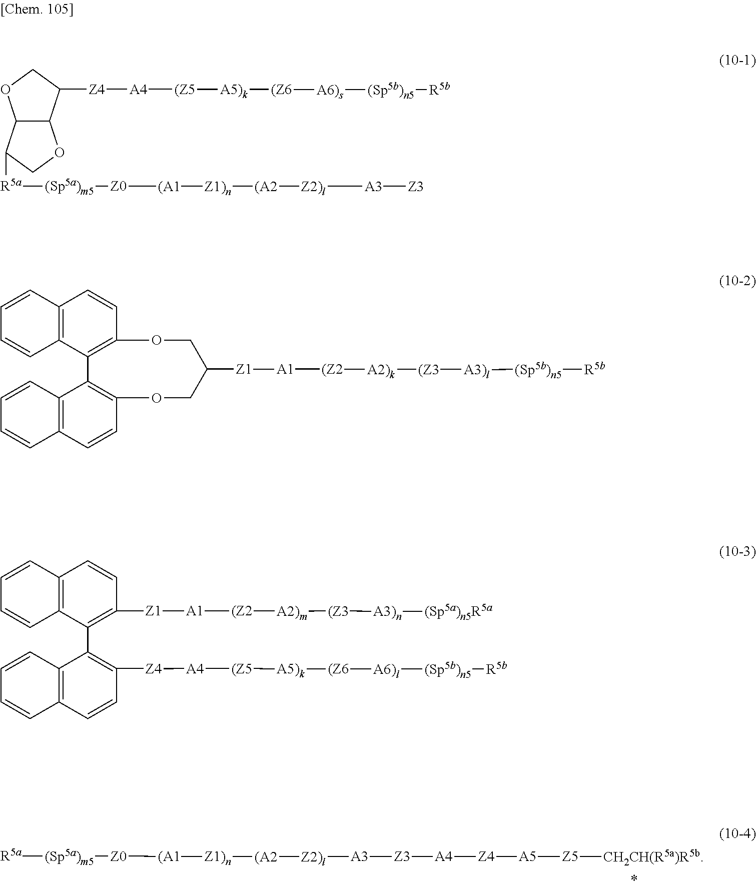

In the formulae, Sp^{5a} and Sp^{5b} each independently represent an alkylene group having 0 to 18 carbon atoms, the alkylene group may be substituted with one or more halogen atoms, a CN group, or an alkyl group having a polymerizable functional group and 1 to 8 carbon atoms, and one —CH₂— or two or more (—CH₂—)'s which are not adjacent to each other in this group may be each independently substituted with —O—, —S—, —NH—, —N(CH₃)—, —CO—, —COO—, —OCO—, —OCOO—, —SCO—, —COS—, or —C≡C— in the form in which oxygen atoms are not directly bonded to each other.

A1, A2, A3, A4, A5, and A6 each independently represent a 1,4-phenylene group, a 1,4-cyclohexylene group, a 1,4-cyclohexenyl group, a tetrahydropyran-2,5-diyl group, a 1,3-dioxane-2,5-diyl group, a tetrahydrothiopyran-2,5-diyl group, a 1,4-bicyclo(2,2,2)octylene group, a decahydronaphthalene-2,6-diyl group, a pyridine-2,5-diyl group, a pyrimidine-2,5-diyl group, a pyrazine-2,5-diyl group, a thiophene-2,5-diyl group, a 1,2,3,4-tetrahydronaphthalene-2,6-diyl group, a 2,6-naphthylene group, a phenanthrene-2,7-diyl group, a 9,10-dihydrophenanthrene-2,7-diyl group, a 1,2,3,4,4a,9,10a-octahydrophenanthrene-2,7-diyl group, a 1,4-naphthylene group, a benzo[1,2-b:4,5-b′]dithiophene-2,6-diyl group, a benzo[1,2-b:4,5-b′]diselenophene-2,6-diyl group, a [1]benzothieno[3,2-b]thiophene-2,7-diyl group, a [1]benzoselenopheno[3,2-b]selenophene-2,7-diyl group, or a fluorene-2,7-diyl group, n, l, and k each independently represent 0 or 1, n+1+k is greater than or equal to 0 and less than or equal to 3,

m5 represents 0 or 1,

Z0, Z1, Z2, Z3, Z4, Z5, and Z6 each independently represent —COO—, —OCO—, —CH₂CH₂—, —OCH₂—, —CH₂O—, —CH═CH—, —C≡C—, —CH═CHCOO—, —OCOCH═CH—, —CH₂CH₂COO—, —CH₂CH₂OCO—, —COOCH₂CH₂—, —OCOCH₂CH₂—, —CONH—, —NHCO—, an alkyl group which may have halogen atoms with 2 to 10 carbon atoms, or a single bond,

R^{5a} and R^{5b} each independently represent a hydrogen atom, a halogen atom, a cyano group, or an alkyl group having 1 to 18 carbon atoms, the alkyl group may be substituted with one or more halogen atoms or CN, one —CH₂— or two or more (—CH₂—)'s which are not adjacent to each other in this group may be each independently substituted with —O—, —S—, —NH—, —N(CH₃)—, —CO—, —COO—, —OCO—, —OCOO—, —SCO—, —COS—, or —C≡C— in the form in which oxygen atoms are not directly bonded to each other. Alternatively, R^{5a} and R^{5b} represent a group represented by Formula (10-a).

[Chem. 106]

—P^{5a} (10-a)

(In the formula, P^{5a} represents a polymerizable functional group and Sp^{5a} has the same definition as that for Sp¹.)

P^{5a} represents a substituent selected from polymerizable groups represented by Formulae (P-1) to (P-20).

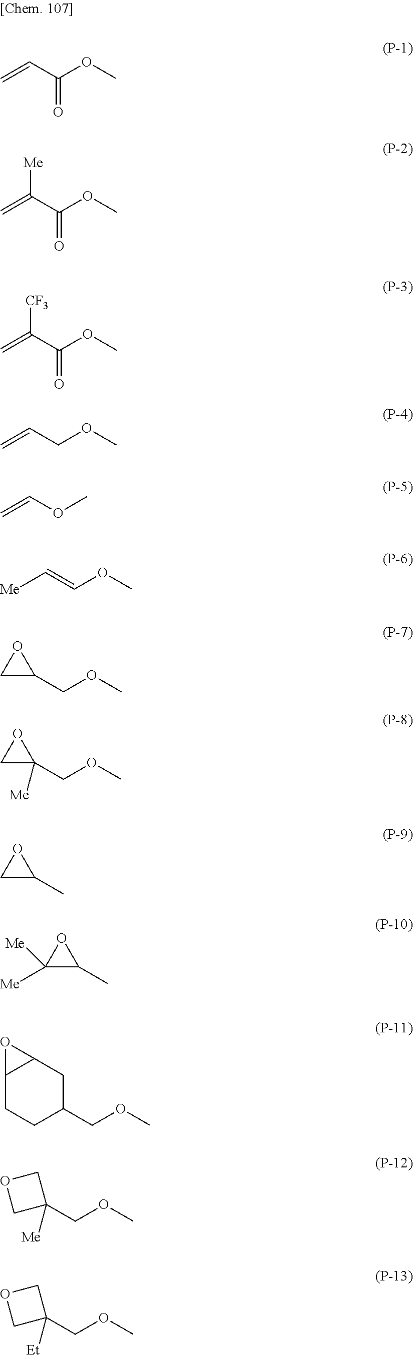

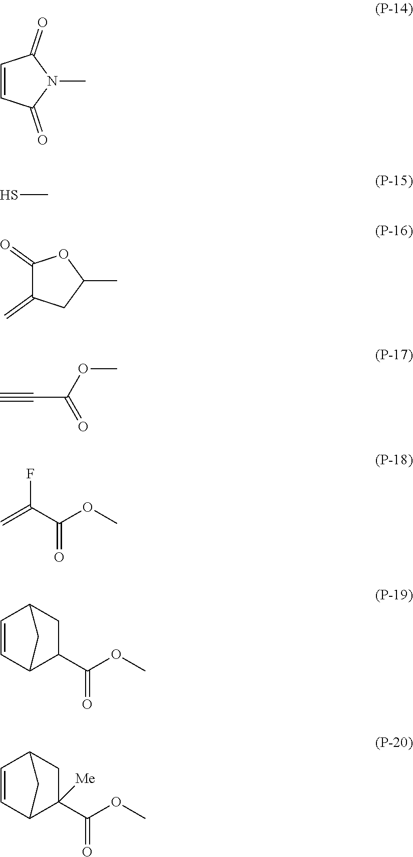

Other specific examples of the chiral compound include compounds represented by General Formulae (10-5) to (10-35).

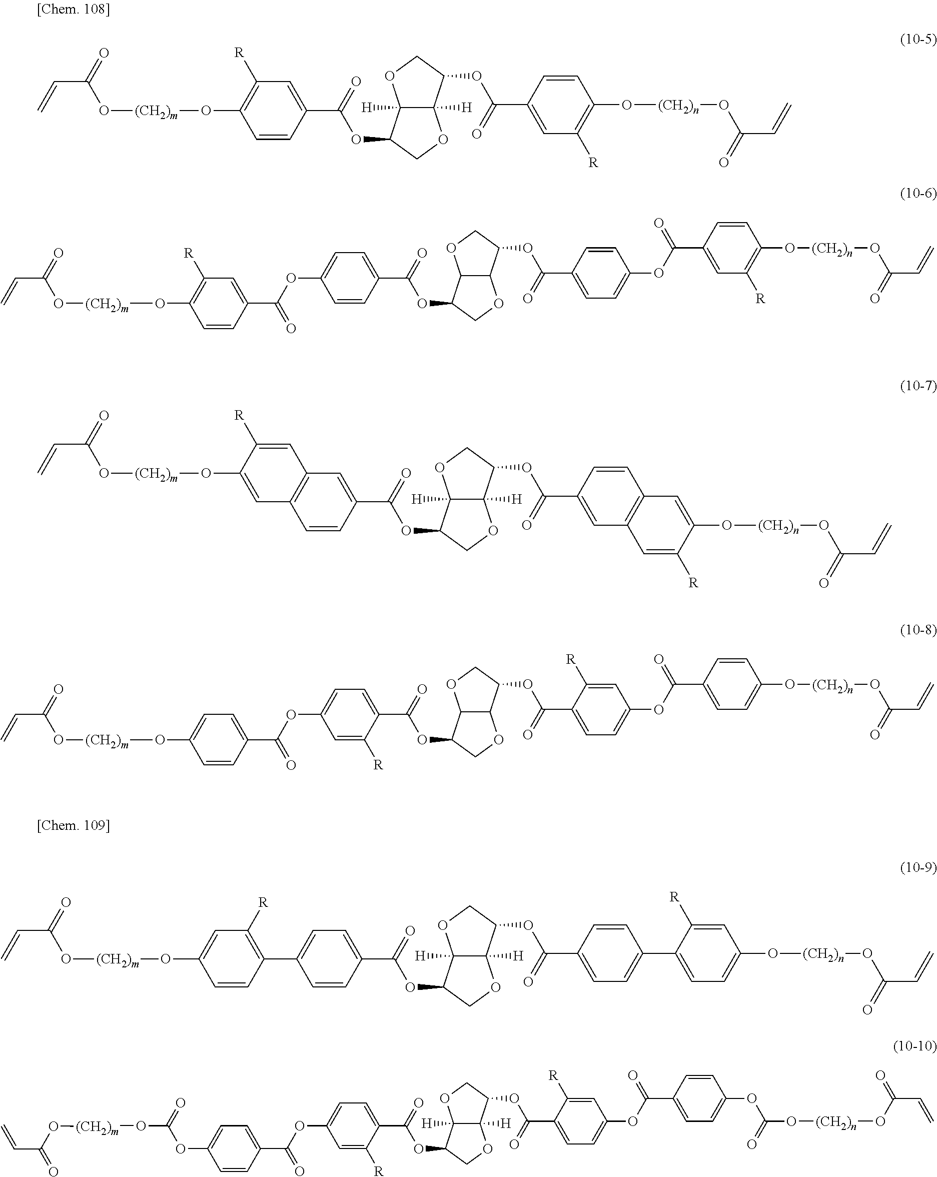

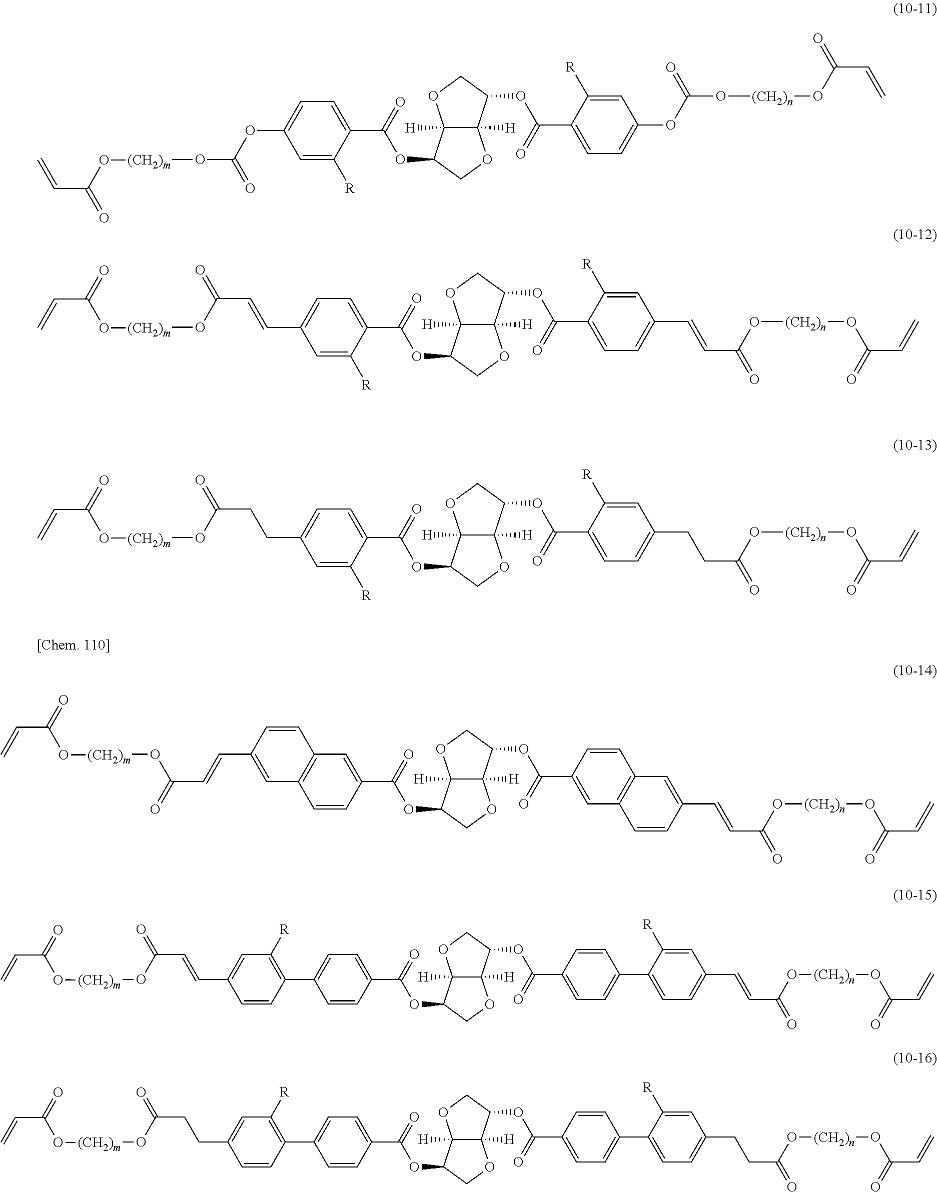

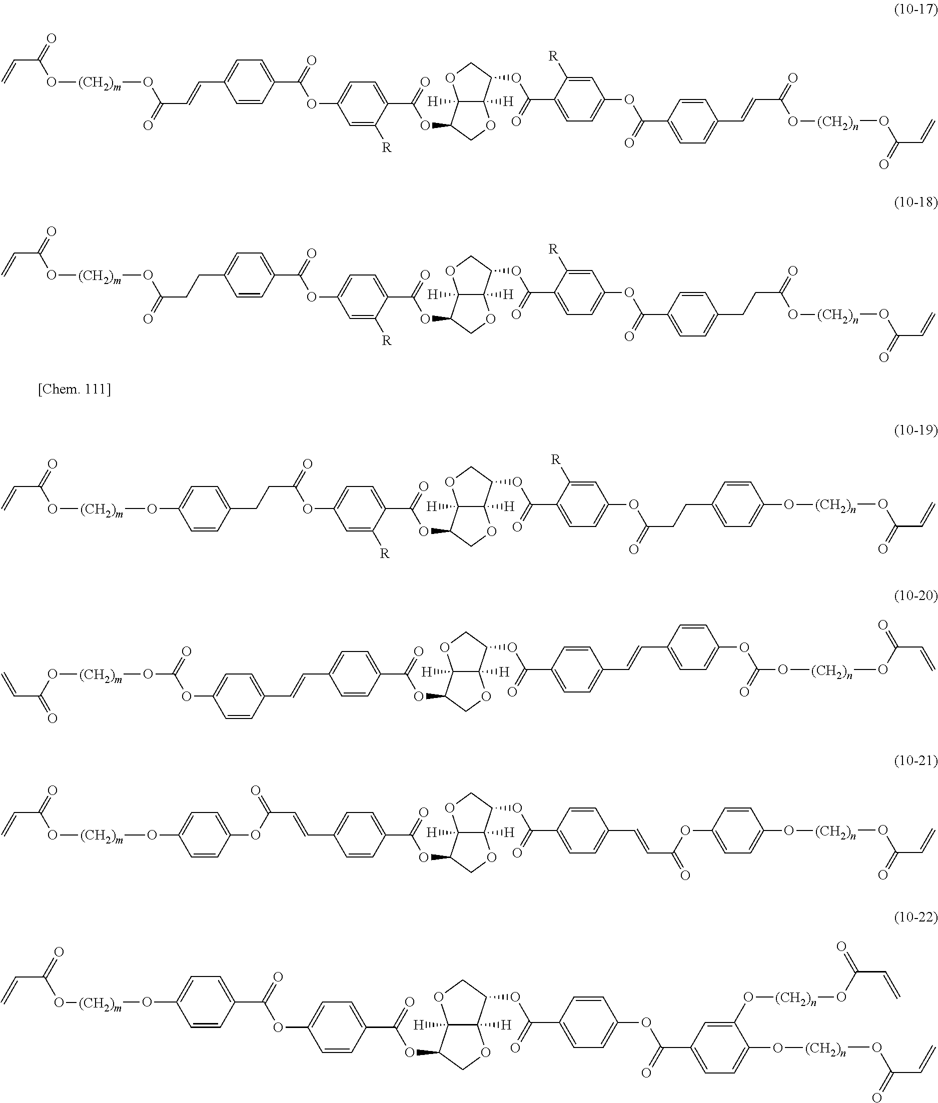

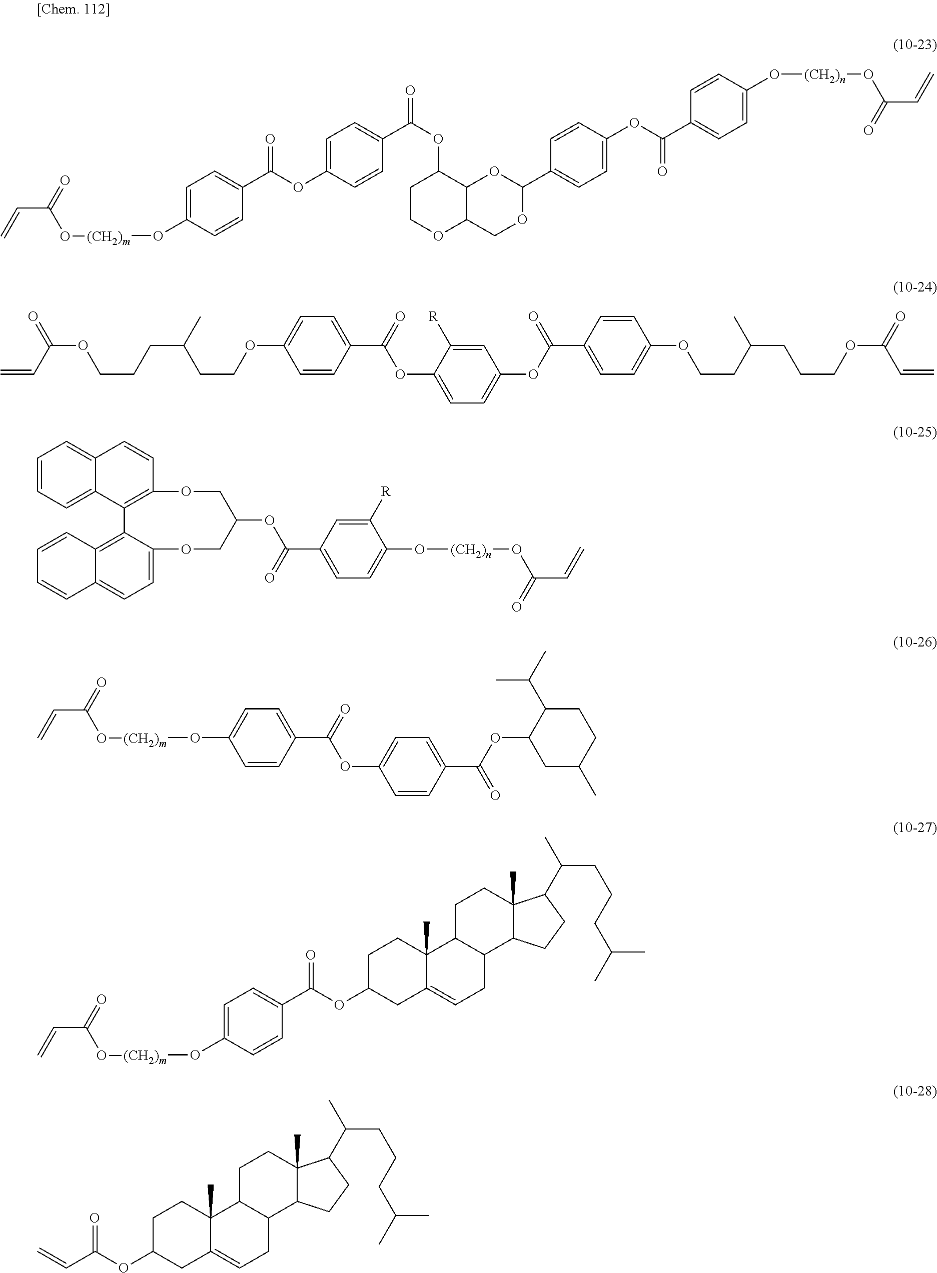

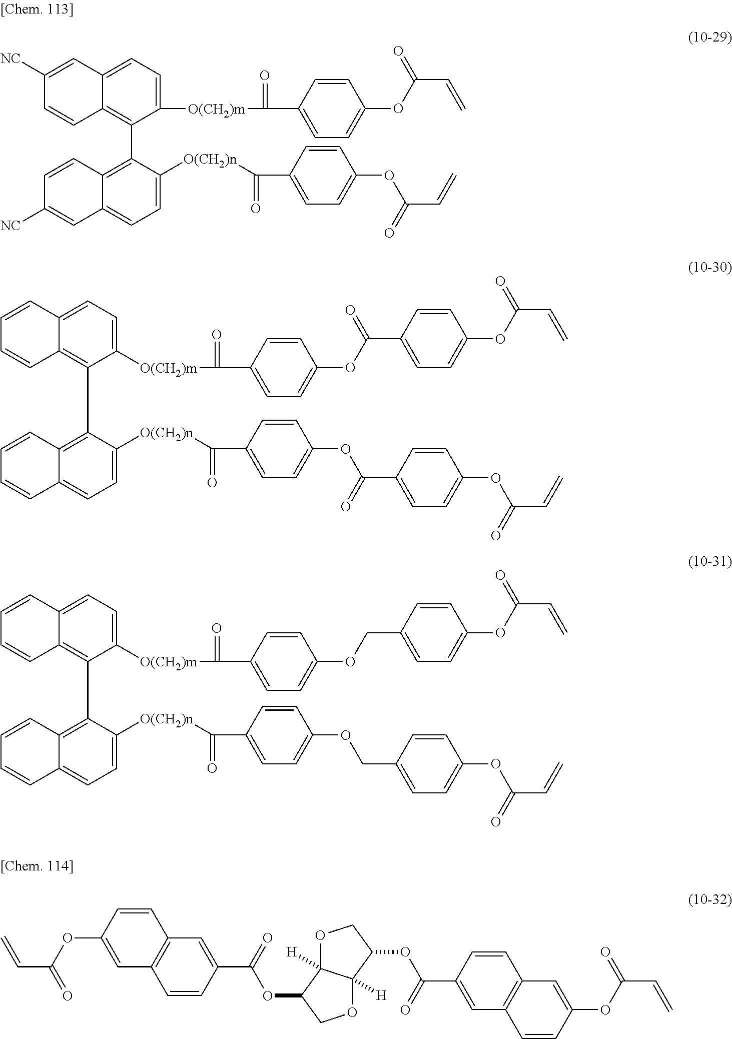

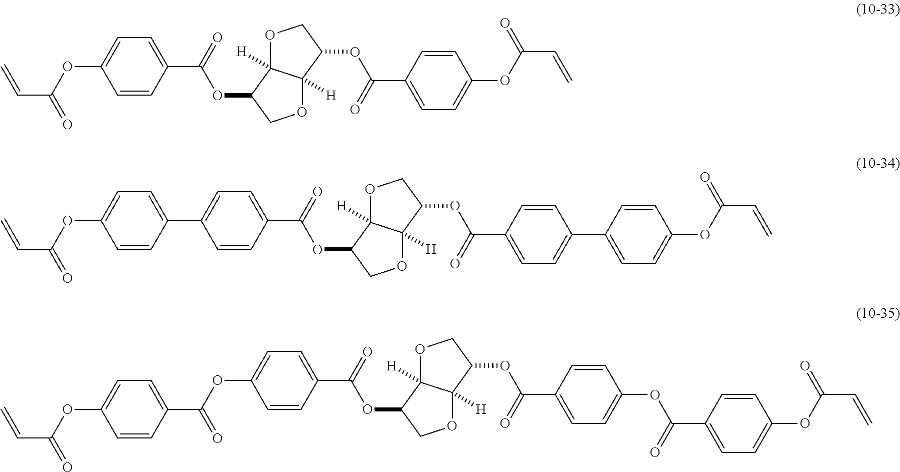

In the formulae, m and n each independently represent an integer of 1 to 10, R represents a hydrogen atom, an alkyl group having 1 to 10 carbon atoms, or a fluorine atom, and in the case where a plurality of R is present, these may be the same as or different from each other.

Specific examples of the chiral compound which does not contain a polymerizable group include cholesterol pelargonate and cholesterol stearate which contain a cholesteryl group as a chiral group; “CB-15”, “C-15” (manufactured by BDH Corporation), “S-1082” (manufactured by Merch Japan), “CM-19”, “CM-20”, and “CM” (manufactured by CHISSO CORPORATION) which contain a 2-methylbutyl group as a chiral group; and “S-811” (manufactured by Merch Japan), “CM-21”, and “CM-22” (manufactured by CHISSO CORPORATION) which contain a 1-methylheptyl group as a chiral group.

In the case where the chiral compound is added, the amount of the chiral compound to be added may vary depending on the applications of the polymer of the polymerizable liquid crystal composition of the present invention, but the amount thereof is determined such that a value (d/P) obtained by dividing a thickness (d) of the polymer to be obtained by a spiral pitch (P) in the polymer is to be preferably 0.1 to 100 and more preferably 0.1 to 20.

(Non-Liquid Crystalline Compound Containing Polymerizable Group)

A compound which is not a liquid crystal compound containing a polymerizable group can be added to the polymerizable composition of the present invention. Such a compound can be used without particular limitation as long as the compound is usually recognized as a polymerizable monomer or a polymerizable oligomer in the technical field. In the case where the compound is added, the content thereof is preferably 15% by mass or less and more preferably 10% by mass or less with respect to the total amount of the polymerizable compound contained in the polymerizable composition.

Specific examples of the compound include mono(meth)acrylate such as methyl (meth)acrylate, ethyl (meth)acrylate, 2-hydroxy ethyl acrylate, propyl (meth)acrylate, 2-hydroxy propyl (meth)acrylate, butyl (meth)acrylate, isobutyl (meth)acrylate, 4-hydroxy butyl (meth)acrylate, 2-hydroxy butyl (meth)acrylate, octyl (meth)acrylate, 2-ethyl hexyl (meth)acrylate, dodecyl (meth)acrylate, stearyl (meth)acrylate, cyclohexyl (meth)acrylate, dicyclopentanyloxyl ethyl (meth)acrylate, isobornyloxyl ethyl (meth)acrylate, isobornyl (meth)acrylate, adamantyl (meth)acrylate, dimethyl adamantly (meth)acrylate, dicyclopentanyl (meth)acrylate, dicyclopentenyl (meth)acrylate, methoxy ethyl (meth)acrylate, ethyl carbitol (meth)acrylate, tetrahydrofurfuryl (meth)acrylate, benzyl (meth)acrylate, phenoxy ethyl (meth)acrylate, 2-phenoxy diethylene glycol (meth)acrylate, 2-hydroxy-3-phenoxy ethyl (meth) acrylate, (2-methyl-2-ethyl-1,3-dioxolan-4-yl) methyl (meth)acrylate, (3-ethyloxetan-3-yl) methyl (meth)acrylate, o-phenyl phenol ethoxy (meth)acrylate, dimethylamino (meth)acrylate, diethylamino (meth)acrylate, 2,2,3,3,3,-pentafluoropropyl (meth)acrylate, 2,2,3,4,4,4-hexafluorobutyl (meth)acrylate, 2,2,3,3,4,4,4-heptafluorobutyl (meth)acrylate, 2-(perfluorobutyl) ethyl (meth)acrylate, 2-(perfluorohexyl) ethyl (meth)acrylate, 1H,1H,3H-tetrafluoropropyl (meth)acrylate, 1H,1H,5H-octafluoropentyl (meth)acrylate, 1H,1H,7H-dodecafluoroheptyl (meth)acrylate, 1H-1-(trifluoromethyl) trifluoroethyl (meth)acrylate, 1H, 1H, 3H-hexafluorobutyl (meth)acrylate, 1,2,2,2-tetrafluoro-1-(trifluoromethyl) ethyl (meth)acrylate, 1H,1H-pentadecafluorooctyl (meth)acrylate, 1H,1H,2H,2H-tridecafluorooctyl (meth)acrylate, 2-(meth)acryloyloxy ethyl phthalic acid, 2-(meth)acryloyloxy ethyl hexahydrophthalic acid, glycidyl (meth)acrylate, 2-(meth)acryloyloxy ethyl phosphoric acid, acryloyl morpholine, dimethyl acrylamide, dimethylamino propyl acrylamide, isopropyl acrylamide, diethyl acrylamide, hydroxy ethyl acrylamide, or N-acryloyloxy ethyl hexahydrophthalimide; diacrylate such as 1,4-butanediol di(meth)acrylate, 1,6-hexanediol di(meth)acrylate, 1,9-nonanediol di(meth)acrylate, neopentyldiol di(meth)acrylate, tripropylene glycol di(meth)acrylate, ethylene glycol di(meth)acrylate, diethylene glycol di(meth)acrylate, triethylene glycol di(meth)acrylate, ethylene oxide-modified bisphenol A di(meth)acrylate, tricyclodecane dimethanol di(meth)acrylate, 9,9-bis[4-(2-acryloyloxyethoxy)phenyl]fluorene, glycerin di(meth)acrylate, 2-hydroxy-3-acryloyloxypropyl methacrylate, an acrylic acid adduct of 1,6-hexanediol diglycidyl ether, or an acrylic acid adduct of 1,4-butanediol diglycidyl ether; tri(meth)acrylate such as trimethylolpropane tri(meth)acrylate, ethoxylated isocyanuric acid triacrylate, pentaerythritol tri(meth)acrylate, or ε-caprolactone-modified tris(2-acryloyloxyethyl) isocyanurate; tetra(meth)acrylate such as pentaerythritol tetra(meth)acrylate or ditrimethylolpropane tetra(meth)acrylate; an ethoxy compound such as dipentaerythritol hexa(meth)acrylate, oligomer type (meth)acrylate, various urethane acrylates, various macromonomers, ethylene glycol diglycidyl ether, diethylene glycol diglycidyl ether, propylene glycol diglycidyl ether, neopentyl glycol diglycidyl ether, 1,6-hexanediol diglycidyl ether, glycerin diglycidyl ether, or bisphenol A diglycidyl ether; and maleimide. These may be used alone or in combination of two or more kinds thereof.

(Other Liquid Crystalline Compounds)

The polymerizable composition used in the present invention may contain a liquid crystalline compound having one or more polymerizable groups in addition to the liquid crystalline compounds of General Formulae (1) to (7). However, if the add amount is too much, the phase difference ratio of a retardation plate obtained using the polymerizable composition may increase, and thus the add amount is preferably 30 mass % or less with respect to the total amount of the polymerizable compounds in the polymerizable composition of the present invention, more preferably 10 mass % or less, and particularly preferably 5 mass % or less.

Examples of such liquid crystalline compounds include liquid crystalline compounds of General Formula (1-b) to General Formula (7-b).

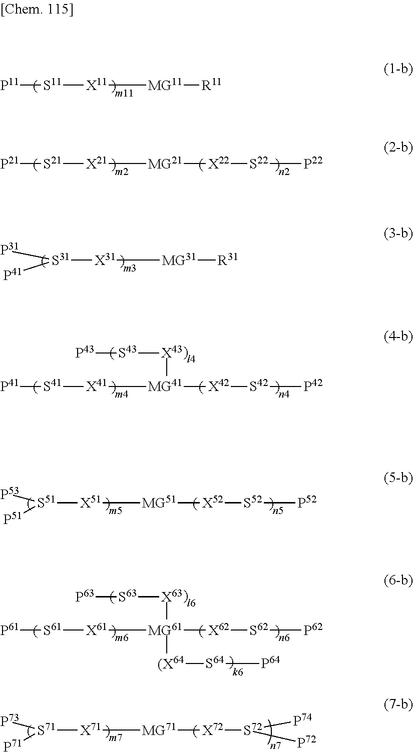

(In the formula, P¹¹ to P⁷⁴ represent a polymerizable group, S¹¹ to S⁷² represent a spacer group or a single bond, and in the case where plural groups are present with respect to each of S¹ to S⁷², these may be the same as or different from each other;

X¹¹ to X⁷² represent —O—, —S—, —OCH₂—, —CH₂O—, —CO—, —COO—, —OCO—, —CO—S—, —S—CO—, —O—CO—O—, —CO—NH—, —NH—CO—, —SCH₂—, —CH₂S—, —CF₂O—, —OCF₂—, —CF₂S—, —SCF₂—, —CH═CH—COO—, —CH═CH—OCO—, —COO—CH═CH—, —OCO—CH═CH—, —COO—CH₂CH₂—, —OCO—CH₂CH₂—, —CH₂CH₂—COO—, —CH₂CH₂—OCO—, —COO—CH₂—, —OCO—CH₂—, —CH₂—COO—, —CH₂—OCO—, —CH═CH—, —N═N—, —CH═N—N═CH—, —CF═CF—, —C≡C—, or a single bond, and in the case where a plurality of X¹¹'s to X⁷²'s are present, these may be the same as or different from each other, provided that each of P—(S—X)— bonds does not have —O—O—;

MG¹¹ to MG⁷¹ each independently represent formula (b):

[Chem. 116]

A⁸³-Z⁸³ⱼ₈₃M⁸¹Z⁸⁴-A⁸⁴ⱼ₈₄ (b)

(In the formula, A⁸³ and A⁸⁴ each independently represent a 1,4-phenylene group, a 1,4-cyclohexylene group, a pyridine-2,5-diyl group, a pyrimidine-2,5-diyl group, a naphthalene-2,6-diyl group, a naphthalene-1,4-diyl group, a tetrahydronaphthalene-2,6-diyl group, a decahydronaphthalene-2,6-diyl group, or a 1,3-dioxane-2,5-diyl group, these groups may be unsubstituted or substituted with one or more L²'s, and in the case where plural groups are present with respect to each of A⁸³ and A⁸⁴, these may be the same as or different from each other;

Z⁸³ and Z⁸⁴ each independently represent —O—, —S—, —OCH₂—, —CH₂O—, —CH₂CH₂—, —CO—, —COO—, —OCO—, —CO—S—, —S—CO—, —O—CO—O—, —CO—NH—, —NH—CO—, —SCH₂—, —CH₂S—, —CF₂O—, —OCF₂—, —CF₂S—, —SCF₂—, —CH═CH—COO—, —CH═CH—OCO—, —COO—CH═CH—, —OCO—CH═CH—, —COO—CH₂CH₂—, —OCO—CH₂CH₂—, —CH₂CH₂—COO—, —CH₂CH₂—OCO—, —COO—CH₂—, —OCO—CH₂—, —CH₂—COO—, —CH₂—OCO—, —CH═CH—, —N═N—, —CH═N—, —N═CH—, —CH═N—N═CH—, —CF═CF—, —C≡C—, or a single bond, and in the case where plural groups are present with respect to each of Z⁸³ and Z⁸⁴, these may be the same as or different from each other;

M⁸¹ represents a group selected from a 1,4-phenylene group, a 1,4-cyclohexylene group, a 1,4-cyclohexenyl group, a tetrahydropyran-2,5-diyl group, a 1,3-dioxane-2,5-diyl group, a tetrahydrothiopyran-2,5-diyl group, a 1,4-bicyclo(2,2,2)octylene group, a decahydronaphthalene-2,6-diyl group, a pyridine-2,5-diyl group, a pyrimidine-2,5-diyl group, a pyrazine-2,5-diyl group, a thiophene-2,5-diyl group, a 1,2,3,4-tetrahydronaphthalene-2,6-diyl group, a naphthylene-1,4-diyl group, a naphthylene-1,5-diyl group, a naphthylene-1,6-diyl group, a naphthylene-2,6-diyl group, a phenanthrene-2,7-diyl group, a 9,10-dihydrophenanthrene-2,7-diyl group, a 1,2,3,4,4a, 9,10a-octahydrophenanthrene-2,7-diyl group, a benzo[1,2-b:4,5-b′ ]dithiophene-2,6-diyl group, a benzo[1,2-b:4,5-b′]diselenophene-2,6-diyl group, a [1]benzothieno[3,2-b]thiophene-2,7-diyl group, a [1]benzoselenopheno[3,2-b]selenophene-2,7-diyl group, and a fluorene-2,7-diyl group, and these groups may be unsubstituted or substituted with one or more L²'s;

L² represents a fluorine atom, a chlorine atom, a bromine atom, an iodine atom, a pentafluorosulfuranyl group, a nitro group, an isocyano group, an amino group, a hydroxy group, a mercapto group, a methylamino group, a dimethylamino group, a diethylamino group, a diisopropylamino group, a trimethylsilyl group, a dimethylsilyl group, a thioisocyano group, or a linear or branched alkyl group having 1 to 20 carbon atoms in which one —CH₂— or two or more (—CH₂—)'s which are not adjacent to each other may be each independently substituted with —O—, —S—, —CO—, —COO—, —OCO—, —CO—S—, —S—CO—, —O—CO—O—, —CO—NH—, —NH—CO—, —CH═CH—COO—, —CH═CH—OCO—, —COO—CH═CH—, —OCO—CH═CH—, —CH═CH—, —CF═CF—, or —C≡C—, and one or more of arbitrary hydrogen atoms may be substituted with a fluorine atom, and in the case where a plurality of L²'s are present in the compound, these may be the same as or different from each other; m represents an integer of 0 to 8; j83 and j84 each independently represent an integer of 0 to 5; and j83+j84 represents an integer of 1 to 5.);

R¹¹ and R³¹ represent a hydrogen atom, a fluorine atom, a chlorine atom, a bromine atom, an iodine atom, a pentafluorosulfuranyl group, a cyano group, a nitro group, an isocyano group, a thioisocyano group, or an alkyl group having 1 to 20 carbon atoms, the alkyl group may be linear or branched, one or more of arbitrary hydrogen atoms in the alkyl group may be substituted with a fluorine atom, and one —CH₂— or two or more (—CH₂—)'s which are not adjacent to each other in the alkyl group may be each independently substituted with —O—, —S—, —CO—, —COO—, —OCO—, —CO—S—, —S—CO—, —O—CO—O—, —CO—NH—, —NH—CO—, or —C≡C—; m11 represents an integer of 0 to 8; and m2 to m7, n2 to n7, 14 to 16, and k6 each independently represent an integer of 0 to 5, provided that compounds represented by General Formula (1) to General Formula (7) are excluded).

Preferred specific examples of the compound represented by General Formula (1-b) include compounds represented by Formula (1-b-1) to Formula (1-b-39).

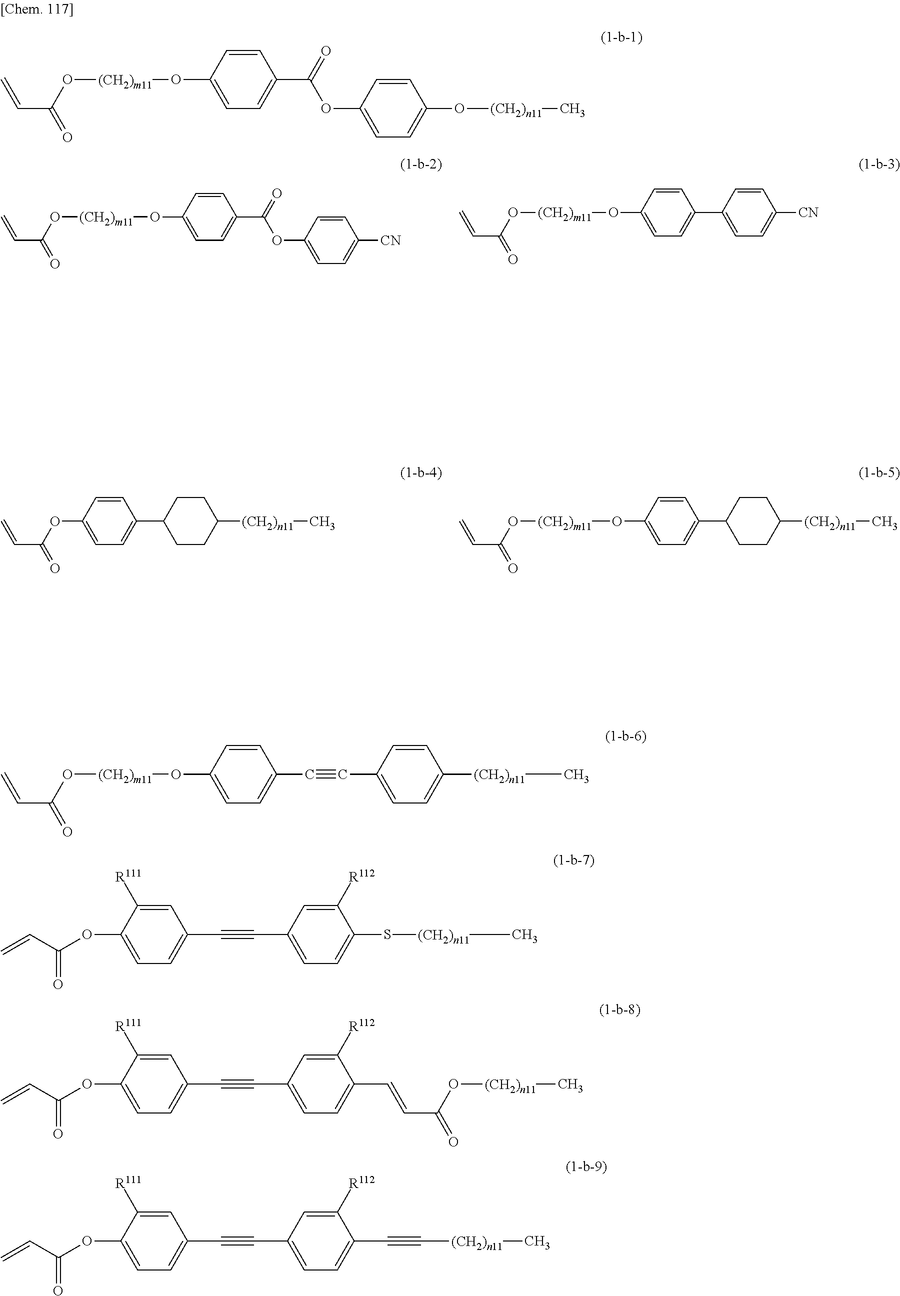

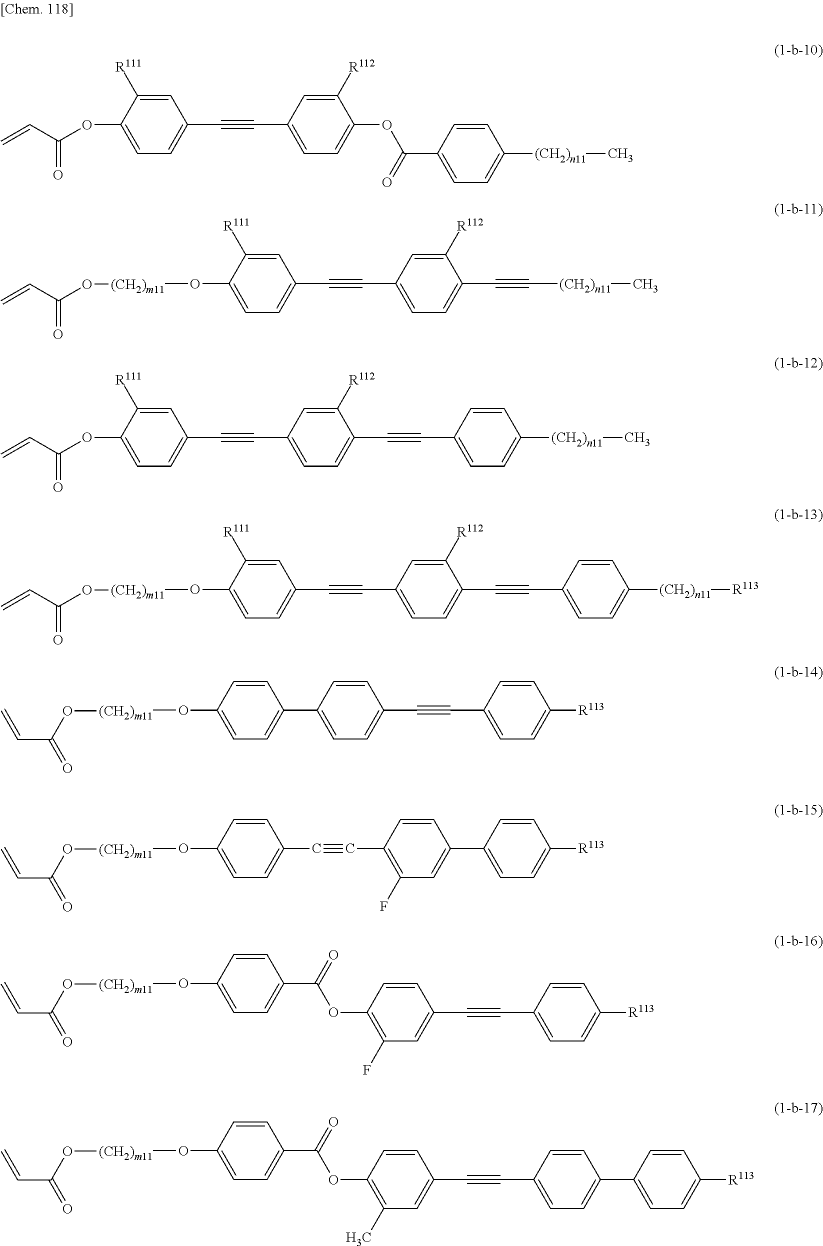

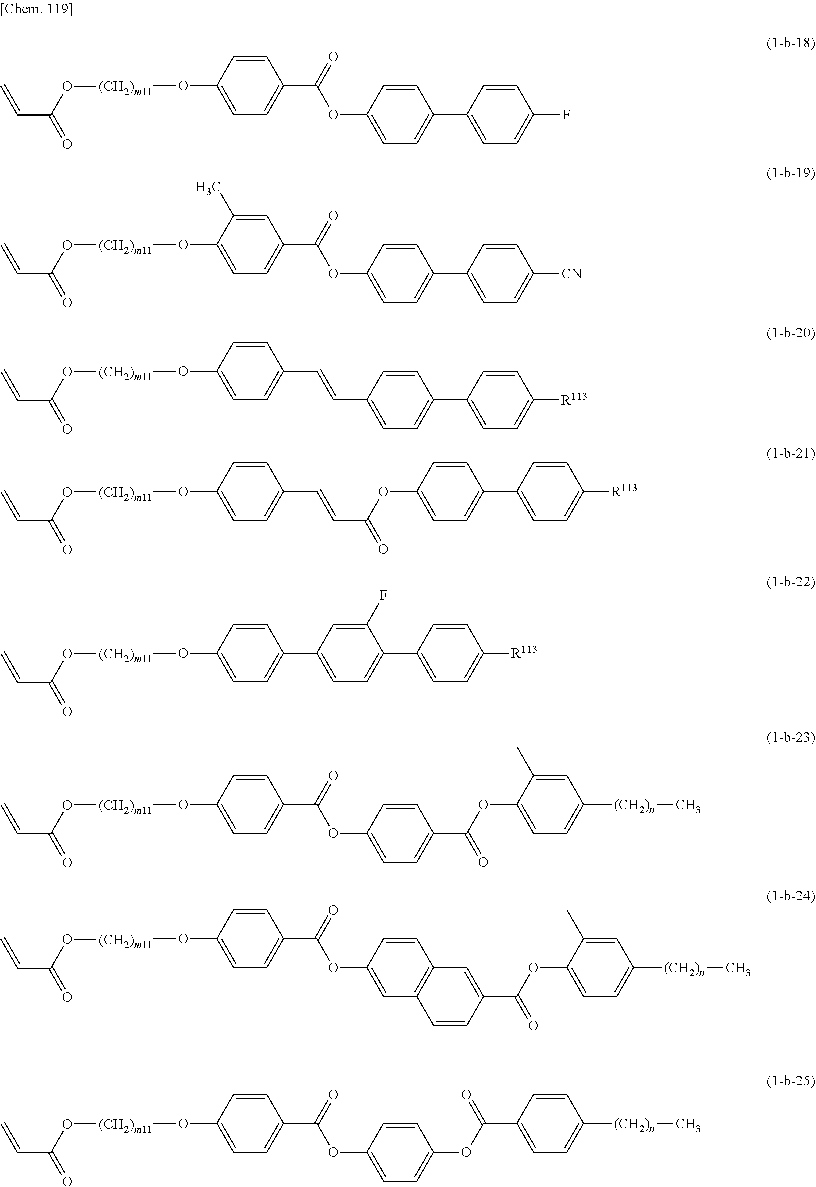

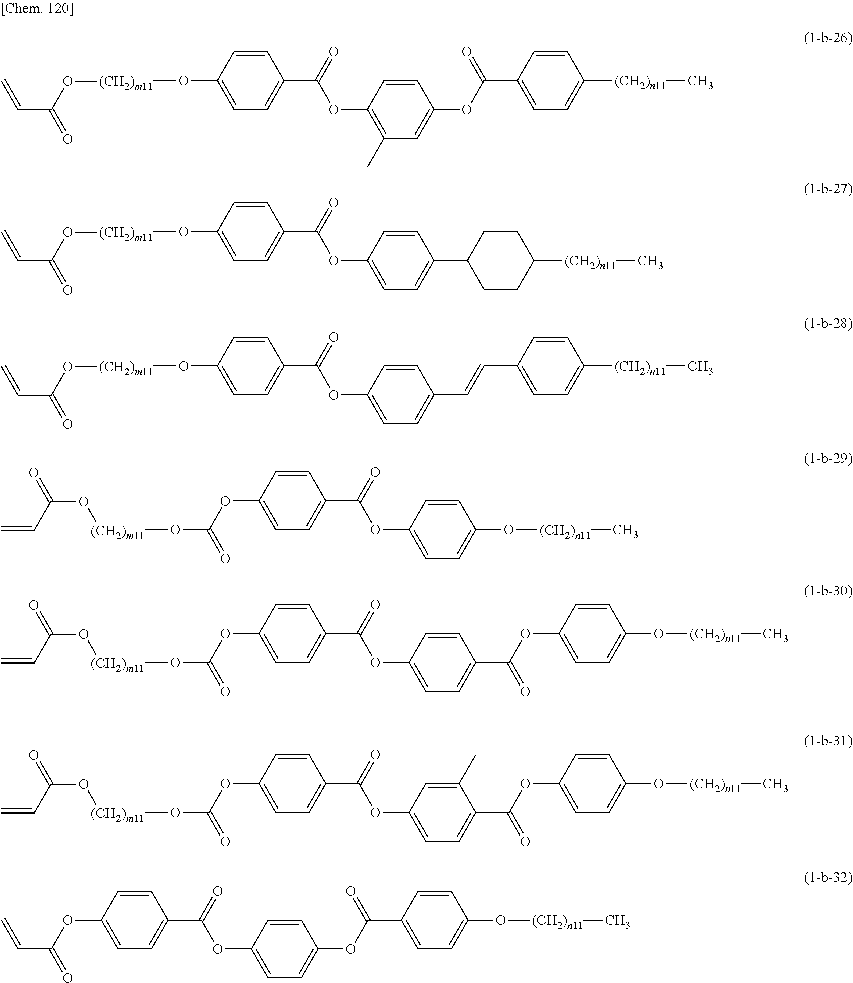

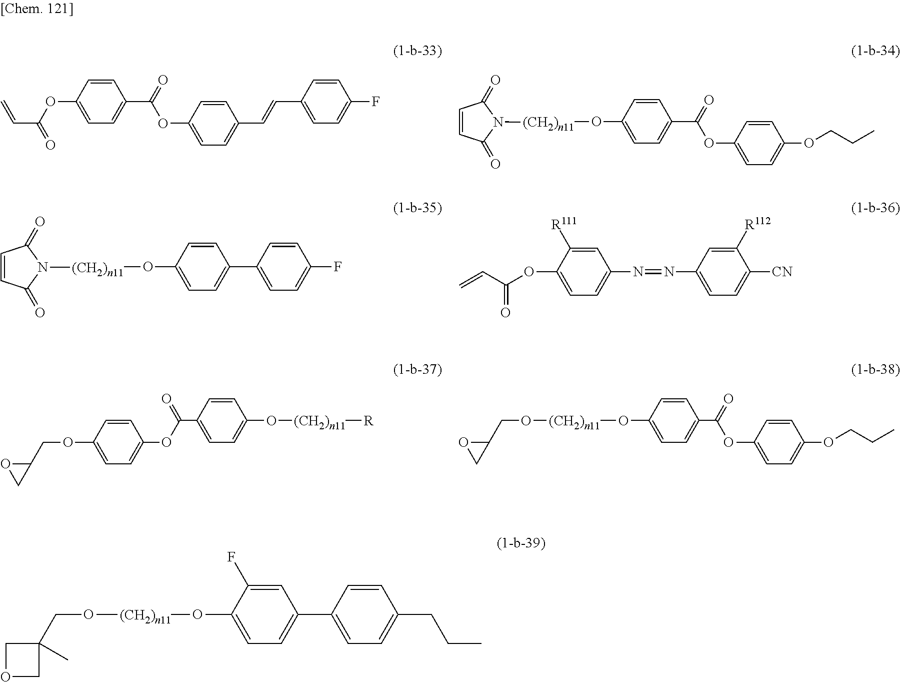

(In the formulae, m11 and n11 each independently represent an integer of 1 to 10, R¹¹¹ and R¹¹² each independently represent a hydrogen atom, an alkyl group having 1 to 10 carbon atoms, or a fluorine atom, R¹³ represents a hydrogen atom, a fluorine atom, a chlorine atom, a bromine atom, an iodine atom, a pentafluorosulfuranyl group, a cyano group, a nitro group, an isocyano group, a thioisocyano group, or a linear or branched alkyl group having 1 to 20 carbon atoms in which one —CH₂— or two or more (—CH₂—)'s which are not adjacent to each other may be each independently substituted with —O—, —S—, —CO—, —COO—, —OCO—, —CO—S—, —S—CO—, —O—CO—O—, —CO—NH—, —NH—CO—, or —C≡C—, and one or more of arbitrary hydrogen atoms in the alkyl group may be substituted with a fluorine atom.) These liquid crystalline compounds may be used singly or two or more thereof may be mixed to be used.

Preferred specific examples of the compound represented by General Formula (2-b) include compounds represented by Formula (2-b-1) to Formula (2-b-33).

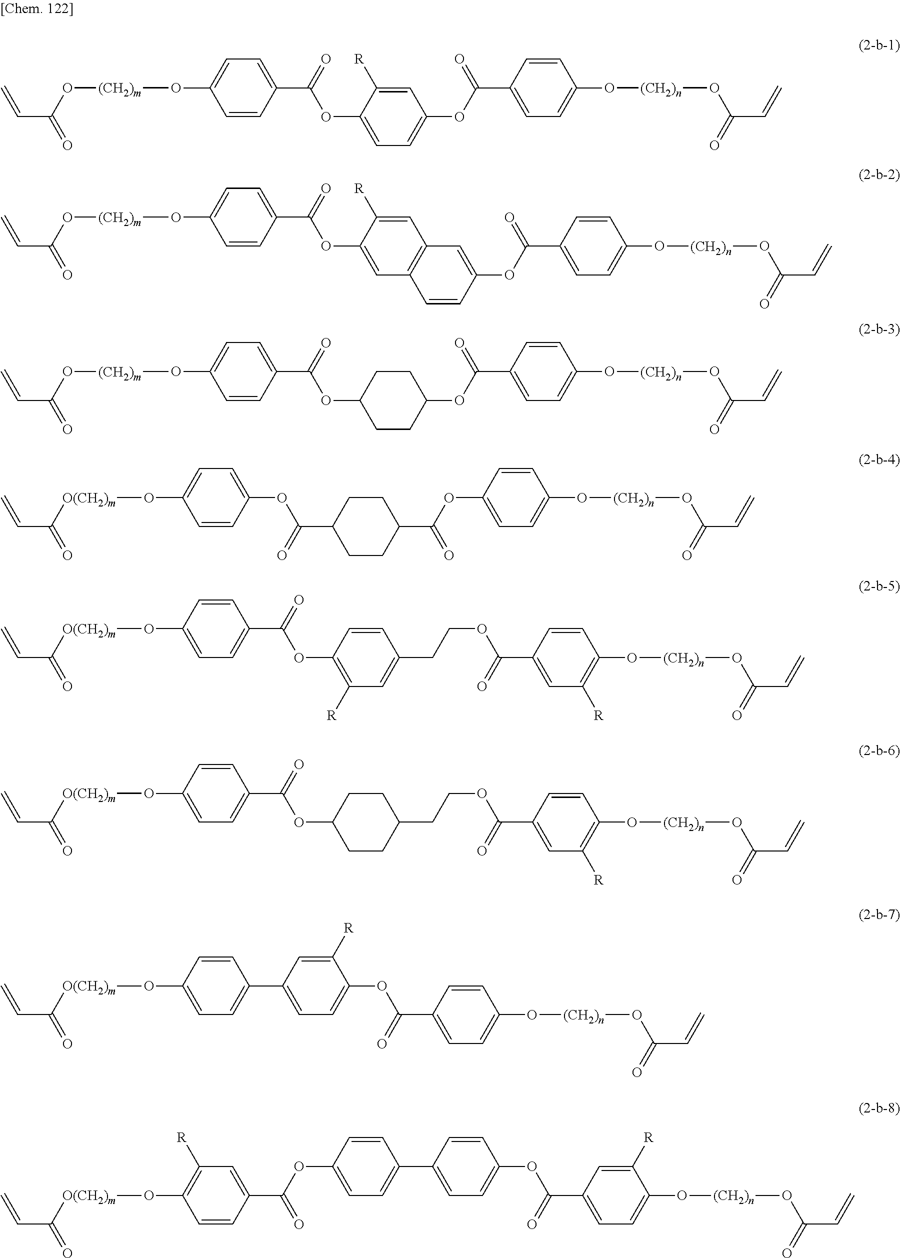

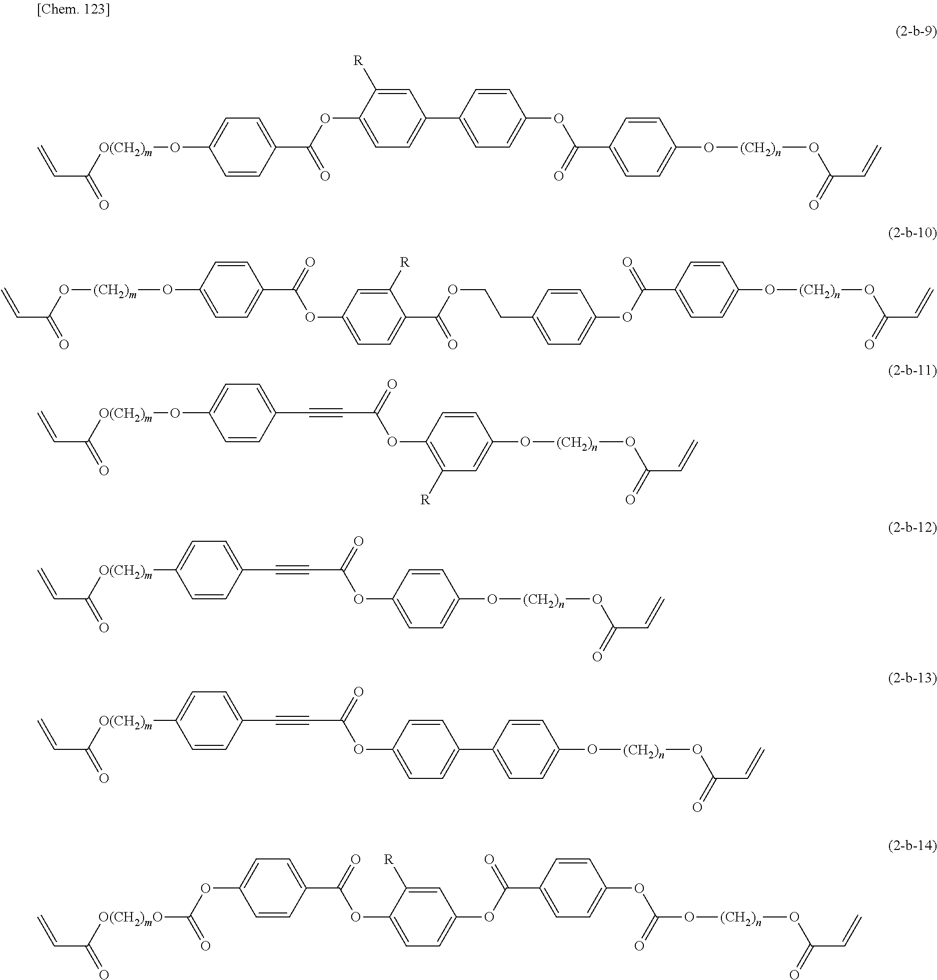

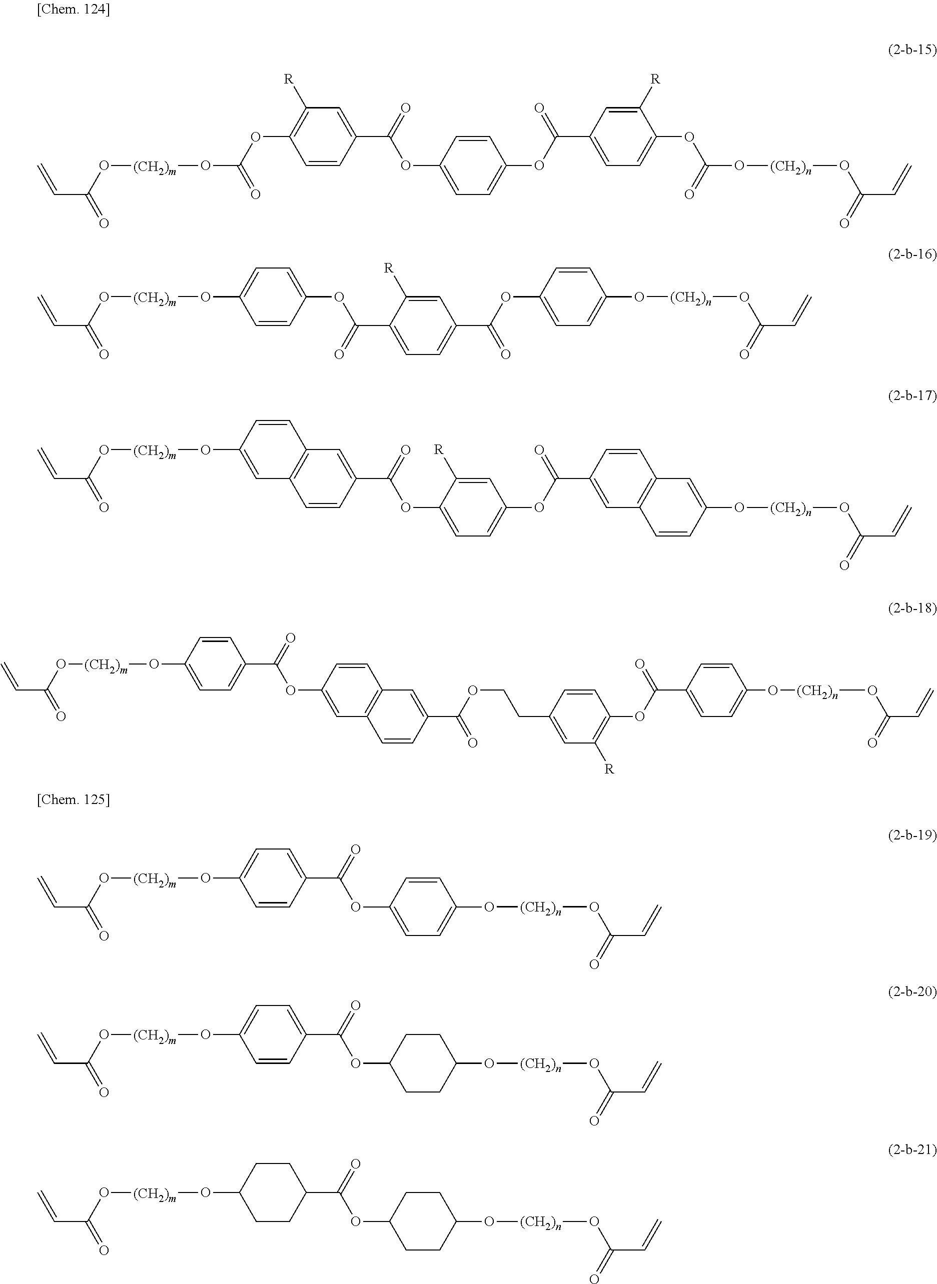

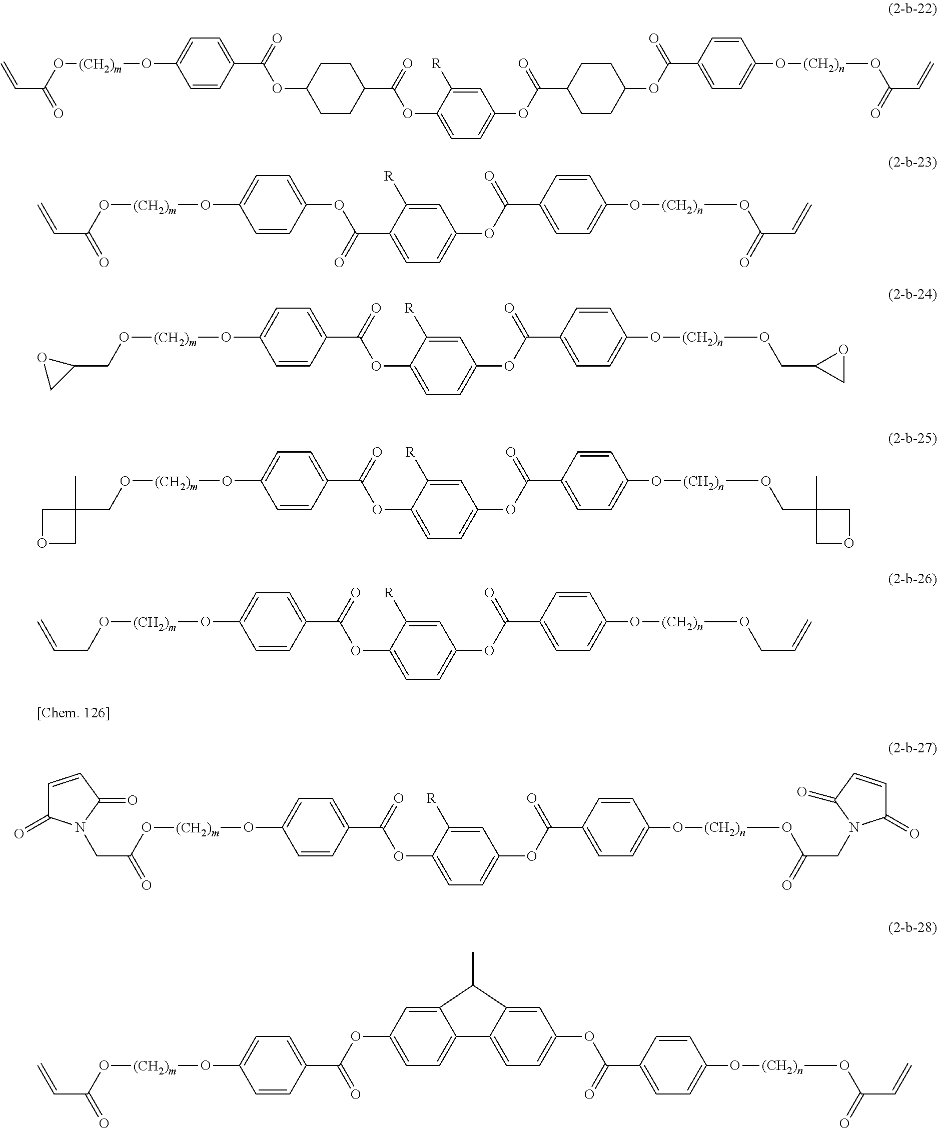

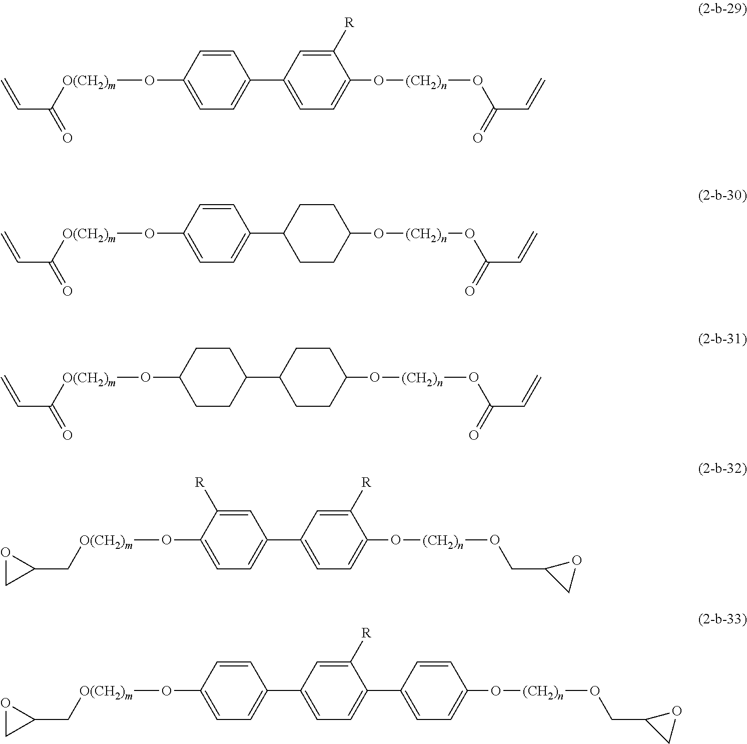

(In the formulae, m and n each independently represent an integer of 1 to 18, and R represents a hydrogen atom, a halogen atom, an alkyl group having 1 to 6 carbon atoms, an alkoxy group having 1 to 6 carbon atoms, or a cyano group. In the case where these groups represent an alkyl group having 1 to 6 carbon atoms or an alkoxy group having 1 to 6 carbon atoms, all groups may be unsubstituted or substituted with one or two or more halogen atoms.) These liquid crystalline compounds may be used singly or two or more thereof may be mixed to be used.

Preferred specific examples of the compound represented by General Formula (3-b) include compounds represented by Formula (3-b-1) to Formula (3-b-16).

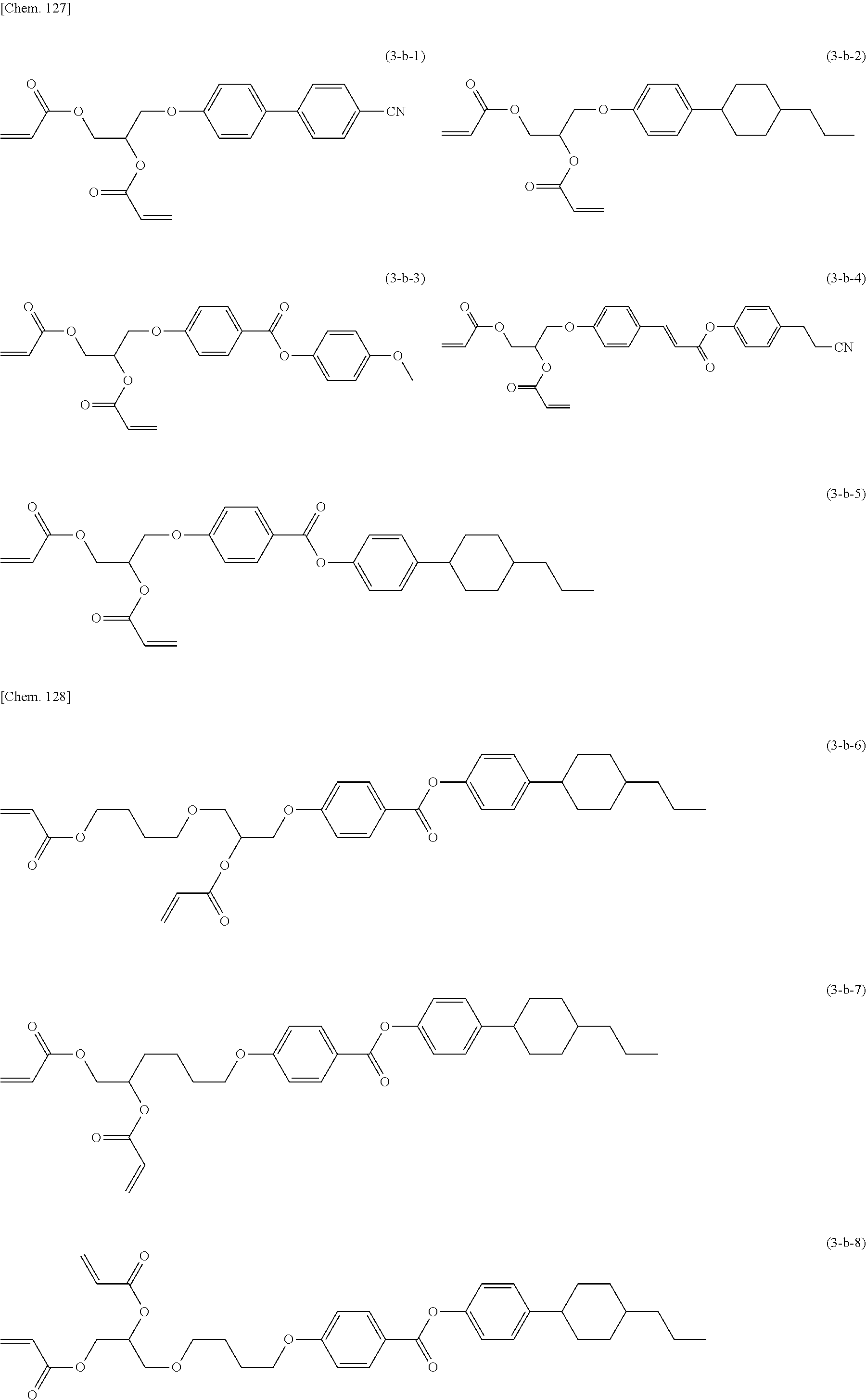

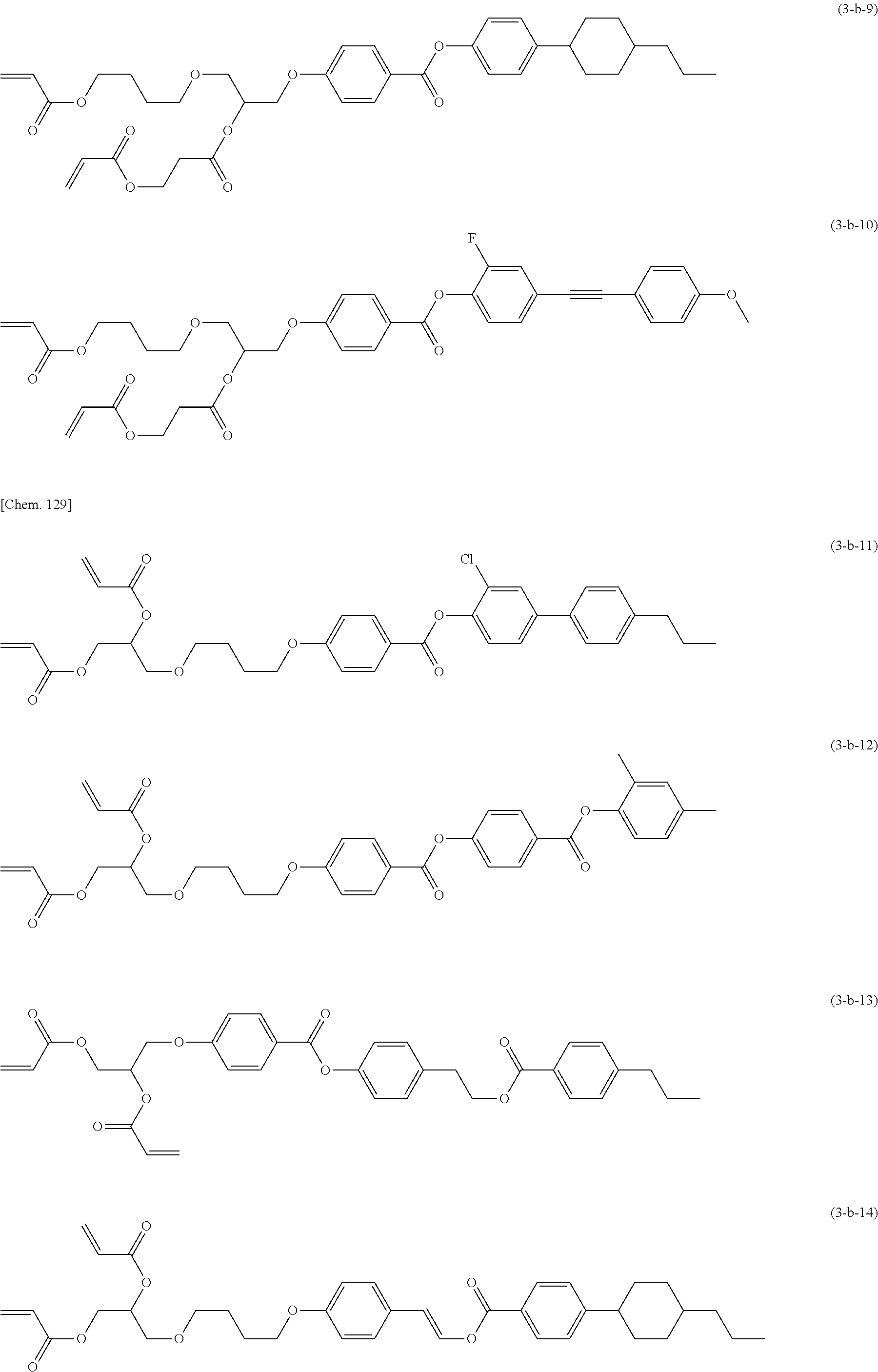

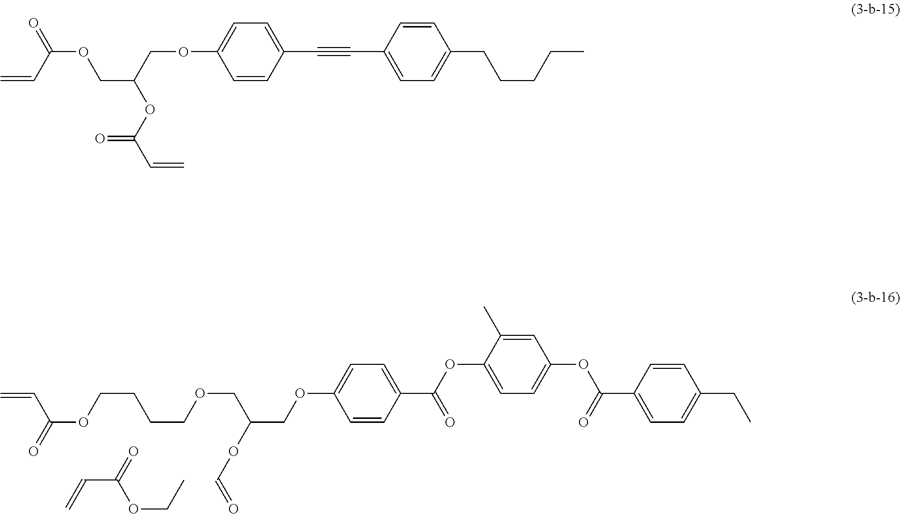

These liquid crystalline compounds may be used singly or two or more thereof may be mixed to be used.

Preferred specific examples of the compound represented by General Formula (4-b) include compounds represented by Formula (4-b-1) to Formula (4-b-29).

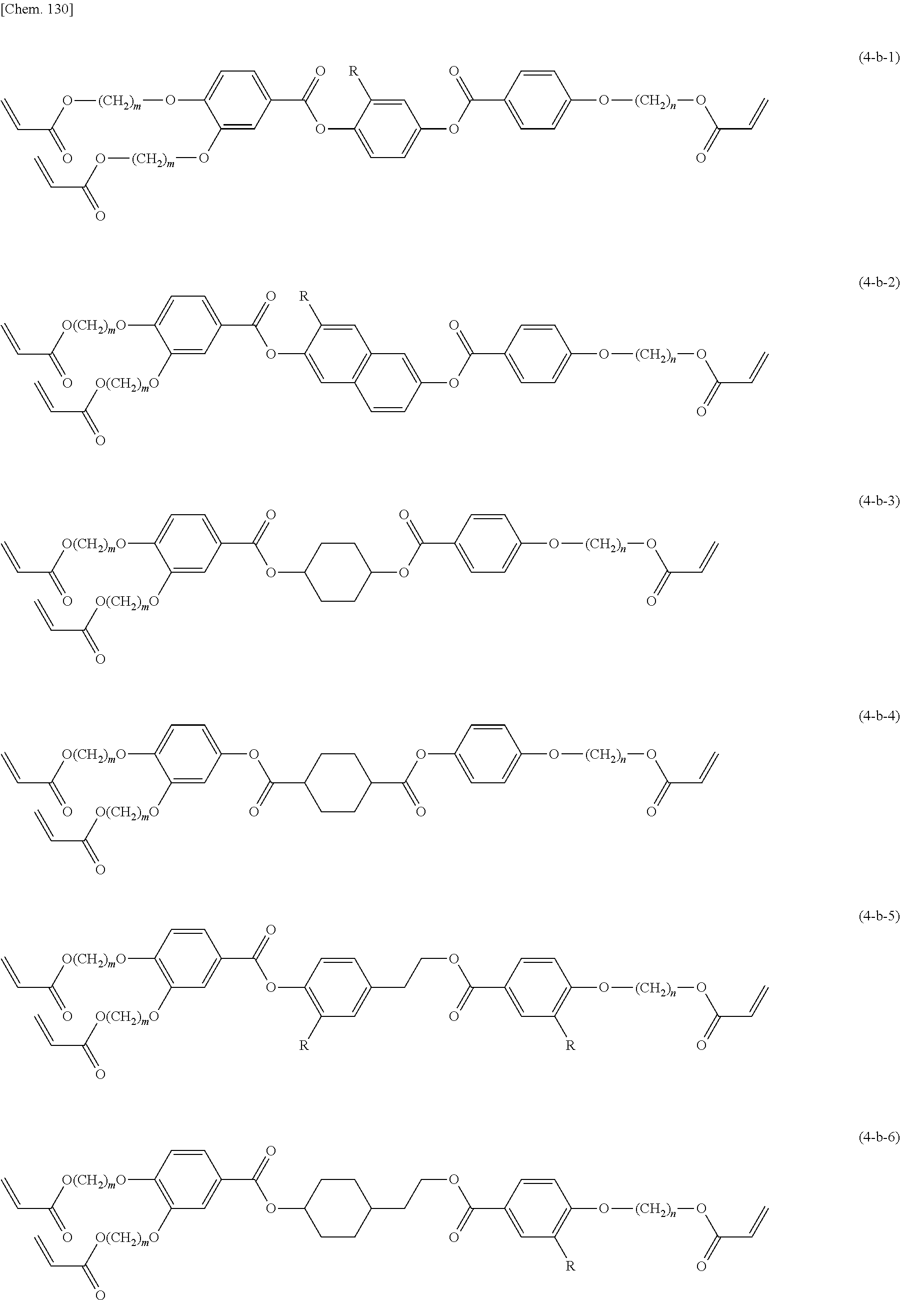

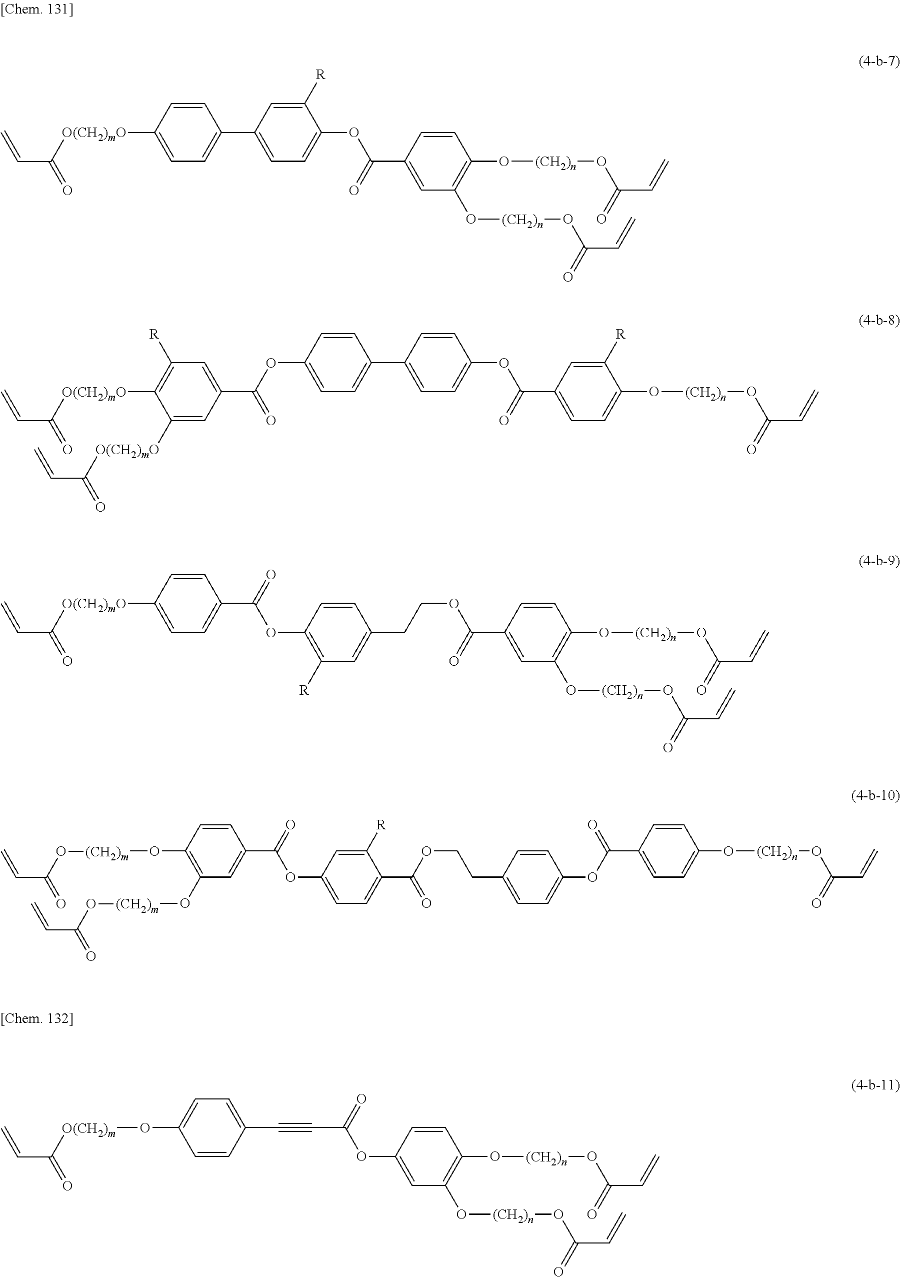

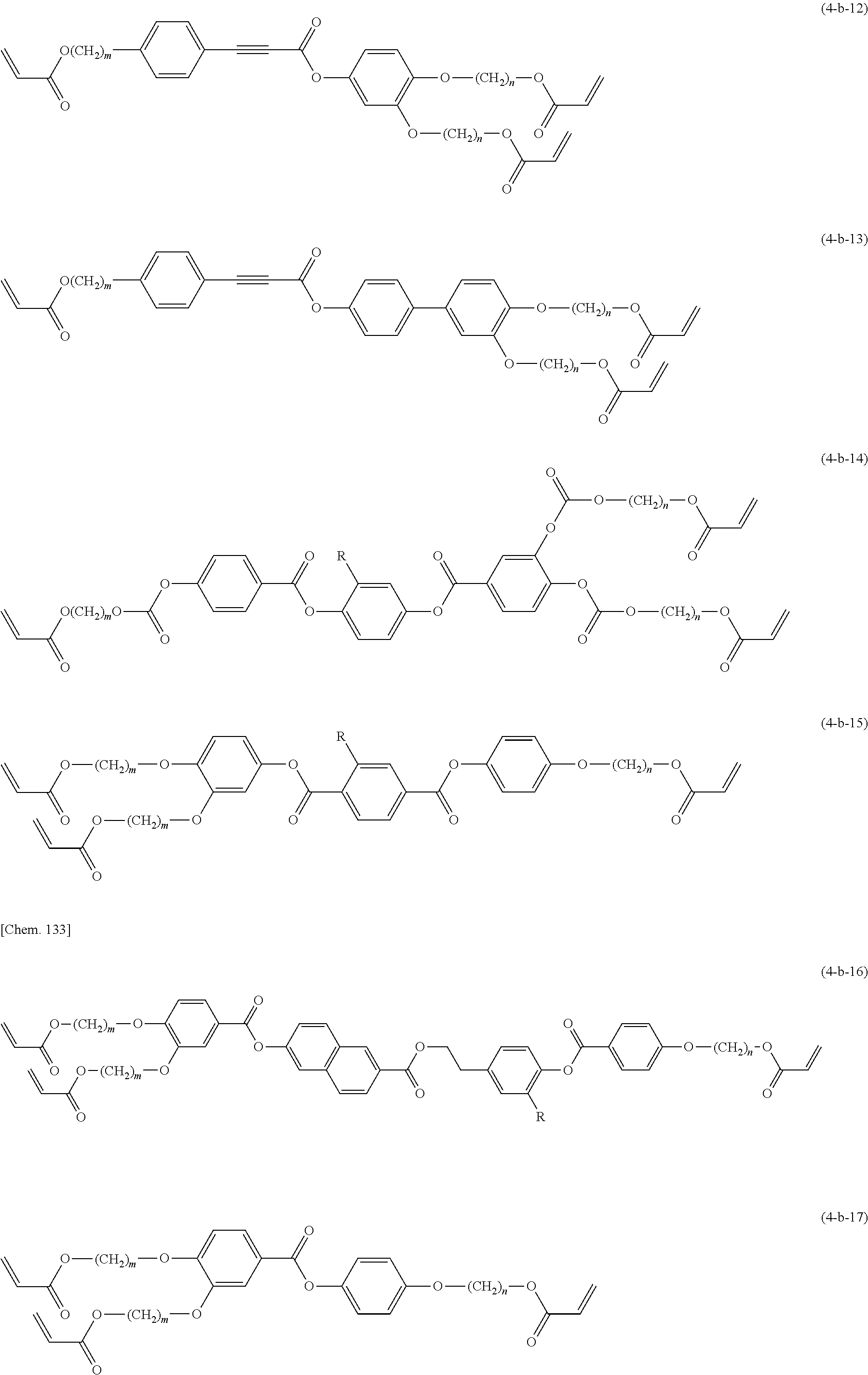

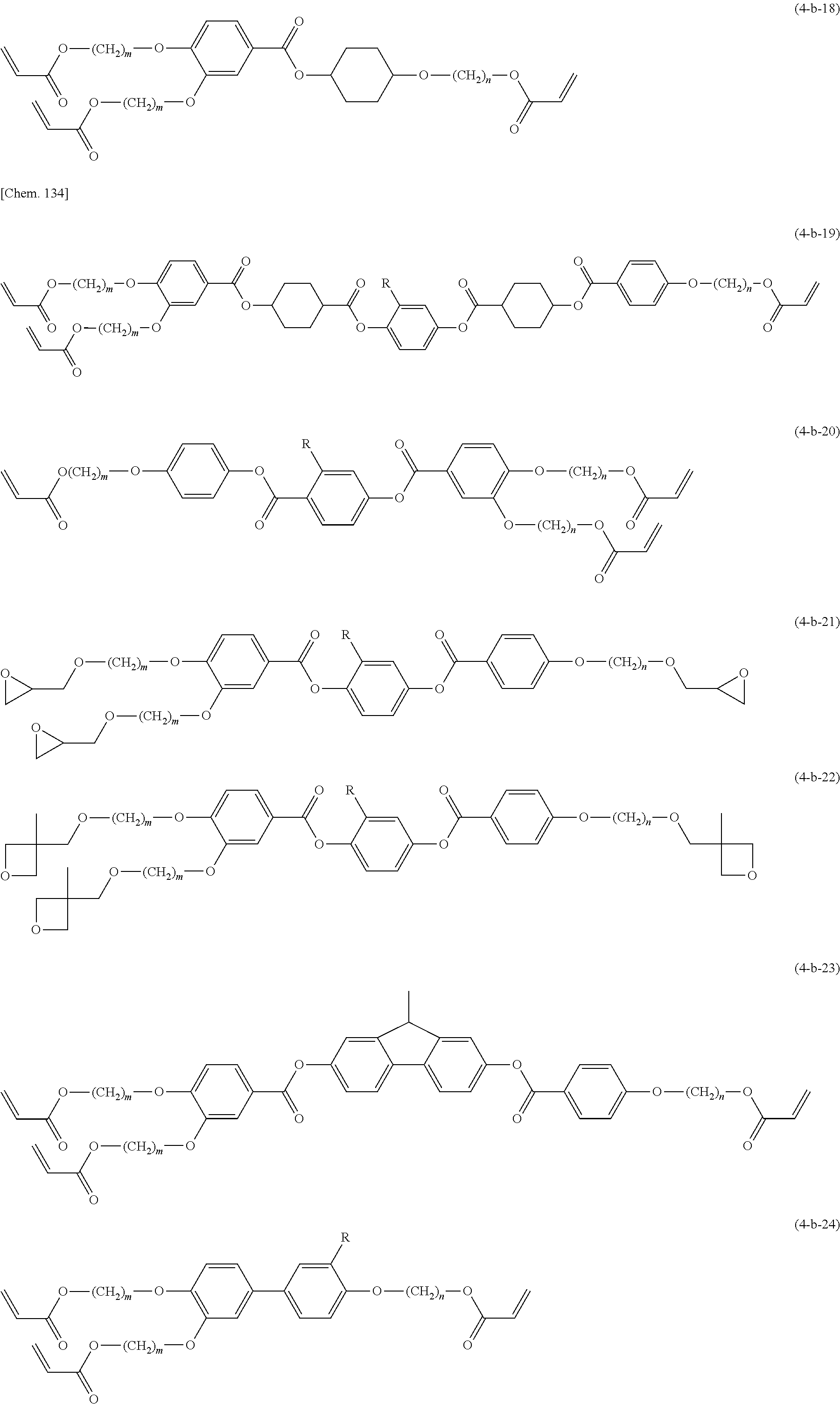

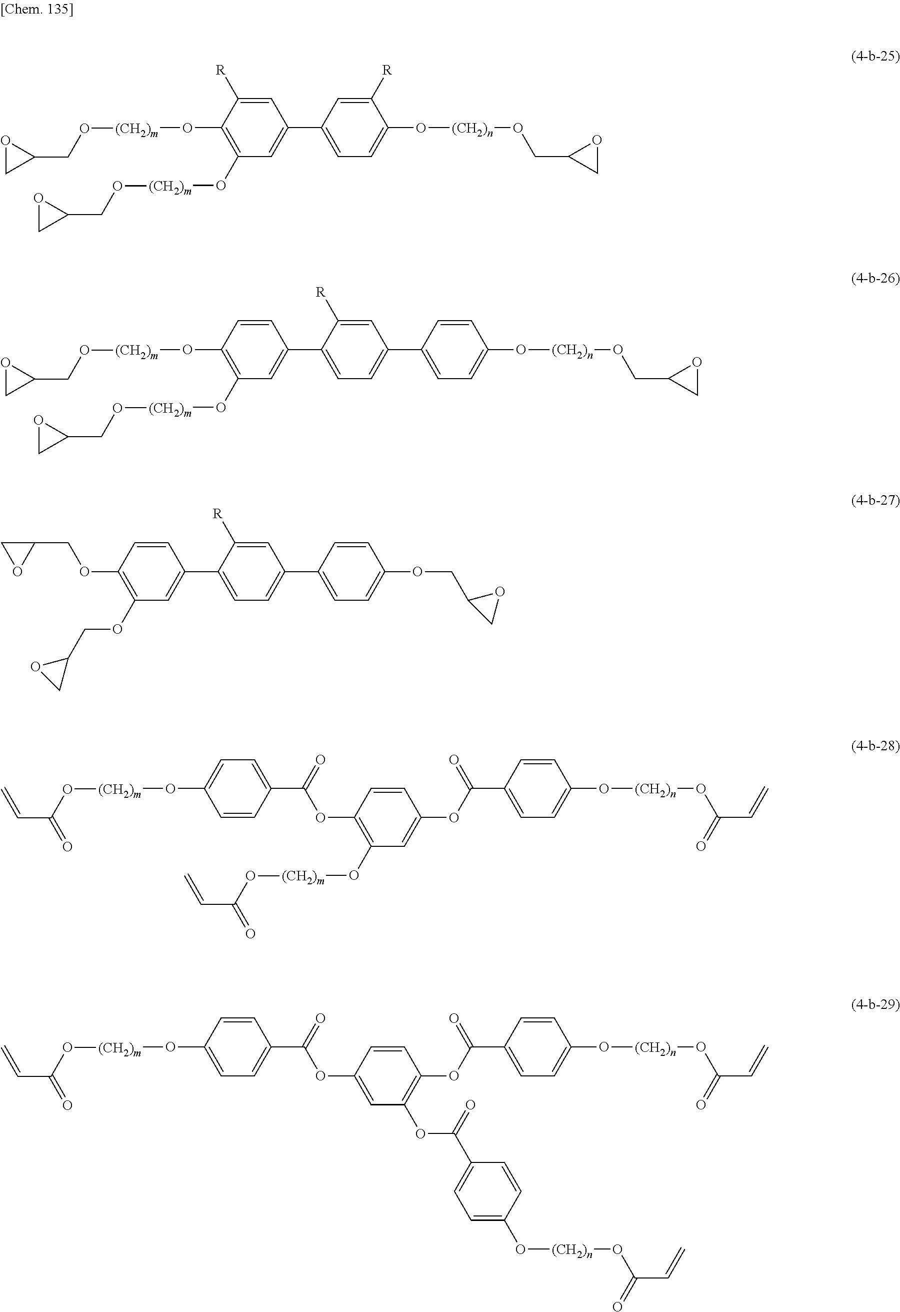

(In the formulae, m and n each independently represent an integer of 1 to 10, and R represents a hydrogen atom, a halogen atom, an alkyl group having 1 to 6 carbon atoms, an alkoxy group having 1 to 6 carbon atoms, or a cyano group. In the case where these groups represent an alkyl group having 1 to 6 carbon atoms or an alkoxy group having 1 to 6 carbon atoms, all groups may be unsubstituted or substituted with one or two or more halogen atoms.) These liquid crystalline compounds may be used singly or two or more thereof may be mixed to be used.

Preferred specific examples of the compound represented by General Formula (5-b) include compounds represented by Formula (5-b-1) to Formula (5-b-26).

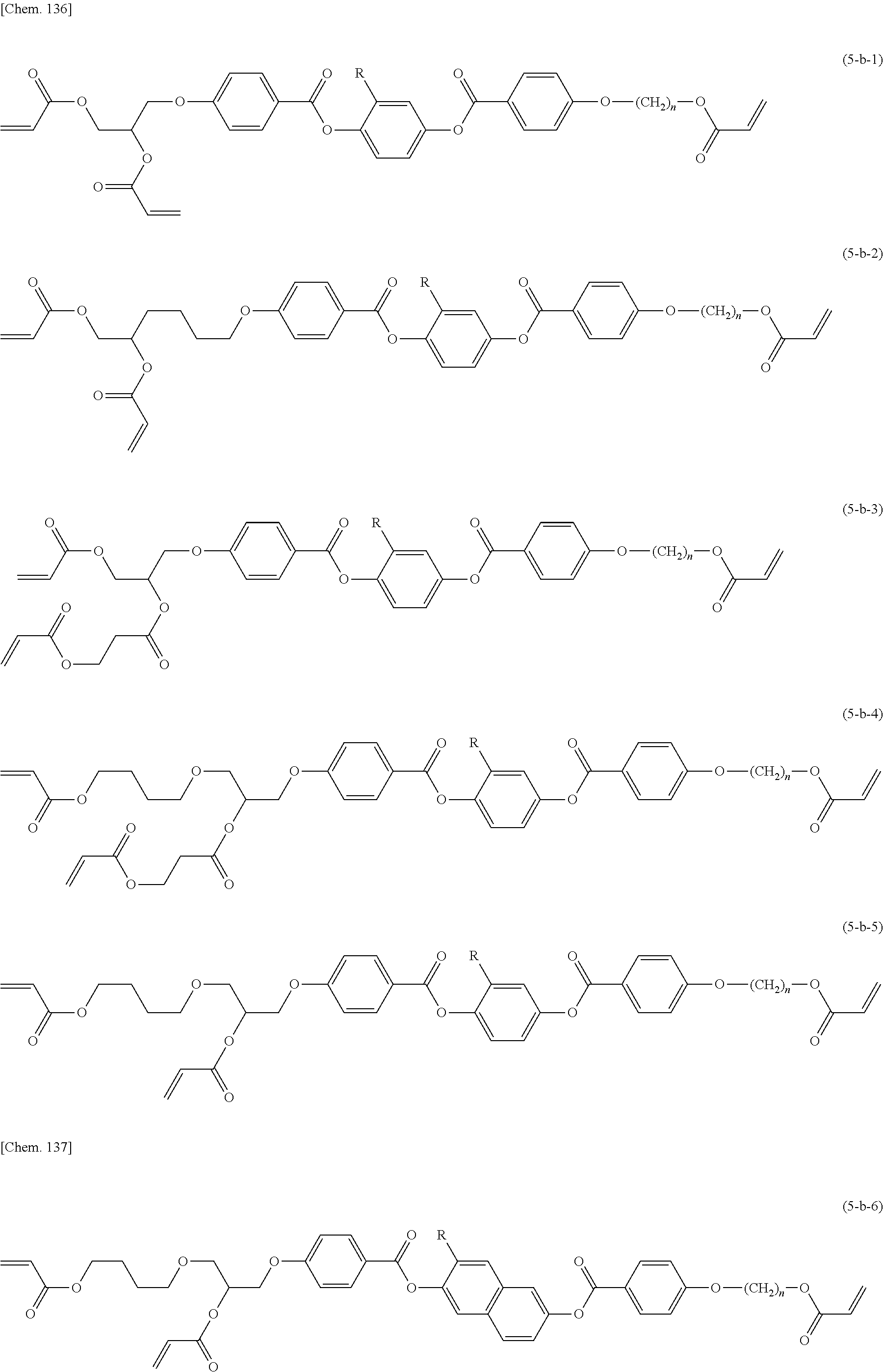

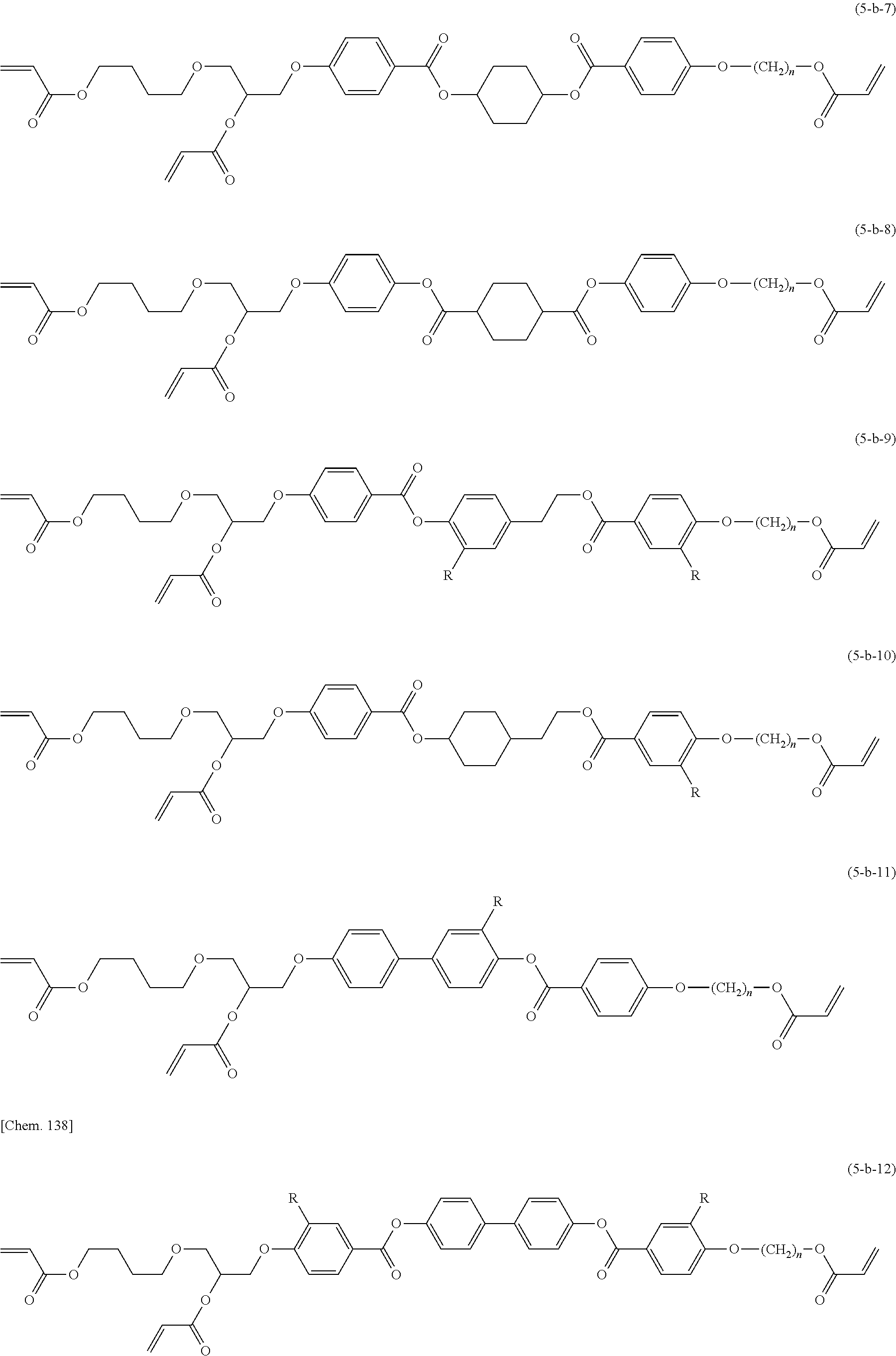

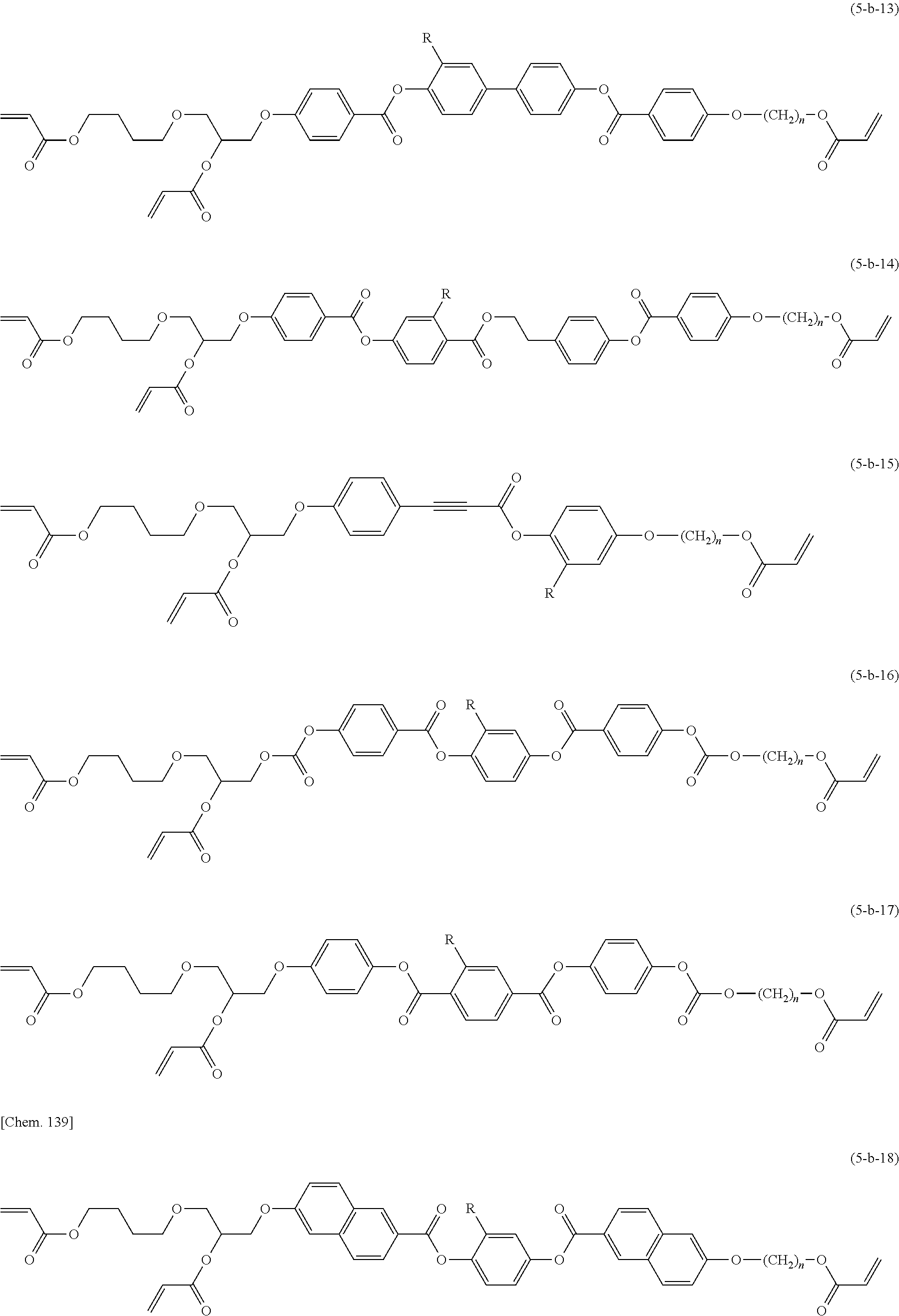

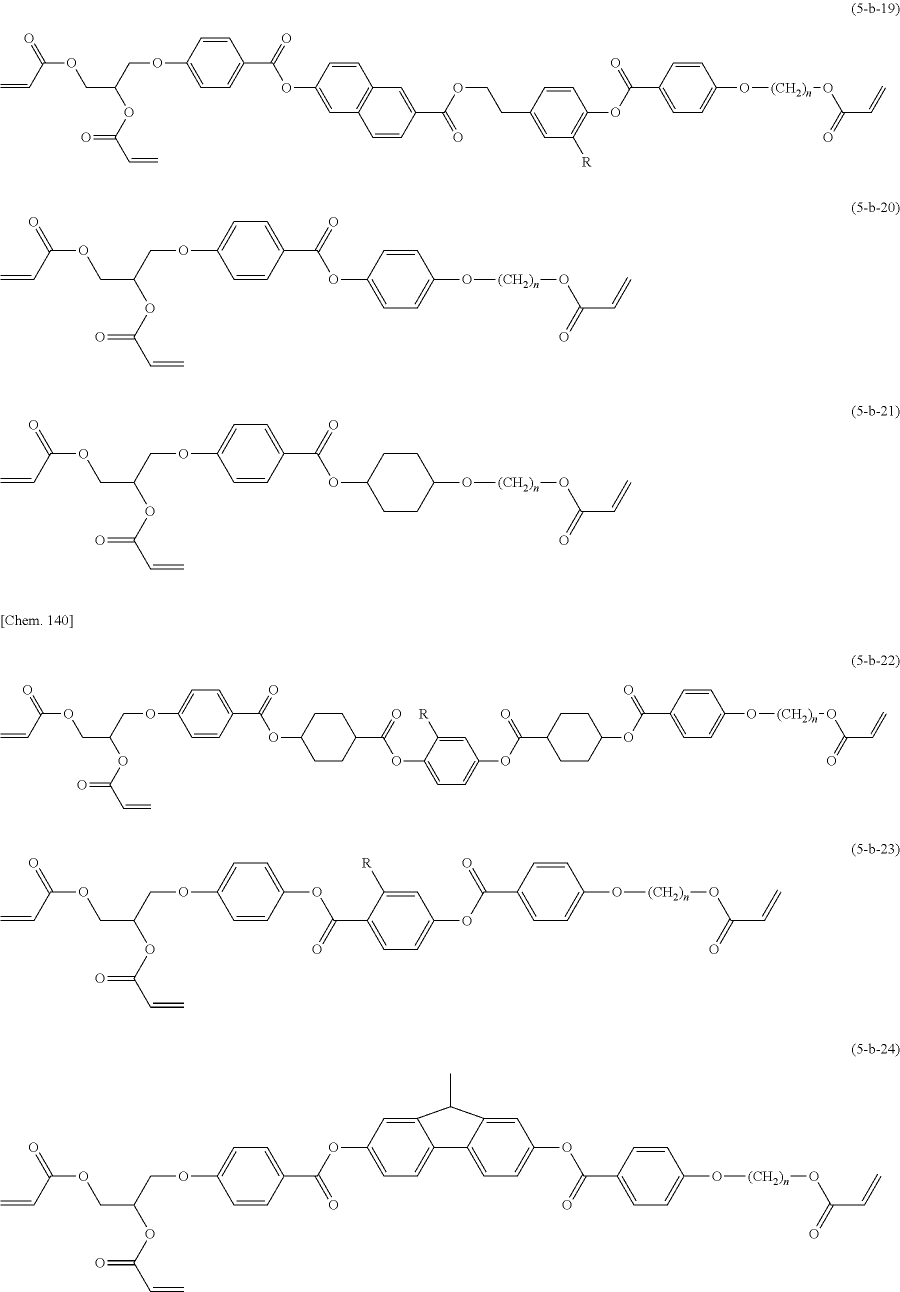

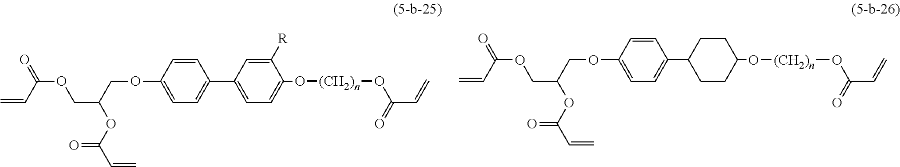

(In the formulae, n each independently represents an integer of 1 to 10, and R represents a hydrogen atom, a halogen atom, an alkyl group having 1 to 6 carbon atoms, an alkoxy group having 1 to 6 carbon atoms, or a cyano group. In the case where these groups represent an alkyl group having 1 to 6 carbon atoms or an alkoxy group having 1 to 6 carbon atoms, all groups may be unsubstituted or substituted with one or two or more halogen atoms.) These liquid crystalline compounds may be used singly or two or more thereof may be mixed to be used.

Preferred specific examples of the compound represented by General Formula (6-b) include compounds represented by Formula (6-b-1) to Formula (6-b-23).

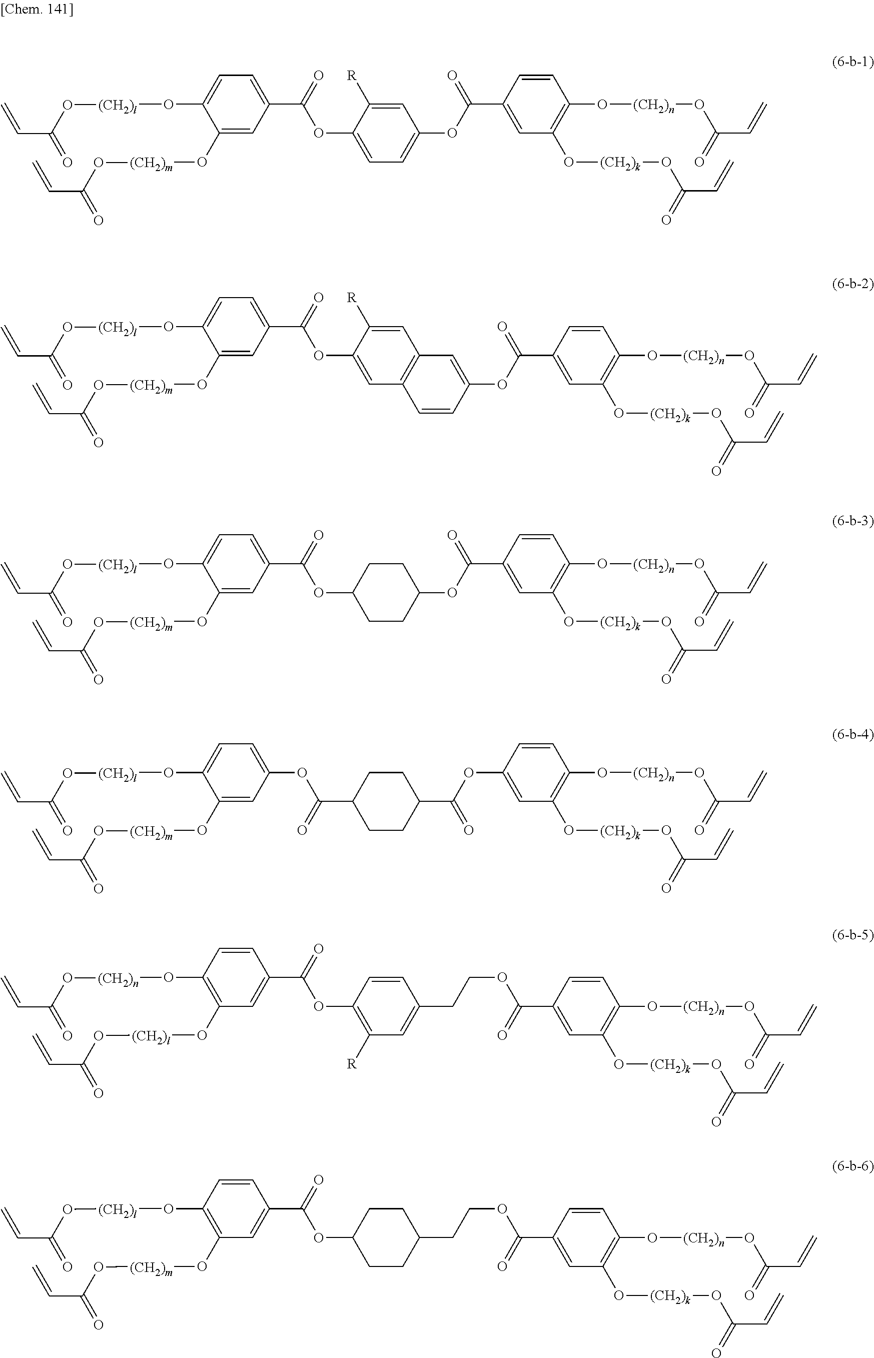

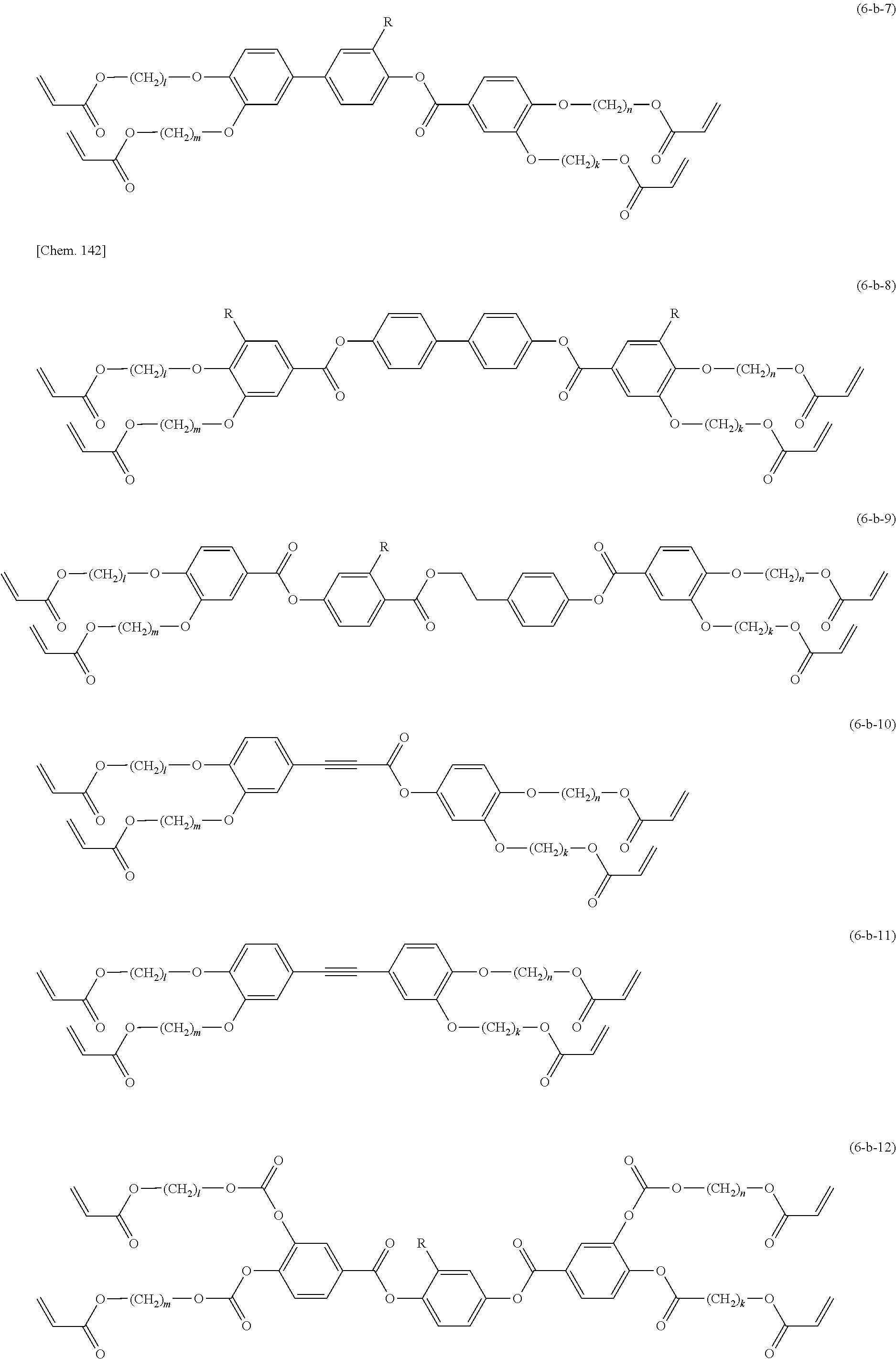

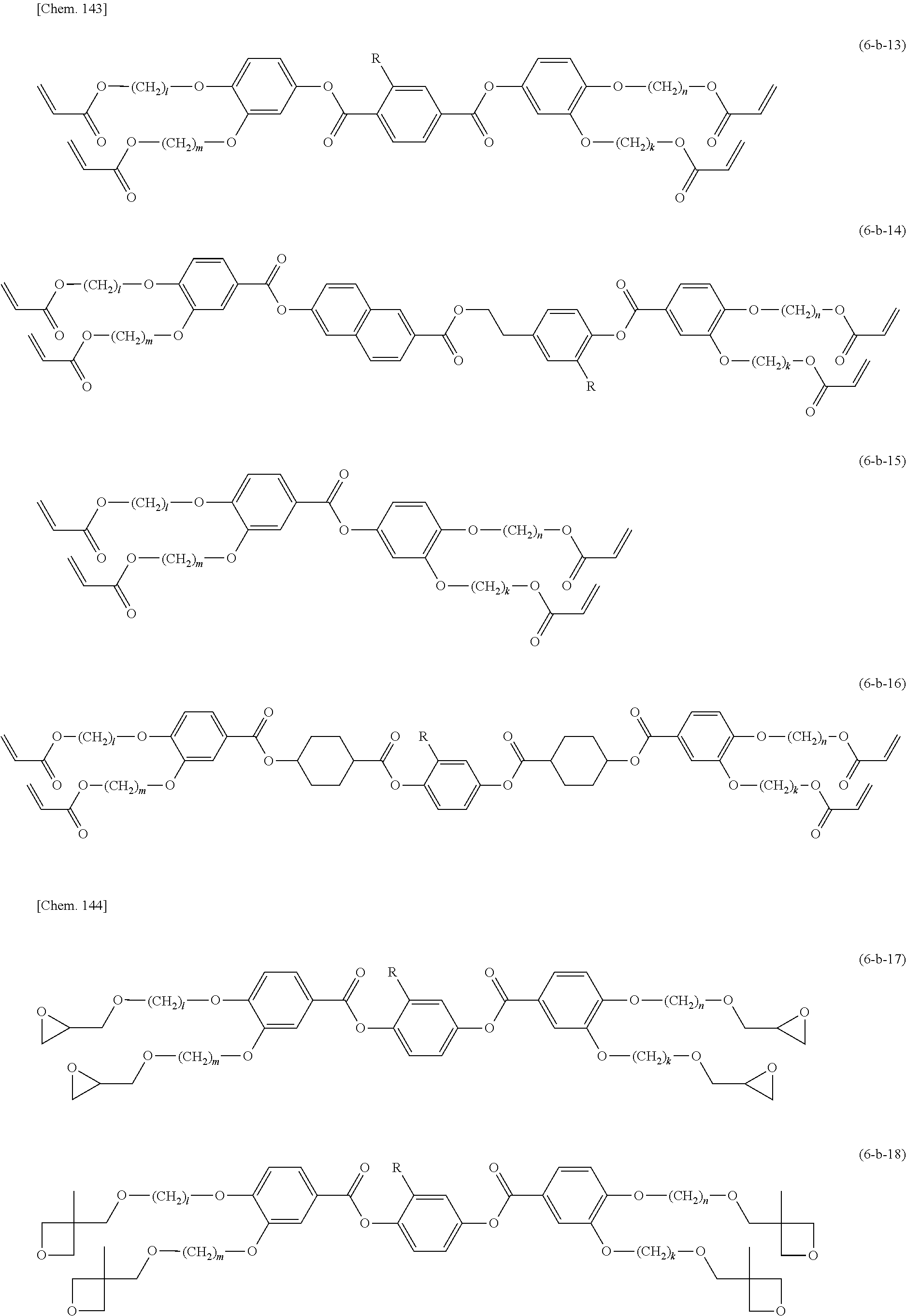

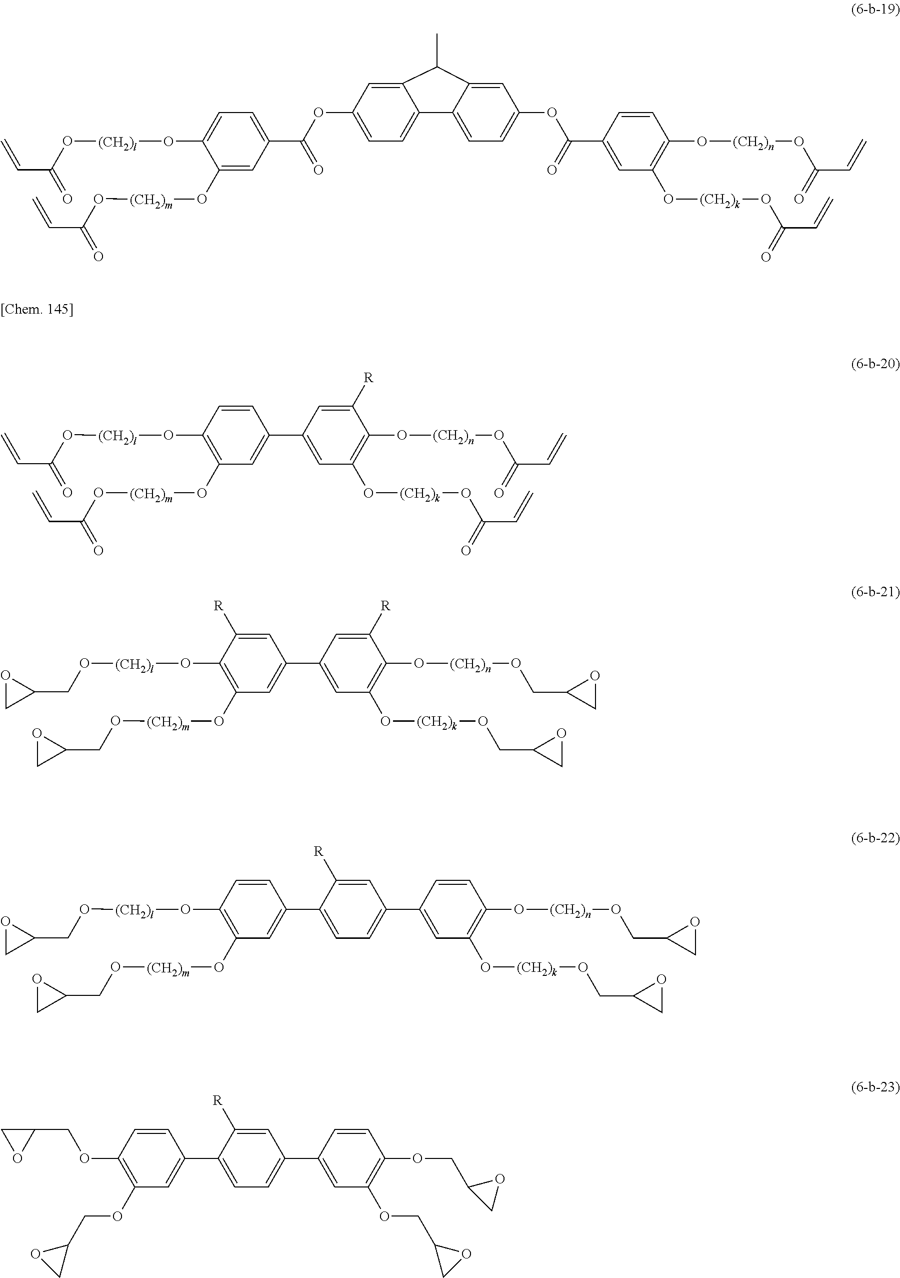

(In the formulae, k, l, m, and n each independently represent an integer of 1 to 10, and R represents a hydrogen atom, a halogen atom, an alkyl group having 1 to 6 carbon atoms, an alkoxy group having 1 to 6 carbon atoms, or a cyano group. In the case where these groups represent an alkyl group having 1 to 6 carbon atoms or an alkoxy group having 1 to 6 carbon atoms, all groups may be unsubstituted or substituted with one or two or more halogen atoms.) These liquid crystalline compounds may be used singly or two or more thereof may be mixed to be used.

Preferred specific examples of the compound represented by General Formula (7-b) include compounds represented by Formula (7-b-1) to Formula (7-b-25).

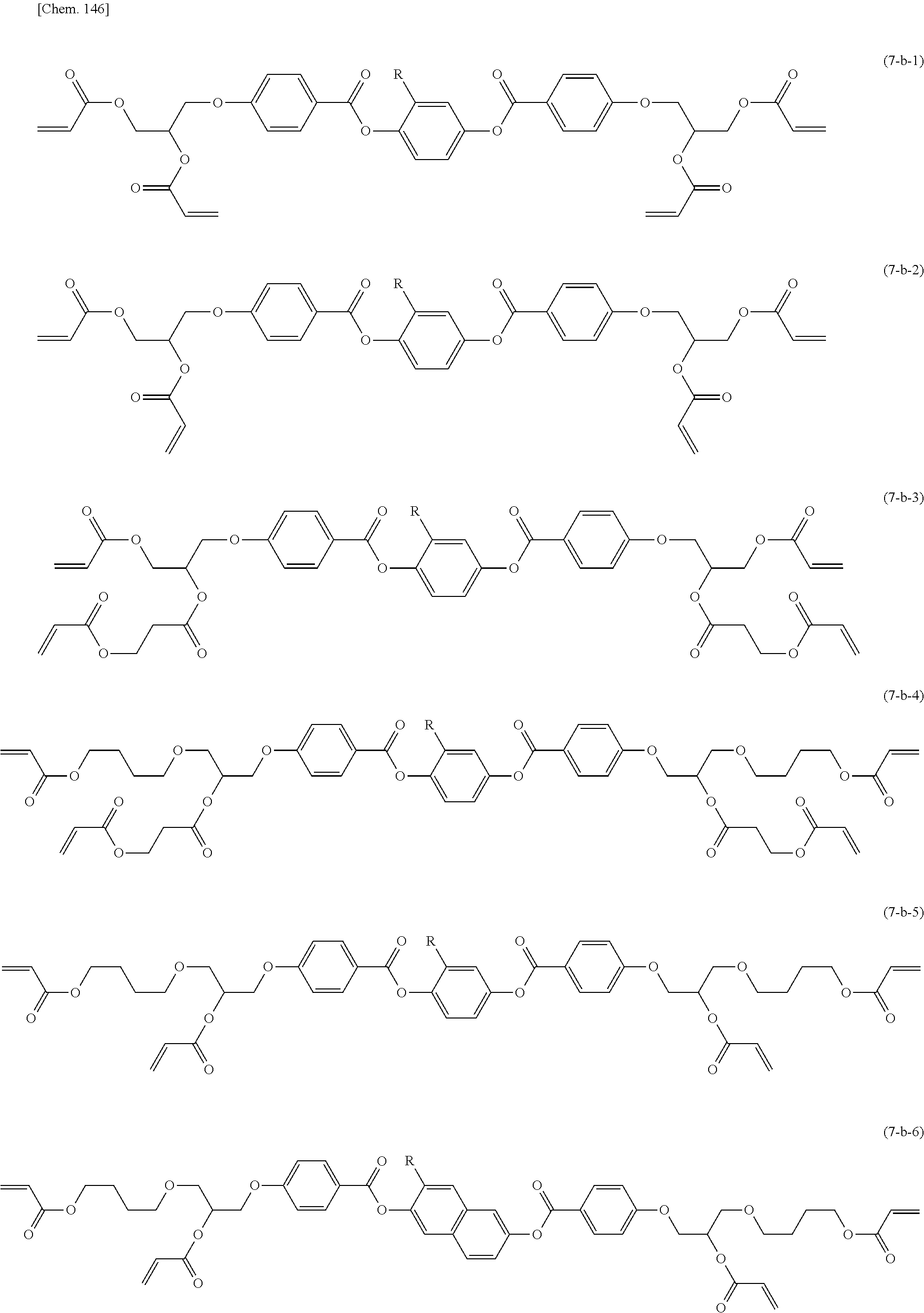

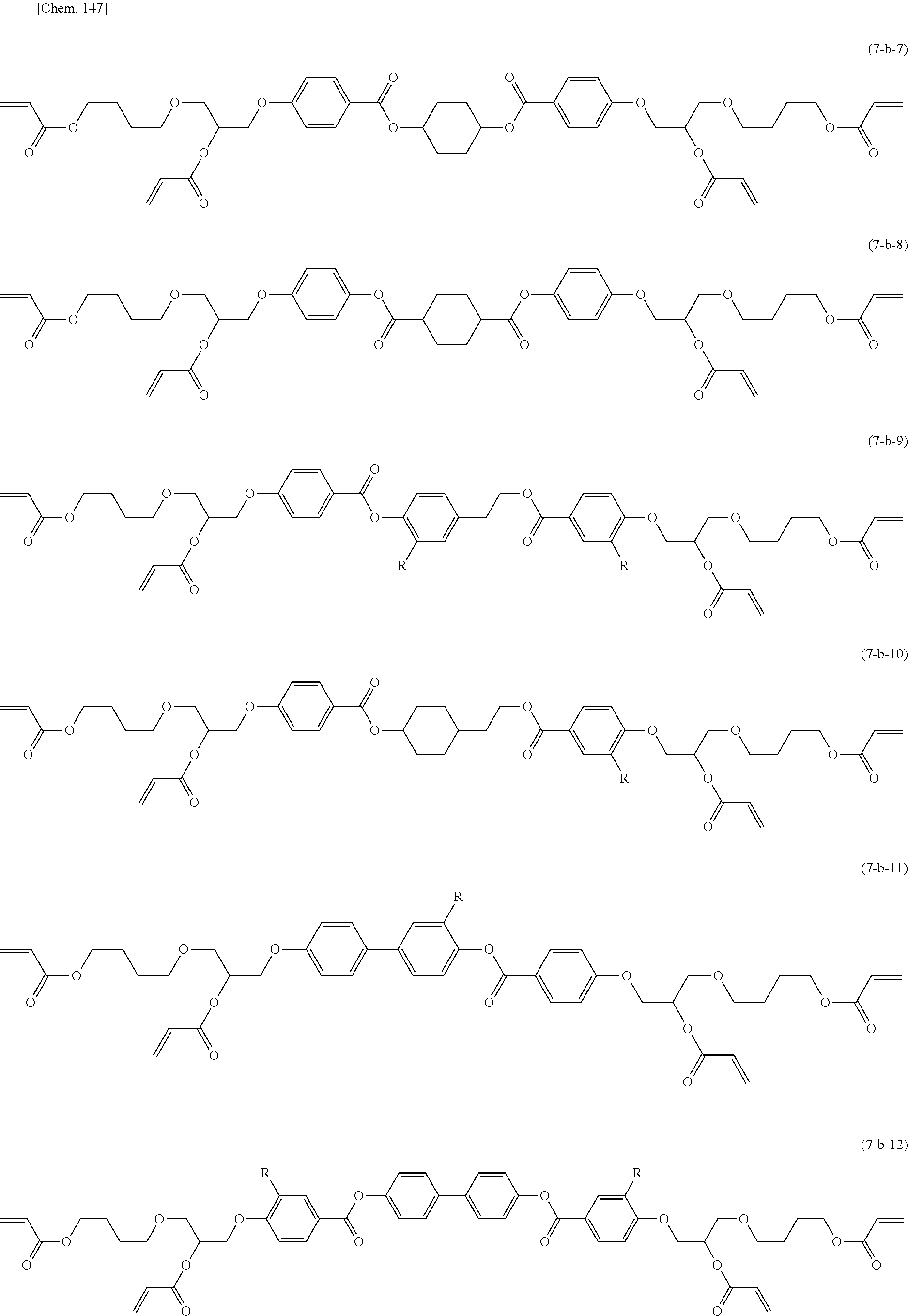

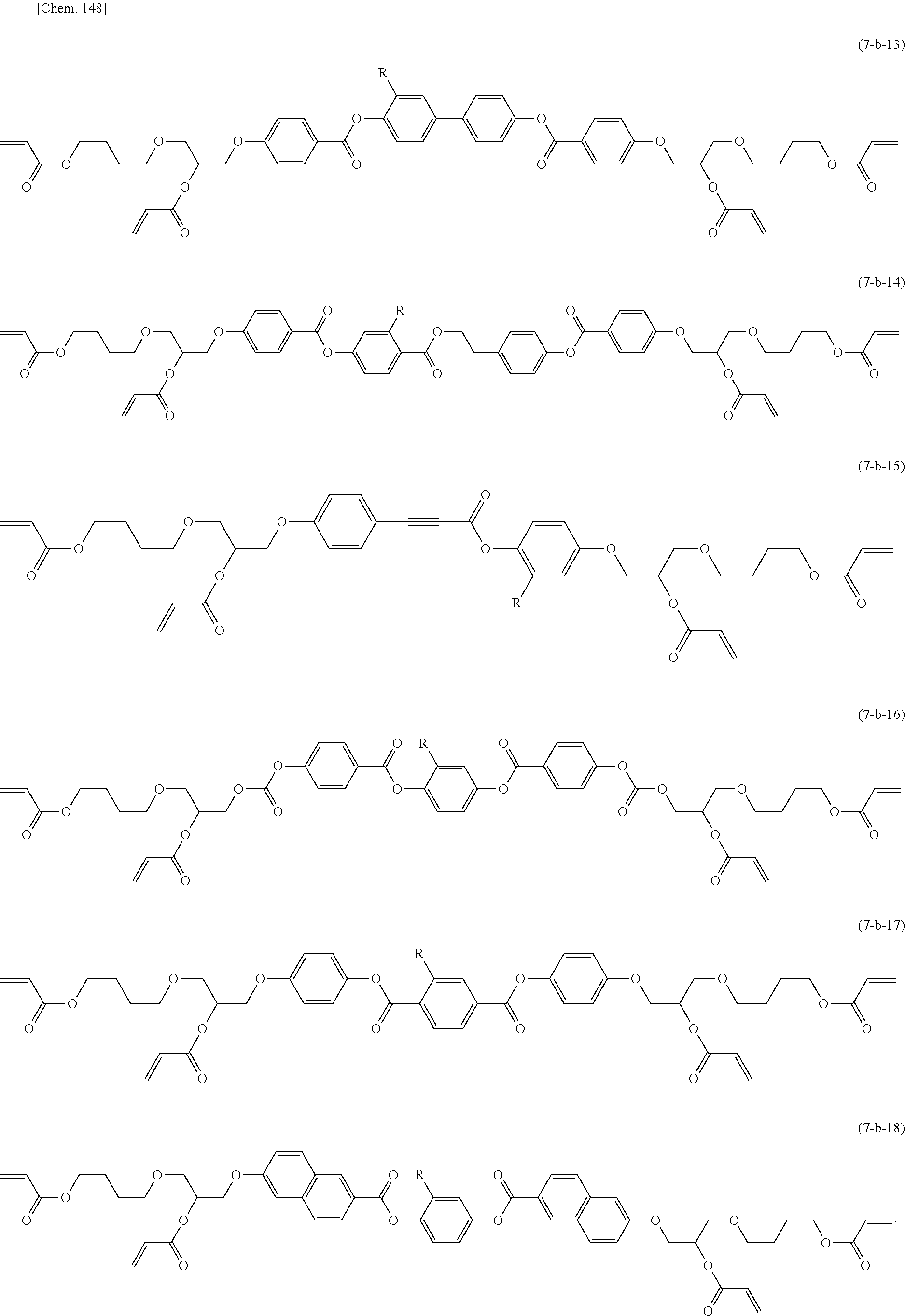

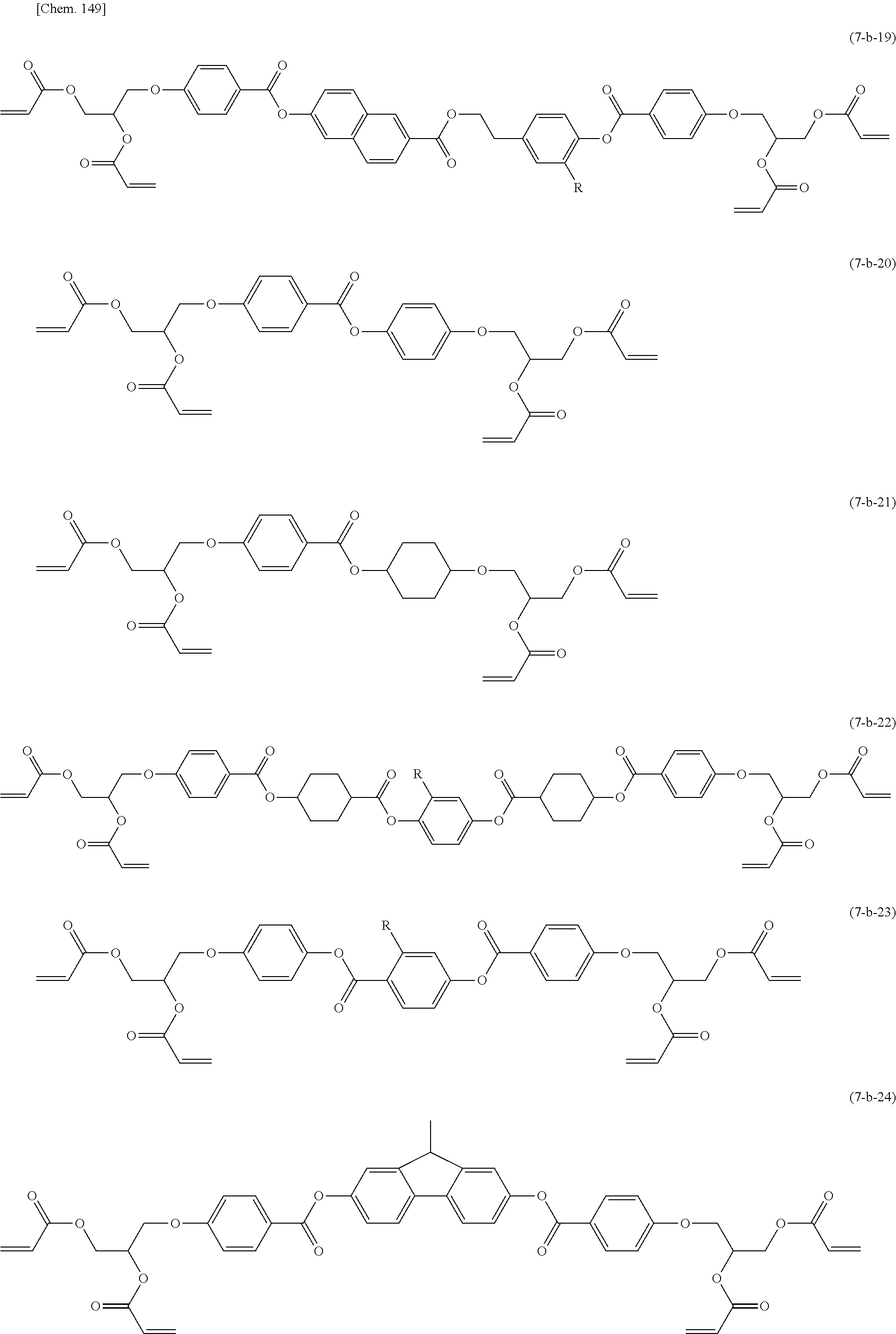

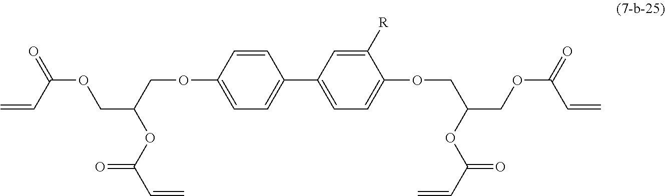

(In the formulae, R represents a hydrogen atom, a halogen atom, an alkyl group having 1 to 6 carbon atoms, an alkoxy group having 1 to 6 carbon atoms, or a cyano group. In the case where these groups represent an alkyl group having 1 to 6 carbon atoms or an alkoxy group having 1 to 6 carbon atoms, all groups may be unsubstituted or substituted with one or two or more halogen atoms.) These liquid crystalline compounds may be used singly or two or more thereof may be mixed to be used.

(Alignment Material)

The polymerizable composition of the present invention may contain an alignment material that improves alignment properties in order to improve alignment properties. Conventionally known one can be used as the alignment material as long as the material is soluble in a solvent that dissolves the liquid crystalline compound containing a polymerizable group, which is used for the polymerizable composition of the present invention, and the alignment material can be added within the range that does not significantly degrade the alignment properties through addition. Specifically, the amount of the alignment material is preferably 0.05% to 30% by weight, more preferably 0.5% to 15% by weight, and particularly preferably 1% to 10% by weight with respect to the total amount of the polymerizable compound contained in the polymerizable composition.

Specific examples of the alignment material include photoisomerizing or photodimerizing compounds such as polyimide, polyamide, a benzocyclobutene (BCB) polymer, polyvinyl alcohol, polycarbonate, polystyrene, polyphenylene ether, polyarylate, polyethylene terephthalate, polyether sulfone, an epoxy resin, an epoxy acrylate resin, an acrylic resin, a coumarin compound, a chalcone compound, a cinnamate compound, a fulgide compound, an anthraquinone compound, an azo compound, and an aryl ethene compound. Further, materials (photo-alignment materials) that are aligned by irradiation with ultraviolet rays or irradiation with visible light are preferable.

Examples of the photo-alignment materials include polyimide having cyclic cycloalkane, wholly aromatic polyarylate, polyvinyl cinnamate described in JP-A-5-232473, polyvinyl ester of paramethoxycinnamic acid, a cinnamate derivative described in JP-A-06-287453 and JP-A-06-289374, and a maleimide derivative described in JP-A-2002-265541. Specifically, compounds represented by Formulae (12-1) to (12-7) are preferable.

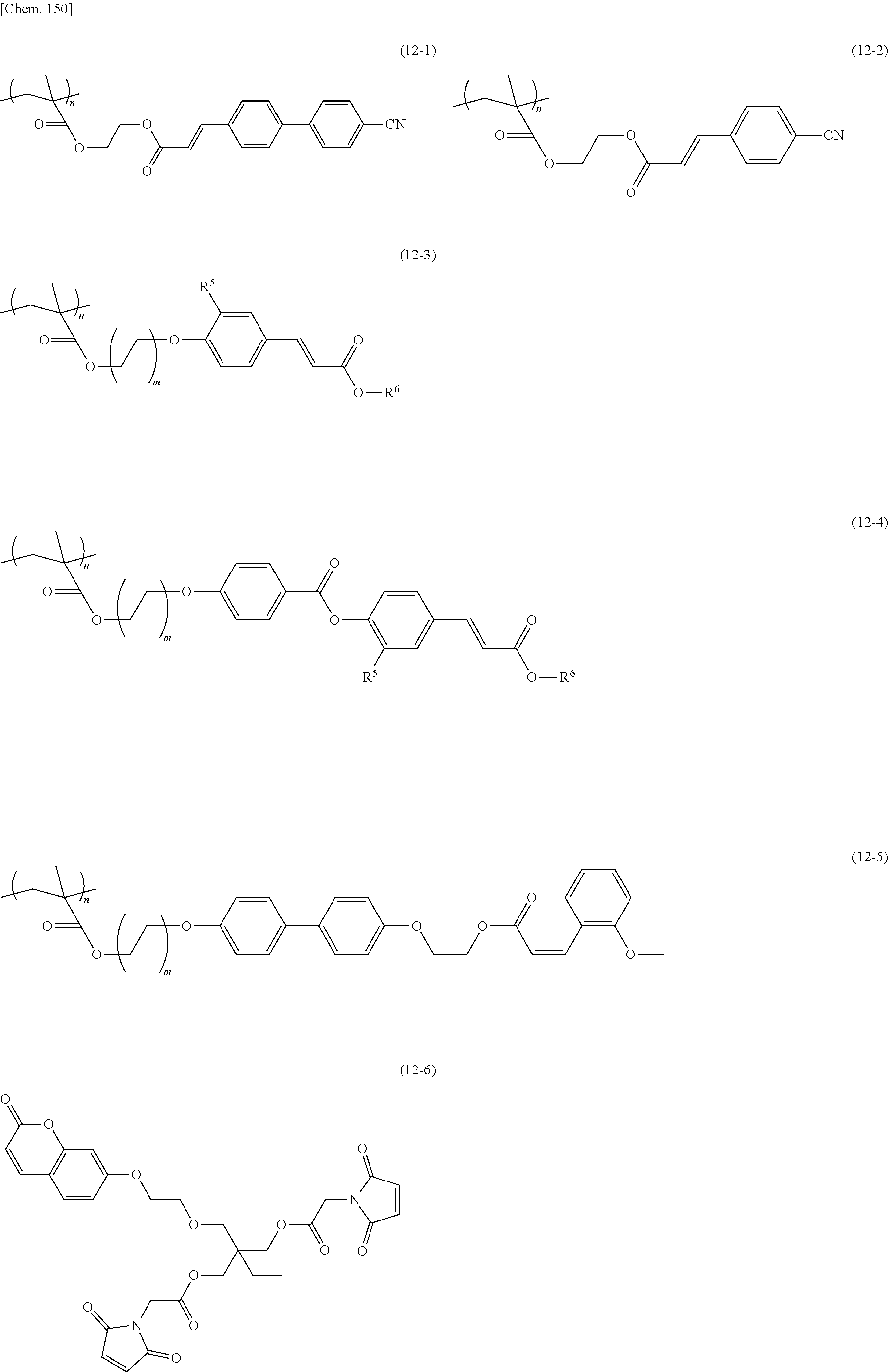

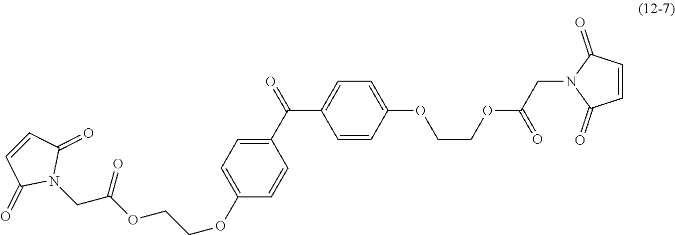

In the formulae, R represents a hydrogen atom, a halogen atom, an alkyl group having 1 to 3 carbon atoms, an alkoxy group, or a nitro group, R′ represents a hydrogen atom or an alkyl group having 1 to 10 carbon atoms, the alkyl group may be linear or branched, one or more of arbitrary hydrogen atoms in the alkyl group may be substituted with a fluorine atom, one —CH₂— or two or more (—CH₂—)'s which are not adjacent to each other in the alkyl group may be each independently substituted with —O—, —S—, —CO—, —COO—, —OCO—, —CO—S—, —S—CO—, —O—CO—O—, —CO—NH—, —NH—CO—, or —C≡C—, and CH₃ at the terminal may be substituted with CF₃, CCl₃, a cyano group, a nitro group, an isocyano group, a thioisocyano group. n represents an integer of 4 to 100,000 and m represents an integer of 1 to 10.

(Polymer)

The polymer of the present invention is obtained by performing polymerization in a state in which the polymerizable composition of the present invention contains an initiator. The polymer of the present invention is used for an optically anisotropic body, a retardation film, a lens, a colorant, a printed matter, and the like.

(Method of Producing Optically Anisotropic Body)

(Optically Anisotropic Body)

The optically anisotropic body of the present invention is obtained by coating a base material or a base material having an alignment function with the polymerizable composition of the present invention, uniformly aligning liquid crystal molecules in the polymerizable liquid crystal composition of the present invention in a state in which a nematic phase or a smectic phase is maintained, and then performing polymerization.

(Base Material)

A base material used for the optically anisotropic body of the present invention is a material that is typically used for a liquid crystal display element, an organic light-emitting display element, other display elements, an optical component, a colorant, a marking, printed matter, or an optical film and is not particularly limited as long as the material has heat resistance so that the material can withstand heating during the drying after the application of the polymerizable composition solution of the present invention. Examples of such a material include organic materials such as a glass base material, a metal base material, a ceramic base material, a plastic base material, and paper. Particularly in the case where the base material is an organic material, examples of the organic material include a cellulose derivative, polyolefin, polyester, polyolefin, polycarbonate, polyacrylate, polyarylate, polyether sulfone, polyimide, polyphenylene sulfide, polyphenylene ether, nylon, and polystyrene. Among these, plastic base materials such as polyester, polystyrene, polyolefin, a cellulose derivative, polyarylate, and polycarbonate are preferable. As the shape of the base material, a base material having a curved surface may be used in addition to a flat plate. These base materials may have an electrode layer, an anti-reflection function, or a reflection function as necessary.

In order to improve the coating properties of the polymerizable composition of the present invention or the adhesiveness between the base material and the polymer, the base material may be subjected to a surface treatment. Examples of the surface treatment include an ozone treatment, a plasma treatment, a corona treatment, and a silane coupling treatment. Further, in order to adjust the transmittance or reflectance of light, an organic thin film, an inorganic oxide thin film, or a metal thin film may be provided on the surface of the base material according to a vapor deposition method. Alternatively, the base material may be a pickup lens, a rod lens, an optical disc, a retardation film, a light diffusion film, or a color filter in order to add the optical added value. Among these, a pickup lens, a retardation film, a light diffusion film, and a color filter that increase the added value are preferable.

(Alignment Treatment)

Further, the base material may be subjected to a typical alignment treatment or provided with an alignment film so that the polymerizable composition is aligned when a polymerizable composition solution of the present invention is applied and dried. Examples of the alignment treatment include a stretching treatment, a rubbing treatment, a polarized ultraviolet visible light irradiation treatment, an ion beam treatment, and an oblique vapor deposition treatment of SiO₂ performed on a base material. In the case of using an alignment film, conventionally known alignment films are used. Examples of such alignment films include compounds such as polyimide, polysiloxane, polyamide, polyvinyl alcohol, polycarbonate, polystyrene, polyphenylene ether, polyarylate, polyethylene terephthalate, polyether sulfone, an epoxy resin, an epoxy acrylate resin, an acrylic resin, an azo compound, a coumarin compound, a chalcone compound, a cinnamate compound, a fulgide compound, an anthraquinone compound, an azo compound, and an aryl ethene compound and polymers or copolymers of these compounds. As a compound that is subjected to an alignment treatment through rubbing, a compound that promotes crystallization of a material by performing a heating process during or after the alignment treatment is preferable. Among the compounds that are subjected to alignment treatments other than the rubbing treatment, compounds for which photo-alignment materials are used are preferable.

In the case where the liquid crystal composition is brought into contact with a substrate having an alignment function, liquid crystal molecules are aligned along a direction in which the substrate has been subjected to the alignment treatment in the vicinity of the substrate. The method of the alignment treatment performed on the substrate greatly affects whether the liquid crystal molecules are aligned horizontally to the substrate or aligned obliquely or vertically to the substrate. For example, a polymerizable liquid crystal layer that is aligned substantially horizontal is obtained when an alignment film having an extremely small pretilt angle, such as a film used for an in-plane switching (IPS) type liquid crystal display element, is provided on the substrate.

Further, in the case where an alignment film, such as a film used for a TN type liquid crystal display element, is provided on the substrate, a polymerizable liquid crystal layer that is slightly obliquely aligned is obtained. In the case where an alignment film, such as a film used for an STN type liquid crystal display element, is used, a polymerizable liquid crystal layer that is largely obliquely aligned is obtained.

(Coating)

As a coating method used to obtain the optically anisotropic body of the present invention, conventionally known methods such as an applicator method, a bar coating method, a spin coating method, a roll coating method, a direct gravure coating method, a reverse gravure coating method, a flexo coating method, an inkjet method, a die coating method, a cap coating method, a dip coating method, a slit coating method, and a spray coating method can be used. The polymerizable composition is dried after the coating.

After the coating, it is preferable that the liquid crystal molecules of the polymerizable composition of the present invention are uniformly aligned in a state in which a smectic phase or a nematic phase is maintained. As an example for this, a heat treatment method may be exemplified. Specifically, the substrate is coated with the polymerizable composition of the present invention, the polymerizable composition is heated at an N (nematic phase)-I (isotropic liquid phase) transition temperature (hereinafter, abbreviated as the N-I transition temperature) of the liquid crystal composition or higher so that the liquid crystal composition enters an isotropic phase liquid state. Thereafter, the resultant is gradually cooled to exhibit a nematic phase. At this time, it is desirable that a liquid crystal phase domain is allowed to be sufficiently grown to obtain a monodomain by temporarily maintaining the temperature at which a liquid crystal phase appears. Alternatively, after the substrate is coated with the polymerizable composition of the present invention, the polymerizable composition may be subjected to a heat treatment of maintaining the temperature range, in which a nematic phase of the polymerizable composition of the present invention appears, for a certain period of time. In the case where a monodomain hardly forms due to the high viscosity of the liquid crystal composition, the viscosity of the liquid crystal composition may be decreased largely by increasing the temperature of the heat treatment, thereby facilitating the formation of the monodomain.

When the heating temperature is extremely high, there is a concern that the polymerizable liquid crystal compound may undergo an undesirable polymerizable reaction and deteriorate. Further, when the polymerizable composition is extremely cooled, phase separation occurs in the polymerizable composition, crystals are precipitated, and a high-order liquid crystal phase such as a smectic phase appears. Therefore, the alignment treatment may not be performed.

A homogeneous optically anisotropic body with few alignment defects can be prepared by performing such a heat treatment, compared to a coating method of only performing coating.

After the homogeneous alignment treatment is performed as described above, when the liquid crystal phase is cooled at the lowest temperature at which phase separation does not occur, in other words, the liquid crystal phase is cooled to enter a supercooled state, and polymerization is carried out in a state in which the liquid crystal phase is aligned at the temperature, an optically anisotropic body having a higher alignment order and excellent transparency can be obtained.

(Polymerization Process)

The polymerization treatment may be performed on the dried polymerizable composition typically by irradiation with light such as visible ultraviolet rays or by heating in a uniformly aligned state. In the case where the polymerization is performed by irradiation with light, it is preferable that visible ultraviolet light having a wavelength of 420 nm or less is applied and most preferable that ultraviolet light having a wavelength of 250 to 370 nm is applied. Here, in the case where decomposition or the like of the polymerizable composition is caused by visible ultraviolet light having a wavelength of 420 nm or less, it is preferable that a polymerization treatment is performed using visible ultraviolet light having a wavelength of 420 nm or greater in some cases.

(Polymerization Method)

As a method of polymerizing the polymerizable composition of the present invention, a method of applying active energy rays or a thermal polymerization method is exemplified. From the viewpoint that heating is not necessary and the reaction proceeds at room temperature, a method of applying active energy rays is preferable. Among the examples thereof, from the viewpoint of a simple operation, a method of applying light such as ultraviolet rays or the like is preferable. The application temperature is set to a temperature at which the liquid crystal phase of the polymerizable composition of the present invention can be maintained, and it is preferable that the temperature thereof is set to 30° C. or lower as much as possible in order to avoid induction of thermal polymerization of the polymerizable composition. Further, the polymerizable liquid crystal composition typically exhibits the liquid crystal phase in the process of raising the temperature, within the N-I transition temperature range from a C (solid phase)-N (nematic) transition temperature (hereinafter, abbreviated as the C-N transition temperature). Further, the polymerizable liquid crystal composition occasionally maintains the liquid crystal state thereof without being solidified at the C-N transition temperature or lower in the process of lowering the temperature, in order to obtain a thermodynamically non-equilibrium state. This state is referred to as a supercooled state. In the present invention, it can be said that the liquid crystal composition in the supercooled state is also in the state of maintaining the liquid crystal phase. Specifically, it is preferable to irradiate with ultraviolet light having a wavelength of 390 nm or less and most preferable to irradiate with light having a wavelength of 250 to 370 nm. In the case where decomposition or the like of the polymerizable composition is caused by the irradiation with ultraviolet light having a wavelength of 390 nm or less, it is preferable that the polymerization treatment is performed using ultraviolet light having a wavelength of 390 nm or greater in some cases. As this light, it is preferable to use diffusion light and non-polarized light. The intensity of irradiation with ultraviolet rays is preferably 0.05 mW/cm² to 10 W/cm² and particularly preferably 0.2 mW/mc² to 2 W/cm². In the case where the intensity of ultraviolet rays is less than 0.05 mW/cm², it takes a long time to complete the polymerization. In addition, in the case where the intensity of ultraviolet rays is greater than 2 W/cm², there is a possibility that the liquid crystal molecules in the polymerizable composition tend to be photodecomposed, a large amount of polymerization heat is generated so that the temperature during the polymerization increases, the order parameter of the polymerizable liquid crystal changes, and the phase difference of the film after the polymerization deviates.

After only a specific portion is polymerized by irradiation with ultraviolet rays using a mask, when the alignment state of the unpolymerized portion is changed by applying an electric field or a magnetic field or raising the temperature and then the unpolymerized portion is polymerized, an optically anisotropic body having a plurality of regions with different alignment directions can be obtained.

Further, an optically anisotropic body having a plurality of regions with different alignment directions can also be obtained by means of restricting the alignment by applying an electric field or a magnetic field to the polymerizable liquid crystal composition or raising a temperature thereof in an unpolymerized state in advance and then polymerizing the unpolymerized portion by irradiation with light from the upper portion of a mask while the state is maintained when only a specific portion is polymerized by irradiation with ultraviolet rays using a mask.

An optically anisotropic body obtained by polymerizing the polymerizable liquid crystal composition of the present invention can be used alone by being peeled off from the substrate or can be used as it is without being peeled off from the substrate. Particularly, since other members are unlikely to be contaminated by the optically anisotropic body, it is useful that the optically anisotropic body is used as a substrate to be laminated or used by being bonded to another substrate.

(Retardation Film)

The retardation film of the present invention contains the optically anisotropic body and the liquid crystalline compound may form a uniform and continuous alignment state with respect to the base material so that the in-plane, the outer plane, both of the in-plane and the outer plane with respect to the base material or the in-plane has biaxiality. Further, an adhesive or an adhesive layer, a pressure sensitive adhesive or a pressure sensitive adhesive layer, a protective film, a polarizing film, or the like may be laminated on the retardation film.

As such a retardation film, for example, the alignment mode of a positive A plate formed by aligning a rod-like liquid crystalline compound substantially horizontally with respect to the base material, a negative A plate formed by aligning a discotic liquid crystalline compound vertically uniaxially with respect to the base material, a positive C plate formed by aligning a rod-like liquid crystalline compound substantially vertically with respect to the base material, a negative C plate formed by aligning a rod-like liquid crystalline compound cholesterically with respect to the base material or aligning a discotic liquid crystalline compound horizontally uniaxially with respect to the base material, a biaxial plate, a positive O plate formed by hybrid aligning a rod-like liquid crystalline compound with respect to the base material, or a negative O plate formed by hybrid aligning a discotic liquid crystalline compound with respect to the base material can be applied. In the case where the alignment mode thereof is used for a liquid crystal display element, the alignment mode is not particularly limited as long as the mode improves the viewing angle dependence and various alignment modes can be applied.

For example, the alignment mode of a positive A plate, a negative A plate, a positive C plate, a negative C plate, a biaxial plate, a positive O plate, or a negative O plate can be applied. Among these, it is preferable to use the alignment mode of a positive A plate or a negative C plate. Further, it is more preferable that a positive A plate or a negative C plate is laminated.

Here, a positive A plate refers to an optically anisotropic body in which a polymerizable composition is homogeneously aligned. Further, a negative C plate refers to an optically anisotropic body in which a polymerizable composition is cholesterically aligned.

In a liquid crystal cell for which a retardation film is used, a positive A plate is preferably used as a first retardation layer in order to widen the viewing angle by compensating the viewing angle dependence of polarization axis orthogonality. Here, the positive A plate is a plate in which when the refractive index of the film in an in-plane slow axis direction is set to nx, the refractive index of the film in an in-plane fast axis direction is set to ny, and the refractive index of the film in a thickness direction is set to nz, nx, ny, and nz satisfy a relationship of “nx>ny=nz”. As the positive A plate, a plate in which the in-plane phase difference value at a wavelength of 550 nm is 30 nm to 500 nm is preferable. Further, the thickness direction retardation value is not particularly limited. An Nz coefficient is preferably 0.9 to 1.1.

Further, in order to cancel the birefringence of the liquid crystal molecules, a so-called negative C plate having negative refractive index anisotropy is preferably used as a second retardation layer. Further, a negative C plate may be laminated on a positive A plate.

Here, the negative C plate is a retardation layer in which when the refractive index of the retardation layer in the in-plane slow axis direction is set to nx, the refractive index of the retardation layer in the in-plane fast axis direction is set to ny, and the refractive index of the retardation layer in the thickness direction is set to nz, nx, ny, and nz are in a relationship of “nx=ny>nz”. The thickness direction phase difference value of the negative C plate is preferably 20 to 400 nm.

Further, the refractive index anisotropy in the thickness direction is represented by a thickness direction phase difference value Rth defined by Equation (2). The thickness direction phase difference value Rth can be calculated by acquiring nx, ny, and nz through numerical calculation from Equation (1) and Equations (4) to (7) using an in-plane phase difference value R₀, a phase difference value R₅₀ measured by tilting the slow axis as a tilt axis by 50°, a thickness d of the film, and an average refractive index no of the film and then substituting these values in Equation (2). Further, the Nz coefficient can be calculated from Equation (3). Hereinafter, the same applies to other descriptions in the present specification.

R₀=(nx−ny)×d (1)

Rth=[(nx+ny)/2−nz]×d (2)

Nz coefficient=(nx−nz)/(nx−ny) (3)

R₅₀=(nx−ny′)×d/cos(ϕ) (4)

(nx+ny+nz)/3=n0 (5)

Here,

ϕ=sin⁻¹[sin(50°)/n₀] (6)

ny′=ny×nz/[ny²×sin²(ϕ)+nz²×cos²(ϕ)]^{1/2} (7)

In commercially available phase difference measuring devices, many measuring devices are designed such that the numerical calculation shown here is automatically performed in the devices and the in-plane phase difference value R₀, the thickness direction phase difference value Rth, and the like are automatically displayed. Examples of such measuring devices include RETS-100 (manufactured by Otsuka Chemical Co., Ltd.).

(Lens)

The polymerizable composition of the present invention can be used as a lens of the present invention by coating a base material or a base material having an alignment function with the polymerizable composition of the present invention or pouring the polymerizable composition in a lens-shaped mold, uniformly aligning liquid crystal molecules in the polymerizable composition of the present invention in a state in which a nematic phase or a smectic phase is maintained, and then performing polymerization. Examples of the shape of the lens include a simple cell shape, a prism shape, and a lenticular shape.

(Liquid Crystal Display Element)

The polymerizable composition of the present invention can be used as a liquid crystal display element of the present invention by coating a base material or a base material having an alignment function with the polymerizable composition of the present invention, uniformly aligning liquid crystal molecules in the polymerizable composition of the present invention in a state in which a nematic phase or a smectic phase is maintained, and then performing polymerization. As the form of the display element to be used, an optical compensation film, a patterned retardation film of a liquid crystal stereoscopic display element, a retardation correction layer of a color filter, an overcoat layer, and an alignment film for a liquid crystal medium may be exemplified. The liquid crystal display element is formed by interposing at least a liquid crystal medium layer, a TFT drive circuit, a black matrix layer, a color filter layer, a spacer, or an electrode circuit corresponding to the liquid crystal medium layer between at least two base materials. An optical compensation layer, a polarizing plate layer, and a touch panel layer are typically aligned outside the two base materials, but an optical compensation layer, an overcoat layer, a polarizing plate layer, or an electrode layer for a touch panel may be interposed between two base materials in some cases.

Examples of the alignment mode of the liquid crystal display element include a TN mode, a VA mode, an IPS mode, an FFS mode, and an OCB mode. In the case where an optical compensation film or an optical compensation layer is used, a film having a retardation corresponding to the alignment mode can be produced. In the case where a patterned retardation film is used, the liquid crystalline compound in the polymerizable composition may be substantially horizontally aligned with respect to the base material. In the case where an overcoat layer is used, a liquid crystalline compound having a larger number of polymerizable groups in one molecule may be thermally polymerized. In the case where an alignment film for a liquid crystal medium is used, it is preferable to use a polymerizable composition into which a liquid crystalline compound containing an alignment material and a polymerizable group is mixed. Further, a liquid crystalline compound can be mixed with a liquid crystalline medium, and various properties such as the response speed or the contrast can be improved by adjusting the ratio between the liquid crystal medium and the liquid crystalline compound.

(Organic Light-Emitting Display Element)

The polymerizable composition of the present invention can be used as an organic light-emitting display element of the present invention by coating a base material or a base material having an alignment function with the polymerizable composition of the present invention, uniformly aligning liquid crystal molecules in the polymerizable composition of the present invention in a state in which a nematic phase or a smectic phase is maintained, and then performing polymerization. As the form of the display element to be used, the retardation film and the polarizing plate obtained by the polymerization are combined so as to be used as an anti-reflective film of an organic light-emitting display element. In the case where the combination of the retardation film and the polarizing film is used as an anti-reflective film, the angle between the polarizing axis of the polarizing plate and the slow axis of the retardation film is preferably approximately 45°. The polarizing plate and the retardation film may be bonded to each other using an adhesive or a pressure sensitive adhesive. Further, the retardation film may be directly laminated on the polarizing plate by performing a rubbing treatment or an alignment treatment of laminating a photo-alignment film. The polarizing plate used at this time may be a film form where a dye is doped or a metal form such as a wire grid.

(Lighting Element)

A polymer polymerized in a state in which the polymerizable composition of the present invention is aligned on a nematic phase, a smectic phase, or a base material having an alignment function can be used as a heat radiation material of a lighting element or particularly a light emitting diode element. Examples of the form of the heat radiation material include a prepreg, a polymer sheet, an adhesive, and a sheet provided with metal foil.

(Optical Component)

The polymerizable composition of the present invention can be used as an optical component of the present invention by performing polymerization in a state in which a nematic phase or a smectic phase is maintained or a state in which the polymerization composition and an alignment material are combined.

(Colorant)

The polymerizable composition of the present invention can be also used as a colorant by adding a colorant such as a dye or an organic pigment.

(Polarizing Film)

The polymerizable composition of the present invention can be also used as a polarizing film by combining the polymerizable composition with a dichroic dye, lyotropic liquid crystals, or chromonic liquid crystals or adding these to the polymerizable composition.

### EXAMPLES

Hereinafter, the present invention will be described with reference to examples and comparative examples, but the present invention is not limited to these. Further, “part” and “%” are on a mass basis unless otherwise noted.

### Example 1

24 parts of a compound represented by Formula (1-a-5), 56 parts of a compound represented by Formula (1-a-6), 10 parts of a compound which is represented by Formula (2-a-1) where n is 6, 10 parts of a compound which is represented by Formula (2-a-1) where n is 3, and 0.1 parts of p-methoxyphenol (MEHQ) were added to 400 parts of cyclopentanone (CPN), heated to 80° C., and stirred so that the mixture was dissolved therein, and after the dissolution was confirmed, the temperature thereof was returned to room temperature, and 3 parts of IRGACURE 907 (manufactured by BASF Japan Ltd.), and 0.075 parts of BYK-322 which is a silicone surfactant were added thereto, and the solution was further stirred, thereby obtaining a solution. The solution was transparent and homogeneous. The obtained solution was filtered using a membrane filter having a pore diameter of 0.20 μm, thereby obtaining a polymerizable composition (1) used in Example 1.

### Examples 2 to 67 and 140 to 147, and Comparative Examples 1 to 16

Under the same conditions as in the preparation of the polymerizable composition (1) of Example 1 except that the respective compounds shown in the following table were each changed to the ratios shown in the following table, polymerizable compositions (2) to (75) of Examples 2 to 67, and 140 to 147 and polymerizable compositions (101) to (116) of Comparative Examples 1 to 16 were obtained.

Specific compositions and their property values of the polymerizable compositions (1) to (75) of and comparative polymerizable compositions (101) to (116) of the present invention are shown in the following table.

The types of surfactants and the weight average molecular weight are also shown in the following table.

TABLE 1

| | Examples | | | | | | | |
|---|---|---|---|---|---|---|---|---|
| | 1 | 2 | 3 | 4 | 5 | 6 | 7 | 8 |
| Polymerizable | (1) | (2) | (3) | (4) | (5) | (6) | (7) | (8) |
| composition | | | | | | | | |
| 1-a-5 | 24 | 24 | 24 | 24 | 24 | 24 | 24 | 24 |
| 1-a-6 | 56 | 56 | 56 | 56 | 56 | 56 | 56 | 56 |
| 2-a-1 | 10 | 10 | 10 | 10 | 10 | 10 | 10 | 10 |
| (n = 6) | | | | | | | | |
| 1-b-1 | 10 | 10 | 10 | 10 | 10 | 10 | 10 | 10 |
| (m11 = 6, n11 = 0) | | | | | | | | |
| Irg907 | 3 | 3 | 3 | 3 | 3 | 3 | 3 | 3 |
| MEHQ | 0.1 | 0.1 | 0.1 | 0.1 | 0.1 | 0.1 | 0.1 | 0.1 |
| BYK-322 | 0.075 | | | | | | | |
| BYK-323 | | 0.075 | | | | | | |
| BYK-320 | | | 0.1 | | | | | |
| Glide 420 | | | | 0.1 | | | | |
| 56 ADDITIVE | | | | | 0.075 | | | |
| Glide B1484 | | | | | | 0.1 | | |
| KP-326 | | | | | | | 0.1 | |
| Tego Flow Z | | | | | | | | 0.1 |
| FS460 | | | | | | | | |
| BYK-354 | | | | | | | | |
| CPN | 400 | 400 | 400 | 400 | 400 | 400 | 400 | 400 |
| Tni (° C.) | 105 | 105 | 105 | 105 | 105 | 105 | 105 | 106 |
| Viscosity | 1,500 | 1,500 | 1,500 | 1,500 | 1,500 | 1,500 | 1,500 | 1,500 |
| (80° C.) Pa · s | | | | | | | | |

TABLE 2

| | Examples | | | | | | | |
|---|---|---|---|---|---|---|---|---|
| | 9 | 10 | 11 | 12 | 13 | 14 | 15 | 16 |
| Polymerizable | (9) | (10) | (11) | (12) | (13) | (14) | (15) | (16) |
| Composition | | | | | | | | |
| 1-a-5 | 24 | 24 | 24 | 24 | 24 | 24 | 24 | 24 |
| 1-a-6 | 56 | 56 | 56 | 56 | 56 | 56 | 56 | 56 |
| 2-a-1 | 10 | 20 | 20 | 20 | 20 | 10 | 10 | 10 |
| (n = 6) | | | | | | | | |
| 1-b-1 | 10 | | | | | | | |
| (m11 = 6, n11 = 0) | | | | | | | | |
| 2-b-1 | | | | | | 10 | 10 | 10 |
| (m = n = 3) | | | | | | | | |
| Irg907 | 3 | 3 | 3 | 3 | 3 | 3 | 3 | 3 |
| MEHQ | 0.1 | 0.1 | 0.1 | 0.1 | 0.1 | 0.1 | 0.1 | 0.1 |
| BYK-322 | | | | | | 0.075 | | |
| BYK-323 | | 0.075 | | | | | 0.075 | |
| BYK-320 | | | | | | | | 0.1 |
| Glide 420 | | | 0.1 | | | | | |
| 56 ADDITIVE | | | | 0.075 | | | | |
| Glide B1484 | | | | | 0.1 | | | |
| BYK-354 | 0.1 | | | | | | | |
| CPN | 400 | 400 | 400 | 400 | 400 | 400 | 400 | 400 |
| Tni (° C.) | 106 | 106 | 106 | 106 | 106 | 110 | 110 | 110 |
| Viscosity | 1,500 | 1,500 | 1,500 | 1,500 | 1,500 | 600 | 600 | 600 |
| (80° C.) Pa · s | | | | | | | | |

TABLE 3

| | Examples | | | | | | | |
|---|---|---|---|---|---|---|---|---|
| | 17 | 18 | 19 | 20 | 21 | 22 | 23 | 24 |
| Polymerizable | (17) | (18) | (19) | (20) | (21) | (22) | (23) | (24) |
| Composition | | | | | | | | |
| 1-a-5 | 24 | 24 | 24 | 15 | 15 | 15 | 55 | 55 |
| 1-a-6 | 56 | 56 | 56 | 65 | 65 | 65 | 25 | 25 |
| 1-a-1 | | | | 10 | 10 | 10 | | |
| 2-a-1 | 10 | 10 | 10 | | | | 10 | 10 |
| (n = 6) | | | | | | | | |
| 2-a-31 | | | | | | | 10 | 10 |
| 2-b-1 | 10 | 10 | 10 | | | | | |
| (m = n = 3) | | | | | | | | |
| 2-b-1 | | | | 10 | 10 | 10 | | |
| (m = n = 4) | | | | | | | | |
| Irg907 | 3 | 3 | 3 | 3 | 3 | 3 | 3 | 3 |
| MEHQ | 0.1 | 0.1 | 0.1 | 0.1 | 0.1 | 0.1 | 0.1 | 0.1 |
| BYK-322 | | | | 0.075 | | | 0.075 | |
| BYK-323 | | | | | 0.075 | | | 0.05 |
| Glide 420 | 0.1 | | | | | | | |
| 56 ADDITIVE | | 0.075 | | | | | | |
| Glide B1484 | | | 0.1 | | | | | |
| Tego Flow Z | | | | | | 0.1 | | |
| FS460 | | | | | | | | |
| CPN | 400 | 400 | 400 | 400 | 400 | 400 | 400 | 400 |
| Tni (° C.) | 110 | 110 | 110 | 113 | 113 | 113 | 120 or | 120 or |
| | | | | | | | higher | higher |
| Viscosity | 600 | 600 | 600 | 600 | 600 | 600 | 2,100 | 2,100 |
| (80° C.) Pa · s | | | | | | | | |

TABLE 4

| | Examples | | | | | | | |
|---|---|---|---|---|---|---|---|---|
| | 25 | 26 | 27 | 28 | 29 | 30 | 31 | 32 |
| Polymerizable | (25) | (26) | (27) | (28) | (29) | (30) | (31) | (32) |
| Composition | | | | | | | | |
| 1-a-5 | 55 | | | | | | | |
| 1-a-6 | 25 | 50 | 50 | 50 | 55 | 55 | 55 | 55 |
| 1-a-1 | | | | | 25 | 25 | | |
| 1-a-2 | | 20 | 20 | 20 | | | 25 | 25 |
| 2-a-1 | 10 | 15 | 15 | 15 | 10 | 10 | 10 | 10 |
| (n = 6) | | | | | | | | |
| 1-b-1 | | | | | 10 | 10 | 10 | 10 |
| (m11 = 6, n11 = 0) | | | | | | | | |
| 2-a-31 | 10 | | | | | | | |
| 2-a-28 | | 15 | 15 | 15 | | | | |
| Irg907 | 3 | 3 | 3 | 3 | 3 | 3 | 3 | 3 |
| MEHQ | 0.1 | 0.1 | 0.1 | 0.1 | 0.1 | 0.1 | 0.1 | 0.1 |
| BYK-322 | | | | | 0.075 | | | |
| BYK-320 | 0.15 | | | | | | 0.2 | |
| Glide 420 | | 0.1 | | | | | | 0.1 |
| 56 ADDITIVE | | | 0.075 | | | | | |
| Glide B1484 | | | | 0.1 | | | | |
| BYK-354 | | | | | | 0.1 | | |
| CPN | 400 | 400 | 400 | 400 | 400 | 400 | 400 | 400 |
| Tni (° C.) | 120 or | 118 | 118 | 118 | 105 | 105 | 106 | 106 |
| | higher | | | | | | | |
| Viscosity | 2,100 | 1,100 | 1,100 | 1,100 | 500 | 500 | 800 | 800 |
| (80° C.) Pa · s | | | | | | | | |

TABLE 5

| | Examples | | | | | | | |
|---|---|---|---|---|---|---|---|---|
| | 33 | 34 | 35 | 36 | 37 | 38 | 39 | 40 |
| Polymerizable | (33) | (34) | (35) | (36) | (37) | (38) | (39) | (40) |
| Composition | | | | | | | | |
| 1-a-5 | | | 30 | 30 | 30 | 30 | 30 | 30 |
| 1-a-6 | 55 | 55 | 40 | 40 | 40 | 40 | 40 | 40 |
| 1-a-83 | 25 | 25 | | | | | | |
| 2-a-1 | 10 | 10 | 20 | 20 | 20 | 20 | 20 | 20 |
| (n = 6) | | | | | | | | |
| 1-b-1 | 10 | 10 | | | | | | |
| (m11 = 6, n11 = 0) | | | | | | | | |
| 2-a-31 | | | | | | | | 10 |
| 3-a-7 | | | 10 | | | | | |
| 1-b-27 | | | | 10 | | | | |
| (m11 = 6, n11 = 2) | | | | | | | | |
| 1-b-1 | | | | | 10 | | | |
| (m11 = 6, n11 = 0) | | | | | | | | |
| 2-b-1 | | | | | | 10 | | |
| (m = n = 3) | | | | | | | | |
| 2-b-1 | | | | | | | 10 | |
| (m = n = 4) | | | | | | | | |
| Irg907 | 3 | 3 | 3 | 3 | 3 | 3 | 3 | 3 |
| MEHQ | 0.1 | 0.1 | 0.1 | 0.1 | 0.1 | 0.1 | 0.1 | 0.1 |
| BYK-322 | 0.075 | | 0.075 | | | | | |
| BYK-323 | | 0.075 | | 0.075 | | | | |
| BYK-320 | | | | | 0.1 | | | |
| Glide 420 | | | | | | 0.1 | | |
| 56 ADDITIVE | | | | | | | 0.075 | |
| Glide B1484 | | | | | | | | 0.1 |
| CPN | 400 | 400 | 400 | 400 | 400 | 400 | 400 | 400 |
| Tni (° C.) | 109 | 109 | 103 | 110 | 104 | 109 | 109 | 120 or |
| | | | | | | | | higher |
| Viscosity | 900 | 900 | 2,100 | 400 | 300 | 600 | 600 | 2,200 |
| (80° C.) Pa · s | | | | | | | | |

TABLE 6

| | Examples | | | | | | | |
|---|---|---|---|---|---|---|---|---|
| | 41 | 42 | 43 | 44 | 45 | 46 | 47 | 48 |
| Polymerizable | (41) | (42) | (43) | (44) | (45) | (46) | (47) | (48) |
| Composition | | | | | | | | |
| 1-a-5 | 30 | | | 40 | | | | |
| 1-a-6 | 40 | | | 40 | 40 | 40 | 50 | 50 |
| 1-a-2 | | | | | 40 | | 30 | |
| 1-a-83 | | | | | | 40 | | 30 |
| 2-a-1 | 20 | | | 10 | 20 | 20 | 5 | 5 |
| (n = 6) | | | | | | | | |
| 2-a-31 | | 100 | | | | | | |
| 2-a-40 | 10 | | 100 | | | | | |
| 2-a-28 | | | | 10 | | | 15 | 15 |
| Irg907 | 3 | 3 | 3 | 3 | 3 | 3 | 3 | 3 |
| MEHQ | 0.1 | 0.1 | 0.1 | 0.1 | 0.1 | 0.1 | 0.1 | 0.1 |
| BYK-322 | | 0.075 | | 0.1 | 0.15 | 0.1 | | |
| BYK-323 | | | 0.075 | | | | | |
| KP-326 | 0.1 | | | | | | | |
| Tego Flow Z | | | | | | | 0.15 | |
| FS460 | | | | | | | | |
| BYK-354 | | | | | | | | 0.075 |
| CLF | | 400 | | | | | | |
| TCE | | | 400 | | | | | |
| CPN | 400 | | | | | | | |
| TOLUENE | | | | 400 | 400 | 400 | 400 | 400 |
| Tni (° C.) | 120 or | 120 or | 120 or | 111 | 105 | 106 | 112 | 111 |
| | higher | higher | higher | | | | | |
| Viscosity | 2,800 | 9,000 | 13,000 | 1,600 | 1,400 | 1,500 | 1,600 | 1,600 |
| (80° C.) Pa · s | | | | | | | | |

TABLE 7

| | Examples | | | | | | | |
|---|---|---|---|---|---|---|---|---|
| | 49 | 50 | 51 | 52 | 53 | 54 | 55 | 56 |
| Polymerizable | (49) | (50) | (51) | (52) | (53) | (54) | (55) | (56) |
| Composition | | | | | | | | |
| 1-a-6 | 30 | 40 | 40 | 40 | 40 | 40 | 40 | 50 |
| 1-a-2 | 30 | 30 | | | | | | 25 |
| 1-a-83 | | | 30 | 30 | 30 | 30 | 30 | |
| 2-a-1 | 25 | 20 | 20 | 20 | 20 | 20 | 20 | 25 |
| (n = 6) | | | | | | | | |
| 1-b-1 | | 10 | | | | | | |
| (m11 = 6, n11 = 0) | | | | | | | | |
| 2-a-28 | 15 | | | | | | | |
| 3-a-7 | | | 10 | | | | | |
| 1-b-27 | | | | 10 | | | | |
| (m11 = 6, n11 = 2) | | | | | | | | |
| 1-b-1 | | | | | 10 | | | |
| (m11 = 6, n11 = 0) | | | | | | | | |
| 2-b-1 | | | | | | 10 | | |
| (m = n = 3) | | | | | | | | |
| 2-b-1 | | | | | | | 10 | |
| (m = n = 4) | | | | | | | | |
| 2-a-11 | | | | | | | | |
| (n = 6) | | | | | | | | |
| Irg907 | 3 | 3 | 3 | 3 | 3 | 3 | 3 | 3 |
| MEHQ | 0.1 | 0.1 | 0.1 | 0.1 | 0.1 | 0.1 | 0.1 | 0.1 |
| BYK-322 | | | | 0.1 | | | | 0.075 |
| BYK-323 | | | | | 0.075 | | | |
| BYK-320 | 0.1 | | | | | 0.15 | | |
| Glide 420 | | 0.1 | | | | | 0.075 | |
| 56 ADDITIVE | | | 0.1 | | | | | |
| TOLUENE | 400 | 400 | 400 | 400 | 400 | 400 | 400 | 200 |
| MIBK | | | | | | | | 200 |
| Tni (° C.) | 111 | 106 | 104 | 108 | 110 | 111 | 111 | 106 |
| Viscosity | 2,000 | 1,800 | 2,100 | 1,800 | 1,700 | 1,900 | 2,000 | 1,800 |
| (80° C.) Pa · s | | | | | | | | |

TABLE 8

| | Examples | | | | | | | |
|---|---|---|---|---|---|---|---|---|
| | 57 | 58 | 59 | 60 | 61 | 62 | 63 | 64 |
| Polymerizable | (57) | (58) | (59) | (60) | (61) | (62) | (63) | (64) |
| Composition | | | | | | | | |
| 1-a-5 | 24 | 24 | 24 | | | | | |
| 1-a-6 | 56 | 56 | 56 | | | | | |
| 1-a-89 | | | | 40 | 40 | 40 | 40 | 40 |
| 2-a-1 | 10 | 10 | 10 | 20 | 20 | 20 | 20 | 20 |
| (n = 6) | | | | | | | | |
| 1-b-1 | 10 | 10 | 10 | | | | | |
| (m11 = 6, n11 = 0) | | | | | | | | |
| 2-a-11 | | | | 40 | 40 | 40 | 40 | 40 |
| (n = 6) | | | | | | | | |
| Irg907 | 3 | 3 | 3 | 6 | 6 | 6 | 6 | 6 |
| MEHQ | 0.1 | 0.1 | 0.1 | 0.1 | 0.1 | 0.1 | 0.1 | 0.1 |
| BYK-322 | 0.075 | | | 0.1 | | | | |
| BYK-323 | | 0.075 | | | 0.075 | | | |
| Glide 420 | | | 0.1 | | | | 0.1 | |
| 56 ADDITIVE | | | | | | | | 0.075 |
| BYK-354 | | | | | | 0.1 | | |
| TOLUENE | 200 | 300 | 200 | 400 | 400 | 400 | 400 | 400 |
| MIBK | 200 | 100 | 200 | | | | | |
| Tni (° C.) | 105 | 105 | 105 | 120 or | 120 or | 120 or | 120 or | 120 or |
| | | | | higher | higher | higher | higher | higher |
| Viscosity | 1,500 | 1,500 | 1,500 | 6,000 | 6,000 | 6,000 | 6,000 | 6,000 |
| (80° C.) Pa · s | | | | | | | | |

TABLE 9

| | Examples | | |
|---|---|---|---|
| | 65 | 66 | 67 |
| Polymerizable | (65) | (66) | (67) |
| Composition | | | |
| 1-a-89 | 40 | 40 | 40 |
| 2-a-1 | 20 | 20 | 20 |
| (n = 6) | | | |
| 2-a-11 | 40 | 40 | 40 |
| (n = 6) | | | |
| Irg907 | 6 | 6 | 6 |
| MEHQ | 0.1 | 0.1 | 0.1 |
| Glide B1484 | 0.1 | | |
| KP-326 | | 0.1 | |
| Tego Flow Z | | | 0.1 |
| FS460 | | | |
| TOLUENE | 400 | 400 | 400 |
| Tni (° C.) | 120 or | 120 or | 120 or |
| | higher | higher | higher |
| Viscosity | 6,000 | 6,000 | 6,000 |
| (80° C.) Pa · s | | | |

TABLE 10

| | Comparative Examples | | | | | | | |
|---|---|---|---|---|---|---|---|---|
| | 1 | 2 | 3 | 4 | 5 | 6 | 7 | 8 |
| Compositions | (101) | (102) | (103) | (104) | (105) | (106) | (107) | (108) |
| 1-a-5 | 24 | 24 | 24 | 24 | 24 | 40 | 40 | 40 |
| 1-a-6 | 56 | 56 | 56 | 56 | 56 | 40 | 40 | 40 |
| 1-a-2 | | | | | | 10 | 10 | 10 |
| 2-a-1 | 10 | 10 | 10 | 10 | 10 | | | |
| (n = 6) | | | | | | | | |
| 2-a-1 | 10 | 10 | 10 | 10 | 10 | | | |
| (n = 3) | | | | | | | | |
| 2-a-28 | | | | | | 10 | 10 | 10 |
| Irg907 | 3 | 3 | 3 | 3 | 3 | 3 | 3 | 3 |
| MEHQ | 0.1 | 0.1 | 0.1 | 0.1 | 0.1 | 0.1 | 0.1 | 0.1 |
| BYK-361N | 0.2 | | | | | 0.3 | | |
| BYK-333 | | 0.2 | | | | | 0.3 | |
| BYK-370 | | | 0.2 | | | | | 0.3 |
| TEGO GLIDE | | | | 0.2 | | | | |
| 432 | | | | | | | | |
| EFKA-3035 | | | | | 0.2 | | | |
| CPN | 400 | 400 | 400 | 400 | 400 | | | |
| MEK | | | | | | 400 | 400 | 400 |
| Tni (° C.) | 105 | 105 | 105 | 105 | 105 | 109 | 109 | 109 |
| Viscosity | 1,500 | 1,500 | 1,500 | 1,500 | 1,500 | 1,100 | 1,100 | 1,100 |
| (80° C.) Pa · s | | | | | | | | |

TABLE 11

| | Comparative Examples | | | | | | | |
|---|---|---|---|---|---|---|---|---|
| | 9 | 10 | 11 | 12 | 13 | 14 | 15 | 16 |
| Compositions | (109) | (110) | (111) | (112) | (113) | (114) | (115) | (116) |
| 1-a-5 | 40 | 40 | | | | | | |
| 1-a-6 | 40 | 40 | | | | | | |
| 1-a-2 | 10 | 10 | | | | | | |
| 1-a-89 | | | 40 | 40 | | | | |
| 2-a-1 | | | 20 | 20 | | | | |
| (n = 6) | | | | | | | | |
| 2-a-28 | 10 | 10 | | | | | | |
| 1-b-27 | | | | | | | 30 | 30 |
| (m11 = 6, n11 = 2) | | | | | | | | |
| 2-b-1 | | | | | 50 | 50 | 35 | 35 |
| (m = n = 3) | | | | | | | | |
| 2-b-1 | | | | | 50 | 50 | 35 | 35 |
| (m = n = 4) | | | | | | | | |
| 2-a-11 | | | 40 | 40 | | | | |
| (n = 6) | | | | | | | | |
| Irg907 | 3 | 3 | 6 | 6 | 3 | 3 | 3 | 3 |
| MEHQ | 0.1 | 0.1 | 0.1 | 0.1 | 0.1 | 0.1 | 0.1 | 0.1 |
| BYK-361N | | | 0.3 | | | | | |
| BYK-333 | | | | 0.3 | | | | |
| TEGO GLIDE | 0.3 | | | | | | | |
| 432 | | | | | | | | |
| EFKA-3035 | | 0.3 | | | | | | |
| BYK-322 | | | | | 0.075 | | | |
| BYK-323 | | | | | | 0.075 | | |
| Glide 420 | | | | | | | 0.1 | |
| 56 ADDITIVE | | | | | | | | 0.075 |
| CPN | | | | | 400 | 400 | | |
| MEK | 400 | 400 | 400 | 400 | | | | |
| MIBK | | | | | | | 400 | 400 |
| Tni (° C.) | 109 | 109 | 120 or | 120 or | 111 | 111 | 113 | 113 |
| | | | higher | higher | | | | |
| Viscosity (80° C.) | 1,100 | 1,100 | 6,000 | 6,000 | 0.160 | 0.160 | 0.130 | 0.130 |
| Pa · s | | | | | | | | |

TABLE 12

| | Examples | | | | | | | |
|---|---|---|---|---|---|---|---|---|
| | 140 | 141 | 142 | 143 | 144 | 145 | 146 | 147 |
| Polymerizable | (68) | (69) | (70) | (71) | (72) | (73) | (74) | (75) |
| compositions | | | | | | | | |
| 1-a-92 | 15 | | | | | | | |
| 1-a-93 | | | | | 5 | 5 | | |
| 2-a-47 | | 90 | 45 | | | | | |
| (m = n = 6) | | | | | | | | |
| 2-a-48 | 80 | | | | | | | |
| (m = n = 6) | | | | | | | | |
| 2-a-49 | | | 45 | | | | | |
| (m = n = 6) | | | | | | | | |
| 2-a-52 | | | | 90 | | | 50 | 50 |
| (m = n = 6) | | | | | | | | |
| 2-a-53 | | | | | 90 | | 45 | |
| (m = n = 6) | | | | | | | | |
| 2-a-69 | | | | | | 90 | | 45 |
| (m = n = 6) | | | | | | | | |
| 1-b-27 | | | | 10 | | | | |
| (m11 = 6, n11 = 2) | | | | | | | | |
| 1-b-1 | | 10 | | | | 5 | 5 | |
| (m11 = 6, n11 = 0) | | | | | | | | |
| 2-b-1 | 5 | | | | 5 | | | 5 |
| (m = n = 3) | | | | | | | | |
| 2-b-1 | | | 10 | | | | | |
| (m = n = 4) | | | | | | | | |
| Irg907 | 5 | 5 | 5 | 5 | 5 | 5 | 5 | 5 |
| MEHQ | 0.1 | 0.1 | 0.1 | 0.1 | 0.1 | 0.1 | 0.1 | 0.1 |
| BYK-322 | 0.075 | | | | | | | |
| BYK-323 | | 0.075 | | | | | | |
| BYK-320 | | | 0.1 | | | | | |
| KP-326 | | | | | | | 0.1 | 0.1 |
| Tego Flow Z | | | | | 0.15 | 0.15 | | |
| FS460 | | | | | | | | |
| BYK-354 | | | | 0.1 | | | | |
| TOLUENE | 200 | 300 | 200 | 400 | 400 | 400 | 400 | 400 |
| MIBK | 200 | 100 | 200 | | | | | |
| Tni (° C.) | 92 | 102 | 99 | 105 | 101 | 101 | 93 | 95 |
| Viscosity | 4,000 | 6,000 | 6,000 | 6,000 | 6,500 | 5,500 | 5,000 | 5,000 |
| (80° C.) Pa · s | | | | | | | | |

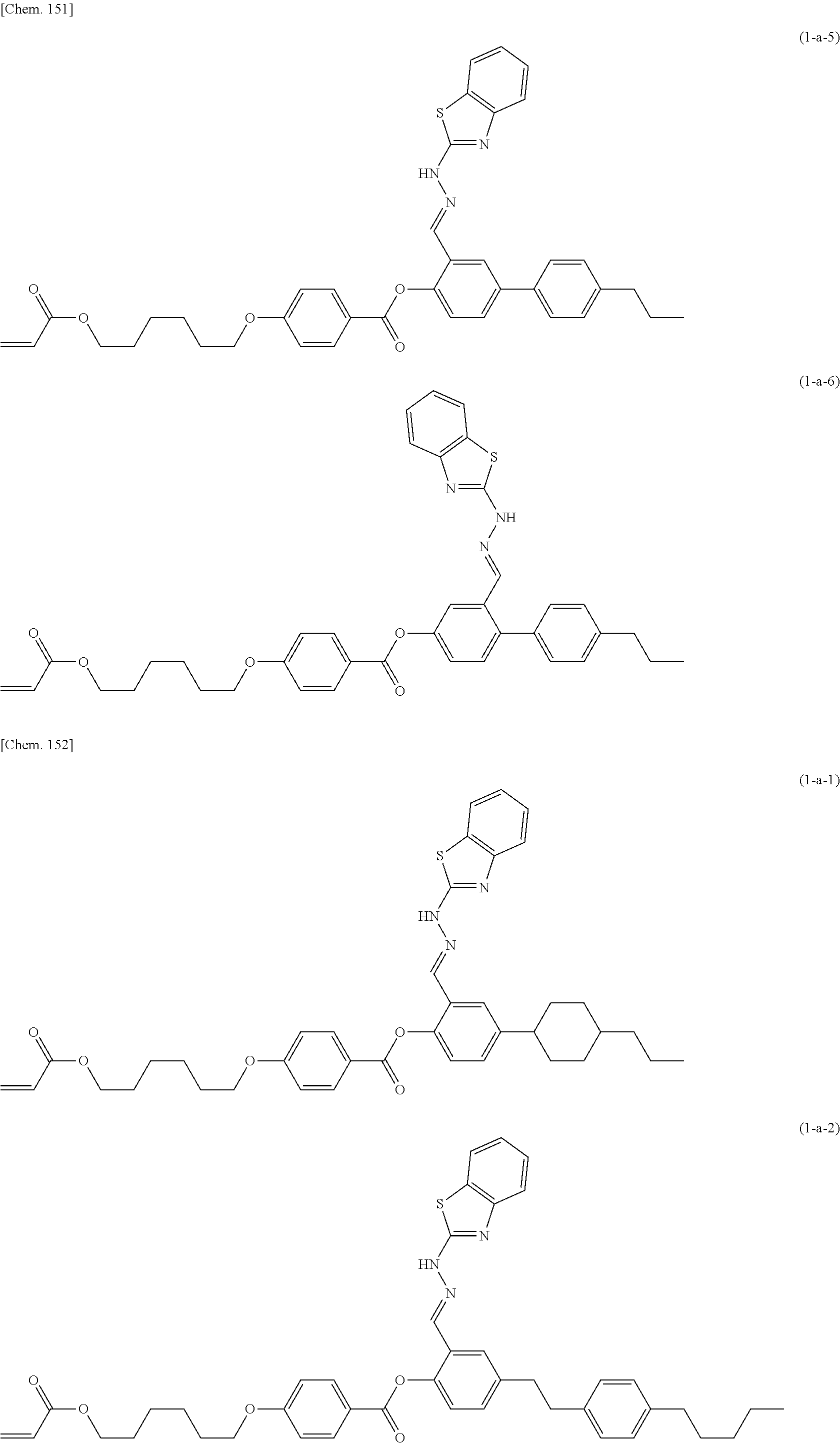

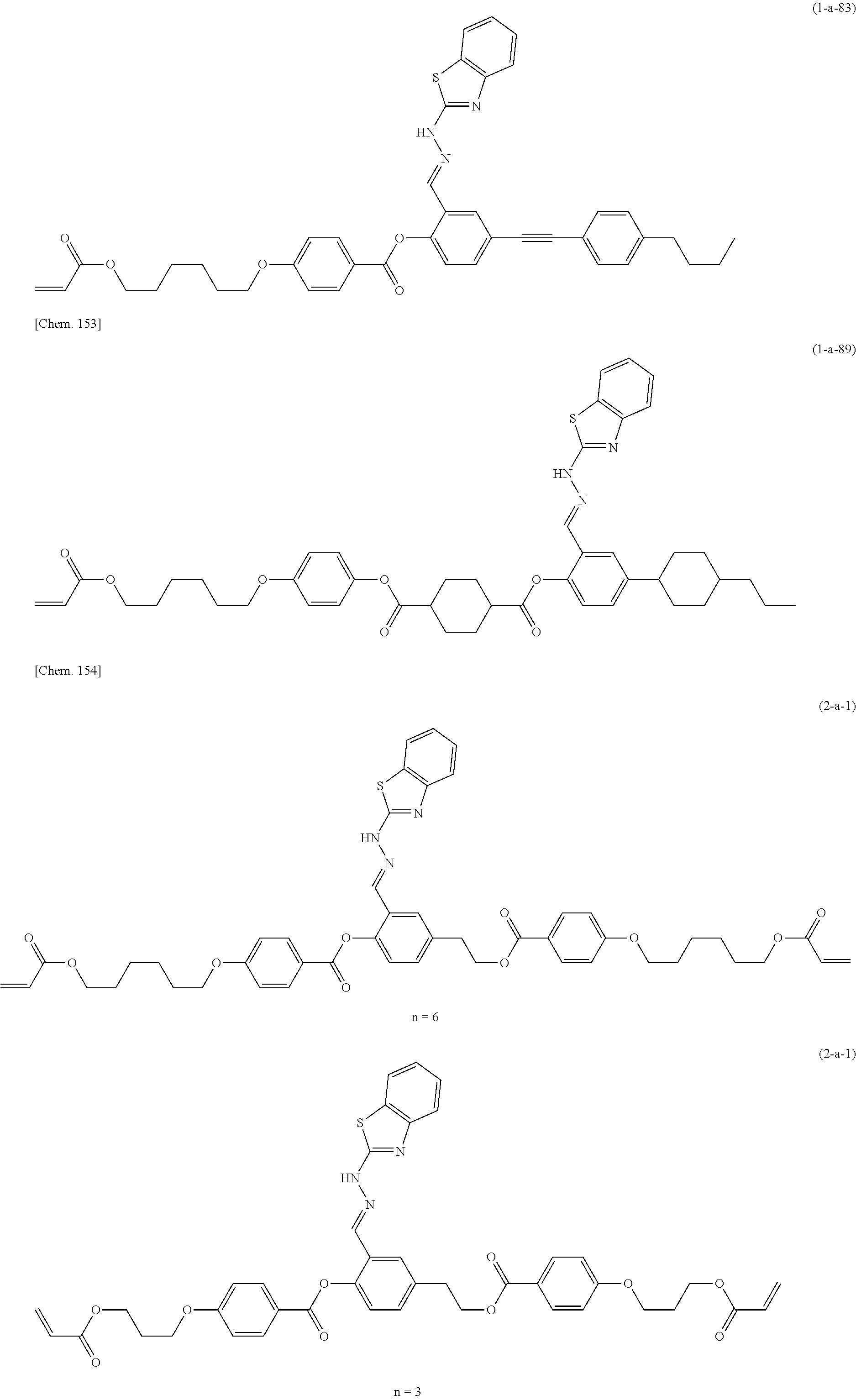

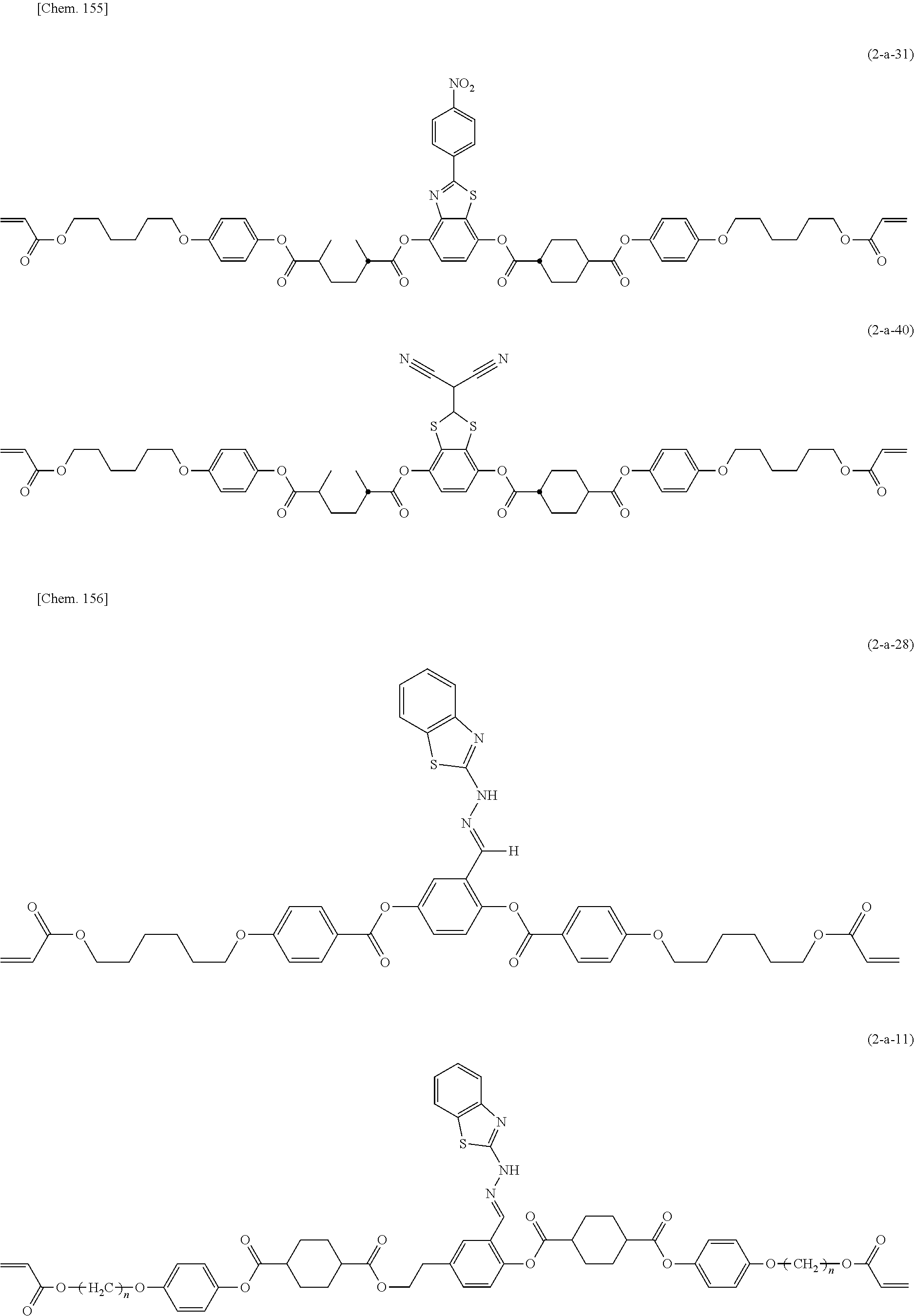

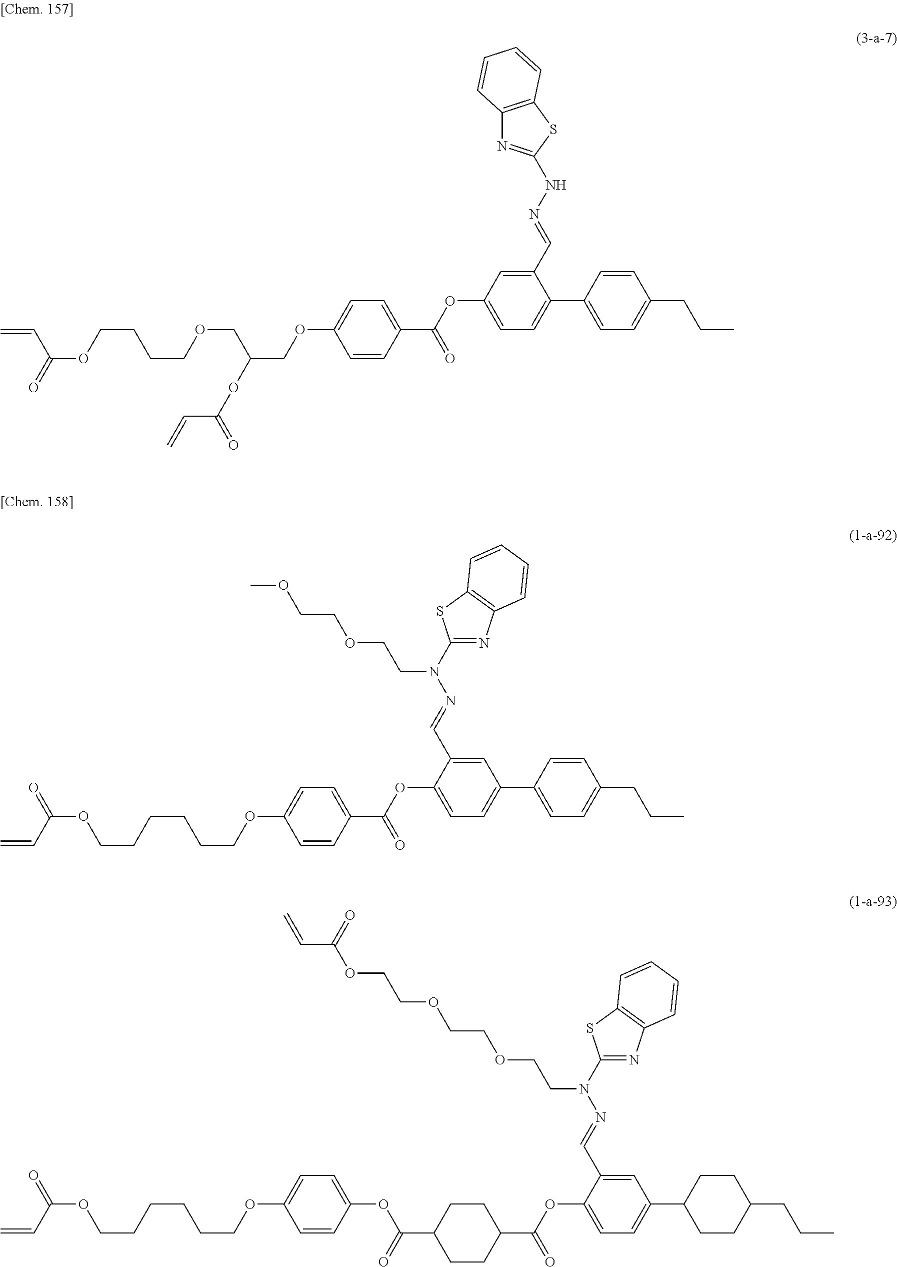

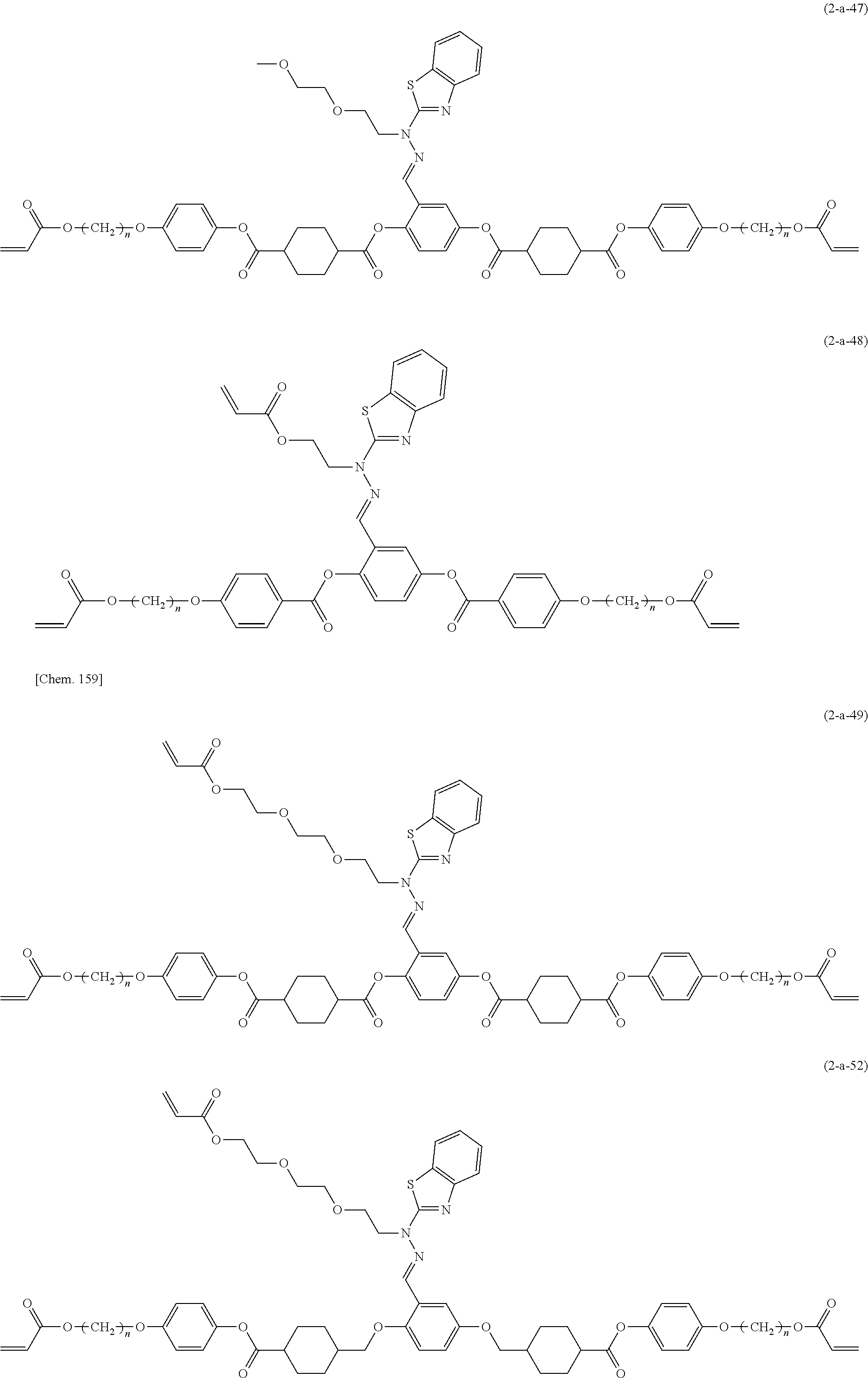

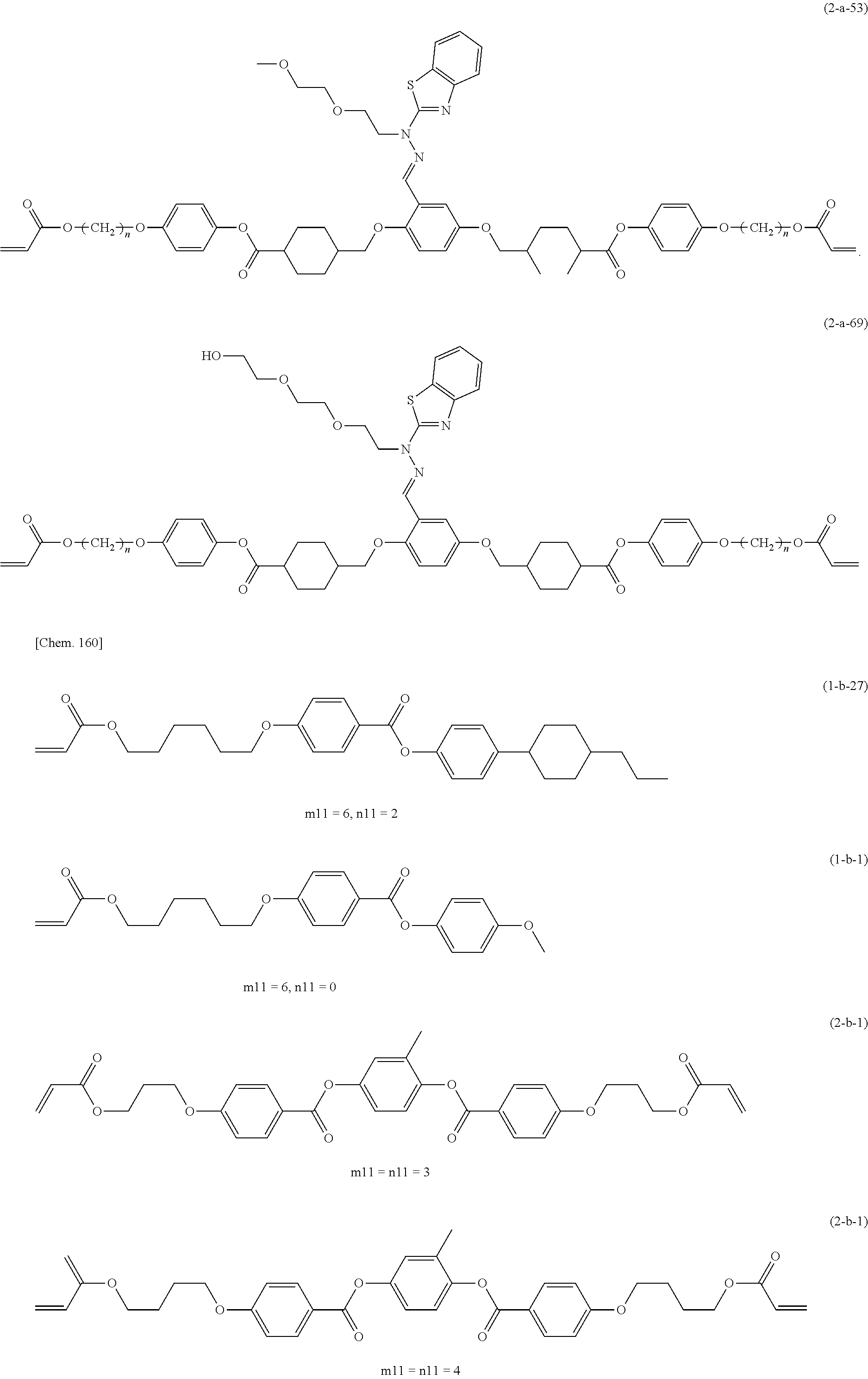

TABLE 13

| | | Weight average |
|---|---|---|
| Product name | Type | molecular weight |
| BYK-322 | Silicone | 10,230 |
| BYK-323 | Silicone | 20,952 |
| BYK-320 | Silicone | 20,728 |
| Glide 420 | Silicone | 14,007 |
| 56 ADDITIVE | Silicone | 35,521 |
| Glide B1484 | Silicone | 7,199 |
| KP-326 | Silicone | 5,450 |
| TEGO Flow ZFS460 | Acrylic | 11,341 |
| BYK-354 | Acrylic | 113,974 |
| BYK-361N | Acrylic | 4,753 |
| BYK-333 | Silicone | 4,621 |
| BYK-370 | Silicone | 3,429 |
| TEGO GLIDE 432 | Silicone | 4,288 |
| EFKA-3035 | Silicone | 3,145 |

Chloroform (CLF)

1,1,2-trichloroethane (TCE)

N-methylpyrrolidone (NMP)

Cyclopentanone (CPN)

Methyl ethyl ketone (MEK)

Methyl isobutyl ketone (MIBK)

Re(450 nm)/Re(550 nm)'s of the compounds represented by the Formula (1-a-5), Formula (1-a-6), Formula (1-a-1), Formula (1-a-2), Formula (1-a-83), Formula (1-a-89), Formula (2-a-1) where n is 6, Formula (2-a-1) where n is 3, Formula (2-a-31), Formula (2-a-40), Formula (2-a-28), Formula (2-a-11), and Formula (3-a-7) are 0.881, 0.784, 0.716, 0.773, 0.967, 0.664, 0.988, 0.802, 0.900, 0.832, 0.845, 0.806, and 0.850, respectively. Further, Re(450 nm)/Re(550 nm)'s of the compounds represented by the Formula (1-b-27) where m11 is 6 and n11 is 2, Formula (2-b-1) where m11 and n11 are 3, and Formula (2-b-2) where m11 and n11 are 4 are 1.089, 1.104, and 1.106, respectively. Re(450 nm)/Re (550 nm)'s of the compounds represented by the Formula (1-a-92), Formula (1-a-93), Formula (2-a-47), Formula (2-a-48), Formula (2-a-49), Formula (2-a-52), Formula (2-a-53), and Formula (2-a-69) are 0.83, 0.85, 0.80, 0.82, 0.81, 0.75, 0.82, and 0.79, respectively.

(Solubility Evaluation)

With respect to Examples 1 to 66 and Comparative Examples 1 to 16, the solubility was evaluated as follows.

A: After the preparation, the state of the polymerizable composition of being transparent and uniform was able to be visually confirmed.

B: The state of the polymerizable composition of being transparent and uniform was able to be visually confirmed when the composition was heated and stirred, but precipitation of the compound was confirmed when the temperature was returned to room temperature.

C: The compound was not able to be uniformly dissolved even when heated and stirred.

(Storage Stability Evaluation)

With respect to each of the polymerizable compositions of Examples 1 to 50 and Comparative Examples 1 to 5, the states of the polymerizable composition after the polymerizable composition was allowed to stand for one week at room temperature were visually observed. The evaluation of the storage stability was performed based on the following evaluation criteria.

A: The state of being transparent and uniform was maintained even after the composition was allowed to stand at room temperature for 5 days.

B: The state of being transparent and uniform was maintained even after the composition was allowed to stand at room temperature for 2 days.

C: The precipitation of the compound was confirmed after the composition was allowed to stand at room temperature for 1 hour.

The obtained results are shown in the following tables.

TABLE 14

| | Polymerizable | | Storage |
|---|---|---|---|
| | composition | Solubility | stability |
| Example 1 | (1) | B | A |
| Example 2 | (2) | B | A |
| Example 3 | (3) | B | A |
| Example 4 | (4) | B | A |
| Example 5 | (5) | B | A |
| Example 6 | (6) | B | A |
| Example 7 | (7) | B | A |
| Example 8 | (8) | B | A |
| Example 9 | (9) | B | A |
| Example 10 | (10) | B | A |
| Example 11 | (11) | B | A |
| Example 12 | (12) | B | A |
| Example 13 | (13) | B | A |
| Example 14 | (14) | B | A |
| Example 15 | (15) | B | A |
| Example 16 | (16) | B | A |
| Example 17 | (17) | B | A |
| Example 18 | (18) | B | A |
| Example 19 | (19) | B | A |

TABLE 15

| | Polymerizable | | Storage |
|---|---|---|---|
| | composition | Solubility | stability |
| Example 20 | (20) | B | A |
| Example 21 | (21) | B | A |
| Example 22 | (22) | B | A |
| Example 23 | (23) | B | B |
| Example 24 | (24) | B | B |
| Example 25 | (25) | B | B |
| Example 26 | (26) | B | A |
| Example 27 | (27) | B | A |
| Example 28 | (28) | B | A |
| Example 29 | (29) | B | A |
| Example 30 | (30) | B | A |
| Example 31 | (31) | B | A |
| Example 32 | (32) | B | A |
| Example 33 | (33) | B | A |
| Example 34 | (34) | B | A |
| Example 35 | (35) | B | A |
| Example 36 | (36) | B | A |
| Example 37 | (37) | B | A |
| Example 38 | (38) | B | A |
| Example 39 | (39) | B | A |
| Example 40 | (40) | B | B |

TABLE 16

| | Polymerizable | | Storage |
|---|---|---|---|
| | composition | Solubility | stability |
| Example 41 | (41) | B | B |
| Example 42 | (42) | B | B |
| Example 43 | (43) | B | B |
| Example 44 | (44) | B | A |
| Example 45 | (45) | B | A |
| Example 46 | (46) | B | A |
| Example 47 | (47) | B | A |
| Example 48 | (48) | B | A |
| Example 49 | (49) | B | A |
| Example 50 | (50) | B | A |
| Example 51 | (51) | B | A |
| Example 52 | (52) | B | A |
| Example 53 | (53) | B | A |
| Example 54 | (54) | B | A |
| Example 55 | (55) | B | A |
| Example 56 | (56) | B | A |
| Example 57 | (57) | B | A |
| Example 58 | (58) | B | A |
| Example 59 | (59) | B | A |
| Example 60 | (60) | B | A |
| Example 61 | (61) | B | A |
| Example 62 | (62) | B | A |
| Example 63 | (63) | B | A |
| Example 64 | (64) | B | A |
| Example 65 | (65) | B | A |
| Example 66 | (66) | B | A |
| Example 67 | (67) | B | A |

TABLE 17

| | Polymerizable | | Storage |
|---|---|---|---|
| | composition | Solubility | stability |
| Example 140 | (68) | B | B |
| Example 141 | (69) | B | B |
| Example 142 | (70) | B | B |
| Example 143 | (71) | B | A |
| Example 144 | (72) | B | A |
| Example 145 | (73) | B | A |
| Example 146 | (74) | B | A |
| Example 147 | (75) | B | A |

TABLE 18

| | Polymerizable | | Storage |
|---|---|---|---|
| | composition | Solubility | stability |
| Comparative | (101) | B | A |
| Example 1 | | | |
| Comparative | (102) | B | A |
| Example 2 | | | |
| Comparative | (103) | B | A |
| Example 3 | | | |
| Comparative | (104) | B | A |
| Example 4 | | | |
| Comparative | (105) | B | A |
| Example 5 | | | |
| Comparative | (106) | B | A |
| Example 6 | | | |
| Comparative | (107) | B | A |
| Example 7 | | | |
| Comparative | (108) | B | A |
| Example 8 | | | |
| Comparative | (109) | B | A |
| Example 9 | | | |
| Comparative | (110) | B | A |
| Example 10 | | | |
| Comparative | (111) | B | A |
| Example 11 | | | |
| Comparative | (112) | B | A |
| Example 12 | | | |
| Comparative | (113) | B | A |
| Example 13 | | | |
| Comparative | (114) | B | A |
| Example 14 | | | |
| Comparative | (115) | B | A |
| Example 15 | | | |
| Comparative | (116) | B | A |
| Example 16 | | | |

### Example 68

A glass substrate having a thickness of 0.7 mm was coated with a polyimide solution for an alignment film according to a spin coating method, dried at 100° C. for 5 minutes, and then baked at 200° C. for 60 minutes to obtain a coated film. Thereafter, the obtained coated film was subjected to a rubbing treatment. The rubbing treatment was performed using a commercially available rubbing device.

The rubbed base material was coated with the polymerizable composition (1) of the present invention according to a spin coating method and then dried at 80° C. or 100° C. for 2 minutes. The obtained coated film was cooled to room temperature and irradiated with ultraviolet rays at an intensity of 30 mW/cm² for 30 seconds using a high-pressure mercury lamp, thereby obtaining an optically anisotropic body. On the obtained optically anisotropic body, alignment property evaluation, phase difference ratio, leveling property evaluation, and offset property evaluation were performed according to the following criteria.

(Alignment Evaluation)

A: No defects were found through visual observation and there were no defects found by observation using a polarizing microscope.

B: No defects were found through visual observation, but non-aligned portions were partly present when the observation was made using a polarizing microscope.

C: No defects were found through visual observation, but non-aligned portions were present in the entire composition when the observation was made using a polarizing microscope.

D: Partial defects were found through visual observation, and non-aligned portions were present in the entire composition when the observation was made using a polarizing microscope.

(Phase Difference Ratio)

When the phase difference of the obtained optically anisotropic body prepared as a sample for evaluation was measured using a retardation film and optical material inspection device RETS-100 (manufactured by Otsuka Electronics Co., Ltd.), the in-plane phase difference (Re(550)) at a wavelength of 550 nm was 130 nm. Further, the ratio Re(450)/Re(550) of the in-plane phase difference (Re(450)) to the in-plane phase difference Re(550) at a wavelength of 450 nm was 0.854 and a retardation film with excellent uniformity was obtained.

(Cissing Evaluation)

The degree of cissing of the optically anisotropic body prepared as a sample for evaluation was visually observed with a crossed Nicol.

A: No cissing defects were observed on the coating film surface.

B: Extremely few amount of cissing defects were observed on the coating film surface.

C: Small amount of cissing defects were observed on the coating film surface.

D: Large amount of cissing defects were observed on the coating film surface.

(Offset Property Evaluation)

TAC film (B) was superimposed on the polymerizable composition surface (A) of the optically anisotropic body prepared as a sample for evaluation and was held at 80° C. for 30 minutes under a load of 40 g/cm², and then cooled to room temperature while being superimposed. Thereafter, the film (B) was peeled off and visually observed whether or not the surfactant in the polymerizable composition was transferred onto the film (B). In the case where the surfactant has been transferred onto the film (B), it is observed that the part to which the surfactant has been transferred is clouded.

A: No clouded part was observed.

B: Extremely few amount of clouded parts were observed.

C: Small amount of clouded parts were observed.

D: Clouded parts were observed in almost the entire area.

### Examples 69 to 134 and Comparative Examples 17 to 32

Under the same conditions as in Example 68 except that the polymerizable compositions used were changed to the polymerizable compositions (1) to (67) and the comparative polymerizable compositions (101) to (116), respectively, the optically anisotrpic bodies of Examples 69 to 134, and Comparative Examples 17 to 32 were obtained. The obtained results are shown in the following table.

TABLE 19

| | | | Drying temperature 80° C. | | | Drying temperature 100° C. | | |
|---|---|---|---|---|---|---|---|---|
| | Polymerizable | Re(450)/ | Alignment | Cissing | Offset | Alignment | Cissing | Offset |
| Examples | composition | Re(550) | Evaluation | Evaluation | Evaluation | Evaluation | Evaluation | Evaluation |
| 68 | (1) | 0.854 | A | A | B | A | A | B |
| 69 | (2) | 0.855 | A | A | B | A | A | B |
| 70 | (3) | 0.854 | A | A | B | A | A | B |
| 71 | (4) | 0.858 | A | A | B | A | A | B |
| 72 | (5) | 0.849 | A | B | B | A | B | B |
| 73 | (6) | 0.860 | B | A | B | A | A | A |
| 74 | (7) | 0.857 | B | A | B | B | A | A |
| 75 | (8) | 0.855 | A | A | A | A | A | A |
| 76 | (9) | 0.849 | A | B | A | A | B | A |
| 77 | (10) | 0.849 | A | A | B | A | A | B |
| 78 | (11) | 0.851 | A | A | B | A | A | B |
| 79 | (12) | 0.850 | A | B | B | A | B | B |
| 80 | (13) | 0.850 | B | A | B | A | A | A |
| 81 | (14) | 0.859 | A | A | B | A | A | B |
| 82 | (15) | 0.861 | A | A | B | A | A | B |
| 83 | (16) | 0.860 | A | A | B | A | A | B |
| 84 | (17) | 0.861 | A | A | B | A | A | B |

TABLE 20

| | | | Drying temperature 80° C. | | | Drying temperature 100° C. | | |
|---|---|---|---|---|---|---|---|---|
| | Polymerizable | Re(450)/ | Alignment | Cissing | Offset | Alignment | Cissing | Offset |
| Examples | composition | Re(550) | Evaluation | Evaluation | Evaluation | Evaluation | Evaluation | Evaluation |
| 85 | (18) | 0.861 | A | B | B | A | B | B |
| 86 | (19) | 0.860 | B | A | B | A | A | A |
| 87 | (20) | 0.895 | A | A | B | A | A | B |
| 88 | (21) | 0.898 | A | A | B | A | A | B |
| 89 | (22) | 0.891 | A | A | A | A | A | A |
| 90 | (23) | 0.861 | A | A | B | A | A | B |
| 91 | (24) | 0.862 | A | A | B | A | A | B |
| 92 | (25) | 0.859 | A | A | B | A | A | B |
| 93 | (26) | 0.854 | A | A | B | A | A | B |
| 94 | (27) | 0.847 | A | B | B | A | B | B |
| 95 | (28) | 0.845 | B | A | B | A | A | A |
| 96 | (29) | 0.851 | A | A | B | A | A | B |
| 97 | (30) | 0.856 | A | B | A | A | B | A |
| 98 | (31) | 0.861 | A | A | B | A | A | B |
| 99 | (32) | 0.856 | A | A | B | A | A | B |
| 100 | (33) | 0.861 | A | A | B | A | A | B |

TABLE 21

| | | | Drying temperature 80° C. | | | Drying temperature 100° C. | | |
|---|---|---|---|---|---|---|---|---|
| | Polymerizable | Re(450)/ | Alignment | Cissing | Offset | Alignment | Cissing | Offset |
| Examples | composition | Re(550) | Evaluation | Evaluation | Evaluation | Evaluation | Evaluation | Evaluation |
| 101 | (34) | 0.862 | A | A | B | A | A | B |
| 102 | (35) | 0.892 | A | A | B | A | A | B |
| 103 | (36) | 0.889 | A | A | B | A | A | B |
| 104 | (37) | 0.893 | A | A | B | A | A | B |
| 105 | (38) | 0.895 | A | A | B | A | A | B |
| 106 | (39) | 0.885 | A | B | B | A | B | B |
| 107 | (40) | 0.875 | B | A | B | A | A | A |
| 108 | (41) | 0.871 | B | A | B | B | A | A |
| 109 | (42) | 0.889 | A | A | B | A | A | B |
| 110 | (43) | 0.832 | A | A | B | A | A | B |
| 111 | (44) | 0.842 | A | A | B | A | A | B |
| 112 | (45) | 0.855 | A | A | B | A | A | B |
| 113 | (46) | 0.879 | A | A | B | A | A | B |
| 114 | (47) | 0.862 | A | A | A | A | A | A |
| 115 | (48) | 0.891 | A | B | A | A | B | A |

TABLE 22

| | | | Drying temperature 80° C. | | | Drying temperature 100° C. | | |
|---|---|---|---|---|---|---|---|---|
| | Polymerizable | Re(450)/ | Alignment | Cissing | Offset | Alignment | Cissing | Offset |
| Examples | composition | Re(550) | Evaluation | Evaluation | Evaluation | Evaluation | Evaluation | Evaluation |
| 116 | (49) | 0.876 | A | A | B | A | A | B |
| 117 | (50) | 0.871 | A | A | B | A | A | B |
| 118 | (51) | 0.882 | A | B | B | A | B | B |
| 119 | (52) | 0.902 | A | A | B | A | A | B |
| 120 | (53) | 0.898 | A | A | B | A | A | B |
| 121 | (54) | 0.902 | A | A | B | A | A | B |
| 122 | (55) | 0.905 | A | A | B | A | A | B |
| 123 | (56) | 0.877 | A | A | B | A | A | B |
| 124 | (57) | 0.854 | A | A | B | A | A | B |
| 125 | (58) | 0.855 | A | A | B | A | A | B |
| 126 | (59) | 0.860 | A | A | B | A | A | B |
| 127 | (60) | 0.852 | A | A | B | A | A | B |
| 128 | (61) | 0.851 | A | A | B | A | A | B |
| 129 | (62) | 0.854 | A | B | A | A | B | A |
| 130 | (63) | 0.843 | A | A | B | A | A | B |
| 131 | (64) | 0.849 | A | B | B | A | B | B |
| 132 | (65) | 0.849 | B | A | B | A | A | A |
| 133 | (66) | 0.847 | B | A | B | B | A | A |
| 134 | (67) | 0.851 | A | A | A | A | A | A |

TABLE 23

| | | | Drying temperature 80° C. | | | Drying temperature 100° C. | | |
|---|---|---|---|---|---|---|---|---|
| | Polymerizable | Re(450)/ | Alignment | Cissing | Offset | Alignment | Cissing | Offset |
| Examples | composition | Re(550) | Evaluation | Evaluation | Evaluation | Evaluation | Evaluation | Evaluation |
| 148 | (68) | 0.832 | A | A | B | A | A | B |
| 149 | (69) | 0.845 | A | A | B | A | A | B |
| 150 | (70) | 0.840 | A | A | B | A | A | B |
| 151 | (71) | 0.831 | A | B | A | A | B | A |
| 152 | (72) | 0.825 | A | A | A | A | A | A |
| 153 | (73) | 0.819 | A | A | A | A | A | A |
| 154 | (74) | 0.822 | B | A | B | B | A | A |
| 155 | (75) | 0.823 | B | A | B | B | A | A |

TABLE 24

| | | | Drying temperature 80° C. | | | Drying temperature 100° C. | | |
|---|---|---|---|---|---|---|---|---|
| Comparative | Polymerizable | Re(450)/ | Alignment | Cissing | Offset | Alignment | Cissing | Offset |
| Examples | composition | Re(550) | Evaluation | Evaluation | Evaluation | Evaluation | Evaluation | Evaluation |
| 17 | (101) | 0.856 | D | A | A | D | A | A |
| 18 | (102) | 0.855 | D | A | A | D | A | B |
| 19 | (103) | 0.856 | D | A | A | D | A | B |
| 20 | (104) | 0.851 | D | A | B | D | A | B |
| 21 | (105) | 0.858 | D | A | B | D | A | B |
| 22 | (106) | 0.847 | D | A | A | D | A | A |
| 23 | (107) | 0.849 | D | A | A | D | A | B |
| 24 | (108) | 0.851 | D | A | B | D | A | B |
| 25 | (109) | 0.851 | D | A | B | D | A | B |
| 26 | (110) | 0.849 | D | A | B | D | A | B |
| 27 | (111) | 0.843 | D | A | A | D | A | A |
| 26 | (112) | 0.849 | D | A | A | D | A | B |
| 29 | (113) | 1.105 | A | D | A | A | D | A |
| 30 | (114) | 1.104 | A | D | A | A | D | A |
| 31 | (115) | 1.106 | A | D | B | A | D | B |
| 32 | (116) | 1.106 | A | D | B | A | D | B |

### Example 135

A photo-alignment film PAM-0021 (manufactured by DIC Corporation) was coated on a 40 μm-thick unstretched cycloolefin polymer film “ZEONOR” (manufactured by Zeon Corporation) by a bar coating method and dried at 80° C. for 2 minutes, and irradiated with polarized UV light of 300 mJ/cm². The polymerizable composition (57) of the present invention was coated on the photoalignment film by a bar coating method and dried at 80° C. or 100° C. for 2 minutes. After cooling the obtained coating film to room temperature, ultraviolet light was irradiated at a conveyor speed of 6 m/min using a UV conveyor system (manufactured by GS Yuasa Co., Ltd.) to obtain an optically anisotropic body of Example 133. The alignment evaluation, the phase difference ratio, the leveling property evaluation, and the offset evaluation of the obtained optically anisotropic body were carried out in the same manner as in Example 68.

### Examples 136 to 139 and Comparative Examples 33 to 35

Under the same conditions as in Example 135 except that the polymerizable compositions used were changed to the polymerizable compositions (58), (59), (60), and (67) of the present invention, and the comparative polymerizable compositions (102), (104), and (115), respectively, the optically anisotropic bodies of Examples 136 to 139, and Comparative Examples 33 to 35 were obtained. The alignment evaluation, the phase difference ratio, the leveling property evaluation, and the offset evaluation of the obtained optically anisotropic bodies were carried out in the same manner as in Example 68.

TABLE 25

| | | | Drying temperature 80° C. | | | Drying temperature 100° C. | | |
|---|---|---|---|---|---|---|---|---|
| | Polymerizable | Re(450)/ | Alignment | Cissing | Offset | Alignment | Cissing | Offset |
| Example | composition | Re (550) | Evaluation | Evaluation | Evaluation | Evaluation | Evaluation | Evaluation |
| 135 | (57) | 0.858 | A | A | B | A | A | B |
| 136 | (58) | 0.860 | A | A | B | A | A | B |
| 137 | (59) | 0.853 | A | A | B | A | A | B |
| 138 | (60) | 0.850 | A | A | B | A | A | B |
| 139 | (67) | 0.858 | A | A | A | A | A | A |

TABLE 26

| | | | Drying temperature 80° C. | | | Drying temperature 100° C. | | |
|---|---|---|---|---|---|---|---|---|
| Comparative | Polymerizable | Re(450)/ | Alignment | Cissing | Offset | Alignment | Cissing | Offset |
| Example | composition | Re(550) | Evaluation | Evaluation | Evaluation | Evaluation | Evaluation | Evaluation |
| 33 | (102) | 0.857 | D | A | B | D | A | B |
| 34 | (104) | 0.860 | D | A | B | D | A | B |
| 35 | (115) | 1.106 | A | D | B | A | D | B |

The polymerizable compositions containing a surfactant having a weight average molecular weight of 5,000 or more (Examples 1 to 67) were excellent in solubility and storage stability, and all of the optically anisotropic bodies (Examples 68 to 139) formed from the polymerizable composition (1) to (67) exhibited satisfactory results in all of the alignment property evaluation, the leveling property evaluation, and the offset evaluation, and were excellent in productivity. In contrast, the results of Comparative Examples 1 to 35 shew that when a surfactant having a weight average molecular weight of 5,000 or less or a polymerizable composition which does not satisfy Formula (I) was used, any of alignment property evaluation, leveling property evaluation, and offset evaluation was unsatisfactory, and the polymerizable compositions of comparative examples were inferior to the polymerizable compositions of the present invention.

1. A polymerizable composition comprising:
one or two or more polymerizable compounds (a) which contain one or two or more polymerizable groups and satisfy Formula (I); and
a surfactant (b) having a weight average molecular weight of 5,000 or more:
Re(450 nm)/Re(550 nm)<1.0 (I)
wherein Re(450 nm) represents an in-plane phase difference of the compound containing one polymerizable group at a wavelength of 450 nm in the case where the molecules of the compound are aligned on a substrate such that a longitudinal axis direction of each molecule is aligned substantially horizontally with respect to the substrate, and Re(550 nm) represents an in-plane phase difference of the compound containing one polymerizable group at a wavelength of 550 nm in the case where the molecules of the compound are aligned on a substrate such that a longitudinal axis direction of each molecule is aligned substantially horizontally with respect to the substrate.

2. The polymerizable composition according to claim 1,
which has a viscosity at 80° C. of 10 Pa·s or more.

3. The polymerizable composition according to claim 1, which comprises, as the polymerizable compound (a) which contains one or two or more polymerizable groups and satisfies Formula (I) recited in claim 1, one or two or more polymerizable compounds selected from the group consisting of the liquid crystalline compounds represented by General Formulae (1) to (7): 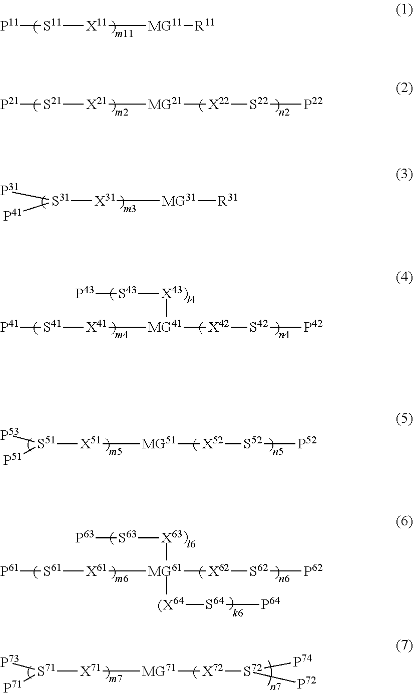
wherein P¹¹ to P⁷⁴ represent a polymerizable group,
S¹¹ to S⁷² represent a spacer group or a single bond, and in the case where plural groups are present with respect to each of S¹¹ to S⁷², these may be the same as or different from each other;
X¹¹ to X⁷² represent —O—, —S—, —OCH₂—, —CH₂O—, —CO—, —COO—, —OCO—, —CO—S—, —S—CO—, —O—CO—O—, —CO—NH—, —NH—CO—, —SCH₂—, —CH₂S—, —CF₂O—, —OCF₂—, —CF₂S—, —SCF₂—, —CH═CH—COO—, —CH═CH—OCO—, —COO—CH═CH—, —OCO—CH═CH—, —COO—CH₂CH₂—, —OCO—CH₂CH₂—, —CH₂CH₂—COO—, —CH₂CH₂—OCO—, —COO—CH₂—, —OCO—CH₂—, —CH₂—COO—, —CH₂—OCO—, —CH═CH—, —N═N—, —CH═N—N═CH—, —CF═CF—, —C≡C—, or a single bond, and in the case where plural groups are present with respect to each of X¹¹ to X⁷², these may be the same as or different from each other, provided that each of P—(S—X)— bonds does not have —O—O—;
MG¹¹ to MG⁷¹ each independently represent formula (a): 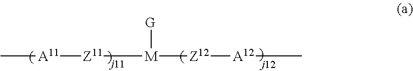
(wherein A¹¹ and A¹² each independently represent a 1,4-phenylene group, a 1,4-cyclohexylene group, a pyridine-2,5-diyl group, a pyrimidine-2,5-diyl group, a naphthalene-2,6-diyl group, a naphthalene-1,4-diyl group, a tetrahydronaphthalene-2,6-diyl group, a decahydronaphthalene-2,6-diyl group, or a 1,3-dioxane-2,5-diyl group, these groups may be unsubstituted or substituted with one or more L¹'s, and in the case where a plural groups are present with respect to each of A¹¹ and A¹²′, these may be the same as or different from each other;
Z¹¹ and Z¹² each independently represent —O—, —S—, —OCH₂—, —CH₂O—, —CH₂CH₂—, —CO—, —COO—, —OCO—, —CO—S—, —S—CO—, —O—CO—O—, —CO—NH—, —NH—CO—, —SCH₂—, —CH₂S—, —CF₂O—, —OCF₂—, —CF₂S—, —SCF₂—, —CH═CH—COO—, —CH═CH—OCO—, —COO—CH═CH—, —OCO—CH═CH—, —COO—CH₂CH₂—, —OCO—CH₂CH₂—, —CH₂CH₂—COO—, —CH₂CH₂—OCO—, —COO—CH₂—, —OCO—CH₂—, —CH₂—COO—, —CH₂—OCO—, —CH═CH—, —N═N—, —CH═N—, —N═CH—, —CH═N—N═CH—, —CF═CF—, —C≡C—, or a single bond, and in the case where plural groups are present with respect to each of Z¹¹ and Z¹², these may be the same as or different from each other;
M represents a group selected from groups represented by Formula (M-1) to Formula (M-11), and these groups may be unsubstituted or substituted with one or more L¹'s: 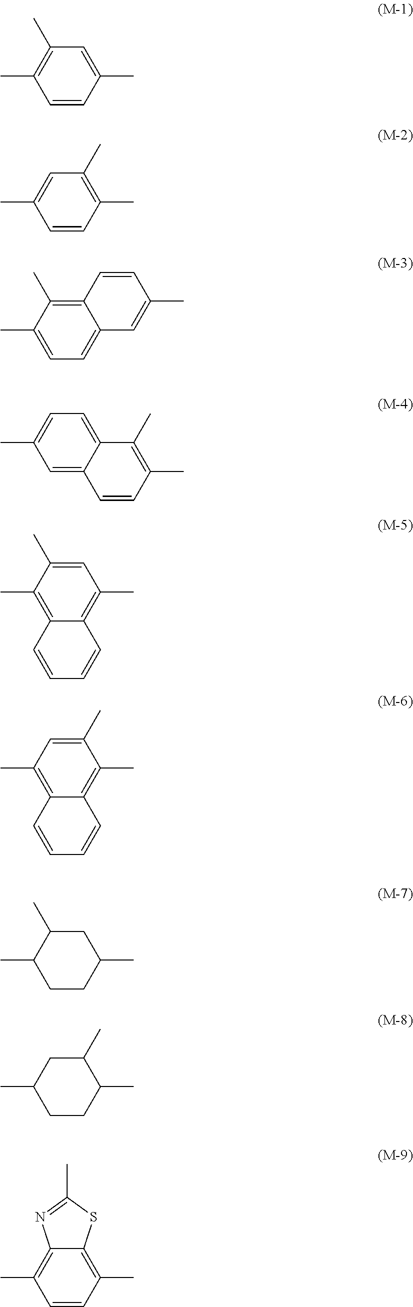 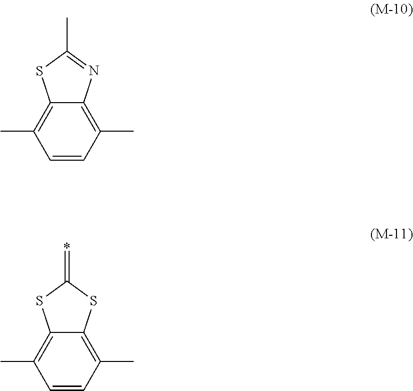
G represents a group selected from groups represented by Formula (G-1) to Formula (G-6): 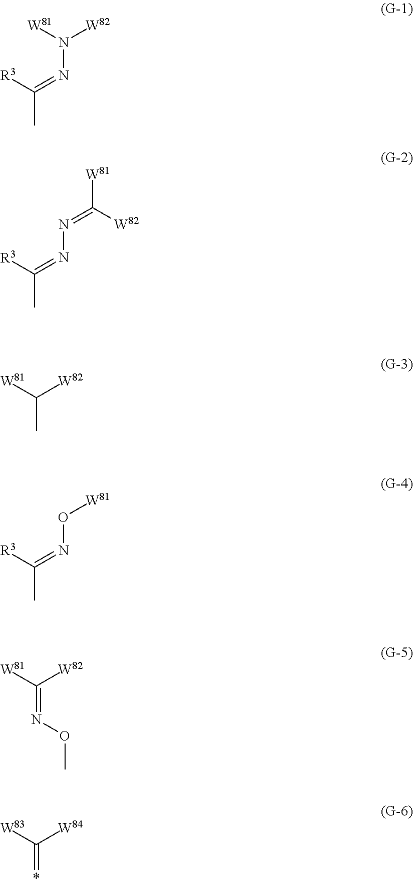
(wherein R³ represents a hydrogen atom or an alkyl group having 1 to 20 carbon atoms, the alkyl group may be linear or branched, one or more of arbitrary hydrogen atoms in the alkyl group may be substituted with a fluorine atom, and one —CH₂— or two or more (—CH₂—)'s which are not adjacent to each other in the alkyl group may be each independently substituted with —O—, —S—, —CO—, —COO—, —OCO—, —CO—S—, —S—CO—, —O—CO—O—, —CO—NH—, —NH—CO—, or —C≡C—;
W⁸¹ represents a group having at least one aromatic group and 5 to 30 carbon atoms and the group may be unsubstituted or substituted with one or more L¹'s;
W⁸² represents a hydrogen atom or an alkyl group having 1 to 20 carbon atoms, the alkyl group may be linear or branched, one or more of arbitrary hydrogen atoms in the alkyl group may be substituted with a fluorine atom and/or —OH, one —CH₂— or two or more (—CH₂—)'s which are not adjacent to each other in the alkyl group may be each independently substituted with —O—, —S—, —CO—, —COO—, —OCO—, —CO—S—, —S—CO—, —O—CO—O—, —CO—NH—, —NH—CO—, —CH═CH—COO—, —CH═CH—OCO—, —COO—CH═CH—, —OCO—CH═CH—, —CH═CH—, —CF═CF—, or —C≡C—, W⁸² may have the same definition as that for W⁸¹, W⁸¹ and W⁸² may be linked to each other to form the same ring structure, or W⁸² may represent a group represented by P⁸—(S⁸—X⁸)ⱼ—, where P⁸ represents a polymerizable group, S⁸ represents a spacer group or a single bond, and in case where a plurality of S⁸'s are present, these may be the same as or different from each other, X⁸ represents —O—, —S—, —OCH₂—, —CH₂O—, —CO—, —COO—, —OCO—, —CO—S—, —S—CO—, —O—CO—O—, —CO—NH—, —NH—CO—, —SCH₂—, —CH₂S—, —CF₂O—, —OCF₂—, —CF₂S—, —SCF₂—, —CH═CH—COO—, —CH═CH—OCO—, —COO—CH═CH—, —OCO—CH═CH—, —COO—CH₂CH₂—, —OCO—CH₂CH₂—, —CH₂CH₂—COO—, —CH₂CH₂—OCO—, —COO—CH₂—, —OCO—CH₂—, —CH₂—COO—, —CH₂—OCO—, —CH═CH—, —N═N—, —CH═N—N═CH—, —CF═CF—, —C≡C—, or a single bond, and in the case where a plurality of X⁸'s are present, these may be the same as or different from each other, provided that P⁸—(S⁸—X⁸)— bonds does not have —O—O—, and j represents an integer of 0 to 10; and
W⁸³ and W^{E4} each independently represent a halogen atom, a cyano group, a hydroxy group, a nitro group, a carboxyl group, a carbamoyloxy group, an amino group, a sulfamoyl group, a group having at least one aromatic group and 5 to 30 carbon atoms, an alkyl group having 1 to 20 carbon atoms, a cycloalkyl group having 3 to 20 carbon atoms, an alkenyl group having 2 to 20 carbon atoms, a cycloalkenyl group having 3 to 20 carbon atoms, an alkoxy group having 1 to 20 carbon atoms, an acyloxy group having 2 to 20 carbon atoms, or an alkylcarbonyloxy group having 2 to 20 carbon atoms, one —CH₂— or two or more (—CH₂—)'s which are not adjacent to each other in the alkyl group, the cycloalkyl group, the alkenyl group, the cycloalkenyl group, the alkoxy group, the acyloxy group, and the alkylcarbonyloxy group may be each independently substituted with —O—, —S—, —CO—, —COO—, —OCO—, —CO—S—, —S—CO—, —O—CO—O—, —CO—NH—, —NH—CO—, or —C≡C—, provided that G represents a group selected from groups represented by Formula (G-1) to Formula (G-5) in the case where M represents a group selected from groups represented by Formula (M-1) to Formula (M-10) and G represents a group represented by Formula (G-6) in the case where M represents a group represented by Formula (M-11));
L¹ represents a fluorine atom, a chlorine atom, a bromine atom, an iodine atom, a pentafluorosulfitranyl group, a nitro group, an isocyano group, an amino group, a hydroxy group, a mercapto group, a methylamino group, a dimethylamino group, a diethylamino group, a diisopropylamino group, a trimethylsilyl group, a dimethylsilyl group, a thioisocyano group, or an alkyl group having 1 to 20 carbon atoms, and the alkyl group may be linear or branched, one or more of arbitrary hydrogen atoms may be substituted with a fluorine atom, one —CH₂— or two or more (—CH₂—)'s which are not adjacent to each other in the alkyl group may be each independently substituted with a group selected from —O—, —S—, —CO—, —COO—, —OCO—, —CO—S—, —S—CO—, —O—CO—O—, —CO—NH—, —NH—CO—, —CH═CH—COO—, —CH═CH—OCO—, —COO—CH═CH—, —OCO—CH═CH—, —CH═CH—, —CF═CF—, or —C≡C—, and in the case where a plurality of L¹'s are present in the compound, these may be the same as or different from each other; and
j11 represents an integer of 1 to 5, and j12 represents an integer of 1 to 5, provided that j11+j12 represents an integer of 2 to 5);
R¹¹ and R³¹ represent a hydrogen atom, a fluorine atom, a chlorine atom, a bromine atom, an iodine atom, a pentafluorosulfuranyl group, a cyano group, a nitro group, an isocyano group, a thioisocyano group, or an alkyl group having 1 to 20 carbon atoms, the alkyl group may be linear or branched, one or more of arbitrary hydrogen atoms in the alkyl group may be substituted with a fluorine atom, and one —CH₂— or two or more (—CH₂—)'s which are not adjacent to each other in the alkyl group may be each independently substituted with —O—, —S—, —CO—, —COO—, —OCO—, —CO—S—, —S—CO—, —O—CO—O—, —CO—NH—, —NH—CO—, or —C≡C—, m11 represents an integer of 0 to 8; and
m2 to m7, n2 to n7, 14 to 16, and k6 each independently represent an integer of 0 to 5.

4. The polymerizable composition according to claim 3,
wherein the polymerizable groups P¹ to P⁷⁴ are represented by any one of General Formulae (P-1) to (P-20):

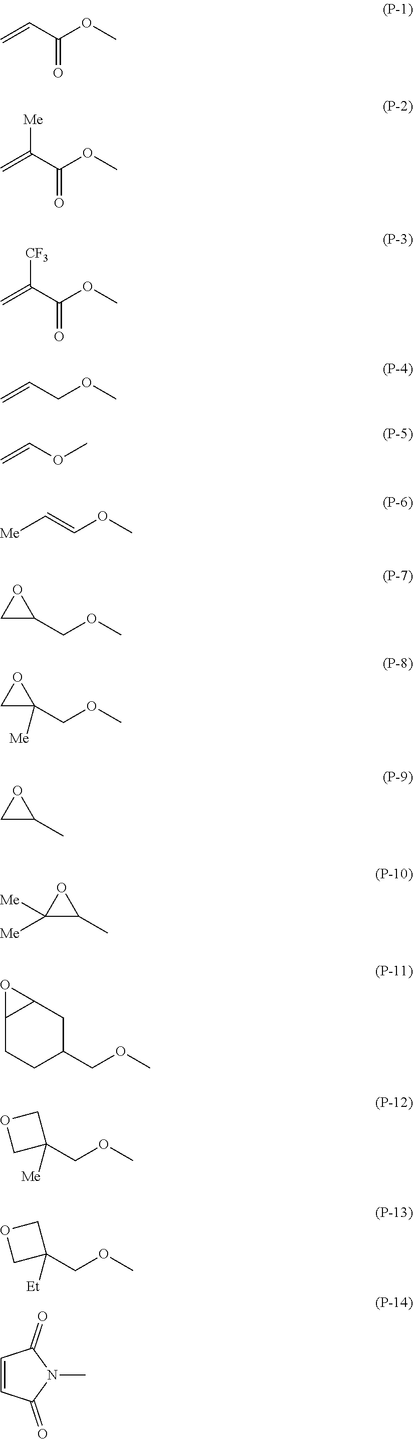

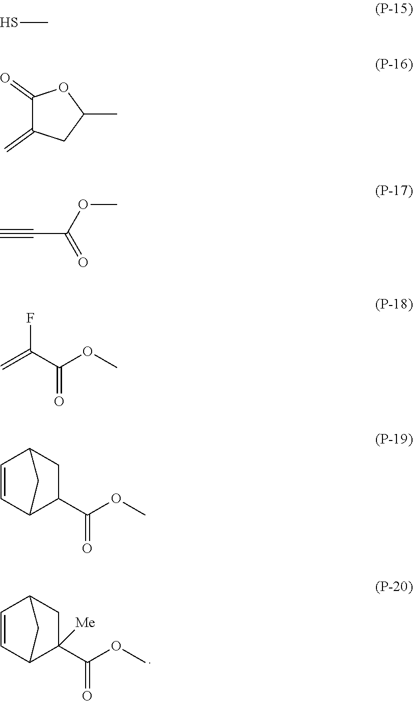

5. A polymer of the polymerizable composition according to claim 1.

6. An optically anisotropic body obtained by using the polymer according to claim 5.

7. A display element comprising the polymer according to claim 5.

8. A light-emitting element comprising the polymer according to claim 5.

9. An organic light-emitting display element comprising the polymer according to claim 5.

10. A display element comprising the optically anisotropic body according to claim 6.

11. A light-emitting element comprising the optically anisotropic body according to claim 6.

12. An organic light-emitting display element comprising the optically anisotropic body according to claim 6.
